(19) United States
(12) Patent Application Publication
(10) Pub. No.: US 2026/0247862 A1
(43) Pub. Date: Aug. 20, 2026

(54) LIGHT EMITTING ELEMENT, FUSED POLYCYCLIC COMPOUND FOR LIGHT-EMITTING ELEMENT, AND ELECTRONIC DEVICE INCLUDING LIGHT-EMITTING ELEMENT

(71) Applicant: Samsung Display Co., Ltd., Yongin-si (KR)

(72) Inventors: Jeongeun KIM, Yongin-si (KR); Hirokazu KUWABARA, Yokohama-shi (JP); Keigo HOSHI, Yokohama-shi (JP); Tetsuji HAYANO, Yokohama-shi (JP); Yasuhiko ASHIKARI, Yokohama-shi (JP); Yoshiro SUGITA, Yokohama-shi (JP); Yuma AOKI, Yokohama-shi (JP); Makoto YAMAMOTO, Yokohama-shi (JP); Naoya OKADA, Yokohama-shi (JP); Nobutaka AKASHI, Yokohama-shi (JP); Toshiyuki MATSUURA, Yokohama-shi (JP); Yuta KAWANO, Yokohama-shi (JP); Yuuki MIYAZAKI, Yokohama-shi (JP)

(73) Assignee: Samsung Display Co., Ltd., Yongin-si (KR)

(21) Appl. No.: 19/430,807

(22) Filed: Dec. 23, 2025

(30) Foreign Application Priority Data
Feb. 20, 2025 (JP) 2025-025793

(51) Int. Cl. H10K 85/60; C07F 5/02; C09K 11/02; C09K 11/06; H10K 50/12

(52) U.S. Cl. CPC H10K 85/658; C07F 5/027; C09K 11/02; C09K 11/06; H10K 85/6572; C09K 2211/1007; C09K 2211/1018; H10K 50/12

(57) ABSTRACT

Provided is a light-emitting element including a first electrode, a second electrode on the first electrode, and an emission layer between the first electrode and the second electrode, the emission layer including a first compound represented by Formula 1:

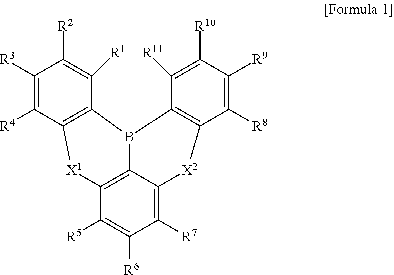

In Formula 1, R¹ to R¹¹, X¹, and X² are the same as described in the detailed description.

### CROSS-REFERENCE TO RELATED APPLICATIONS

This U.S. non-provisional patent application claims priority under 35 U.S.C. § 119 of Japanese Patent Application No. JP-2025-025793, filed on Feb. 20, 2025, the entire contents of which are hereby incorporated by reference.

### BACKGROUND

The present inventive concepts herein relate to light-emitting elements, fused polycyclic compounds that may be used in light-emitting elements, and electronic apparatuses including light-emitting elements.

As a display device included in an electronic apparatus, an organic electroluminescence display device including an organic light-emitting element is used. The organic electroluminescence display device is a display device including so-called self-luminous type light-emitting element, which injects, in an emission layer, holes and electrons respectively from a first electrode and a second electrode, thereby emitting light using an emission material in the emission layer to implement displaying.

### SUMMARY

Some example embodiments of the present inventive concepts provide a light-emitting element having improved element lifespan. Such a light-emitting element may improve the light efficiency and lifespan of a display device including same.

Some example embodiments of the present inventive concepts provide a fused polycyclic compound that is capable of improving an element lifespan of a light-emitting element.

Some example embodiments of the present inventive concepts provide an electronic apparatus having excellent display quality by including a light-emitting element having an improved lifespan.

Some example embodiments of the inventive concepts provide a light-emitting element including a first electrode, a second electrode disposed on the first electrode, and an emission layer disposed between the first electrode and the second electrode and including a first compound represented by Formula 1 below.

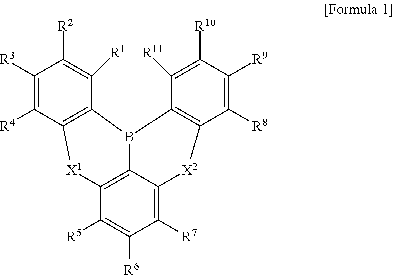

In Formula 1 above, R¹ to R¹¹ may each independently be a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to each other to form a ring, a continuous two or three selected from each of R¹ to R⁴ and R¹ to R¹¹ are each connected to a separate group represented by Formula 2, such that the first compound includes two separate groups that are each represented by Formula 2, one of the two separate groups is connected to a continuous two or three of R¹ to R⁴ of Formula 1, and another one of the two separate groups is connected to a continuous two or three of R¹ to R¹¹ of Formula 1, and X¹ and X² are each independently O, S, or Se, or represented by any one among Formula 3 to Formula 5 below.

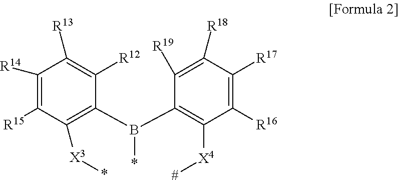

In Formula 2 above, R¹² to R¹⁹ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to each other to form a ring, X³ and X⁴ are each independently O, S, or Se, or represented by any one among Formula 3 to Formula 5 below, [symbol] is a position to which Formula 1 above is connected, and [symbol] is a position to which PGP-2 ART [symbol] Formula 1 above is connected or R¹² in Formula 2 above is connected.

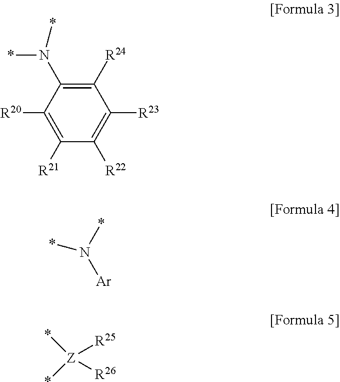

In Formula 3 to Formula 5 above, [symbol] is a position to which Formula 1 or Formula 2 above is connected, R²⁰ to R²⁶ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, at least one among R²⁰ or R²⁴ is a substituted or unsubstituted aryl group having 6 to 30 ring-forming carbon atoms, Ar is a substituted or unsubstituted aryl group having 10 to 30 ring-forming carbon atoms, Z is a carbon atom or a silicon atom, wherein when Z is a silicon atom, R²⁵ and R²⁶ are not hydrogen atoms, at least one among X¹ to X⁴ is represented by Formula 3 above, when X¹ and X² in Formula 1 are represented by Formula 4, Ar in Formula 4 is not a fluorenyl group or a heteroaryl group, and when at least one of X¹ or X² in Formula 1 is represented by Formula 3, at least one of R²⁰ or R²⁴ in Formula 3 is a substituted or unsubstituted aryl group having 6 to 30 ring-forming carbon atoms.

In some example embodiments, the emission layer may include a host and a dopant, and the dopant may include a first compound represented by Formula 1 above.

In some example embodiments, at least two among X¹ to X⁴ may be represented by Formula 3 above.

In some example embodiments, Formula 3 above may be represented by Formula 3-1 or Formula 3-2 below.

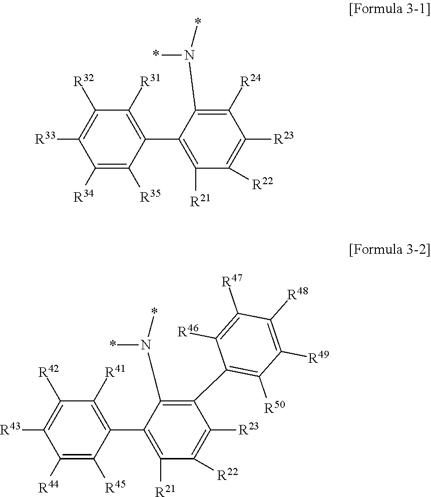

In Formula 3-1 and Formula 3-2 above, [symbol] may be a position at which Formula 2 or Formula 3 above is connected, R³¹ to R³⁵, and R⁴¹ to R⁵⁰ may be each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula 3-1 and Formula 3-2 above, the descriptions defined in Formula 3 above may be similarly applied to R²¹ to R²⁴ such that R²¹ to R²⁴ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In some example embodiments, the first compound represented by Formula 1 above may be represented by Formula 1-1-1 or Formula 1-1-2 below.

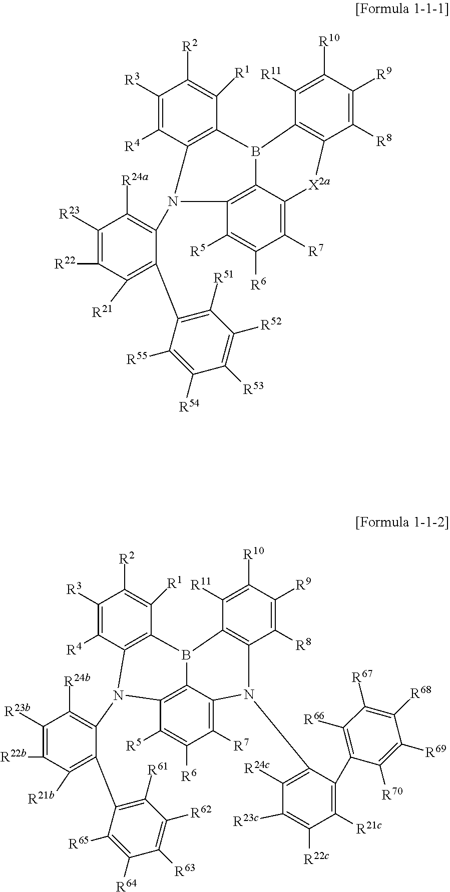

In Formula 1-1-1 and Formula 1-1-2 above, X^{2a} may be O, S, or Se, or represented by Formula 4 or Formula 5 above, R^{24a} may be a substituted or unsubstituted aryl group having 6 to 30 ring-forming carbon atoms, R⁵¹ to R⁵⁵, R⁶¹ to R⁷⁰, R^{21b} to R^{24b}, and R^{21c} to R^{24c} may be each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula 1-1-1 and Formula 1-1-2 above, the descriptions described in Formula 1 above may be similarly applied to R¹ to R¹¹ such that R¹ to R¹¹ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to each other to form a ring.

In some example embodiments, the first compound represented by Formula 1 above may be represented by Formula 1-2 below.

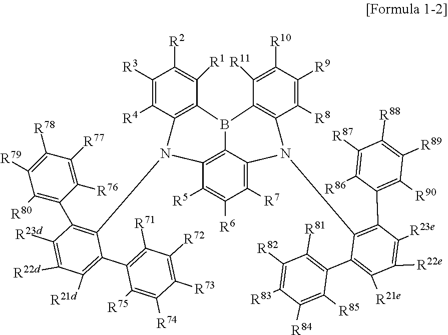

In Formula 1-2 above, R⁷¹ to R⁹⁰, R^{21d} to R^{23d}, and R^{21e} to R^{23e} may be each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula 1-2 above, the descriptions described in Formula 1 above may be similarly applied to R¹ to R¹¹ such that R¹ to R¹¹ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to each other to form a ring.

In some example embodiments, the first compound represented by Formula 1 above may be represented by any one among Formula 1-3-1 to Formula 1-3-3 below.

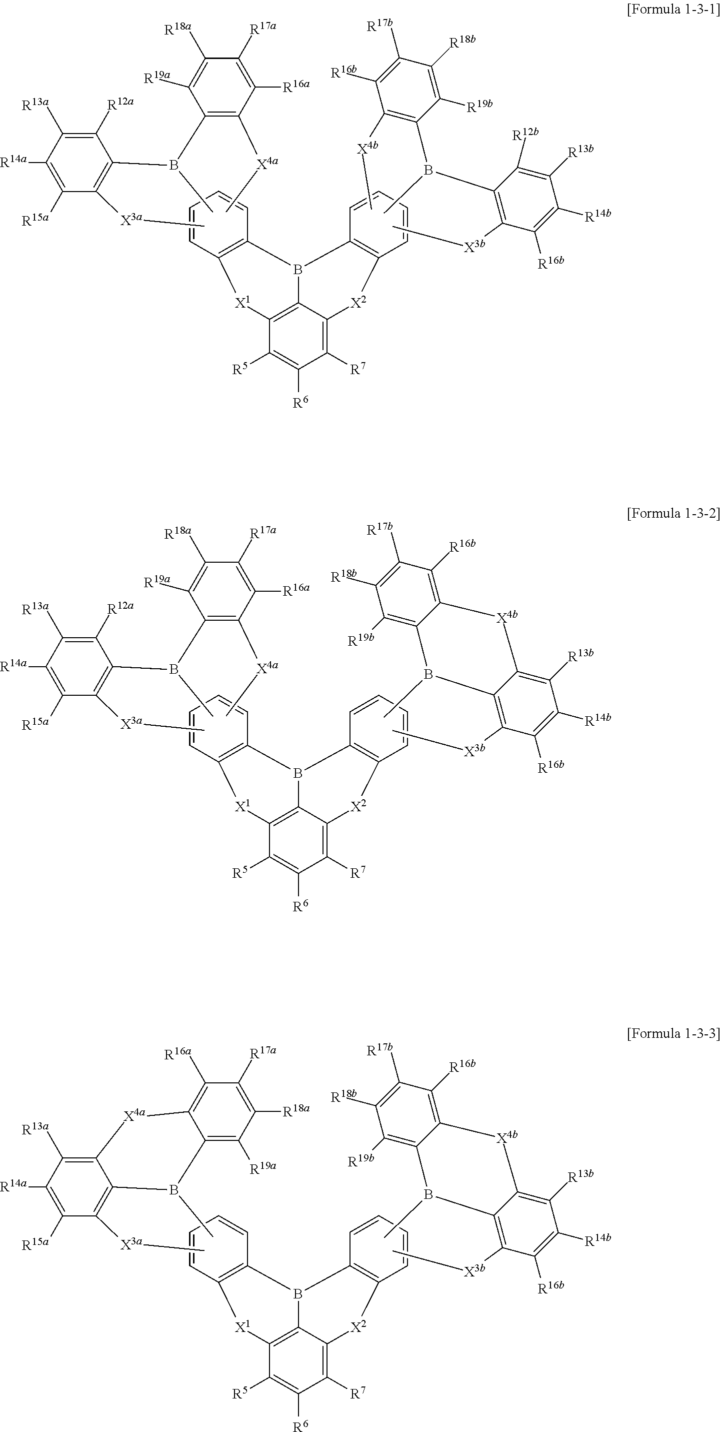

In Formula 1-3-1 to Formula 1-3-3 above, X^{3a}, X^{3b}, X^{4a}, and X^{4b} may be each independently O, S, or Se, or represented by any one among Formula 3 to Formula 5 above, and R^{12a} to R^{19a}, and R^{12b} to R^{19b} are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula 1-3-1 to Formula 1-3-3 above, the descriptions described in Formula 1 above may be similarly applied to X¹, X², and R⁵ to R⁷ such that X¹ and X² are each independently O, S, or Se, or represented by any one among Formula 3 to Formula 5, and R⁵ to R⁷ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to each other to form a ring.

In some example embodiments, the first compound represented by Formula 1 above may be represented by any one among Formula 1-4-1 to Formula 1-4-3 below.

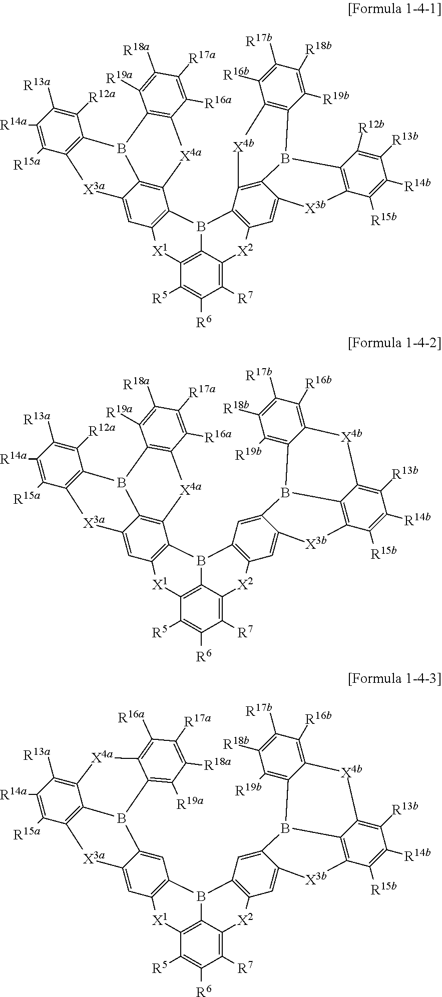

In Formula 1-4-1 to Formula 1-4-3 above, X^{3a}, X^{3b}, X^{4a}, and X^{4b} may be each independently O, S, or Se, or represented by any one among Formula 3 to Formula 5 above, and R^{12a} to R^{19a}, and R^{12b} to R^{19b} may be each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula 1-4-1 to Formula 1-4-3 above, the descriptions described in Formula 1 above may be applied to X¹, X², and R⁵ to R⁷ such that X¹ and X² are each independently O, S, or Se, or represented by any one among Formula 3 to Formula 5, and R⁵ to R⁷ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to each other to form a ring.

In some example embodiments, the emission layer may further include at least one among a second compound represented by Formula HT-1 below, a third compound represented by Formula ET-1 below, and a fourth compound represented by Formula D-1 below.

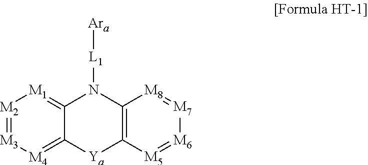

In Formula HT-1 above, M₁ to M₈ may be each independently N or CR₅₁, L₁ may be a direct linkage, a substituted or unsubstituted arylene group having 6 to 30 ring-forming carbon atoms, or a substituted or unsubstituted heteroarylene group having 2 to 30 ring-forming carbon atoms, Yₐ may be a direct linkage, CR₅₂R₅₃, or SiR₅₄R₅₅, Arₐ may be a substituted or unsubstituted aryl group having 6 to 30 ring-forming carbon atoms, or a substituted or unsubstituted heteroaryl group having 2 to 30 ring-forming carbon atoms, and R₅₁ to R₅₅ may be each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to each other to form a ring.

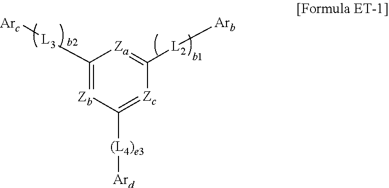

In Formula ET-1 above, at least one among Zₐ to Z_{c} may be N, and a remainder of Zₐ to Z_{c} may each be CR₅₆, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, b1 to b3 may be each independently an integer of 0 to 10, Ar_{b} to Ar_{d} may be each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and L₂ to L₄ may be each independently a direct linkage, a substituted or unsubstituted arylene group having 6 to 30 ring-forming carbon atoms, or a substituted or unsubstituted heteroarylene group having 2 to 30 ring-forming carbon atoms.

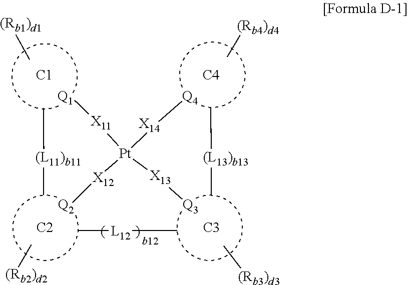

In Formula D-1 above, Q₁ to Q₄ are each independently C or N, C1 to C4 may be each independently a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle having 2 to 30 ring-forming carbon atoms, X₁₁ to X₁₄ are each independently a direct linkage or [symbol] L₁₁ to L₃ are each independently, a direct linkage,

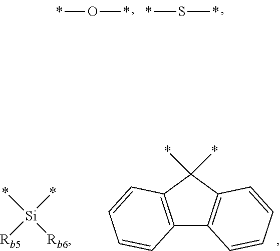

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, b11 to b13 are each independently 0 or 1, R_{b1} to R_{b4} are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and d1 to d4 are each independently an integer of 0 to 4.

In some example embodiments of the inventive concepts, an electronic apparatus includes a base layer, a circuit layer on the base layer, and a display element layer on the circuit layer and including a light-emitting element, and the light-emitting element includes a first electrode, a second electrode on the first electrode, and an emission layer between the first electrode and the second electrode and including a first compound represented by Formula 1 above.

In some example embodiments, the light-emitting element may further include a capping layer on the second electrode, and the capping layer may have a refractive index of about 1.6 or greater for light with a wavelength in a range of about 550 nm to about 660 nm.

In some example embodiments, the electronic apparatus may further include an optical control layer disposed on the display element layer and including quantum dots, the light-emitting element may be configured to emit first color light, and the optical control layer may include a first optical control part which includes a first quantum dot configured to convert the first color light into a second color light in a longer wavelength region than the first color light, a second optical control part which includes a second quantum dot configured to convert the first color light into a third color light in a longer wavelength region than the first color light and the second color light, and a third optical control part which is configured to transmit the first color light.

In some example embodiments, the electronic apparatus may further include a color filter layer disposed on the optical control layer, and the color filter layer may include a first color filter configured to selectively transmit the second color light, a second color filter configured to selectively transmit the third color light, and a third color filter configured to selectively transmit the first color light.

In some example embodiments, the electronic apparatus may be selected from: a large-sized display device including at least one of a television, a monitor, or an outdoor billboard, and a medium- or small-sized display device including at least one of a computer, a laptop computer, a personal digital assistant, a vehicular display device, a game console, a portable electronic device, or a camera.

In some example embodiments of the inventive concepts, a fused polycyclic compound is represented by Formula 1 above.

### BRIEF DESCRIPTION OF THE DRAWINGS

The accompanying drawings are included to provide a further understanding of the inventive concepts, and are incorporated in and constitute a part of this specification. The drawings illustrate some example embodiments of the inventive concepts and, together with the description, serve to explain principles of the inventive concepts. In the drawings:

FIG. 1 is a block diagram of an electronic apparatus according to some example embodiments;

FIG. 2 shows schematic views of an electronic apparatus according to some example embodiments;

FIG. 3 is a plan view of a display module according to some example embodiments of the inventive concepts;

FIG. 4 is a cross-sectional view of a display module according to some example embodiments of the inventive concepts;

FIG. 5 is a cross-sectional view schematically illustrating a light-emitting element according to some example embodiments of the inventive concepts;

FIG. 6 is a cross-sectional view schematically illustrating a light-emitting element according to some example embodiments of the inventive concepts;

FIG. 7 is a cross-sectional view schematically illustrating a light-emitting element according to some example embodiments of the inventive concepts;

FIG. 8 is a cross-sectional view schematically illustrating a light-emitting element according to some example embodiments of the inventive concepts;

FIG. 9 and FIG. 10 are each a cross-sectional view of a display module of according to some example embodiments of the inventive concepts;

FIG. 11 is a cross-sectional view illustrating a display module according to some example embodiments of the inventive concepts;

FIG. 12 is a cross-sectional view illustrating a display module according to some example embodiments of the inventive concepts;

FIG. 13 is a perspective view of an electronic apparatus according to some example embodiments;

FIG. 14 is a perspective view of an electronic apparatus according to some example embodiments;

FIG. 15 is a view illustrating a vehicle in which a display device according to some example embodiments is disposed;

FIG. 16 is a view showing a three-dimensional molecular model of Comparative Example Compound;

FIG. 17A and FIG. 17B are each a view showing a three-dimensional molecular model of Example Compound; and

FIG. 18A and FIG. 18B are each a view showing a three-dimensional molecular model of Example Compound.

### DETAILED DESCRIPTION

The inventive concepts may have various modifications and may be embodied in different forms, and example embodiments will be explained in detail with reference to the accompanying drawings. The inventive concepts may, however, be embodied in different forms and should not be construed as limited to the example embodiments set forth herein. Rather, all modifications, equivalents, and substituents which are included in the spirit and technical scope of the inventive concepts should be included in the inventive concepts.

Like reference numerals refer to like elements throughout. In the drawings, the dimensions of structures are exaggerated for clarity of illustration. It will be understood that, although the terms first, second, etc. may be used herein to describe various elements, these elements should not be limited by these terms. These terms are only used to distinguish one element from another element. Thus, a first element could be termed a second element without departing from the teachings of the present invention. Similarly, a second element could be termed a first element. As used herein, the singular forms are intended to include the plural forms as well, unless the context clearly indicates otherwise.

In the present specification, it will be further understood that the terms “comprises” and/or “comprising,” when used in this specification, specify the presence of stated features, numerals, steps, operations, elements, parts, or the combination thereof, but do not preclude the presence or addition of one or more other features, numerals, steps, operations, elements, parts, or the combination thereof.

In the present specification, when a layer, a film, a region, a plate, etc. is referred to as being “on” or “above” another part, it can be “directly on” the other part, or intervening layers may also be present. On the contrary, when a layer, a film, a region, a plate, etc. is referred to as being “under” or “below” another part, it can be “directly under” the other part, or intervening layers may also be present. Also, when an element is referred to as being disposed “on” another element, it can be disposed under the other element.

In the present specification, the term “substituted or unsubstituted” corresponds to substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In addition, each of the exemplified substituents may be substituted or unsubstituted. For example, a biphenyl group may be interpreted as an aryl group or a phenyl group substituted with a phenyl group.

In the present specification, the term “forming a ring via the combination with an adjacent group” may mean forming a substituted or unsubstituted hydrocarbon ring, or a substituted or unsubstituted heterocycle via the combination with an adjacent group. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocycles or polycycles. In addition, the ring formed via the combination with each other may be combined with another ring to form a spiro structure.

In the present specification, the term “an adjacent group” may mean a substituent substituted for an atom which is directly connected to an atom substituted with a corresponding substituent, another substituent substituted for an atom which is substituted with a corresponding substituent, or a substituent sterically positioned at the nearest position to a corresponding substituent. For example, in 1,2-dimethylbenzene, two methyl groups may be interpreted as “adjacent groups” to each other, and in 1,1-diethylcyclopentane, two ethyl groups may be interpreted as “adjacent groups” to each other. In addition, in 4,5-dimethylphenanthrene, two methyl groups may be interpreted as “adjacent groups” to each other.

In the present specification, examples of a halogen atom may be a fluorine atom, a chlorine atom, a bromine atom or an iodine atom.

In the present specification, an alkyl group may be linear, branched, or cyclic. The carbon number of the alkyl group may be 1 to 50, 1 to 30, 1 to 20, 1 to 10, or 1 to 6. Examples of the alkyl group may include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, cyclopentyl, 1-methylpentyl, 3-methylpentyl, 2-ethylpentyl, 4-methyl-2-pentyl, n-hexyl, 1-methylhexyl, 2-ethylhexyl, 2-butylhexyl, cyclohexyl, 4-methylcyclohexyl, 4-t-butylcyclohexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, cyclooctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldocecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-henicosyl, n-docosyl, n-tricosyl, n-tetracosyl, n-pentacosyl, n-hexacosyl, n-heptacosyl, n-octacosyl, n-nonacosyl, n-triacontyl, cyclopropyl, cyclobutyl, cyclopentyl, cyclohexyl, 4-methylcyclohexyl, 4-t-butylcyclohexyl, cycloheptyl, cyclooctyl, cyclononyl, cyclodecyl, norbornyl, 1-adamantyl, 2-adamantyl, isobornyl, bicycloheptyl, etc., without limitation.

In the present specification, an alkenyl group means a hydrocarbon group including one or more carbon double bonds in the middle or at the terminal of an alkyl group having a carbon number of 2 or more. The alkenyl group may be linear chain or branched. The carbon number is not specifically limited, but may be 2 to 30, 2 to 20, or 2 to 10. Examples of the alkenyl group include a vinyl group, a 1-butenyl group, a 1-pentenyl group, a 1,3-butadienyl aryl group, a styrenyl group, a styrylvinyl group, etc., without limitation.

In the present specification, an alkynyl group means a hydrocarbon group including one or more carbon triple bonds in the middle or at the terminal of an alkyl group having a carbon number of 2 or more. The alkynyl group may be linear chain or branched. The carbon number is not specifically limited, but may be 2 to 30, 2 to 20, or 2 to 10. Specific examples of the alkynyl group include an ethynyl group, a propynyl group, etc., without limitation.

In the present specification, a hydrocarbon ring group means an arbitrary functional group or substituent derived from an aliphatic hydrocarbon ring. The hydrocarbon ring group may be a saturated hydrocarbon ring group of 5 to 20 ring-forming carbon atoms.

In the present specification, an aryl group means an arbitrary functional group or substituent derived from an aromatic hydrocarbon ring. The aryl group may be a monocyclic aryl group or a polycyclic aryl group. The ring-forming carbon number of the aryl group may be 6 to 30, 6 to 20, or 6 to 15. Examples of the aryl group may include phenyl, naphthyl, fluorenyl, anthracenyl, phenanthrenyl, biphenylyl, terphenylyl, quaterphenylyl, quinquephenylyl, sexyphenylyl, triphenylenyl, pyrenyl, benzofluoranthene, chrysene, etc., without limitation.

In the present specification, a fluorenyl group may be substituted, and two substituents may be combined with each other to form a spiro structure. Examples in which the fluorenyl group is substituted are as follows, but some example embodiments of the inventive concepts are not limited thereto.

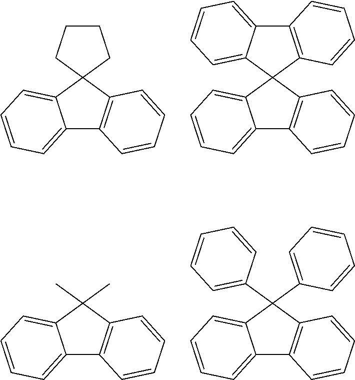

In the present specification, a heterocyclic group means an arbitrary functional group or substituent derived from a ring including one or more among B, O, N, P, Si and S as a heteroatom. The heterocyclic group includes an aliphatic heterocyclic group and an aromatic heterocyclic group. The aromatic heterocyclic group may be a heteroaryl group. The aliphatic heterocyclic group and the aromatic heterocyclic group may be a monocycle or a polycycle.

In the present specification, a heterocyclic group may include one or more among B, O, N, P, Si, and S as a heteroatom. When the heterocyclic group includes two or more heteroatoms, the two or more heteroatoms may be the same as or different from each other. The heterocyclic group may be a monocyclic heterocyclic group or a polycyclic heterocyclic group, and is a concept including a heteroaryl group. The ring-forming carbon number of the heterocyclic group may be 2 to 30, 2 to 20, or 2 to 10.

In the present specification, an aliphatic heterocyclic group may include one or more among B, O, N, P, Si and S as a heteroatom. The ring-forming carbon number of the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., without limitation.

In the present specification, a heteroaryl group may include one or more among B, O, N, P, Si, and S as a heteroatom. When the heteroaryl group includes two or more heteroatoms, the two or more heteroatoms may be the same as or different from each other. The heteroaryl group may be a monocyclic heterocyclic group or polycyclic heterocyclic group. The ring-forming carbon number of the heteroaryl group may be 2 to 30, 2 to 20, or 2 to 10. Examples of the heteroaryl group may include thienyl, furyl, pyrrolyl, imidazolyl, pyridyl, bipyridinyl, and bipyridinyl groups, triazolyl, acridinyl, pyridazinyl, pyrazinyl, quinolyl, and quinazolinyl, quinoxalinyl, phenoxazinyl, phthalazinyl, and pyridopyrimidinyl, pyridopyrazinyl, pyrazinopyrazinyl, isoquinolinyl, indolyl, carbazolyl, N-arylcarbazolyl group, N-heteroarylcarbazolyl group, N-alkylcarbazolyl group, benzoxazolyl group, benzoxazolyl group, benzoimidazolyl, benzothiazolyl, benzocarbazolyl, benzothiophenyl, and dibenzothiophenyl, thienothiophenyl, benzofuranyl, phenanthrolinyl, thiazolyl, isoxazolyl, and oxazolyl, oxadiazolyl, thiadiazolyl, phenothiazinyl, dibenzosilolyl, dibenzofuranyl, dibenzofuranyl, etc., without limitation.

In the present specification, the description on the aryl group may be applied to an arylene group except that the arylene group is a divalent group. The description on the heteroaryl group may be applied to a heteroarylene group except that the heteroarylene group is a divalent group.

In the present specification, a silyl group includes an alkyl silyl group and an aryl silyl group. Examples of the silyl group include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., without limitation.

In the present specification, the carbon number of a carbonyl group is not specifically limited, but the carbon number may be 1 to 40, 1 to 30, or 1 to 20. For example, the carbonyl group may have the structures below, but is not limited thereto.

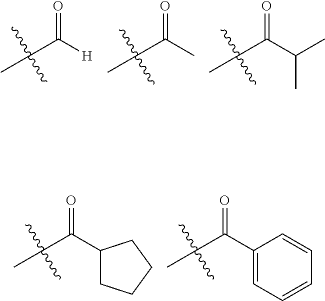

In the present specification, the carbon number of a sulfinyl group and sulfonyl group is not specifically limited, but may be 1 to 30. The sulfinyl group may include an alkyl sulfinyl group and an aryl sulfinyl group. The sulfonyl group may include an alkyl sulfonyl group and an aryl sulfonyl group.

In the present specification, a thio group may include an alkyl thio group and an aryl thio group. The thio group may mean the above-defined alkyl group or aryl group combined with a sulfur atom. Examples of the thio group are a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., without limitation.

In the present specification, an oxy group may mean the above-defined alkyl group or aryl group which is combined with an oxygen atom. The oxy group may include an alkoxy group and an aryl oxy group. The alkoxy group may be linear, branched or cyclic. The carbon number of the alkoxy group is not specifically limited but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc., without limitation.

In the present specification, a boron group may mean the above-defined alkyl group or aryl group which is combined with a boron atom. The boron group includes an alkyl boron group and an aryl boron group. Examples of the boron group include a trimethylboron group, a triethylboron group, a t-butyldimethylboron group, a triphenylboron group, a diphenylboron group, a phenylboron group, etc., without limitation.

In the present specification, the carbon number of an amine group is not specifically limited, but may be 1 to 30. The amine group may include an alkyl amine group and an aryl amine group. Examples of the amine group include a methylamine group, a dimethylamine group, a phenylamine group, a diphenylamine group, a naphthylamine group, a 9-methyl-anthracenylamine group, etc., without limitation.

In the present specification, the alkyl group in the alkylthio group, alkylsulfoxy group, alkylaryl group, alkylamino group, alkylboron group, alkyl silyl group, and alkyl amine group is the same as the examples of the above-described alkyl group.

In the present specification, the aryl group in the aryloxy group, arylthio group, arylsulfoxy group, aryl amino group, arylboron group, aryl silyl group and aryl amine group are the same as the examples of the above-described aryl group.

In the present specification, a direct linkage may mean a single bond.

In the present specification,

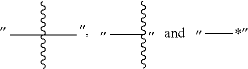

mean positions to be connected and may be interchangeably referred to as linking positions, linking points, or the like.

It will be understood that “one among” multiple elements may be interchangeably referred to as “one of” the multiple elements. It will be understood that “at least one among” multiple elements may be interchangeably referred to as “at least one of” the multiple elements.

In the specification and the claims, the term “and/or” is intended to include arbitrary combinations of the terms “and” and “or” for the purposes of meaning and interpretation. For example, the expression of “A and/or B” may be understood to signify “A, B, or A and B”.

In the specification and claims, the phrase “at least one of” and the phrase “at least one among” is intended to include the meaning of “at least one selected from the group of,” for the purpose of meaning and interpretation. For example, “at least one of A and B” may be understood to signify “A, B, or A and B”. In another example, “at least one among A and B” may be understood to signify “A, B, or A and B”.

In the specification and claims, the phrase “one of” and the phrase “one among” is intended to include the meaning of “one selected from the group of,” for the purpose of meaning and interpretation. For example, “one of A and B” may be understood to signify “A or B”. In another example, “one among A and B” may be understood to signify “A or B”.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the inventive concepts. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

Hereinafter, some example embodiments of the inventive concepts will be described with reference to drawings.

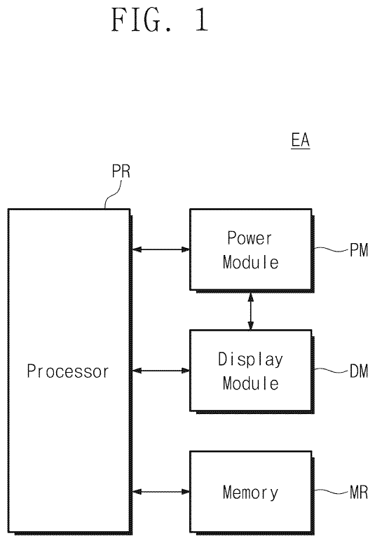

FIG. 1 is a block diagram of an electronic apparatus according to some example embodiments. Referring to FIG. 1, the electronic apparatus EA according to some example embodiments may include a display module DM, a processor PR, a memory MR, and a power module PM.

The processor PR may include at least one among a central processing unit (CPU), an application processor (AP), a graphic processing unit (GPU), a communication processor (CP), an image signal processor (ISP), and a controller.

The memory MR may store data information needed for the operation of the processor PR or the display module DM. When the processor PR executes an application stored in the memory MR, an image data signal and/or an input control signal are/is transmitted to the display module DM, and the display module DM may process the received signal and output image information through a display screen. The display module DM may include a display panel that displays an image.

The power module PM may include a power supply module such as a power adaptor or a battery device, and a power conversion module that converts power supplied by the power supply module to generate power needed for the operation of the electronic apparatus EA.

At least one among the components of the electronic apparatus EA may be included in a display module according to some example embodiments, to be described later, and a display device according to some example embodiments, which includes the same. In addition, some of individual modules functionally included in one module may be included in the display device, and some others may be provided separately from the display device. For example, the display device may include the display module DM, and the processor PR, the memory MR and the power module PM may be provided in the form of other devices within the electronic apparatus EA, not the display device.

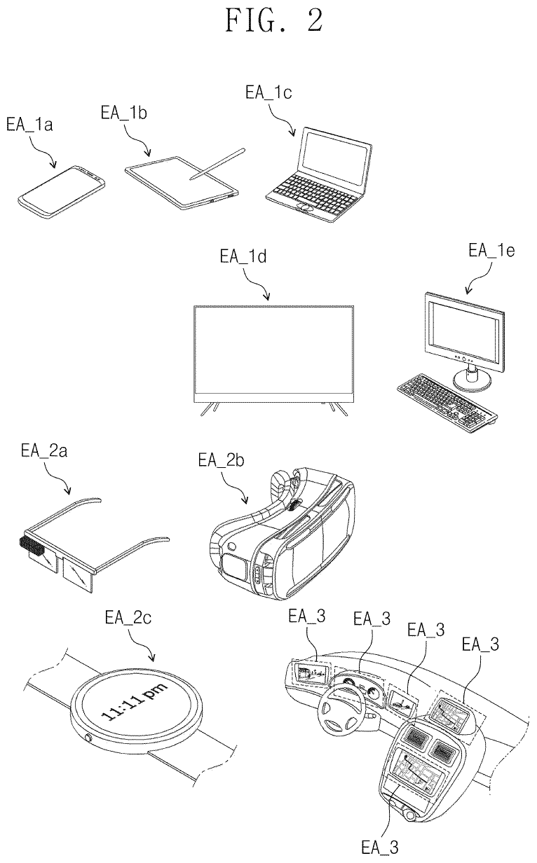

FIG. 2 shows schematic views of electronic apparatuses according to various embodiments.

Referring to FIG. 2, various electronic apparatuses which include the display device according to some example embodiments may include not only an image-displaying electronic apparatus such as a smart phone EA_1a, a tablet PC EA_1b, a laptop computer EA_1c, a TV EA_1d, and a desktop monitor EA_1e, but also a wearable electronic apparatus such as smart glasses EA_2a, a head mounted display EA_2b, or a smart watch EA_2c, and a vehicular electronic apparatus EA_3 such as a car dashboard, a center fascia, a center information display (CID) disposed in a dashboard, or a room mirror display, etc.

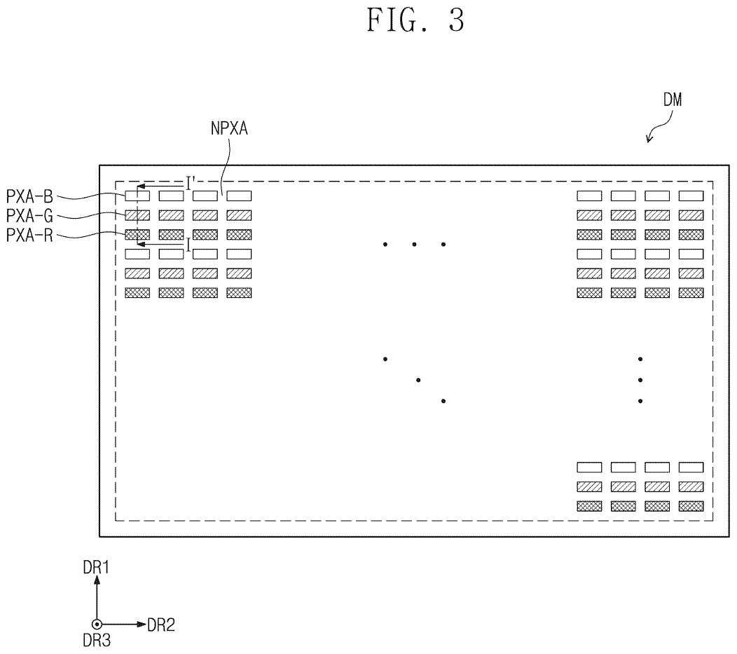

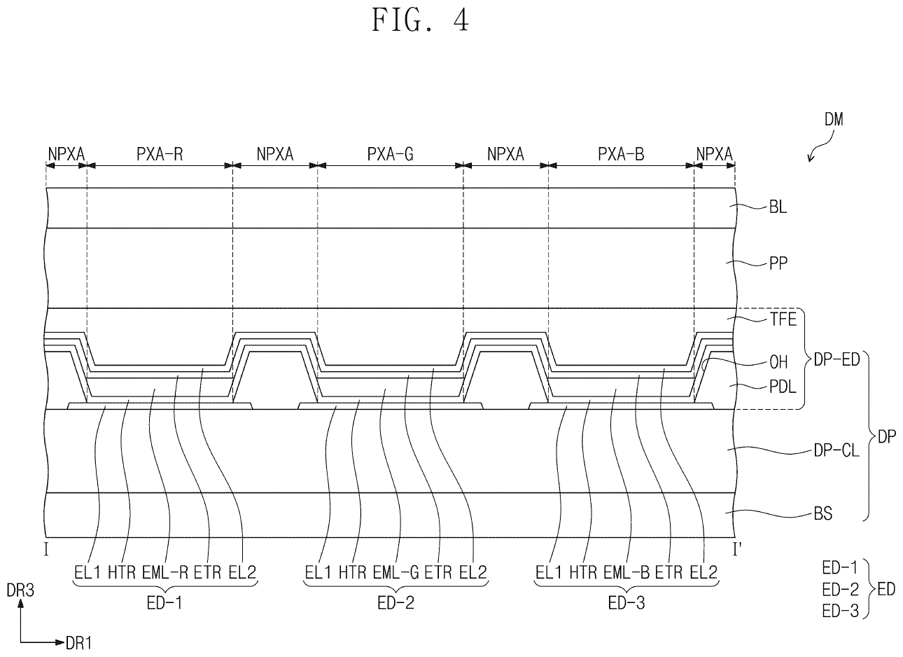

FIG. 3 is a plan view illustrating some example embodiments of a display module DM. FIG. 4 is a cross-sectional view of a display module DM of some example embodiments. FIG. 4 is a cross-sectional view showing a part corresponding to line I-I′ in FIG. 3.

The display module DM may include a plurality of light-emitting elements ED-1, ED-2 and ED-3. In some example embodiments, the display module DM may further include a display panel DP including a plurality of light-emitting elements ED-1, ED-2, and ED-3 and an optical layer PP disposed on the display panel DP.

The display panel DP may include a base layer BS, a circuit layer DP-CL provided on the base layer BS, and a display element layer DP-ED. The display element layer DP-ED may include pixel defining films PDL, a plurality of light-emitting elements ED-1, ED-2, and ED-3 disposed between the pixel defining films PDL, and an encapsulation layer TFE disposed on the plurality of light-emitting elements ED-1, ED-2, and ED-3.

The base layer BS may be a member providing a base surface on which the display element layer DP-ED is disposed. The base layer BS may be a glass substrate, a metal substrate, a plastic substrate, or the like. However, the example embodiments are not limited thereto, and the base layer BS may be an inorganic layer, an organic layer, or a composite material layer.

In some example embodiments, the circuit layer DP-CL may be disposed on the base layer BS, and the circuit layer DP-CL may include a plurality of transistors (not shown). The transistors (not shown) may each include a control electrode, an input electrode, and an output electrode. For example, the circuit layer DP-CL may include a switching transistor and a driving transistor for driving the light-emitting elements ED-1, ED-2 and ED-3 of the display element layer DP-ED.

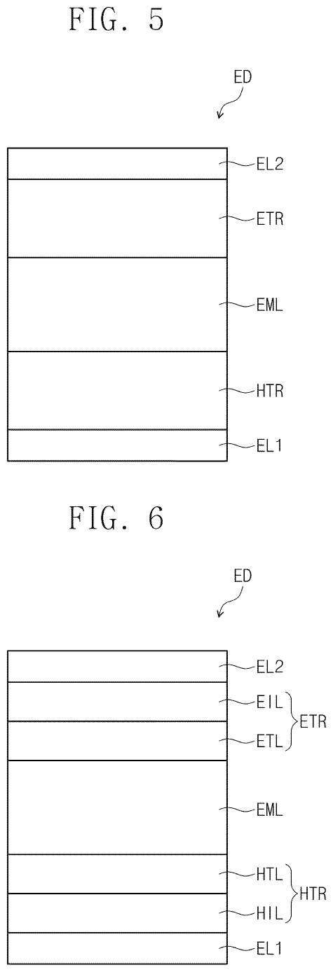

The light-emitting elements ED-1, ED-2, and ED-3 may each have a structure of a light-emitting element ED of some example embodiments from FIGS. 5 to 9, which will be described later. The light-emitting elements ED-1, ED-2, and ED-3 may each include a first electrode EL1, a hole transport region HTR, emission layers EML-R, EML-G, and EML-B, an electron transport region ETR, and a second electrode EL2.

The optical layer PP may be disposed on the display panel DP to control reflected light in the display panel DP due to external light. The optical layer PP may include, for example, a polarizing layer or a color filter layer. Unlike what is shown in the drawings, the optical layer PP may not be provided in the display module DM of some example embodiments.

A base substrate BL may be disposed on the optical layer PP. The base substrate BL may be a member providing a base surface on which the optical layer PP is disposed. The base substrate BL may be a glass substrate, a metal substrate, a plastic substrate, or the like. However, the example embodiments are not limited thereto, and the base substrate BL may be an inorganic layer, an organic layer, or a composite material layer. In addition, unlike what is shown, the base substrate BL may not be provided in some example embodiments.

The display module DM according to some example embodiments may further include a filling layer (not shown). The filling layer (not shown) may be disposed between a display element layer DP-ED and the base substrate BL. The filling layer (not shown) may be an organic material layer. The filling layer (not shown) may include at least one of an acrylic resin, a silicone-based resin, or an epoxy-based resin.

FIG. 4 shows some example embodiments in which the emission layers EML-R, EML-G, and EML-B of the light-emitting elements ED-1, ED-2, and ED-3 are disposed in openings OH defined in the pixel defining films PDL, and the hole transport region HTR, the electron transport region ETR, and the second electrode EL2 are provided as a common layer throughout the light-emitting elements ED-1, ED-2, and ED-3. However, the example embodiments are not limited thereto, and unlike what is shown in FIG. 4, in some example embodiments, the hole transport region HTR and the electron transport region ETR may be provided to be patterned inside the openings OH defined in the pixel defining films PDL. For example, in some example embodiments, the hole transport region HTR, the emission layers EML-R, EML-G, and EML-B, and the electron transport region ETR of the light-emitting elements ED-1, ED-2, and ED-3 may be patterned and provided through an inkjet printing method.

The encapsulation layer TFE may cover the light-emitting elements ED-1, ED-2 and ED-3. The encapsulation layer TFE may seal the display element layer DP-ED. The encapsulation layer TFE may be a thin film encapsulation layer. The encapsulation layer TFE may be a single layer or a stack layer of a plurality of layers. The encapsulation layer TFE includes at least one insulating layer. The encapsulation layer TFE according to some example embodiments may include at least one inorganic film (hereinafter, an encapsulation inorganic film). In addition, the encapsulation layer TFE according to some example embodiments may include at least one organic film (hereinafter, an encapsulation organic film) and at least one encapsulation inorganic film.

The encapsulation inorganic film protects the display element layer DP-ED from moisture/oxygen, and the encapsulation organic film protects the display element layer DP-ED from foreign substances such as dust particles. The encapsulation inorganic film may include silicon nitride, silicon oxy nitride, silicon oxide, titanium oxide, aluminum oxide, or the like, but is not particularly limited thereto. The encapsulation organic film may include an acrylic compound, an epoxy-based compound, or the like. The encapsulation organic film may include a photopolymerizable organic material, and is not particularly limited.

The encapsulation layer TFE may be disposed on the second electrode EL2, and may be disposed to fill the openings OH.

Referring to FIGS. 3 and 4, the display module DM may include non-light emitting regions NPXA and light emitting regions PXA-R, PXA-G, and PXA-B. The light emitting regions PXA-R, PXA-G, and PXA-B may each be a region emitting light generated from each of the light-emitting elements ED-1, ED-2, and ED-3. The light emitting regions PXA-R, PXA-G, and PXA-B may be spaced apart from each other when viewed on a plane.

The light emitting regions PXA-R, PXA-G, and PXA-B may each be a region separated by the pixel defining films PDL. The non-light emitting regions NPXA may be regions between neighboring light emitting regions PXA-R, PXA-G, and PXA-B, and may correspond to the pixel defining films PDL. Herein, the light emitting regions PXA-R, PXA-G, and PXA-B may each correspond to a pixel. The pixel defining films PDL may separate the light-emitting elements ED-1, ED-2 and ED-3. The emission layers EML-R, EML-G, and EML-B of the light-emitting elements ED-1, ED-2 and ED-3 may be disposed in the openings OH defined by the pixel defining films PDL and thus be separated.

The light emitting regions PXA-R, PXA-G, and PXA-B may be divided into a plurality of groups according to the color of light generated from the light-emitting elements ED-1, ED-2, and ED-3. In the display module DM of some example embodiments shown in FIGS. 3 and 4, three light emitting regions PXA-R, PXA-G, and PXA-B which emit red light, green light, and blue light, are shown as an example. For example, the display module DM of some example embodiments may include a red light emitting region PXA-R, a green light emitting region PXA-G, and a blue light emitting region PXA-B, which are distinct from one another.

In the display module DM according to some example embodiments, the plurality of light-emitting elements ED-1, ED-2, and ED-3 may emit light having different wavelength ranges. For example, in some example embodiments, the display module DM may include a first light-emitting element ED-1 emitting red light, a second light-emitting element ED-2 emitting green light, and a third light-emitting element ED-3 emitting blue light. That is, the red light emitting region PXA-R, the green light emitting region PXA-G, and the blue light emitting region PXA-B of the display module DM may correspond to the first light-emitting element ED-1, the second light-emitting element ED-2, and the third light-emitting element ED-3, respectively.

However, the example embodiments are not limited thereto, and the first to third light-emitting elements ED-1, ED-2 and ED-3 may emit light in the same wavelength range or emit light in at least one different wavelength range. For example, the first to third light-emitting elements ED-1, ED-2, and ED-3 may all emit blue light.

The light emitting regions PXA-R, PXA-G, and PXA-B in the display module DM according to some example embodiments may be arranged in the form of a stripe. Referring to FIG. 3, a plurality of red light emitting regions PXA-R, a plurality of green light emitting regions PXA-G, and a plurality of blue light emitting regions PXA-B may each be arranged along a second directional axis DR2. In some example embodiments, the red light emitting region PXA-R, the green light emitting region PXA-G, and the blue light emitting region PXA-B may be alternately arranged in that order along a first directional axis DR1.

FIGS. 3 and 4 show that the light emitting regions PXA-R, PXA-G, and PXA-B are all similar in size, but the example embodiments are not limited thereto, and the light emitting regions PXA-R, PXA-G, and PXA-B may be different in size from each other according to wavelength range of emitted light. The areas of the light emitting regions PXA-R, PXA-G, and PXA-B may indicate areas when viewed on a plane defined by the first directional axis DR1 and the second directional axis DR2.

The arrangement of the light emitting regions PXA-R, PXA-G, and PXA-B is not limited to what is shown in FIG. 3, and the order in which the red light emitting region PXA-R, the green light emitting region PXA-G, and the blue light emitting region PXA-B are arranged comes with varied combination according to display quality characteristics required for the display module DM. For example, the light emitting regions PXA-R, PXA-G, and PXA-B may be arranged in the form of a pentile (PENTILE™) or a diamond (Diamond Pixel™).

In addition, areas of each of the light emitting regions PXA-R, PXA-G, and PXA-B may be different in size from one another. For example, in some example embodiments, the green light emitting region PXA-G may be smaller than the blue light emitting region PXA-B in size, but the example embodiments are not limited thereto.

Hereinafter, FIGS. 5 to 8 are cross-sectional views schematically illustrating a light-emitting element according to some example embodiments. The light-emitting element ED according to some example embodiments may be any of the light-emitting elements ED in a display module DM, including for example any of light-emitting elements ED-1, ED-2 and ED-3 of the display module DM as shown in FIGS. 3 and 4. The light-emitting element ED according to some example embodiments may include the first electrode EL1, the second electrode EL2 facing the first electrode EL1, and at least one functional layer disposed between the first electrode EL1 and the second electrode EL2. The light-emitting element ED according to some example embodiments may include a fused polycyclic compound according to some example embodiments to be described later in the at least one functional layer.

The light-emitting element ED may include, as the at least one functional layer, the hole transport region HTR, the emission layer EML, the electron transport region ETR or the like sequentially stacked. That is, the light-emitting element ED according to some example embodiments may include the first electrode EL1, the hole transport region HTR, the emission layer EML, the electron transport region ETR and the second electrode EL2 sequentially stacked.

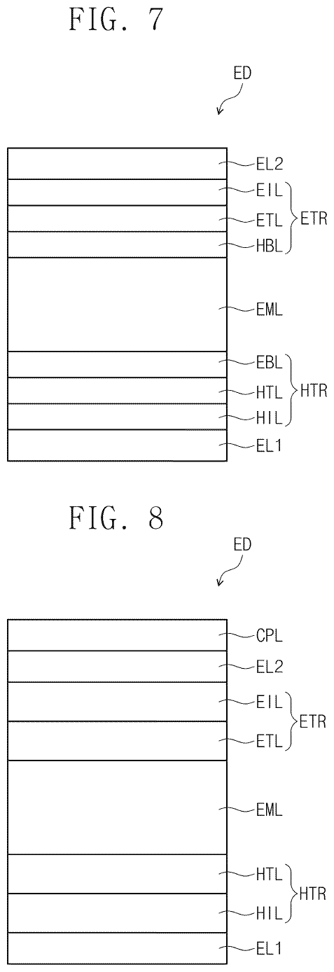

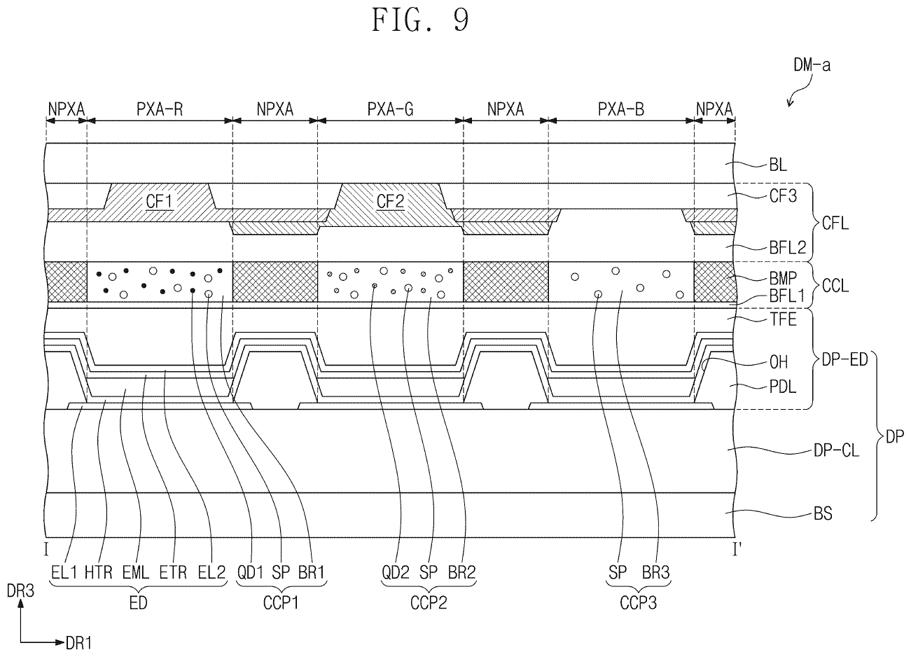

When compared with FIG. 5, FIG. 6 illustrates the cross-sectional view of the light-emitting element ED according to some example embodiments, wherein the hole transport region HTR includes a hole injection layer HIL and a hole transport layer HTL, and the electron transport region ETR includes an electron injection layer EIL and an electron transport layer ETL. In addition, when compared with FIG. 5, FIG. 7 illustrates the cross-sectional view of the light-emitting element ED according to some example embodiments, wherein the hole transport region HTR includes a hole injection layer HIL, a hole transport layer HTL, and an electron blocking layer EBL, and the electron transport region ETR includes an electron injection layer EIL, an electron transport layer ETL, and a hole blocking layer HBL. When compared with FIG. 5, FIG. 8 illustrates the cross-sectional view of the light-emitting element ED according to some example embodiments, including a capping layer CPL disposed on the second electrode EL2.

A light-emitting element ED according to some example embodiments may include a fused polycyclic compound according to some example embodiments, to be described later, in at least one functional layer included in the light-emitting element ED. In the light-emitting element ED according to some example embodiments, at least one among a hole transport region HTR, an emission layer EML, and an electron transport region ETR may include the fused polycyclic compound according to some example embodiments. For example, in the light-emitting element ED according to some example embodiments, the emission layer EML may include the fused polycyclic compound according to some example embodiments.

The first electrode EL1 may be conductive. The first electrode EL1 may be formed of a metal material, a metal alloy or a conductive compound. The first electrode EL1 may be a cathode or an anode, but the example embodiments of the inventive concepts are not limited thereto. In addition, the first electrode EL1 may be a pixel electrode. The first electrode EL1 may be a transmissive electrode, a semi-transmissive electrode, or a reflective electrode. The first electrode EL1 may include at least one selected from Ag, Mg, Cu, Al, Pt, Pd, Au, Ni, Nd, Ir, Cr, Li, Ca, LiF, Mo, Ti, W, In, Sn, and Zn, a compound of at least two selected therefrom, a mixture of at least two selected therefrom, or an oxide thereof.

When the first electrode EL1 is a transmissive electrode, the first electrode EL1 may include a transparent metal oxide, for example, indium-tin oxide (ITO), indium-zinc oxide (IZO), zinc oxide (ZnO), indium-tin-zinc oxide (ITZO), or the like. When the first electrode EL1 is a semi-transmissive electrode or a reflective electrode, the first electrode EL1 may include Ag, Mg, Cu, Al, Pt, Pd, Au, Ni, Nd, Ir, Cr, Li, Ca, LiF/Ca (a stack structure of LiF and Ca), LiF/Al (a stack structure of LiF and Al), Mo, Ti, W, or a compound or a mixture thereof (e.g., a mixture of Ag and Mg). In some example embodiments, the first electrode EL1 may have a multi-layered structure including the reflective film or the semi-transmissive film formed of the above material, and a transparent conductive film formed of indium-tin oxide (ITO), indium-zinc oxide (IZO), zinc oxide (ZnO), indium-tin-zinc oxide (ITZO), or the like. For example, the first electrode EL1 may have a three-layered structure of an ITO/Ag/ITO, but the example embodiments of the inventive concepts are not limited thereto. In addition, the first electrode EL1 may include the above metal material, a combination of at least two metal materials selected from the above metal materials, an oxide of the above metal materials, or the like. The first electrode EL1 may have a thickness of about 700 Å to about 10000 Å. For example, the first electrode EL1 may have a thickness of about 1000 Å to about 3000 Å.

The hole transport region HTR is provided on the first electrode EL1. The hole transport region HTR may include at least one of the hole injection layer HIL, the hole transport layer HTL, a buffer layer or an auxiliary emission layer (not shown), or the electron blocking layer EBL. The hole transport region HTR may have a thickness of about 50 Å to about 15,000 Å.

The hole transport region HTR may have a single layer formed of a single material, a single layer formed of a plurality of different materials, or a multi-layered structure including a plurality of layers formed of a plurality of different materials.

For example, the hole transport region HTR may have the structure of a single layer of the hole injection layer HIL or the hole transport layer HTL, and may have a structure of a single layer formed of a hole injection material and a hole transport material. In addition, the hole transport region HTR may have a structure of a single layer formed of a plurality of different materials, or a structure of the hole injection layer HIL/the hole transport layer HTL, the hole injection layer HIL/the hole transport layer HTL/the buffer layer (not shown), the hole injection layer HIL/the buffer layer (not shown), the hole transport layer HTL/the buffer layer (not shown), or the hole injection layer HIL/the hole transport layer HTL/the electron blocking layer EBL, which are stacked from the first electrode EL1, without limitation.

The hole transport region HTR may be formed in various processes such as vacuum deposition, spin coating, casting, a Langmuir-Blodgett (LB) process, inkjet printing, laser printing, and laser induced thermal imaging (LITI).

The hole transport region HTR may include a compound represented by Formula H-1 below.

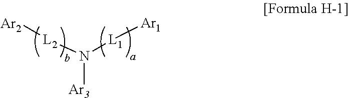

In Formula H-1 above, L₁ and L₂ may be each independently a direct linkage, a substituted or unsubstituted arylene group having a ring-forming carbon number of 6 to 30 or a substituted or unsubstituted heteroarylene group having a ring-forming carbon number of 2 to 30. “a” and “b” may be each independently an integer of 0 to 10. When “a” or “b” is an integer of 2 or more, a plurality of L₁ and L₂ may be each independently a substituted or unsubstituted arylene group having a ring-forming carbon number of 6 to 30, or a substituted or unsubstituted heteroarylene group having a ring-forming carbon number of 2 to 30.

In Formula H-1, Ar₁ and Ar₂ may be each independently a substituted or unsubstituted aryl group of 6 to 30 ring-forming carbon atoms, or a substituted or unsubstituted heteroaryl group of 2 to 30 ring-forming carbon atoms. In addition, in Formula H-1, Ar₃ may be a substituted or unsubstituted aryl group of 6 to 30 ring-forming carbon atoms, or a substituted or unsubstituted heteroaryl group of 2 to 30 ring-forming carbon atoms.

The compound represented by Formula H-1 above may be a monoamine compound. Otherwise, the compound represented by Formula H-1 above may be a diamine compound in which at least one among Ar₁ to Ar₃ includes an amine group as a substituent. In addition, the compound represented by Formula H-1 above may be a carbazole-based compound in which at least one of Ar₁ or Ar₂ includes a substituted or unsubstituted carbazole group, or a fluorene-based compound in which at least one of Ar₁ or Ar₂ includes a substituted or unsubstituted fluorene group.

The compound represented by Formula H-1 may be represented by any one among compounds in Compound Group H below. However, the compounds listed in Compound Group H below are examples, and the compound represented by Formula H-1 is not limited to the compounds represented in Compound Group H below.

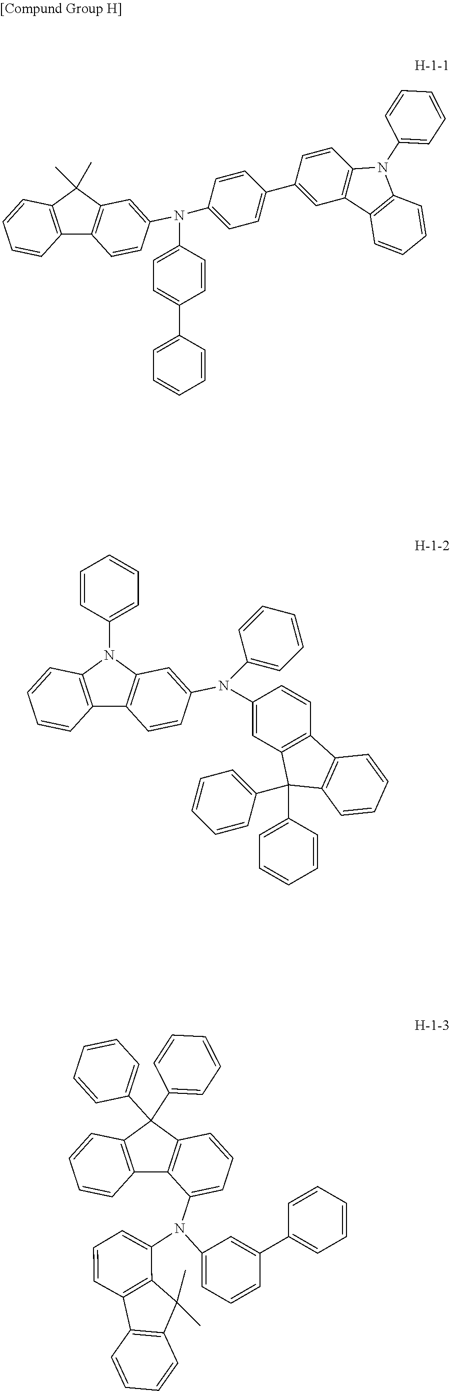 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

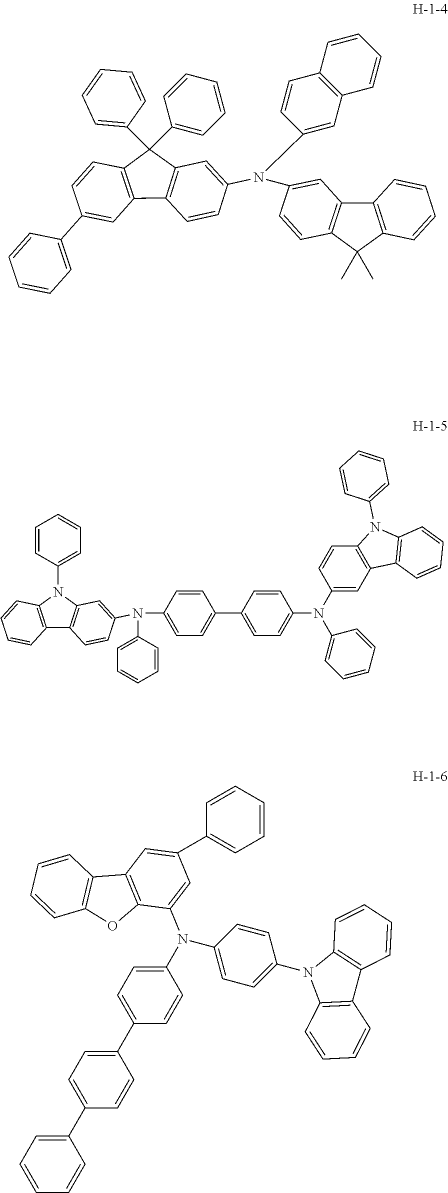 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

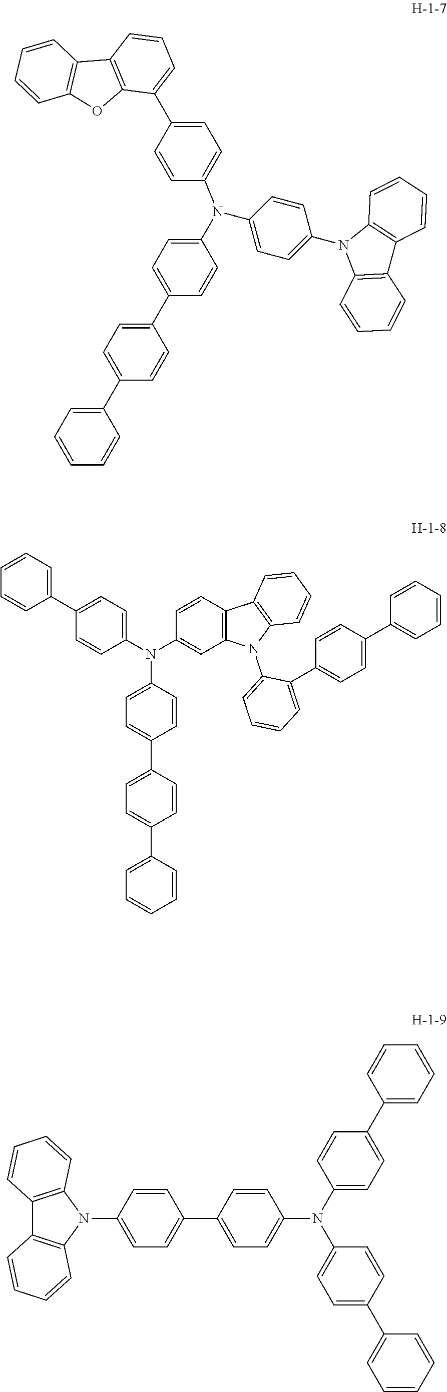 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

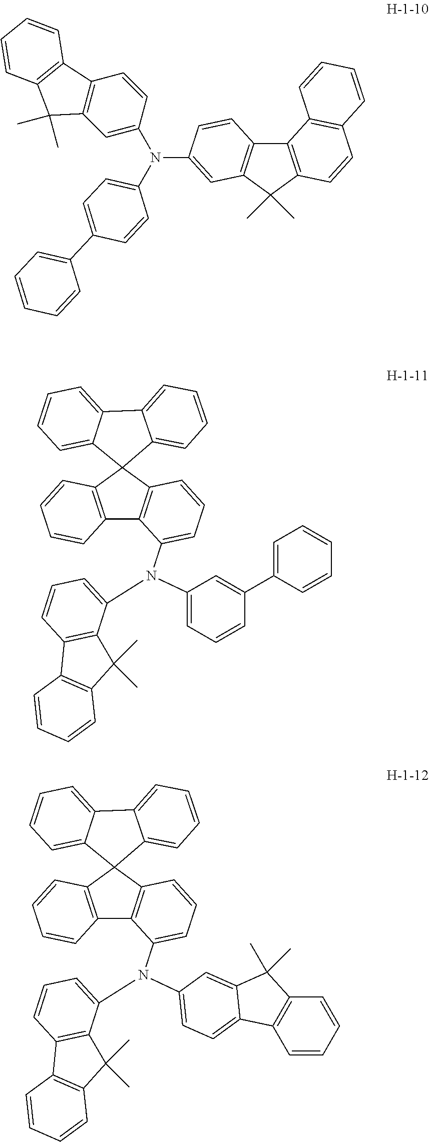

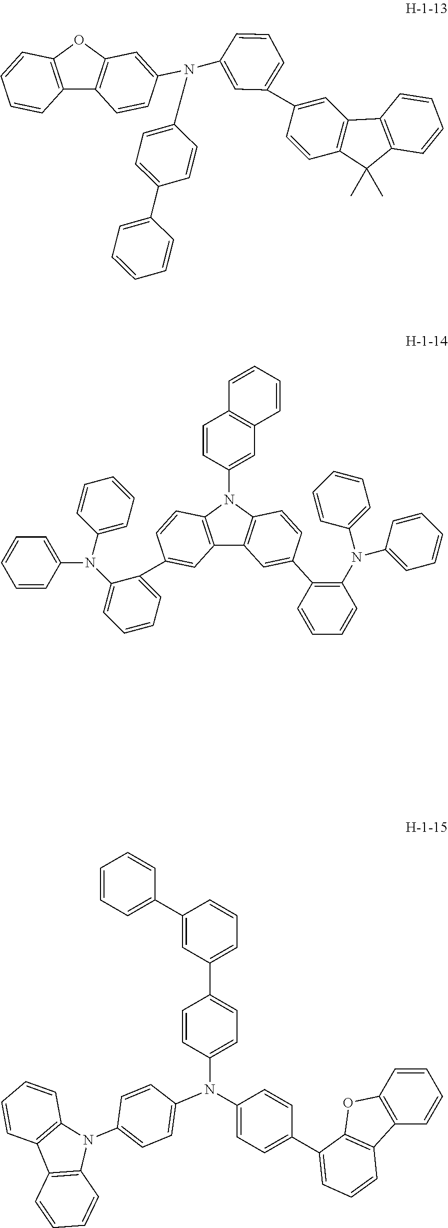 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

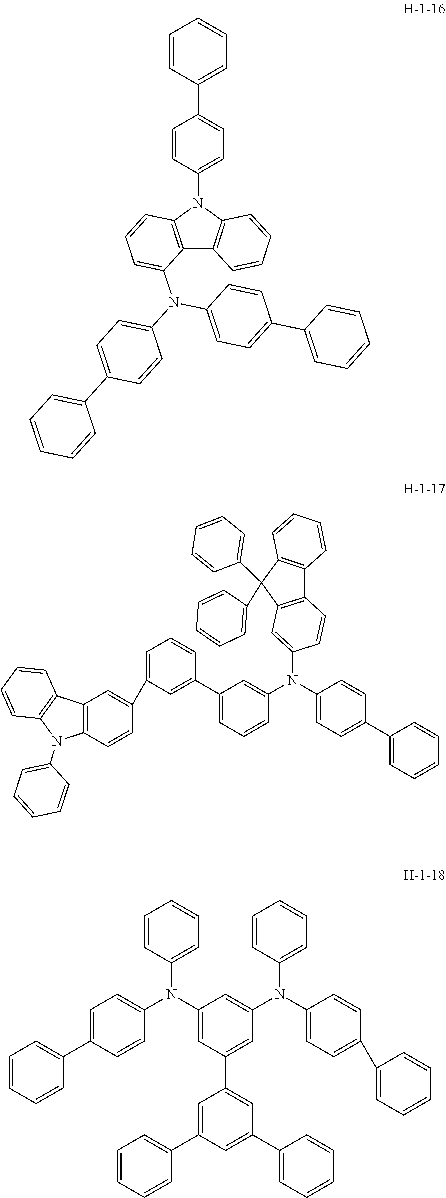 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

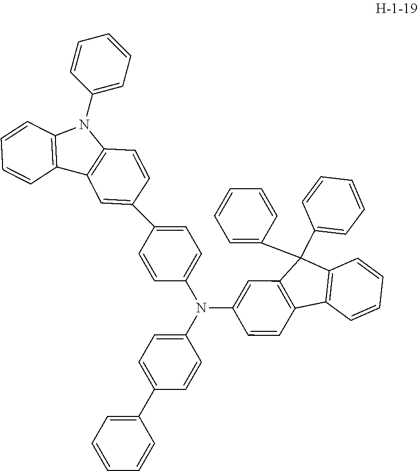 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N1,N1′-([1,1′-biphenyl]-4,4′-diyl)bis(N1-phenyl-N4,N4-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(1-naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], and dipyrazino[2,3-f:2′,3′-h]quinoxaline-2,3,6,7,10,11-hexacarbonitrile (HATCN).

The hole transport region HTR may include carbazole derivatives such as N-phenyl carbazole and polyvinyl carbazole, fluorene-based derivatives, N,N′-bis(3-methylphenyl)-N,N′-diphenyl-[1,1′-biphenyl]-4,4′-diamine (TPD), triphenylamine-based derivatives such as 4,4′,4″-tris(N-carbazolyl)triphenylamine (TCTA), N,N′-di(1-naphthalene-1-yl)-N,N′-diphenyl-benzidine (NPB), 4,4′-cyclohexylidene bis[N,N-bis(4-methylphenyl)benzeneamine](TAPC), 4,4′-bis[N,N′-(3-tolyl)amino]-3,3′-dimethylbiphenyl (HMTPD), 1,3-bis(N-carbazolyl)benzene (mCP), etc.

In addition, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

According to some example embodiments, the hole transport region HTR may include any one among the compounds of Compound Group 2 above.

The hole transport region HTR may include the compounds of the hole transport region described above in at least one among the hole injection layer HIL, the hole transport layer HTL, and the electron blocking layer EBL.

The hole transport region HTR may have a thickness of about 100 Å to about 10,000 Å, for example, of about 100 Å to about 5,000 Å. In a case where the hole transport region HTR includes the hole injection layer HIL, the hole injection region HIL may have a thickness of, for example, about 30 Å to about 1,000 Å. In a case where the hole transport region HTR includes the hole transport layer HTL, the hole transport layer HTL may have a thickness of about 30 Å to about 1,000 Å. For example, in a case where the hole transport region HTR includes the electron blocking layer, the electron blocking layer EBL may have a thickness of about 10 Å to about 1,000 Å. When the thicknesses of the hole transport region HTR, the hole injection layer HIL, the hole transport layer HTL and the electron blocking layer EBL satisfy the above-described ranges, satisfactory hole transport characteristics may be obtained without substantial increase of a driving voltage.

The hole transport region HTR may further include a charge generation material so as to increase conductivity in addition to the above-described materials. The charge generation material may be dispersed uniformly or non-uniformly in the hole transport region HTR. The charge generation material may be, for example, a p-dopant. The p-dopant may include at least one of a metal halide compound, a quinone derivative, a metal oxide, and a cyano group-containing compound, without limitation. For example, the p-dopant may include the metal halide compound such as CuI and RbI, the quinone derivative such as tetracyanoquinodimethane (TCNQ) and 2,3,5,6-tetrafluoro-7,7′,8,8-tetracyanoquinodimethane (F4-TCNQ), the metal oxide such as tungsten oxide and molybdenum oxide, the cyano group-containing compound such as dipyrazino[2,3-f. 2′,3′-h]quinoxaline-2,3,6,7,10,11-hexacarbonitrile (HATCN) and 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., without limitation.

As described above, the hole transport region HTR may further include at least one among the buffer layer (not shown) and the electron blocking layer EBL in addition to the hole injection layer HIL and the hole transport layer HTL. The buffer layer (not shown) may compensate a resonance distance according to the wavelength of light emitted by an emission layer EML and may increase light emission efficiency. As a material included in the buffer layer (not shown), a material which may be included in the hole transport region HTR may be used. The electron blocking layer EBL is a layer serving to prevent injection of electrons from the electron transport region ETR to the hole transport region HTR.

The emission layer EML is provided on the hole transport region HTR. The emission layer EML may have a thickness of, for example, about 100 Å to about 1000 Å, or about 100 Å to about 300 Å. The emission layer EML may have a single layer formed of a single material, a single layer formed of a plurality of materials different from each other, or a multilayer structure that has a plurality of layers formed of a plurality of materials different from each other.

The light-emitting element ED according to some example embodiments may include a fused polycyclic compound represented by Formula 1 below in at least one functional layer disposed between a first electrode EL1 and a second electrode EL2. In the light-emitting element ED according to some example embodiments, the emission layer EML may include the fused polycyclic compound according to some example embodiments. In some example embodiments, the emission layer EML may include the fused polycyclic compound as a dopant. The fused polycyclic compound according to some example embodiments may be a dopant material of the emission layer EML. In the present specification, the fused polycyclic compound according to some example embodiments may be referred to as a first compound.

The fused polycyclic compound according to some example embodiments includes first to third fused cores each including a boron-centered fused skeleton. In the fused polycyclic compound according to some example embodiments, the second fused core, and the third fused core may each have a form connected to the first fused core by sharing one benzene ring. The second fused core may be connected to the first fused core by sharing one benzene ring, and the third fused core may be connected to the first fused core by sharing another benzene ring. The fused polycyclic compound of the inventive concepts has a structure in which the first and the third fused cores are bonded via a specific connection structure and thus may exhibit reduced full width at half maximum and stokes-shift characteristics, and increased emission quantum efficiency, such that a light emission performance, light emission efficiency, and/or power consumption efficiency of a light emitting element may be improved based on having an emission layer EML that includes the fused polycyclic compound.

In some example embodiments, the first fused core may have a fused structure of five rings are fused, centered on a first boron atom, a first atom, and a second atom. In some example embodiments, the first atom and the second atom may be each independently a nitrogen atom, a carbon atom, or a silicon atom. In the first fused core, three substituted or unsubstituted benzene rings may be connected via the first boron atom, the first atom, and the second atom to form five fused rings. More specifically, in the three benzene rings included in the first fused core, the three benzene rings may be connected, centered on the first boron atom, a first benzene ring and a second benzene ring among the three benzene rings may be connected via the first atom, and the second benzene ring and a third benzene ring may be connected via the second atom. In the first fused core, the first benzene ring may be shared with the above-described second fused core, and the third benzene ring may be shared with the above-described third fused core. That is, the first fused core, and the second fused core may be connected to each other by sharing the first benzene ring, and the first fused core and the third fused core may be connected to each other by sharing the third benzene ring.

In some example embodiments, the second fused core may have a fused structure of five rings, centered on a second boron atom, a third atom, and a fourth atom. In some example embodiments, the third and fourth atoms may be each independently an oxygen atom, a sulfur atom, a selenium atom, a nitrogen atom, a carbon atom, or a silicon atom. In the second fused core, three substituted or unsubstituted benzene rings are connected via the second boron atom, the third atom, and fourth atom to form five fused rings. In the three benzene rings included in the second fused core, the three benzene rings may be connected, centered on the second boron atom, and the first benzene ring and the fourth benzene ring among the three benzene rings may be connected via the third atom. The remaining fifth benzene ring among the three benzene rings may be connected to the first benzene ring or the fourth benzene ring via the fourth atom. In the second fused core, the first benzene ring may be shared with the above-described first fused core.

In some example embodiments, the third fused core may include a fused structure of five rings, centered on a third boron atom, a fifth atom, and a sixth atom. In some example embodiments, the fifth and sixth atoms may be each independently an oxygen atom, a sulfur atom, a selenium atom, a nitrogen atom, a carbon atom, or a silicon atom. In the third fused core, three substituted or unsubstituted benzene rings are connected via a third boron atom, a fifth atom, and a sixth atom to form five fused rings. In the three benzene rings included in the third fused core, the three benzene rings may be connected, centered on the third boron atom, and a third benzene ring and a sixth benzene ring among the three benzene rings may be connected via the fifth atom. A remaining seventh benzene ring among the three benzene rings may be connected to the third benzene ring or the sixth benzene ring via the sixth atom. In the third fused core, the third benzene ring may be shared with the above-described first fused core.

In the fused polycyclic compound according to some example embodiments, the first fused core may be represented by Structure S1 below, the second fused core may be represented by Structure S2a or Structure S2b below, and the third fused core may be represented by Structure S3a or Structure S3b below. For convenience of explanation, the fused polycyclic compound is illustrated by omitting a substituent that is connected to benzene rings in each of Structures S1, S2a, S2b, S3a, and S3b below.

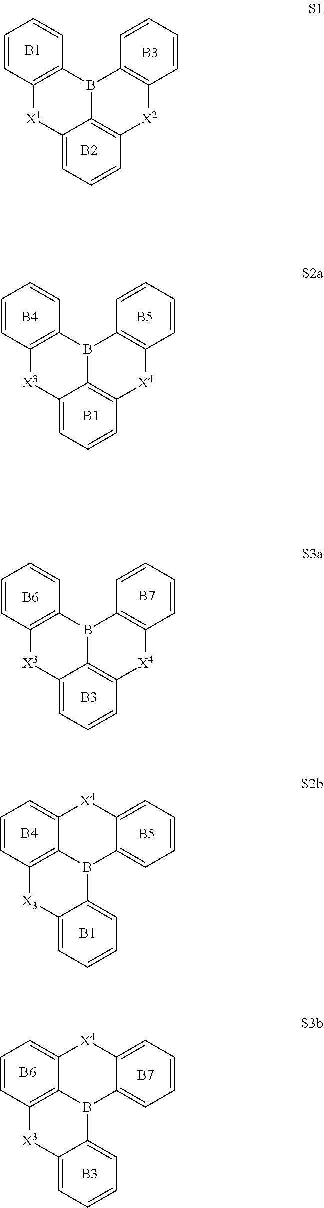

In Structure S1, Ring B1 may correspond to the above-described first benzene ring, Ring B2 may correspond to the above-described second benzene ring, and Ring B3 may correspond to the above-described third benzene ring. In addition, X¹ and X² may be each independently an oxygen atom, a sulfur atom, a selenium atom, a substituted nitrogen atom represented by Formula 3 or Formula 4, to be described later, a substituted carbon atom represented by Formula 5, to be described later, or a substituted silicon atom.

Structure S2a represents a case where the fifth benzene ring is connected to the first benzene ring via the fourth atom in the second fused core, and Structure S2b corresponds to a case where the fifth benzene ring is connected to the fourth benzene ring via the fourth atom in the second fused core. Structure S3a represents a case where the seventh benzene ring is connected to the third benzene ring via the sixth atom in the third fused core, and Structure S3b represents a case where the seventh benzene ring is connected to the sixth benzene ring via the sixth atom in the third fused core.

In Structure S2a and Structure S2b, Ring B1 may correspond to the above-described first benzene ring, Ring B4 may correspond to the above-described fourth benzene ring, and Ring B5 may correspond to the above-described fifth benzene ring. In Structure S3a and Structure S3b, Ring B3 may correspond to the third benzene ring, Ring B6 may correspond to the above-described sixth benzene ring, and Ring B7 may correspond to the above-described seventh benzene ring.

In Structure S2a, Structure S2b, Structure S3a, and Structure S3b, X³ and X⁴ may be each independently an oxygen atom, a sulfur atom, a selenium atom, or a substituted nitrogen atom represented by Formula 3 or Formula 4, to be described later, or a substituted carbon atom or a substituted silicon atom represented by Formula 5, to be described later. X³ included in Structure S2a and Structure S2b may be the same as or different from X³ included in Structure S3a, and Structure S3b. In addition, X⁴ included in Structure S2a and Structure S2b may be the same as or different from X⁴ included in Structure S3a, and Structure S3b.

In the fused polycyclic compound according to some example embodiments, the first fused core represented by Structure S1, and the second fused core represented by Structure S2a or Structure S2b may be connected to each other by sharing the first benzene ring B1. In addition, the first fused core represented by Structure S1, and the third fused core represented by Structure S3a or Structure S3b may be connected to each other by sharing the third benzene ring B3. In some example embodiments, the first fused core may be connected to the second and third fused cores to each other by respectively sharing one benzene ring, Ring B1 and Ring B3 to form a fused ring with 13 rings such as Structure S-F1 to Structure S-F3 below.

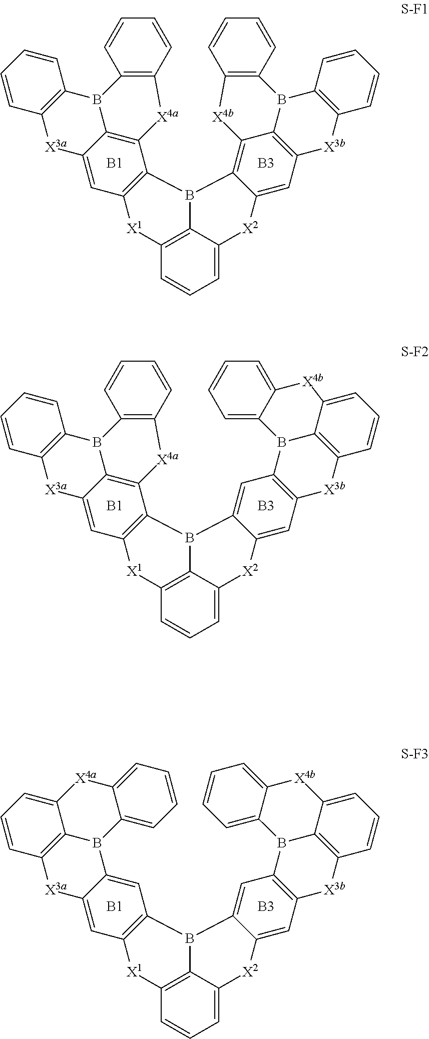

In Structure S-F1 to Structure S-F3, X^{3a}, X^{3b}, X^{4a}, and X^{4b} may be each independently an oxygen atom, a sulfur atom, or a selenium atom, or a substituted nitrogen atom represented by Formula 3 or Formula 4, to be described later, or a substituted carbon atom or a substituted silicon atom represented by Formula 5, to be described later, and X¹ and X² may each independently be an oxygen atom, a sulfur atom, a selenium atom, a substituted nitrogen atom represented by Formula 3 or Formula 4, to be described later, a substituted carbon atom represented by Formula 5, to be described later, or a substituted silicon atom.

In Structure S-F1 to Structure S-F3, Ring B1 may correspond to the above-described first benzene ring, and ring B3 may correspond to the above-described third benzene ring.

The details of X¹ and X², described in Structure S1 above, may be similarly applied to Structure S-F1 to Structure S-F3.

A thermally activated delayed fluorescence material having a boron-centered fused ring skeleton exhibits a narrow full width at half maximum and a high emission quantum yield and thus is gaining attention as a material of an organic light-emitting element. A triboron-based thermally activated delayed fluorescence material is expected to have improvements in element lifespan and element efficiency due to high absorbance and rapid reverse intersystem crossing. However, in general, the triboron-centered fused skeleton has larger full width at half maximum and stokes-shift than a single-boron based fused skeleton, caused by structural relaxation in an excited state and a ground state, and thus is yet insufficient as a material for a high-performance display device. The fused polycyclic compound of the inventive concepts has a structure in which first to third fused cores are bonded through a specific connection structure and thus may exhibit a high emission quantum yield while exhibiting small full width at half maximum and stokes-shift characteristics, such that a light emission performance, light emission efficiency, and/or power consumption efficiency of a light emitting element may be improved based on having an emission layer EML that includes the fused polycyclic compound.

In the fused polycyclic compound according to some example embodiments, at least one among the first to sixth atoms may be a nitrogen atom substituted with a first substituent. In some example embodiments, the first substituent may include a first benzene moiety and a first sub substituent that is connected to a carbon atom at a specific position of the first benzene moiety. More specifically, the first substituent may include the first benzene moiety connected to the nitrogen atom, and the first sub substituent connected at at least one of two ortho positions with respect to the nitrogen atom. For example, the first substituent may include a structure which includes the first benzene moiety connected to the nitrogen atom, and the first sub substituent connected at one ortho position with respect to the nitrogen atom. In some example embodiments, the first substituent may include a structure that includes the first benzene moiety connected to the nitrogen atom, and the first sub substituent connected at each of two ortho positions with respect to the nitrogen atom. The first sub substituent may be a substituted or unsubstituted aryl group having 6 to 30 ring-forming carbon atoms. For example, the first sub substituent may be a substituted or unsubstituted phenyl group. In this specification, the nitrogen atom substituted with the first substituent may be represented by Formula 3 to be described later.

The fused polycyclic compound according to some example embodiments may effectively maintain a trigonal planar structure of a boron atom through a steric hindrance effect by the first substituent. A boron atom has electron-deficient properties due to an unoccupied p-orbital and thus may change into a tetrahedral structure by forming a bond with another nucleophile, which may cause element deterioration. According to the inventive concepts, the fused polycyclic compound according to some example embodiments includes a first substituent having a steric hindrance structure, and thus the unoccupied p-orbital of boron may be effectively protected, thereby preventing a deterioration phenomenon due to a structural deformation. As a result, a light emission performance and/or reliability of a light emitting element may be improved based on having an emission layer EML that includes the fused polycyclic compound.

In addition, the fused polycyclic compound according to some example embodiments may control formation of an excimer or an exciplex since an intermolecular interaction is suppressed by introduction of the first substituent and thus emission efficiency may increase. In addition, the fused polycyclic compound according to some example embodiments represented by Formula 1 has an increased intermolecular distance by including the first substituent, and thus there is an effect in which Dexter energy transfer may decrease. Dexter energy transfer is a phenomenon where triplet excitons transfer between molecules. Dexter energy transfer increases when an intermolecular distance is short and may cause an increase in quenching phenomenon as triplet concentration increases. According to the inventive concepts, Dexter energy transfer may be suppressed by increasing a distance between adjacent molecules due to a structure having large steric hindrance of the fused polycyclic compound according to some example embodiments, and thus lifespan deterioration due to an increase in triplet concentration may be suppressed. Therefore, when the fused polycyclic compound according to some example embodiments is applied to the emission layer EML of the light-emitting element ED, it may not only increase emission efficiency but also improve an element lifespan. As a result, a light emission performance, light emission efficiency, and/or reliability of a light emitting element may be improved based on having an emission layer EML that includes the fused polycyclic compound.

The fused polycyclic compound according to some example embodiments may be represented by Formula 1 below.

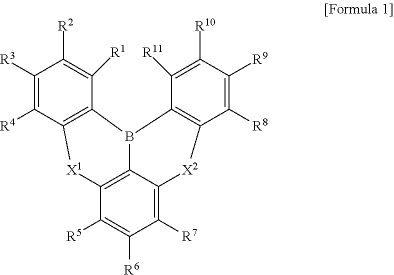

The fused polycyclic compound according to some example embodiments, represented by Formula 1, includes first to third fused cores each including a boron-centered fused skeleton. In the fused polycyclic compound according to some example embodiments, the first fused core may have a form connected to the second and third fused cores, while sharing one benzene ring with each.

In the present specification, a benzene ring substituted with a substituent represented by R¹ to R⁴ in Formula 1 may correspond to the above-described first benzene ring, a benzene ring substituted with a substituent represented by R⁵ to R⁷ in Formula 1 may correspond to the above-described second benzene ring, and a benzene ring substituted with a substituent represented by R⁸ to R¹¹ in Formula 1 may correspond to the above-described third benzene ring. In addition, in Formula 2 to be described later, a benzene ring substituted with a substituent represented by R¹² to R¹¹ may correspond to the above-described fourth benzene ring or the sixth benzene ring, and a benzene ring substituted with a substituent represented by R¹⁶ to R¹⁹ may correspond to the above-described fifth benzene ring or the seventh benzene ring.

In Formula 1, R¹ to R¹¹ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In addition, R¹ to R¹¹ may be each bonded to an adjacent group to each other to form a ring. For example, R¹ to R¹¹ may be each independently a hydrogen atom, a deuterium atom, a substituted or unsubstituted t-butyl group, a substituted or unsubstituted phenyl group, a substituted or unsubstituted biphenyl group.

In Formula 1, continuous two or three selected from R¹ to R⁴ and R¹ to R¹¹ are positions to which Formula 2 below is connected. For example, a continuous (or “adjacent”) two or three selected from each of R¹ to R⁴ and R¹ to R¹¹ may each be connected to a separate group represented by Formula 2, such that the fused polycyclic compound (also referred to herein as a first compound) includes two separate groups that are each represented by Formula 2 and are each connected to a separate continuous two or three of a separate one of R¹ to R⁴ or R¹ to R¹¹ of Formula 1. For example, the fused polycyclic compound (also referred to herein as a first compound) may include two separate groups that are each represented by Formula 2 where one of the two separate groups is connected to a continuous two or three of R¹ to R⁴ of Formula 1 and another one of the two separate groups is connected to a continuous two or three of R⁸ to R¹¹ of Formula 1. For example, in Formula 1, R¹ to R³ among R¹ to R⁴ may be positions to which a first group represented by Formula 2 below is connected, and R⁹ to R¹¹ among R⁸ to R¹¹ may be positions to which a second group represented by Formula 2 below is connected. In some example embodiments, R¹ to R³ among R¹ to R⁴ may be positions to which a first group represented by Formula 2 below is connected, and R⁹ to R¹⁰ among R⁸ to R¹¹ may be positions to which a second group represented by Formula 2 below is connected. In some example embodiments, R² and R³ among R¹ to R⁴ may be positions to which a first group represented by Formula 2 below is connected, and R⁹ and R¹⁰ among R¹ to R¹¹ maybe positions to which a second group represented by Formula 2 below is connected.

In Formula 1, X¹ and X² are each O, S, or Se, or represented by any one among Formula 3 to Formula 5 below.

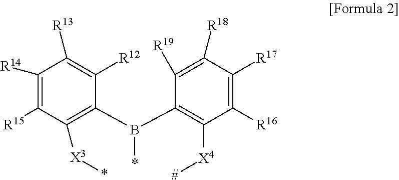

In Formula 2 (e.g., in Formula 2 of one or both of the two groups represented by Formula 2), R¹² to R¹⁹ may be each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In some example embodiments, R¹² to R¹⁹ may be each bonded to an adjacent group to each other to form a ring. For example, R¹² to R¹⁹ may be each independently a hydrogen atom, a deuterium atom, a substituted or unsubstituted t-butyl group, a substituted or unsubstituted phenyl group, or a substituted or unsubstituted biphenyl group.

In Formula 2, X³ and X⁴ are each independently O, S, or Se, or represented by any one among Formula 3 to Formula 5 below.

In Formula 2, [symbol] is a position to which Formula 1 above is connected.

In Formula 2, [symbol] is a position to which Formula 1 above is connected, or R¹² in Formula 2 above is connected.

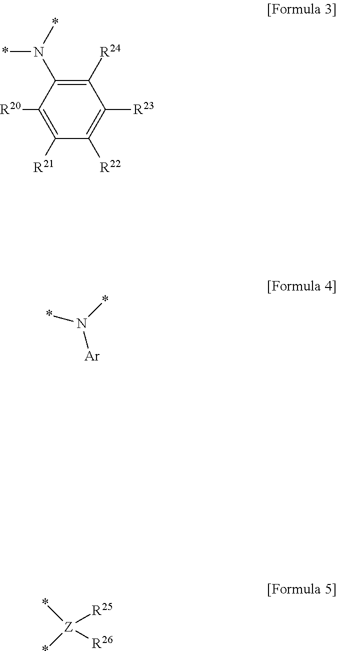

In Formula 3 to Formula 5, [symbol] is a position to which Formula 1 or Formula 2 above [symbol] is connected.

In Formula 3 and Formula 5, R²⁰ to R²⁶ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R²⁰ to R²⁶ may be each independently a hydrogen atom, a deuterium atom, or a substituted or unsubstituted phenyl group.

In Formula 3, at least one among R²⁰ or R²⁴ is a substituted or unsubstituted aryl group having 6 to 30 ring-forming carbon atoms. In some example embodiments, in Formula 3, at least one among R²⁰ or R²⁴ may be a substituted or unsubstituted phenyl group. For example, in Formula 3, any one among R²⁰ or R²⁴ may be a substituted or unsubstituted phenyl group, or R²⁰ and R²⁴ may be each independently a substituted or unsubstituted phenyl group.

In Formula 4, Ar is a substituted or unsubstituted aryl group having 10 to 30 ring-forming carbon atoms.

In Formula 5, Z is a carbon atom or a silicon atom. However, when Z is a silicon atom, R²⁵ and R²⁶ are not hydrogen atoms.

In Formula 1 and Formula 2, at least one among X¹ to X⁴ is represented by Formula 3. In some example embodiments, at least two among X¹ to X⁴ may be represented by Formula 3. In some example embodiments, X¹ and X² may be each independently represented by Formula 3.

In Formula 1, when X¹ and X² are represented by Formula 4, a case where Ar is a fluorenyl group or a heteroaryl group in Formula 4 is excluded. For example, when X¹ and X² in Formula 1 are represented by Formula 4, Ar in Formula 4 may not be a fluorenyl group or a heteroaryl group (e.g., may not be any fluorenyl group or any heteroaryl group).

In Formula 1, when any one among X¹ or X² is represented by Formula 3, a case where any one among R²⁰ and R²⁴ in Formula 3 is not a substituted or unsubstituted aryl group having 6 to 30 ring-forming carbon atoms is excluded. For example, when at least one of X¹ or X² in Formula 1 is represented by Formula 3, at least one of R²⁰ or R²⁴ in Formula 3 may be a substituted or unsubstituted aryl group having 6 to 30 ring-forming carbon atoms. In another example, when any one among X¹ or X² is represented by Formula 3, R²⁰ and R²⁴ in Formula 3 may be each independently a substituted or unsubstituted aryl group having 6 to 30 ring-forming carbon atoms.

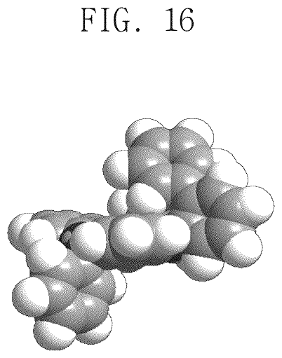

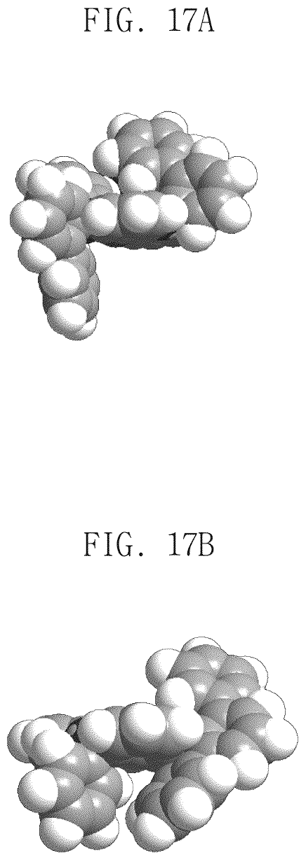

FIG. 16 is a view showing a three-dimensional molecular model of Fused Polycyclic Compound C-S1, according to Comparative Example. FIG. 17A is a view showing a three-dimensional molecular model of Fused Polycyclic Compound E-S1, according to some example embodiments. FIG. 17B is a view showing a three-dimensional molecular model of Fused Polycyclic Compound E-S2, according to some example embodiments. FIG. 16, FIG. 17A, and FIG. 17B respectively show a three-dimensional molecular model of Comparative Example Compound and Example Compounds, respectively, viewed from a side. Structures of Comparative Example Compound C-S1, Example Compounds E-S1 and E-S2 are illustrated below. Hereinafter, the detailed descriptions with reference to FIG. 16, FIG. 17A, and FIG. 17B are not limited to Structure S-F1, but also similarly applied to Structure S-F2 and Structure S-F73.

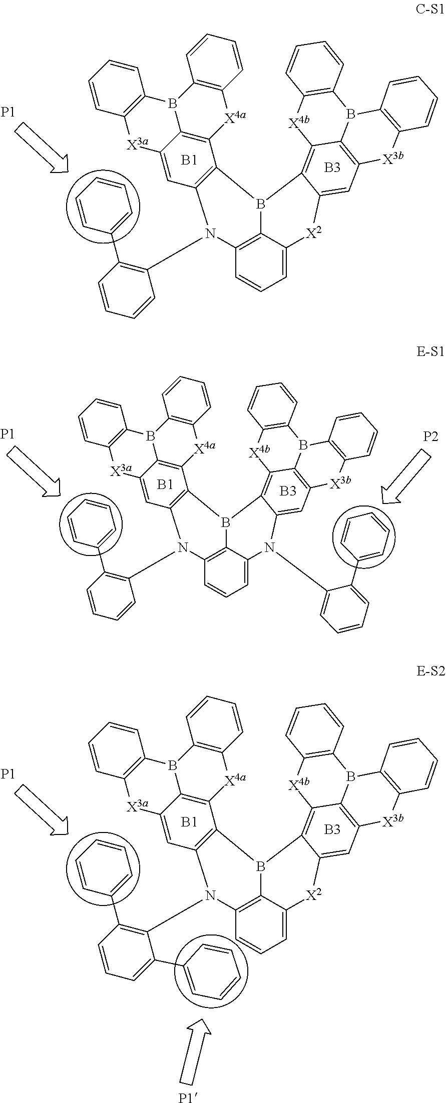

Since emission transition of a boron atom-centered multi-resonance molecule occurs in a plate-type core, it is necessary to protect the core portion from an external nucleophile, a radical, a decomposition product within the element, etc. Therefore, a method of introducing a sterically long substituent may be used in order to physically mask the p-orbital of the boron atom. FIG. 16, FIG. 17A, and FIG. 17B show differences of a molecular structure according to a type of a substituent introduced for steric hindrance properties in the fused polycyclic compound.

Comparative Example Compound C-S1 corresponds to a case where any one of X¹ or X² in Formula 1 is represented by Formula 3, and any one among R²⁰ or R²⁴ in Formula 3 is not a substituted or unsubstituted aryl group having 6 to 30 ring-forming carbon atoms. That is, Comparative Example Compound C-S1 corresponds to a case where any one among X¹ or X² in Formula 1 is represented by Formula 3, and only one among R²⁰ or R²⁴ in Formula 3 is a substituted or unsubstituted phenyl group.

Example Compound E-S1 corresponds to a case where both X¹ and X² in Formula 1 are represented by Formula 3. Example Compound E-S2 corresponds to a case where any one among X¹ or X² in Formula 1 is represented by Formula 3, and R²⁰ and R²⁴ in Formula 3 are each a phenyl group.

Referring together to FIG. 16, FIG. 17A, and FIG. 17B, Fused Polycyclic Compounds E-S1, and E-S2, according to some example embodiments may have a further increased steric shielding effect on a fused skeleton than Comparative Example Compound C-S1.

Comparative Example Compound C-S1 has a structure in which any one among X¹ or X² is represented by Formula 3, but only one phenyl group P1 is present at ortho positions with respect to the nitrogen atom and thus has a lowered steric shielding effect on the fused skeleton. Since Comparative Example Compound C-S1 includes a structure in which only one phenyl group P1 is introduced at ortho positions with respect to the nitrogen atom, Comparative Example Compound C-S1 has a steric bulk in only one direction with respect to the planar structure of the fused skeleton. Therefore, an opposite side of the planar structure may not be protected, and thus there is a limitation in which the boron atom is not effectively protected from an external nucleophile, a radical, a decomposition product within an element, which approach from the opposite side.

On the contrary, in Example Compound E-S1, both X¹ and X² are represented by Formula 3, and two or more substituted phenyl groups P1 and P2 are present at ortho positions, thereby having an improved shielding effect on the fused skeleton, compared to Comparative Example Compound C-S1. In addition, even when any one among X¹ or X² in Example Compound E-S2 is represented by Formula 3, since the phenyl groups P1 and P1′ are respectively present at two ortho positions, Example Compound E-S2 has improved shielding effect on the fused skeleton, compared to Comparative Example Compound C-S1. Since Example Compounds E-S1 and E-S2 may have stereochemistry in both directions with respect to a planar structure, the boron atom may be effectively and sterically protected, and thus Example Compounds E-S1 and E-S2 may have further improved lifespan and efficiency than Comparative Example Compound C-S1, thereby providing improved lifespan, reliability, and/or light emission efficiency to an emission layer EML including one of Example Compounds E-S1 and E-S2, and any light-emitting element ED and/or device including same. In a case where both X¹ and X² are represented by Formula 3, the fused polycyclic compound according to some example embodiments of the inventive concepts may have a sufficient steric shielding effect on the fused skeleton (or an improved steric shielding effect, for example in comparison to that of Comparative Example Compound C-S1) by introducing at least two substituted phenyl groups at the ortho positions.

In some example embodiments, Formula 3 may be represented by Formula 3-1 or Formula 3-2 below.

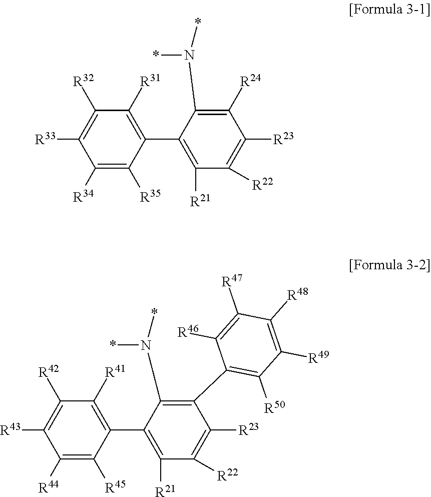

Formula 3-1 and Formula 3-2 correspond to cases where types of R²⁰ or R²⁴ are specified in Formula 3. Formula 3-1 corresponds to a case where R²⁰ is a substituted or unsubstituted phenyl group in Formula 3, and Formula 3-2 corresponds to a case where R²⁰ and R²⁴ are each a substituted or unsubstituted phenyl group in Formula 3.

In Formula 3-1 and Formula 3-2, [symbol] may be a position to which Formula 2 or Formula 3 above is connected.

In Formula 3-1 and Formula 3-2, R³¹ to R³⁵, and R⁴¹ to R⁵⁰ may be each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R³¹ to R³⁵, and R⁴¹ to R⁵⁰ may be each independently a hydrogen atom, or a substituted or unsubstituted phenyl group.

In Formula 3-1 and Formula 3-2, the same content described in Formula 3 above may be similarly applied to R²¹ to R²⁴. For example, in Formula 3-1 and Formula 3-2, R²¹ to R²⁴ may each independently be a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In some example embodiments, the first compound represented by Formula 1 may be represented by Formula 1-1-1 or Formula 1-1-2 below.

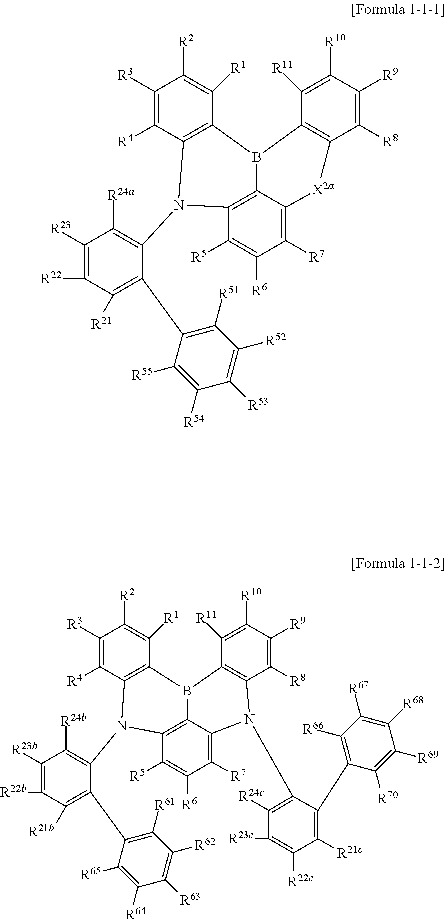

Formula 1-1-1 and Formula 1-1-2 represent cases where types of X¹ and X² in Formula 1 are specified. Formula 1-1-1 represents a case where X¹ in Formula 1 is represented by Formula 3, and S2 is O, S, or Se, or represented by Formula 4 or Formula 5. Formula 1-1-2 represents a case where X¹ and X² in Formula 1 are represented by Formula 3. Formula 1-1-1 or Formula 1-1-2 respectively correspond to cases where R²⁰ is a substituted or unsubstituted phenyl group in Formula 3 corresponding to X¹ or X² in Formula 1.

In Formula 1-1-1, X^{2a} may be O, S, or Se, or may be represented by Formula 4 or Formula 5 above.

In Formula 1-1-1, R^{24a} may be a substituted or unsubstituted aryl group having 6 to 30 ring-forming carbon atoms. For example, R^{24a} may be a substituted or unsubstituted phenyl group.

In Formula 1-1-1 and Formula 1-1-2, R⁵¹ to R⁵⁵, R⁶¹ to R⁷⁰, R^{21b} to R^{24b}, and R^{21c} to R^{24c} may be each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R⁵¹ to R⁵⁵, R⁶¹ to R⁷⁰, R^{21b} to R^{24b}, and R^{21c} to R^{24c} may be each independently a hydrogen atom, or a substituted or unsubstituted phenyl group.

In Formula 1-1-1 and Formula 1-1-2, the same content described in Formula 1 above may be similarly applied to R¹ to R¹¹, for example such that R¹ to R¹¹ may each independently be a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to each other to form a ring.

In the fused polycyclic compound according to some example embodiments, at least one among the first atom and the second atom included in the first fused ring may be a nitrogen atom substituted with the above-described first substituent. That is, in the fused polycyclic compound according to some example embodiments, at least one among X¹ and X² in Formula 1 may be represented by Formula 3. For example, X¹ and X² in Formula 1 may be each independently represented by Formula 3. The fused polycyclic compound according to some example embodiments includes a structure in which a nitrogen atom represented by Formula 3 is introduced at the first fused ring position, and thus a steric shielding effect on the fused skeleton may increase.

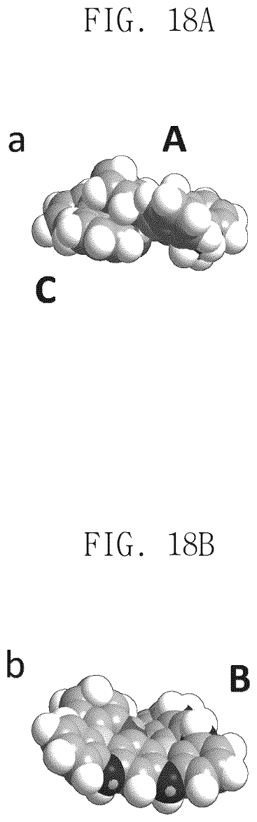

FIG. 18A and FIG. 18B are each a view showing a three-dimensional molecular model of a fused polycyclic compound according to some example embodiments. FIG. 18A and FIG. 18B each show, as an example, a three-dimensional molecular model of a fused polycyclic compound having Structure S-F1 according to some example embodiments, described previously. FIG. 18A shows the three-dimensional molecular model of the fused polycyclic compound according to some example embodiments viewed from a “a” direction and FIG. 18B illustrates the three-dimensional molecular model of the fused polycyclic compound according to some example embodiments viewed from a “b” direction. Hereinafter, the details described with reference to FIG. 18A and FIG. 18B, are not limited to Structure S-F1, and may also be similarly applied to Structure S-F2 and Structure S-F3.

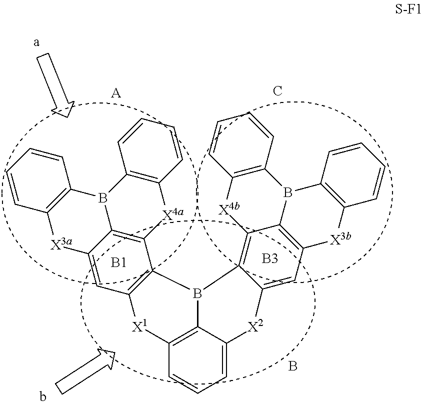

The fused polycyclic compound according to some example embodiments of the inventive concepts includes a fused polycyclic ring that contains three boron atoms. In order to impart sufficient durability (or improved durability) to a fused skeleton containing a boron atom, the fused skeleton should be protected sterically and sufficiently by being shielded. The fused polycyclic compound according to some example embodiments, represented by Formula 1, may have a structure to which a substituent sterically protecting the fused skeleton is connected. The fused polycyclic compound according to some example embodiments has an effect that sterically and sufficiently shields the fused skeleton by including at least one substituent represented by Formula 3.

In the fused polycyclic compound according to some example embodiments of the inventive concepts, for achieving a sufficient shielding effect (or improved shielding effect) on the fused skeleton, relative positional relationship of the fused rings is also important. The skeleton of the fused polycyclic compound, represented by Structure S-F1 above, includes, as illustrated in Structure S-F1, a first fused ring, Ring B, a second fused ring, Ring A, and a third fused ring, Ring C. Referring to FIG. 18A and FIG. 18B, the second fused ring, Ring A and the Third Fused Ring C have a shape in which the second fused ring, Ring A and the third fused ring, Ring C overlap each other. Therefore, a shielding effect required for the first fused ring, Ring B, may not be sufficient if it is not greater than a shielding effect required for the second fused ring, Ring A, or the third fused ring, Ring C. The fused polycyclic compound of the inventive concepts includes a structure in which at least one among X¹ and X² included in the first fused ring, Ring B is represented by Formula 3, and thus an increased steric shielding effect on the fused skeleton may be exhibited.

In some example embodiments, the first compound represented by Formula 1 may be represented by Formula 1-2 below.

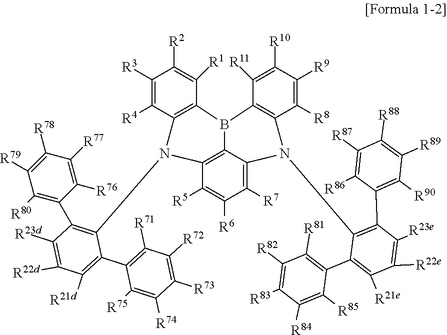

In Formula 1-2, R⁷¹ to R⁹⁰, R^{21d} to R^{23d}, and R^{21e} to R^{23e} may be each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R⁷¹ to R⁹⁰, R^{21d} to R^{23d}, and R^{21e} to R^{23e} may be each independently a hydrogen atom, or a substituted or unsubstituted phenyl group.

In Formula 1-2, the details described in Formula 1 above may be similarly applied to R¹ to R¹¹, for example such that R¹ to R¹¹ may each independently be a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to each other to form a ring.

In some example embodiments, the first compound represented by Formula 1 may be represented by any one among Formula 1-3-1 to Formula 1-3-3 below.

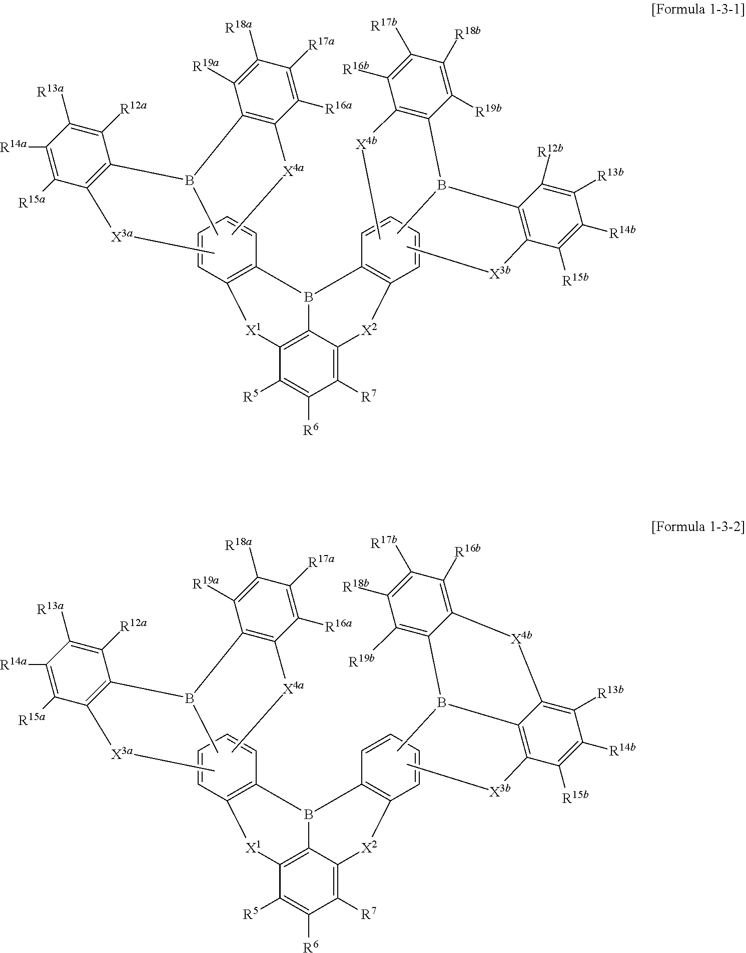

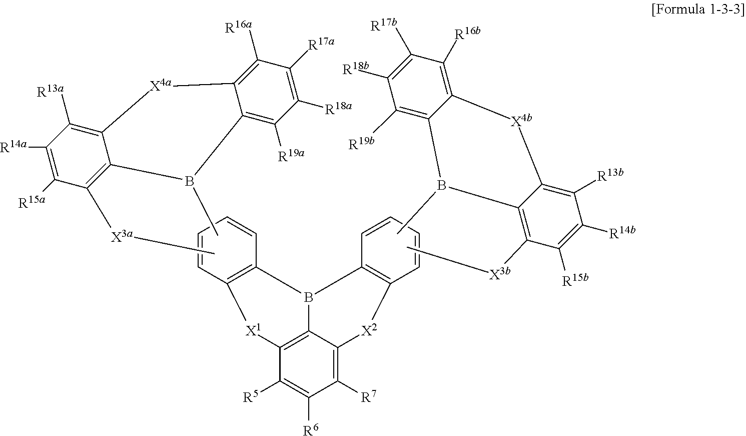

In Formula 1-3-1 to Formula 1-3-3, X³a, X^{3b}, X^{4a}, and X^{4b} may be each independently O, S, or Se, or may be represented by any one among Formula 3 to Formula 5 above.

In Formula 1-3-1 to Formula 1-3-3, R^{12a} to Formula R^{19a}, and R^{12b} to Formula R^{19b} may be each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R^{12a} to R^{19a}, and R^{12b} to R^{19b} may be each independently a hydrogen atom, a deuterium atom, a substituted or unsubstituted t-butyl group, a substituted or unsubstituted phenyl group, or a substituted or unsubstituted biphenyl group.

In Formula 1-3-1 to Formula 1-3-3, the details described in Formula 1 above may be similarly applied to X¹, X², and R⁵ to R⁷, for example such that and X¹ and X² may each independently be O, S, or Se, or represented by any one among Formula 3 to Formula 5, and R⁵ to R⁷ may each independently be a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to each other to form a ring.

In some example embodiments, the first compound represented by Formula 1 may be represented by any one among Formula 1-4-1 to Formula 1-4-3.

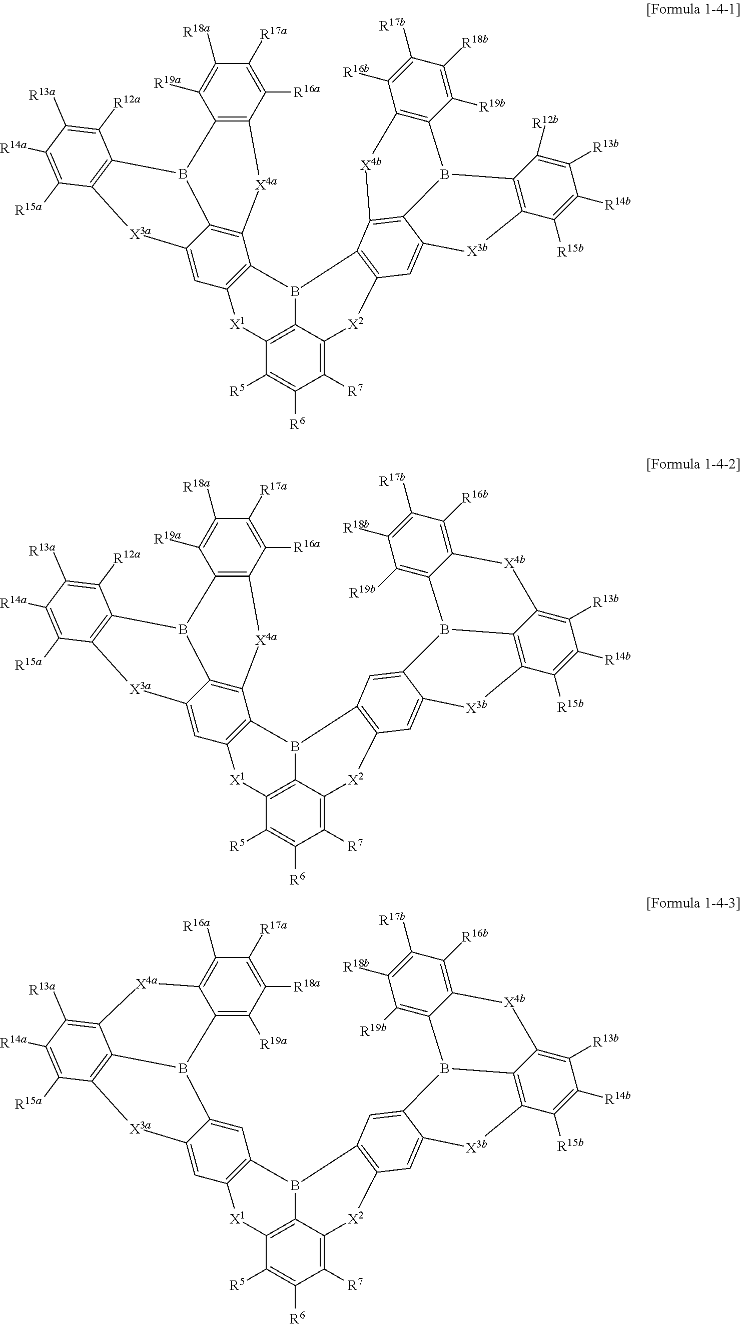

In Formula 1-4-1 to Formula 1-4-3, X^{3a}, X^{3b}, X^{4a}, and X^{4b} may be each independently O, S, or Se, or may be represented by any one among Formula 3 to Formula 5 above.

In Formula 1-4-1 to Formula 1-4-3 above, R^{12a} to R^{19a}, and R^{12b} to R^{19b} may be each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R^{12a} to R^{19a}, and R^{12b} to R^{19b} may be each independently a hydrogen atom, a deuterium atom, a substituted or unsubstituted t-butyl group, a substituted or unsubstituted phenyl group, a substituted or unsubstituted biphenyl group.

In Formula 1-4-1 to Formula 1-4-3, the details described in Formula 1 above may be similarly applied to X¹, X², and R⁵ to R⁷, for example such that X¹ and X² may each independently be O, S, or Se, or represented by any one among Formula 3 to Formula 5, and R⁵ to R⁷ may each independently be a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to each other to form a ring.

In some example embodiments, the fused polycyclic compound according to some example embodiments, represented by Formula 1 may include at least one deuterium atom as a substituent. The fused polycyclic compound according to some example embodiments, represented by Formula 1 may include a structure in which at least one hydrogen atom is substituted with a deuterium atom.

The fused polycyclic compound according to some example embodiments may be any one among compounds present in Compound Group 1 below. At least one functional layer included in the light-emitting element ED may include at least one fused polycyclic compound among the compounds present in Compound Group 1. The light-emitting element ED according to some example embodiments may include at least one fused polycyclic compound among the compounds present in Compound Group 1 (e.g., at least one of Compounds 1 to 51) in the emission layer EML.

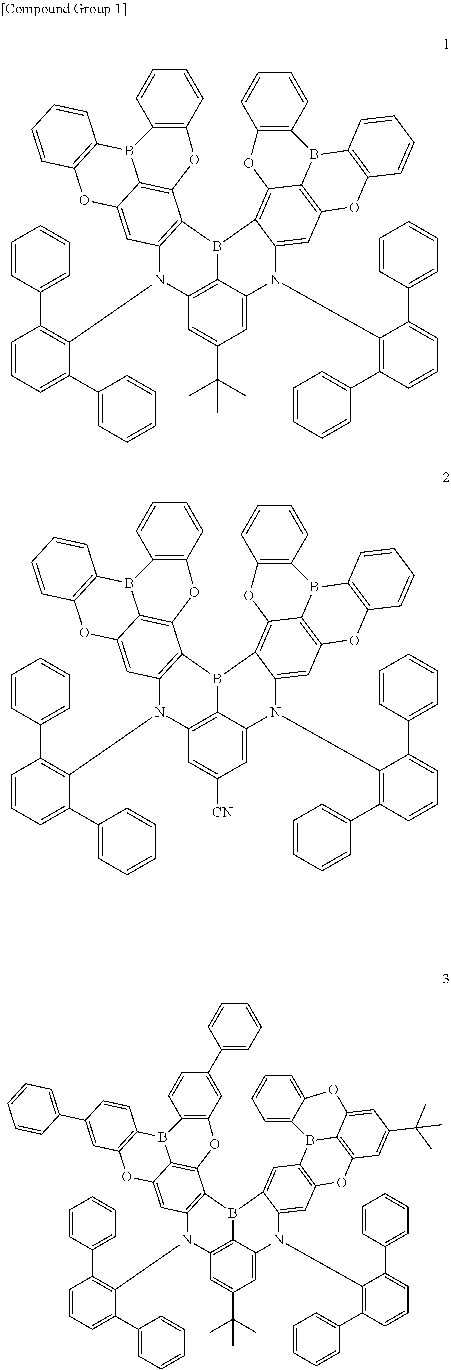 [SMILES: CC(C)(C)c1cc2c3c(c1)N(c1c(-c4ccccc4)cccc1-c1ccccc1)c1cc4c5c(c1B3c1c(cc3c6c1Oc1ccccc1B6c1ccccc1O3)N2c1c(-c2ccccc2)cccc1-c1ccccc1)Oc1ccccc1B5c1ccccc1O4 ; N#Cc1cc2c3c(c1)N(c1c(-c4ccccc4)cccc1-c1ccccc1)c1cc4c5c(c1B3c1c(cc3c6c1Oc1ccccc1B6c1ccccc1O3)N2c1c(-c2ccccc2)cccc1-c1ccccc1)Oc1ccccc1B5c1ccccc1O4 ; CC(C)(C)c1cc2c3c(c1)Oc1cc4c(cc1B3c1ccccc1O2)B1c2c(cc(C(C)(C)C)cc2N(c2c(-c3ccccc3)cccc2-c2ccccc2)c2cc3c5c(c21)Oc1cc(-c2ccccc2)ccc1B5c1ccc(-c2ccccc2)cc1O3)N4c1c(-c2ccccc2)cccc1-c1ccccc1]

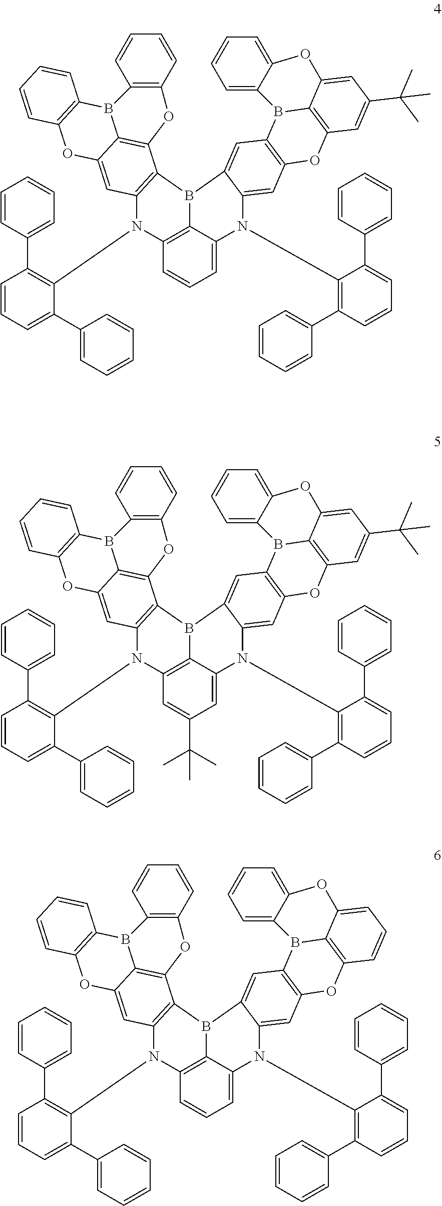 [SMILES: CC(C)(C)c1cc2c3c(c1)Oc1cc4c(cc1B3c1ccccc1O2)B1c2c(cccc2N(c2c(-c3ccccc3)cccc2-c2ccccc2)c2cc3c5c(c21)Oc1ccccc1B5c1ccccc1O3)N4c1c(-c2ccccc2)cccc1-c1ccccc1 ; CC(C)(C)c1cc2c3c(c1)Oc1cc4c(cc1B3c1ccccc1O2)B1c2c(cc(C(C)(C)C)cc2N(c2c(-c3ccccc3)cccc2-c2ccccc2)c2cc3c5c(c21)Oc1ccccc1B5c1ccccc1O3)N4c1c(-c2ccccc2)cccc1-c1ccccc1 ; c1ccc(-c2cccc(-c3ccccc3)c2N2c3cc4c(cc3B3c5c2cccc5N(c2c(-c5ccccc5)cccc2-c2ccccc2)c2cc5c6c(c23)Oc2ccccc2B6c2ccccc2O5)B2c3ccccc3Oc3cccc(c32)O4)cc1]

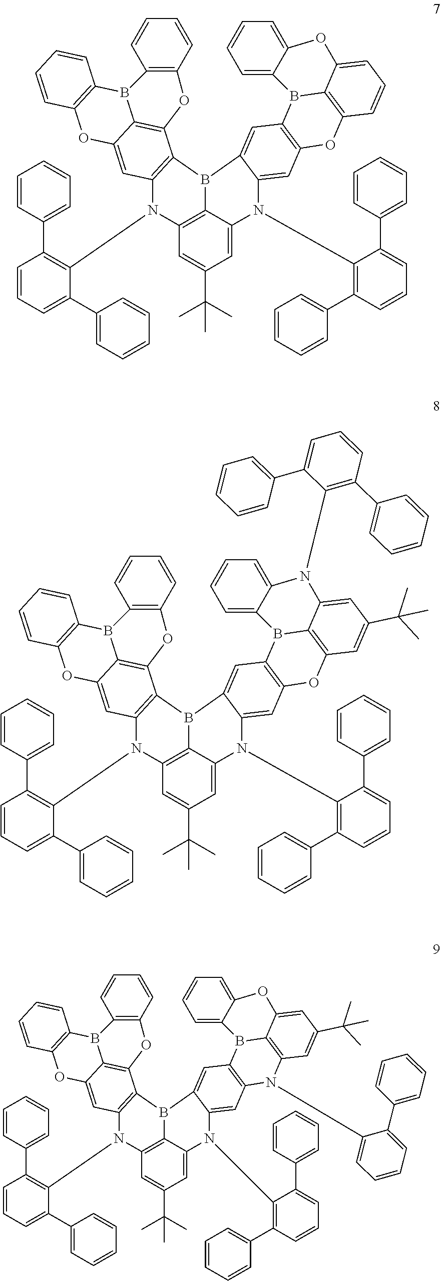

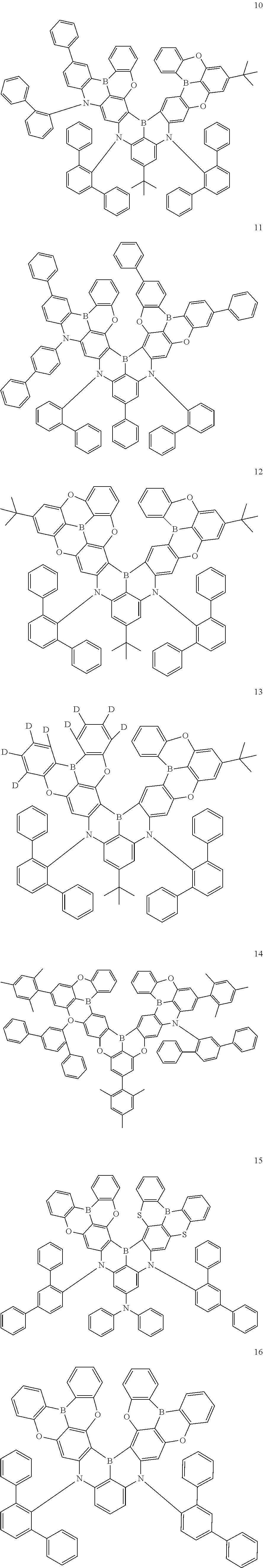

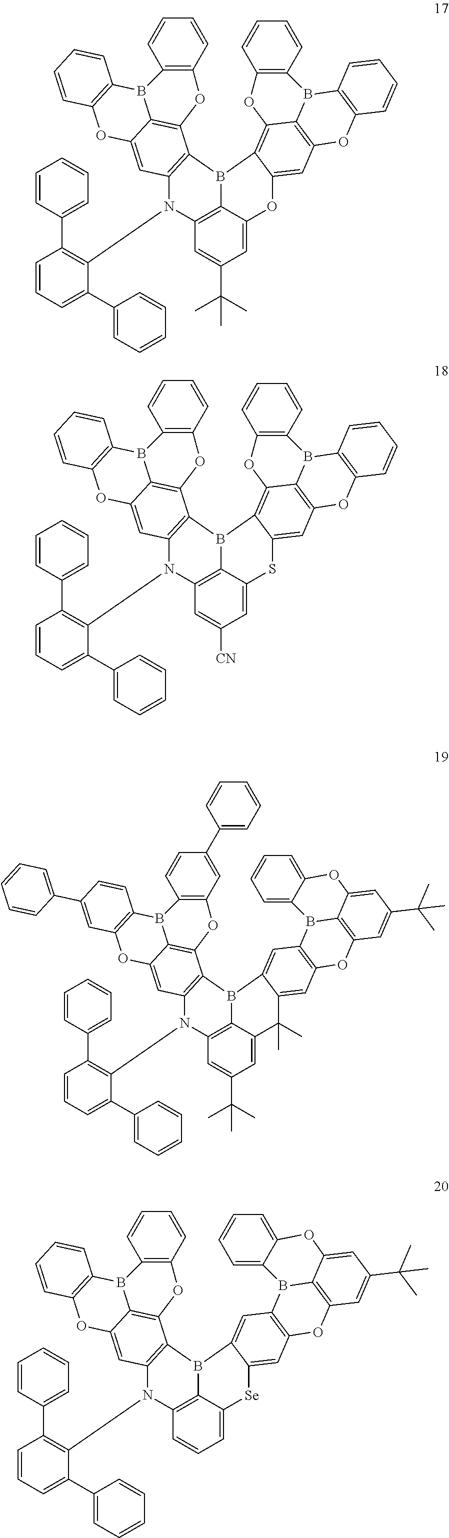

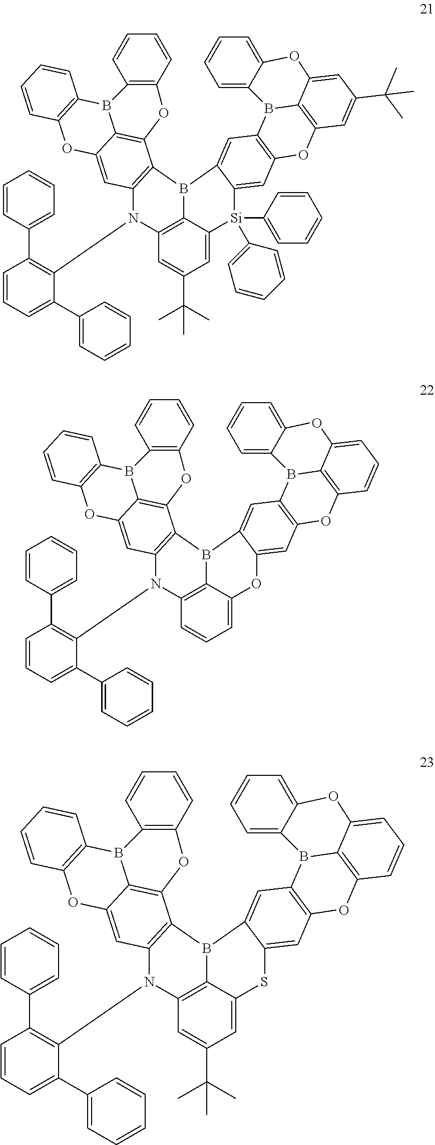 [SMILES: CC(C)(C)c1cc2c3c(c1)Oc1cc4c(cc1B3c1ccccc1O2)B1c2c(cc(C(C)(C)C)cc2[Si]4(c2ccccc2)c2ccccc2)N(c2c(-c3ccccc3)cccc2-c2ccccc2)c2cc3c4c(c21)Oc1ccccc1B4c1ccccc1O3 ; c1ccc(-c2cccc(-c3ccccc3)c2N2c3cccc4c3B(c3cc5c(cc3O4)Oc3cccc4c3B5c3ccccc3O4)c3c2cc2c4c3Oc3ccccc3B4c3ccccc3O2)cc1 ; CC(C)(C)c1cc2c3c(c1)N(c1c(-c4ccccc4)cccc1-c1ccccc1)c1cc4c5c(c1B3c1cc3c(cc1S2)Oc1cccc2c1B3c1ccccc1O2)Oc1ccccc1B5c1ccccc1O4]

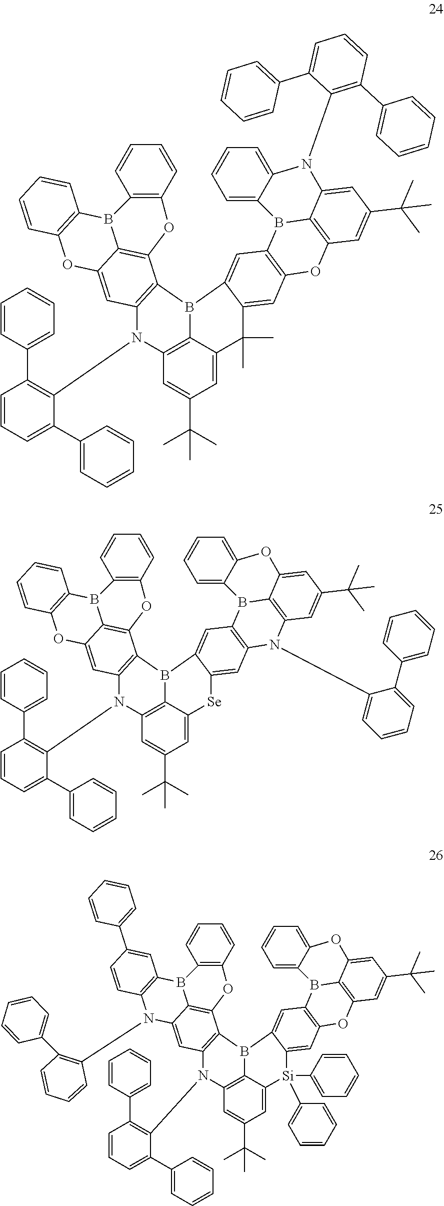

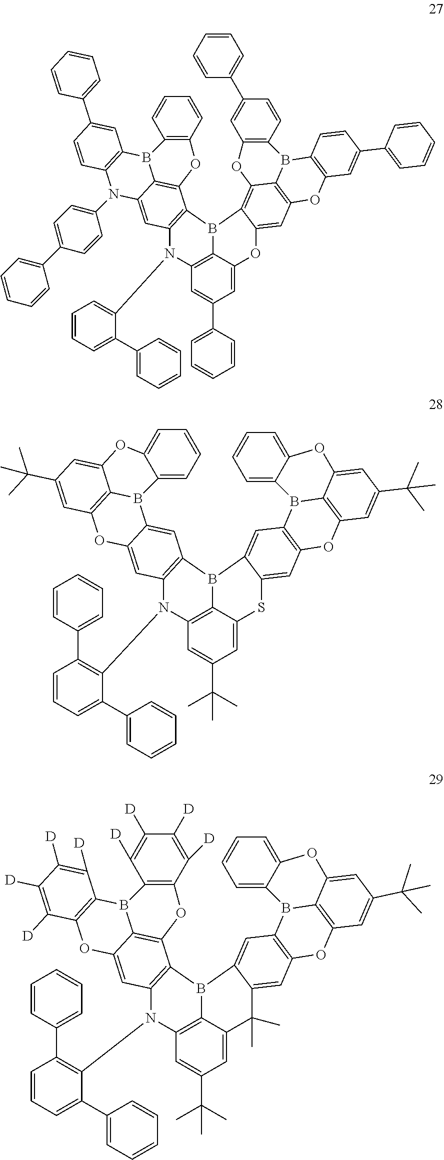 [SMILES: c1ccc(-c2ccc(N3c4ccc(-c5ccccc5)cc4B4c5ccccc5Oc5c4c3cc3c5B4c5c(cc(-c6ccccc6)cc5N3c3ccccc3-c3ccccc3)Oc3cc5c6c(c34)Oc3cc(-c4ccccc4)ccc3B6c3ccc(-c4ccccc4)cc3O5)cc2)cc1 ; CC(C)(C)c1cc2c3c(c1)Oc1cc4c(cc1B3c1ccccc1O2)B1c2cc3c(cc2N(c2c(-c5ccccc5)cccc2-c2ccccc2)c2cc(C(C)(C)C)cc(c21)S4)Oc1cc(C(C)(C)C)cc2c1B3c1ccccc1O2 ; [2H]c1c([2H])c([2H])c2c(c1[2H])Oc1cc3c(c4c1B2c1c([2H])c([2H])c([2H])c([2H])c1O4)B1c2cc4c(cc2C(C)(C)c2cc(C(C)(C)C)cc(c21)N3c1c(-c2ccccc2)cccc1-c1ccccc1)Oc1cc(C(C)(C)C)cc2c1B4c1ccccc1O2]

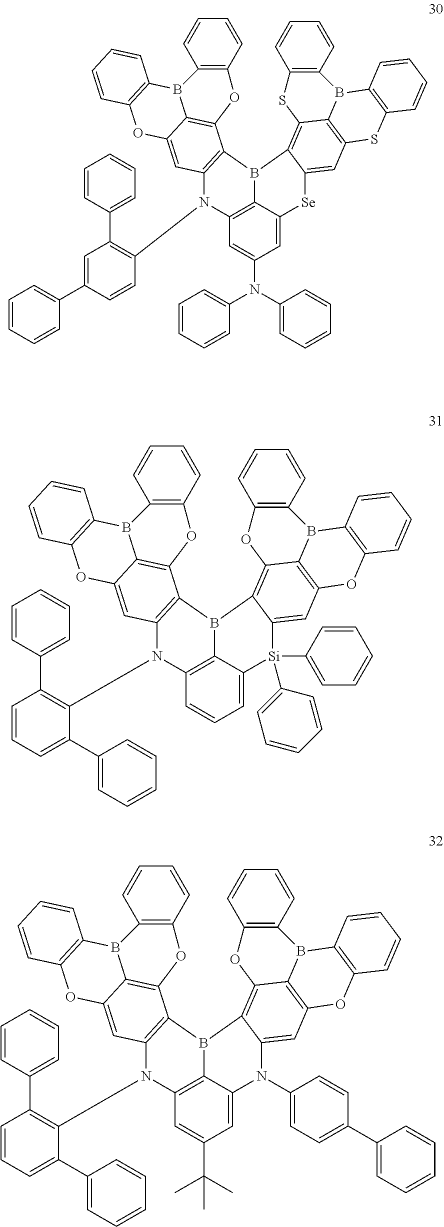 [SMILES: c1ccc(-c2ccc(N3c4cc(N(c5ccccc5)c5ccccc5)cc5c4B(c4c3cc3c6c4Oc4ccccc4B6c4ccccc4O3)c3c(cc4c6c3Sc3ccccc3B6c3ccccc3S4)[Se]5)c(-c3ccccc3)c2)cc1 ; c1ccc(-c2cccc(-c3ccccc3)c2N2c3cccc4c3B(c3c2cc2c5c3Oc3ccccc3B5c3ccccc3O2)c2c(cc3c5c2Oc2ccccc2B5c2ccccc2O3)[Si]4(c2ccccc2)c2ccccc2)cc1 ; CC(C)(C)c1cc2c3c(c1)N(c1c(-c4ccccc4)cccc1-c1ccccc1)c1cc4c5c(c1B3c1c(cc3c6c1Oc1ccccc1B6c1ccccc1O3)N2c1ccc(-c2ccccc2)cc1)Oc1ccccc1B5c1ccccc1O4]

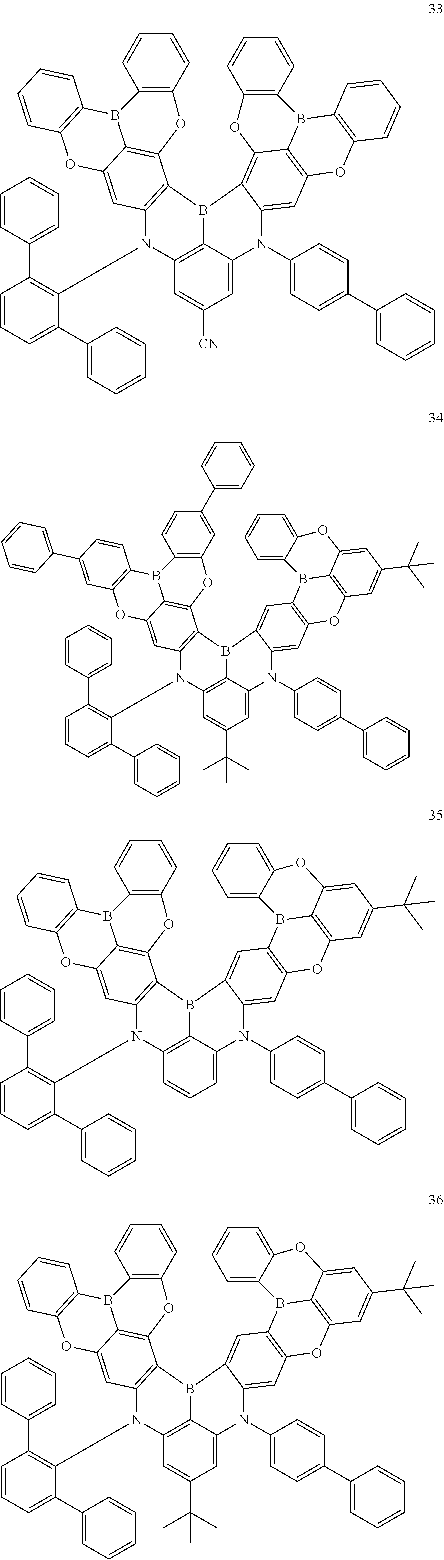

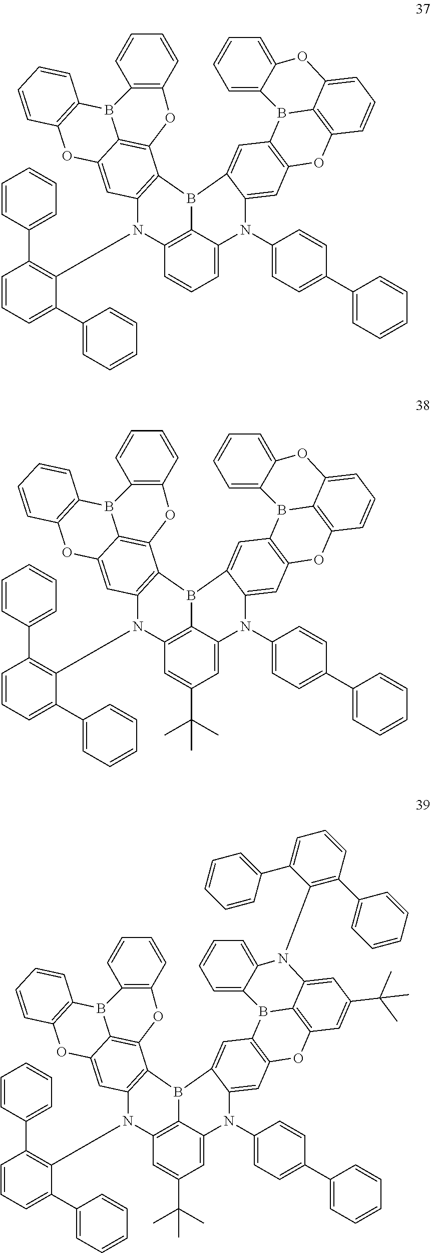 [SMILES: c1ccc(-c2ccc(N3c4cc5c(cc4B4c6c3cccc6N(c3c(-c6ccccc6)cccc3-c3ccccc3)c3cc6c7c(c34)Oc3ccccc3B7c3ccccc3O6)B3c4ccccc4Oc4cccc(c43)O5)cc2)cc1 ; CC(C)(C)c1cc2c3c(c1)N(c1c(-c4ccccc4)cccc1-c1ccccc1)c1cc4c5c(c1B3c1cc3c(cc1N2c1ccc(-c2ccccc2)cc1)Oc1cccc2c1B3c1ccccc1O2)Oc1ccccc1B5c1ccccc1O4 ; CC(C)(C)c1cc2c3c(c1)N(c1c(-c4ccccc4)cccc1-c1ccccc1)c1ccccc1B3c1cc3c(cc1O2)N(c1ccc(-c2ccccc2)cc1)c1cc(C(C)(C)C)cc2c1B3c1c(cc3c4c1Oc1ccccc1B4c1ccccc1O3)N2c1c(-c2ccccc2)cccc1-c1ccccc1]

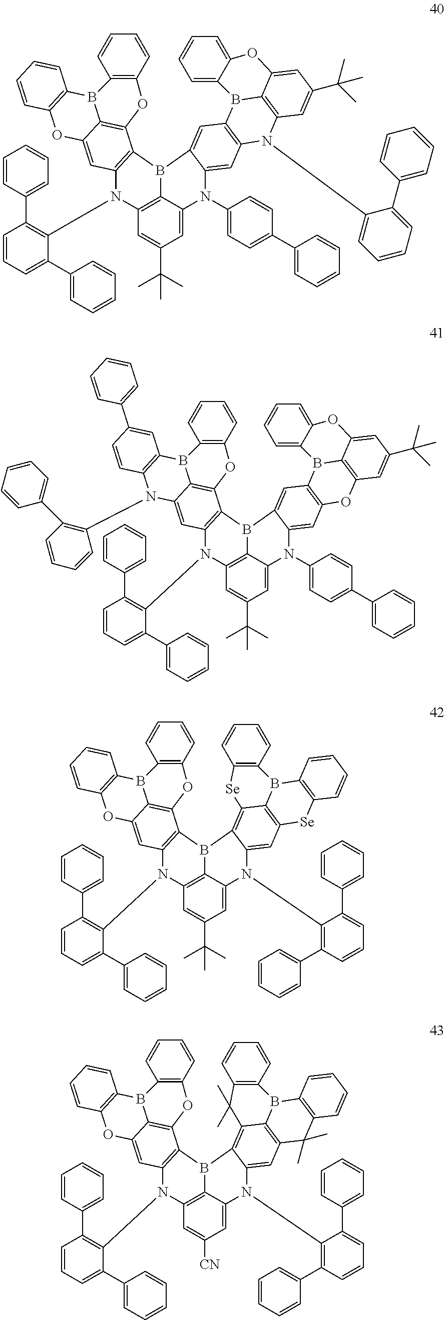

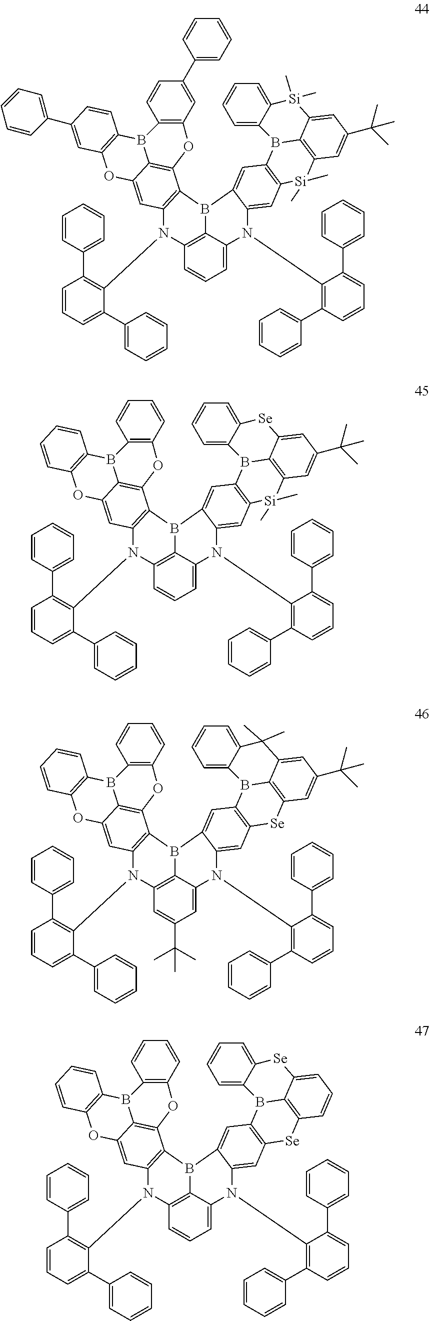

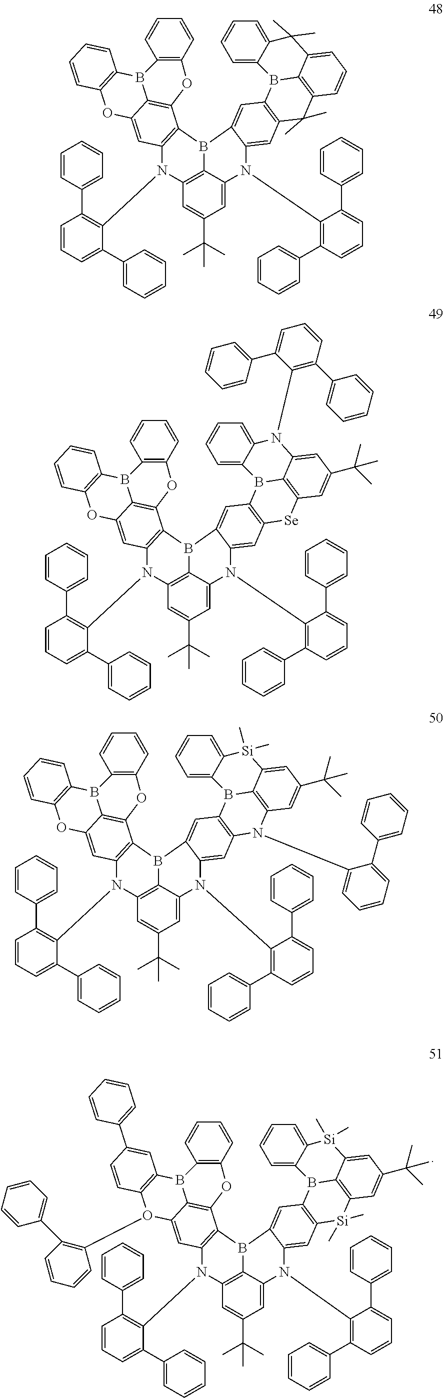

An emission spectrum of the fused polycyclic compound according to some example embodiments, represented by Formula 1, has a full width at half maximum of about 10 nm to about 50 nm, and preferably, about 20 nm to about 40 nm. Since the emission spectrum has the full width at half maximum of a first dopant according to some example embodiments falling within the above-described range, when the first dopant according to some example embodiments is applied to an element, an emission efficiency may be improved, thereby improving the power consumption efficiency of the element and any device including same. In addition, when the first dopant according to some example embodiments is used as a blue light-emitting element material for a light-emitting element, an element lifespan may be improved, thereby improving the reliability of the light-emitting element and any device including same.

In some example embodiments, the fused polycyclic compound according to some example embodiments, represented by Formula 1 may be a thermally activated delayed fluorescence emission material. In addition, the fused polycyclic compound according to some example embodiments, represented by Formula 1 may be a thermally activated delayed fluorescence dopant having a difference (ΔE_{ST}) between a lowest triplet excited energy level (T1 level) and a lowest singlet excited energy level (S1 level) of about 0.6 eV or less. The fused polycyclic compound according to some example embodiments, represented by Formula 1 may be a thermally activated delayed fluorescence dopant having a difference (ΔE_{ST}) between a lowest triplet excited energy level (T1 level) and a lowest singlet excited energy level (S1 level), of about 0.2 eV or less. However, example embodiments are not limited thereto.

The fused polycyclic compound according to some example embodiments, represented by Formula 1, may be an emission material that has a peak emission wavelength in a wavelength region of about 430 nm to about 490 nm. For example, the fused polycyclic compound according to some example embodiments, represented by Formula 1 may be a blue thermally activated delayed fluorescence (TADF) dopant. However, example embodiments are not limited thereto, and when the fused polycyclic compound is used as an emission material, the fused polycyclic compound may be used as a dopant material that emits light with various wavelength regions, such as a red light-emitting dopant, and a green light-emitting dopant.

In the light-emitting element ED according to some example embodiments, the emission layer EML may emit delayed fluorescence. For example, the emission layer EML may emit a thermally activated delayed fluorescence (TADF).

In addition, the emission layer EML of the light-emitting element ED may emit blue light. For example, the emission layer EML of an organic light-emitting element ED according to some example embodiments may emit blue light with a wavelength region of about 490 nm or less. However, example embodiments are not limited thereto, and the emission layer EML may emit green light or red light.

The fused polycyclic compound according to some example embodiments may be included in the emission layer EML. The fused polycyclic compound according to some example embodiments may be included as a dopant material in the emission layer EML. The fused polycyclic compound according to some example embodiments may be a thermally activated delayed fluorescence emission material. The fused polycyclic compound according to some example embodiments may be used as a thermally activated delayed fluorescence dopant. For example, the emission layer EML in the light-emitting element ED may include at least one among the fused polycyclic compounds present in Compound Group 1 described previously as a thermally activated delayed fluorescence dopant. However, a use of the fused polycyclic compound according to some example embodiments is not limited thereto.

According to some example embodiments, the emission layer EML may include a plurality of compounds. The emission layer EML according to some example embodiments may include the fused polycyclic compound represented by Formula 1, that is, the first compound, and may additionally include at least one among a second compound represented by Formula HT-1 below, a third compound represented by Formula ET-1 below, and a fourth compound represented by Formula D-1 below.

According to some example embodiments, the emission layer EML may include the first compound represented by Formula 1, and may additionally include at least any one of the second compound represented by Formula HT-1 below or the third compound represented by Formula ET-1 below.

According to some example embodiments, the emission layer EML may include the second compound represented by Formula HT-1 below. According to some example embodiments, the second compound may be used as a hole-transporting host material.

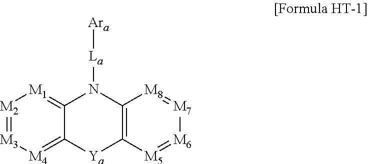

In Formula HT-1, M₁ to M₈ may be N or CR₅₁. For example, M₁ to M₈ may be all CR₅₁. In some example embodiments, any one of M₁ to M₈ may be N, and the rest thereof may be CR₅₁.

In Formula HT-1, Lₐ may be a direct linkage, a substituted or unsubstituted arylene group having a ring-forming carbon number of 6 to 30, or a substituted or unsubstituted heteroarylene group having a ring-forming carbon number of 2 to 30. For example, Lₐ may be a direct linkage, a substituted or unsubstituted phenylene group, a substituted or unsubstituted divalent biphenyl group, or a substituted or unsubstituted divalent carbazole group, but example embodiments of the inventive concepts are not limited thereto.

In Formula HT-1, Yₐ may be a direct linkage, CR₅₂R₅₃ or SiR₅₄R₅₅. That is, two benzene rings connected to a nitrogen atom of Formula HT-1 may be connected through a direct linkage,

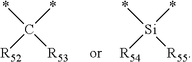

In Formula HT-1, when Yₐ is a direct linkage, a substituent represented by Formula HT-1 may include a carbazole moiety.

In Formula HT-1, Arₐ may be a substituted or unsubstituted aryl group having a ring-forming carbon number of 6 to 30, or a substituted or unsubstituted heteroaryl group having a ring-forming carbon number of 2 to 30. For example, Arₐ may be a substituted or unsubstituted carbazole group, a substituted or unsubstituted dibenzofuran group, a substituted or unsubstituted dibenzothiophene group, or a substituted or unsubstituted biphenyl group, but example embodiments of the inventive concepts are not limited thereto.

In Formula HT-1, R₅₁ to R₅₅ may be each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having a carbon number of 1 to 20, a substituted or unsubstituted alkenyl group having a carbon number of 2 to 20, a substituted or unsubstituted aryl group having a ring-forming carbon number of 6 to 60, or a substituted or unsubstituted heteroaryl group having a ring-forming carbon number of 2 to 60. In some example embodiments, each of R₅₁ to R₅₅ may be combined with an adjacent group to form a ring. For example, R₅₁ to R₅₅ may be each independently a hydrogen atom or a deuterium atom. R₅₁ to R₅₅ may be each independently an unsubstituted methyl group or an unsubstituted phenyl group.

The second compound represented by Formula HT-1 according to some example embodiments may be represented by any one among compounds represented by Compound Group 2 below. The emission layer EML may include, as the hole-transporting host material, at least one among compounds represented by Compound Group 2 below (e.g., at least one of Compounds HT1 to HT60).

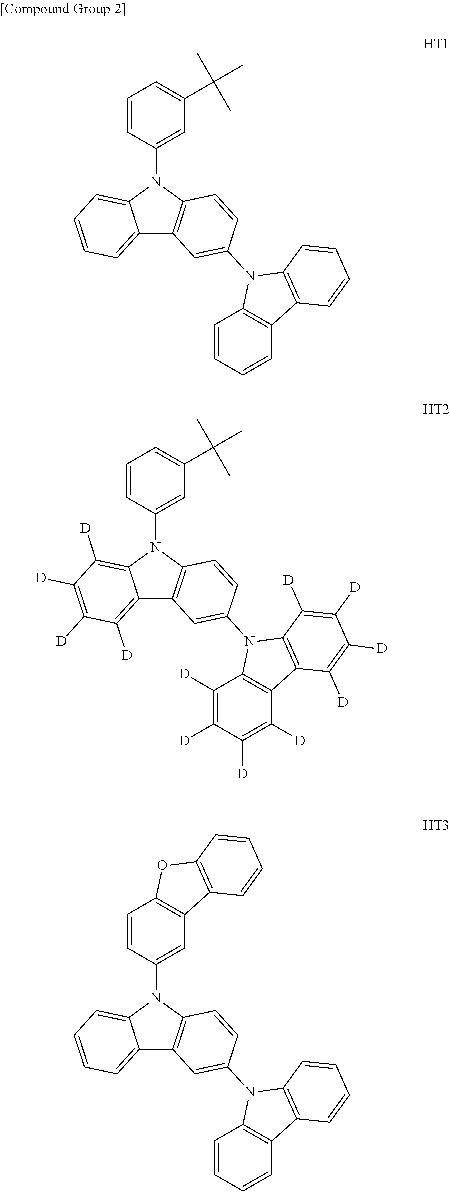 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

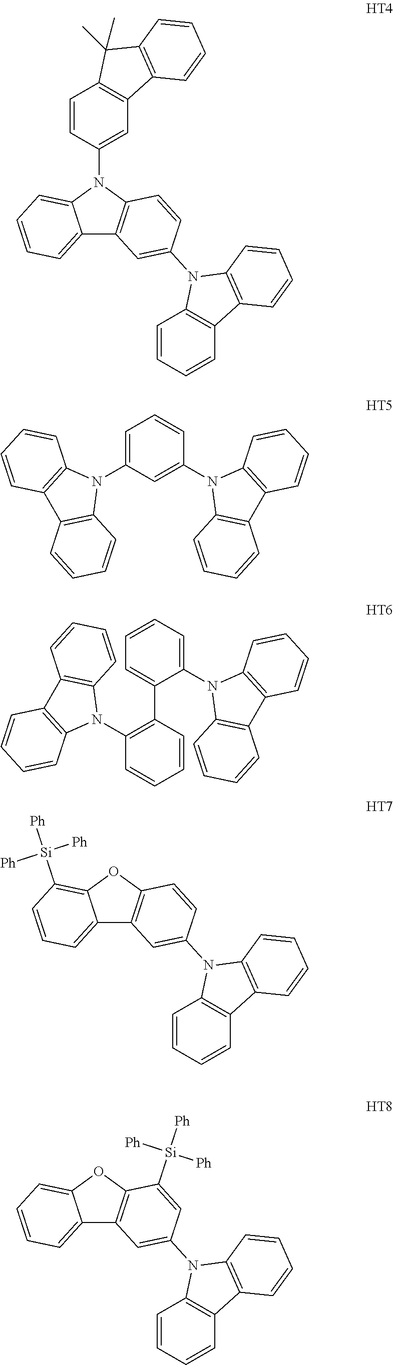

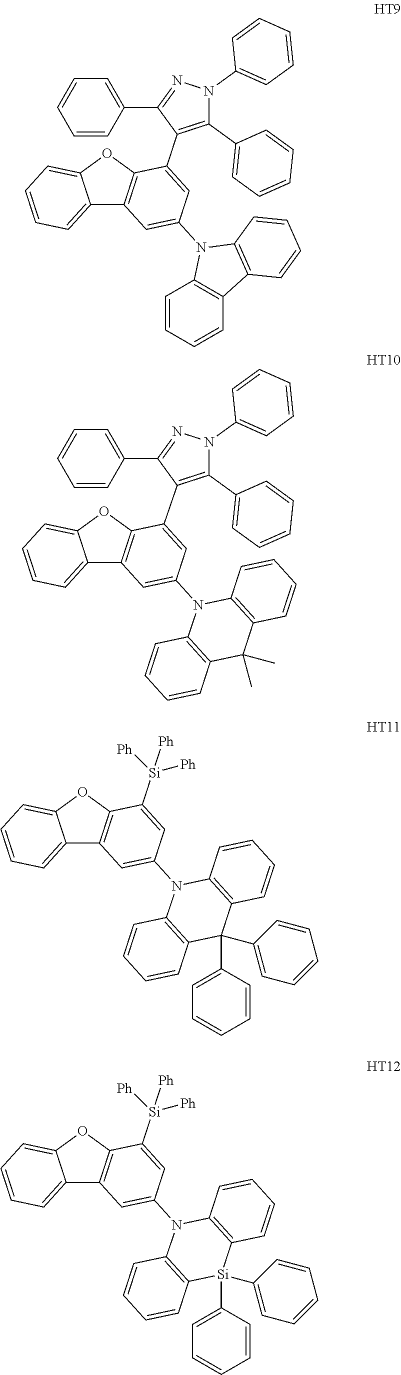

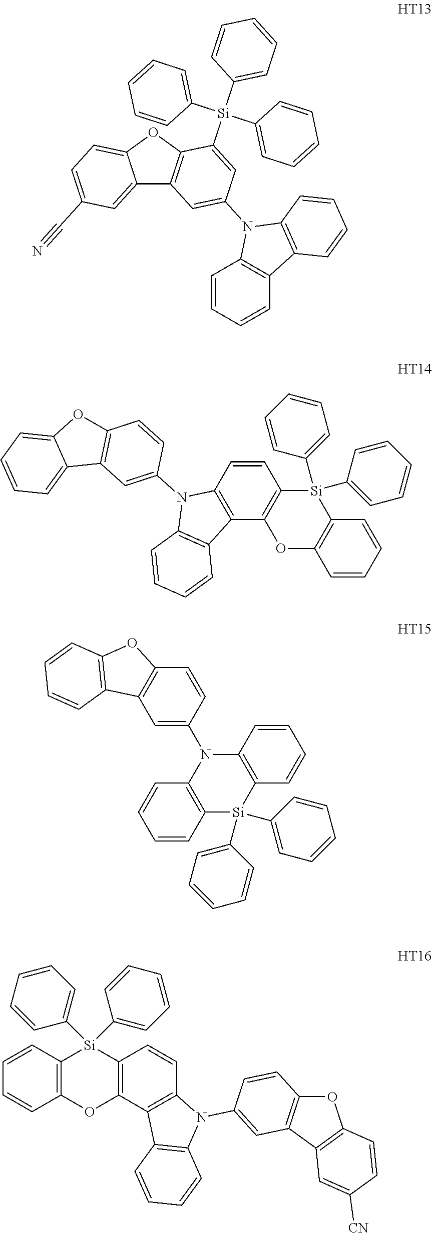 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

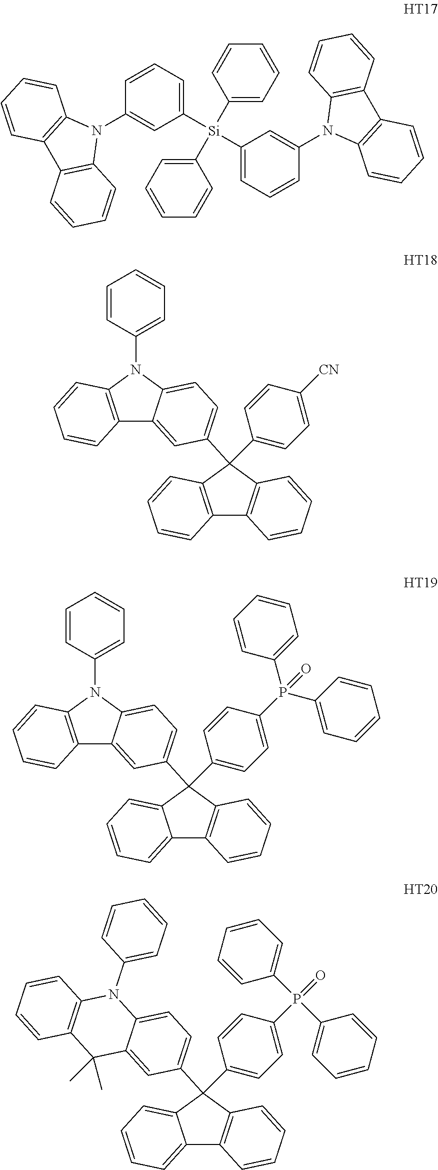

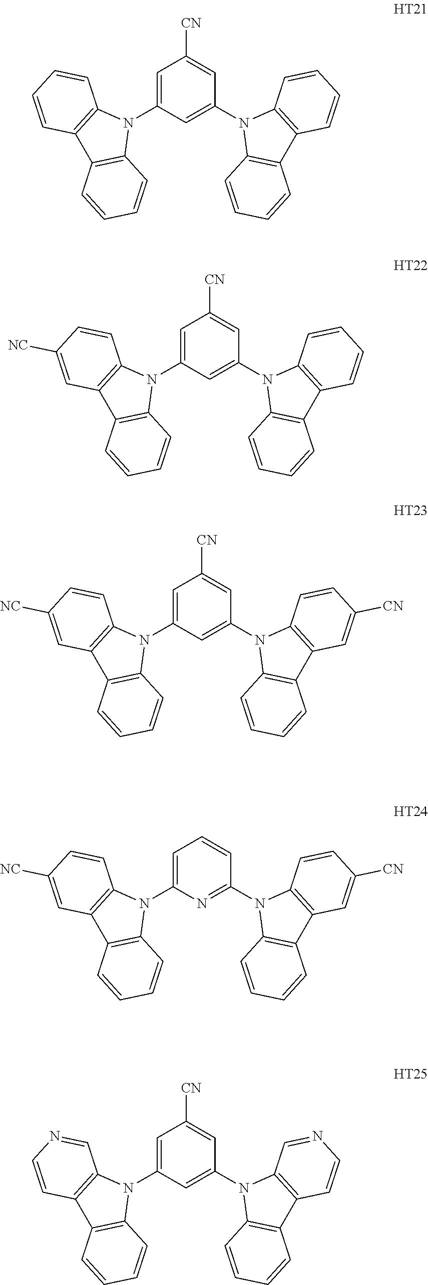 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1]

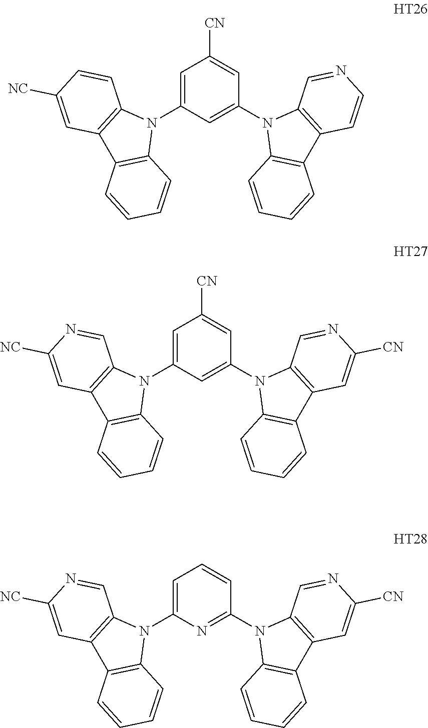 [SMILES: N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

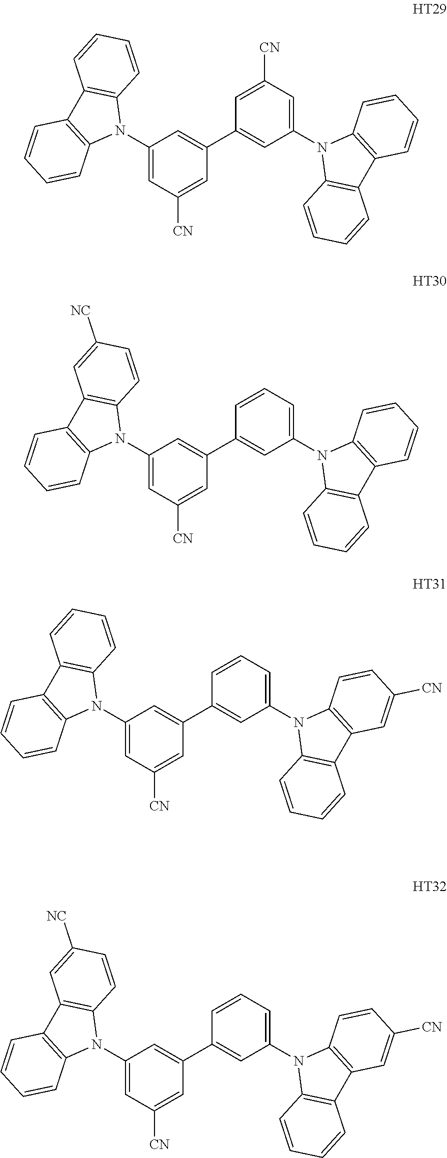 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1]

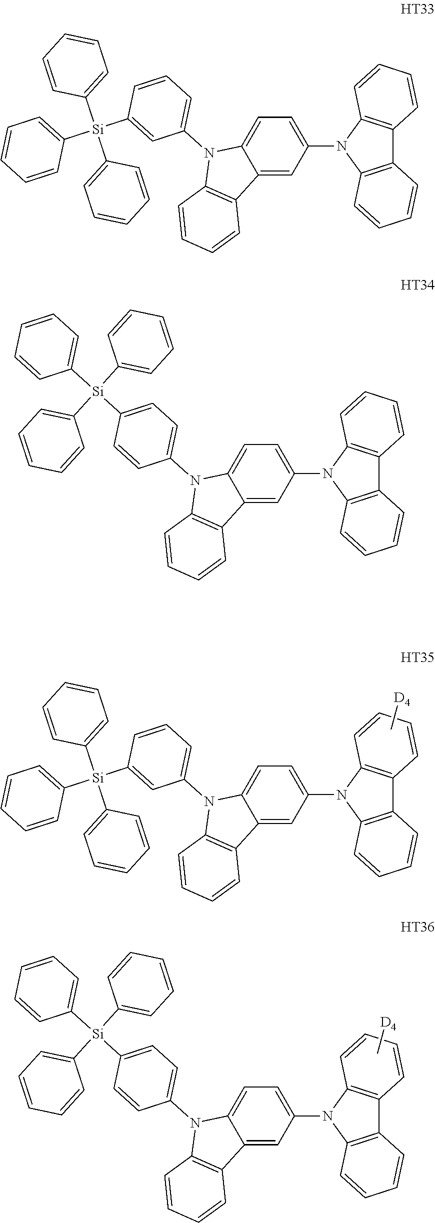

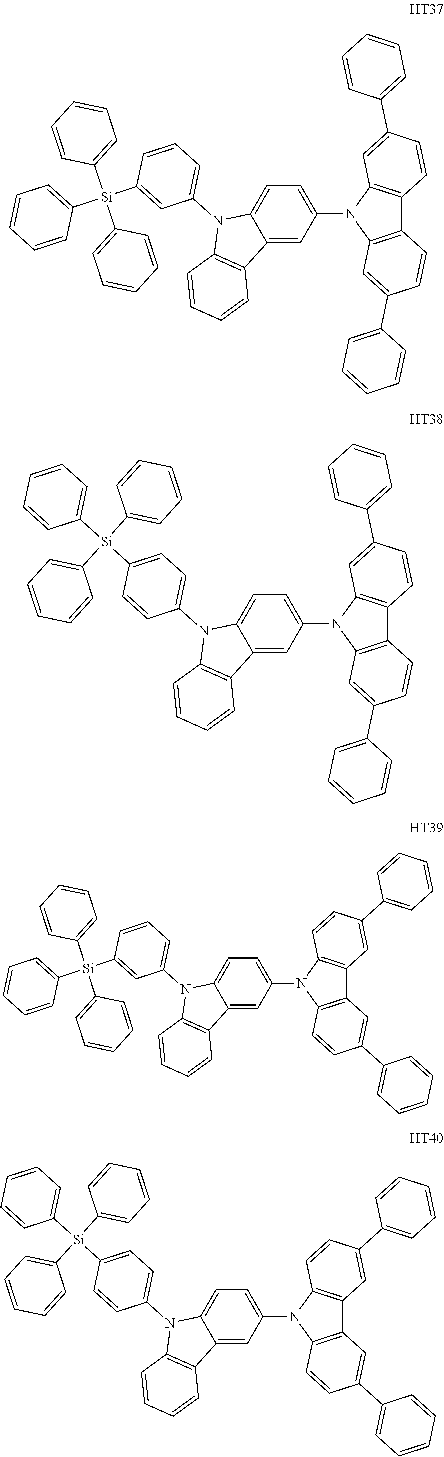 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

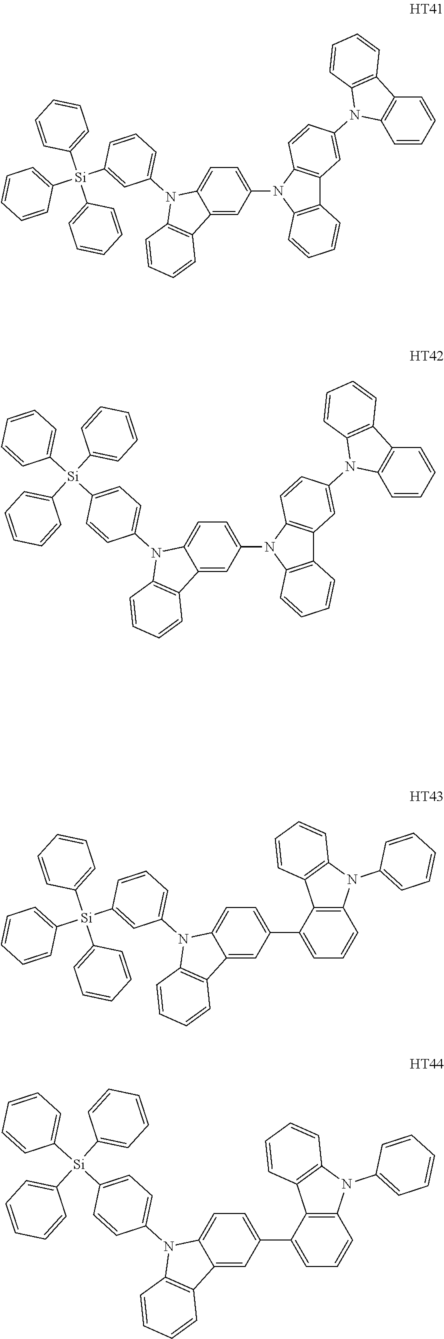 [SMILES: c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1 ; c1ccc(-n2c3ccccc3c3c(-c4ccc5c(c4)c4ccccc4n5-c4cccc([Si](c5ccccc5)(c5ccccc5)c5ccccc5)c4)cccc32)cc1 ; c1ccc(-n2c3ccccc3c3c(-c4ccc5c(c4)c4ccccc4n5-c4ccc([Si](c5ccccc5)(c5ccccc5)c5ccccc5)cc4)cccc32)cc1]

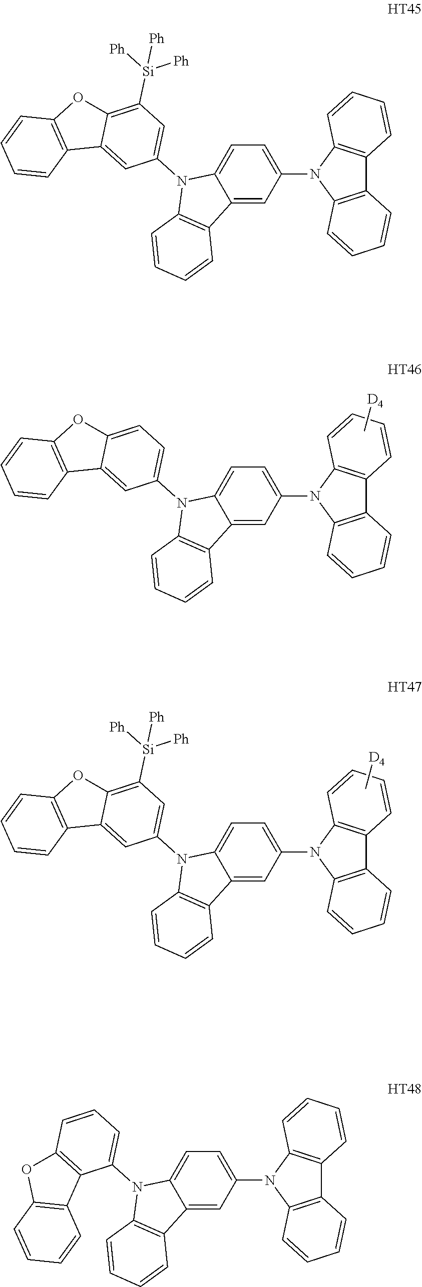

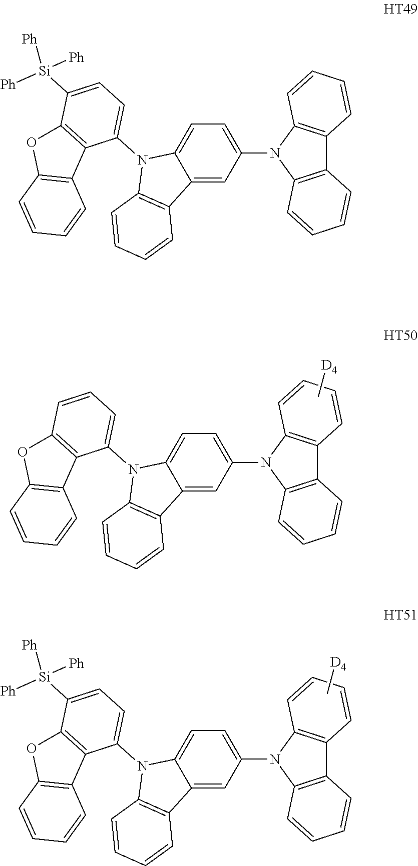

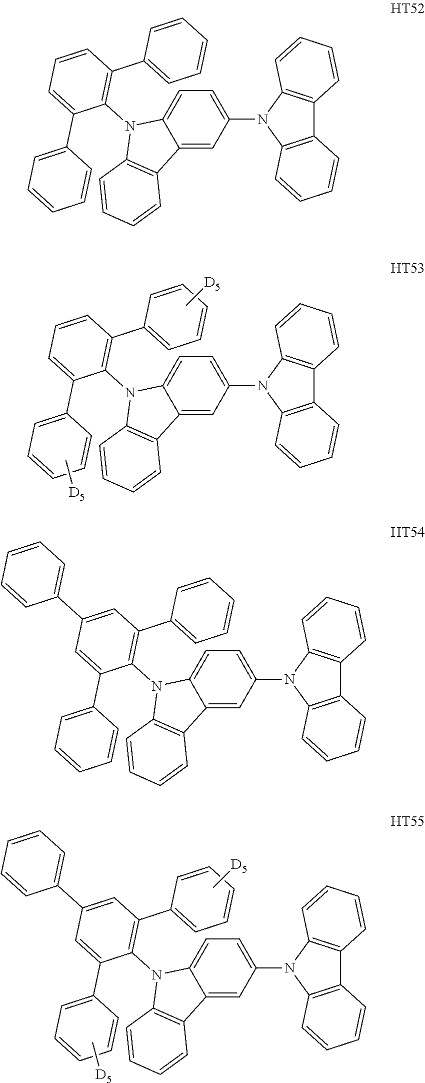

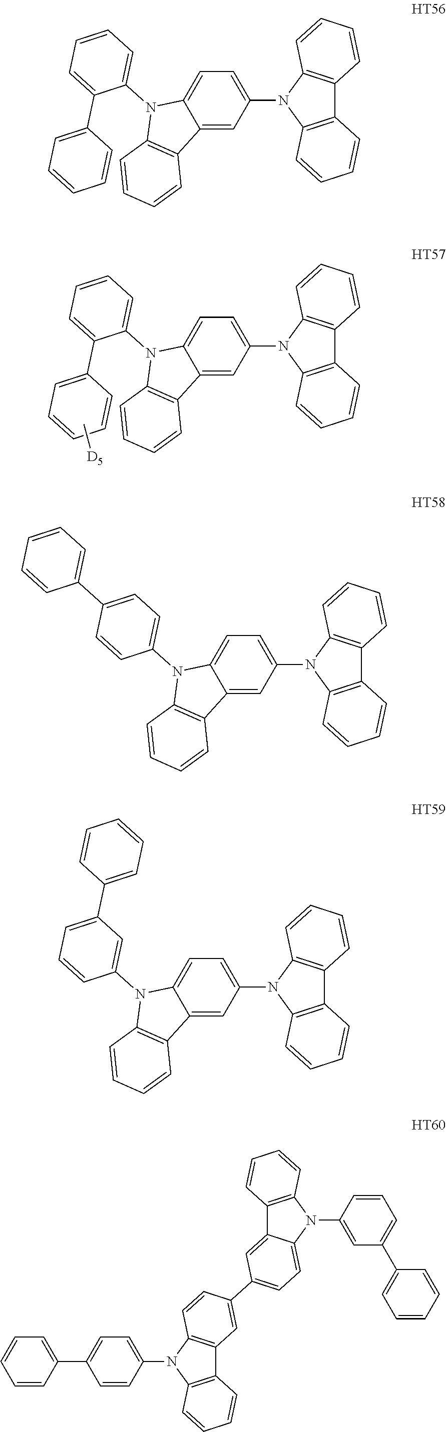

In example compounds suggested in Compound Group 2, “D” may mean a deuterium atom, and “Ph” may be an unsubstituted phenyl group.

According to some example embodiments, the emission layer EML may include a third compound represented by Formula ET-1 below. For example, the third compound may be used as an electron-transporting host material of the emission layer EML.

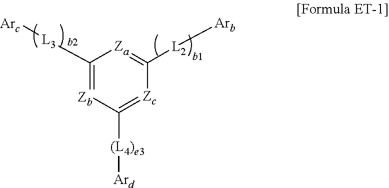

In Formula ET-1, at least one Zₐ to Zₑ is N, and the rest thereof CR₅₆ (e.g., a remainder of Zₐ to Z_{c} may each be CR₅₆). For example, any one of Zₐ to Zₑ may be N, and the rest two may be each independently CR₅₆. In this case, the third compound represented by Formula ET-1 may include a pyridine moiety. In some example embodiments, two of Zₐ to Zₑ may be N, and the rest one may be CR₅₆. In this case, the third compound represented by Formula ET-1 may include a pyrimidine moiety. In some example embodiments, all of Zₐ to Z_{c} may be N. In this case, the third compound represented by Formula ET-1 may include a triazine moiety.

In Formula ET-1, R₅₆ may be a hydrogen atom, a deuterium atom, a substituted or unsubstituted alkyl group having a carbon number of 1 to 20, a substituted or unsubstituted aryl group having a ring-forming carbon number of 6 to 60, or a substituted or unsubstituted heteroaryl group having a ring-forming carbon number of 2 to 60.

In Formula ET-1, b1 to b3 may be each independently an integer of 0 to 10.

In Formula ET-1, Ar_{b} to Ar_{d} may be each independently a hydrogen atom, a deuterium atom, a substituted or unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30. For example, Ar_{b} to Ar_{d} may be a substituted or unsubstituted phenyl group, or a substituted or unsubstituted carbazole group.

In Formula ET-1, L₂ to L₄ may be each independently a direct linkage, a substituted or unsubstituted arylene group having a ring-forming carbon number of 6 to 30, or a substituted or unsubstituted heteroarylene group having a ring-forming carbon number of 2 to 30. When b1 to b3 are an integer of 2 or more, L₂ to L₄ may be each independently a substituted or unsubstituted arylene group having a ring-forming carbon number of 6 to 30, or a substituted or unsubstituted heteroarylene group having a ring-forming carbon number of 2 to 30.

According to some example embodiments, the third compound may be represented by any one among compounds of Compound Group 3 below. The light-emitting element ED according to some example embodiments may include any one among compounds of Compound Group 3 below (e.g., at least one of Compounds ETH1 to ETH88). [Compound Group 3]

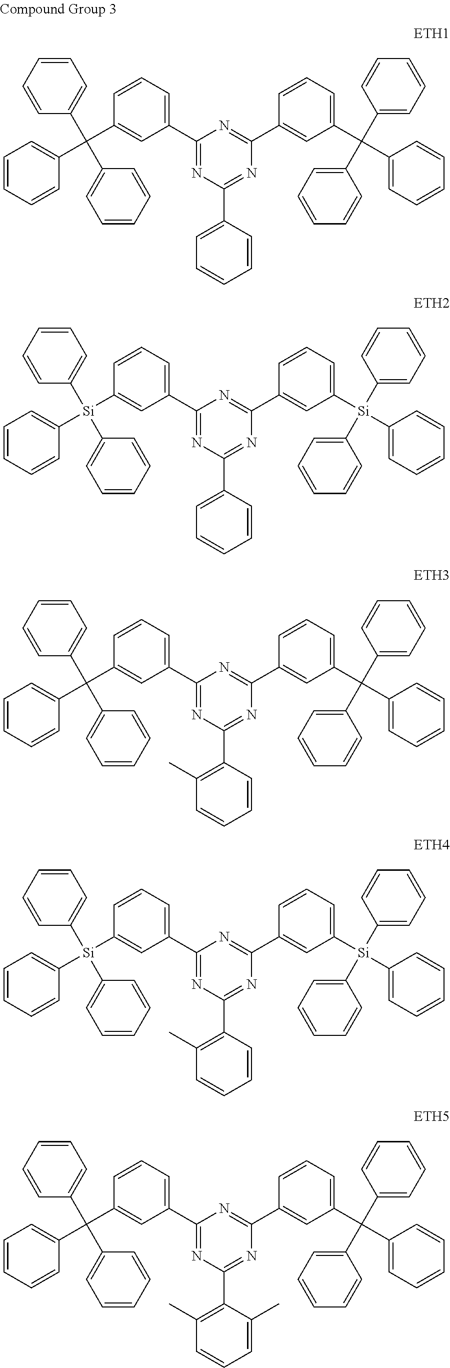

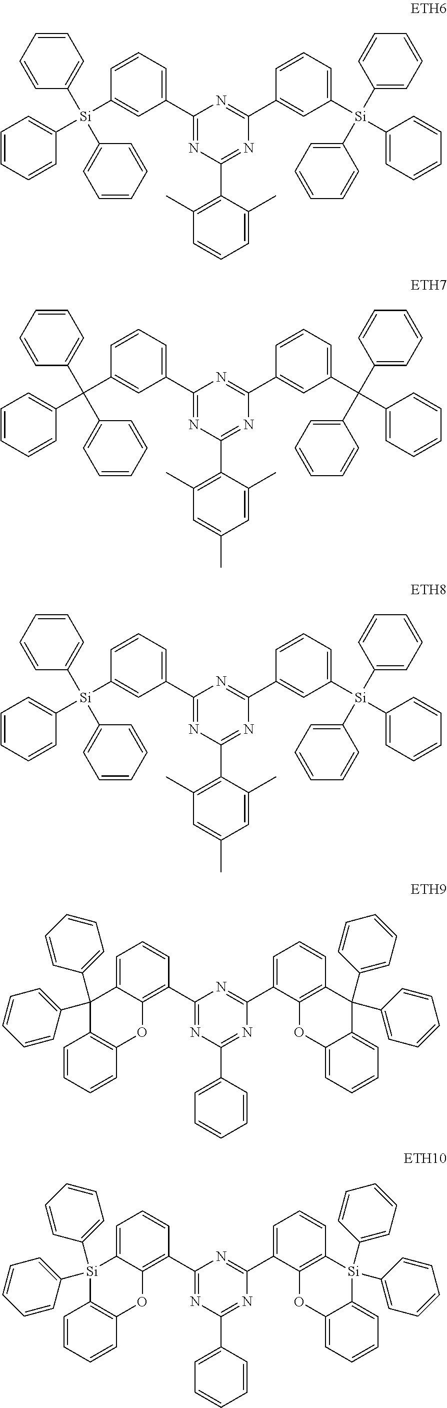

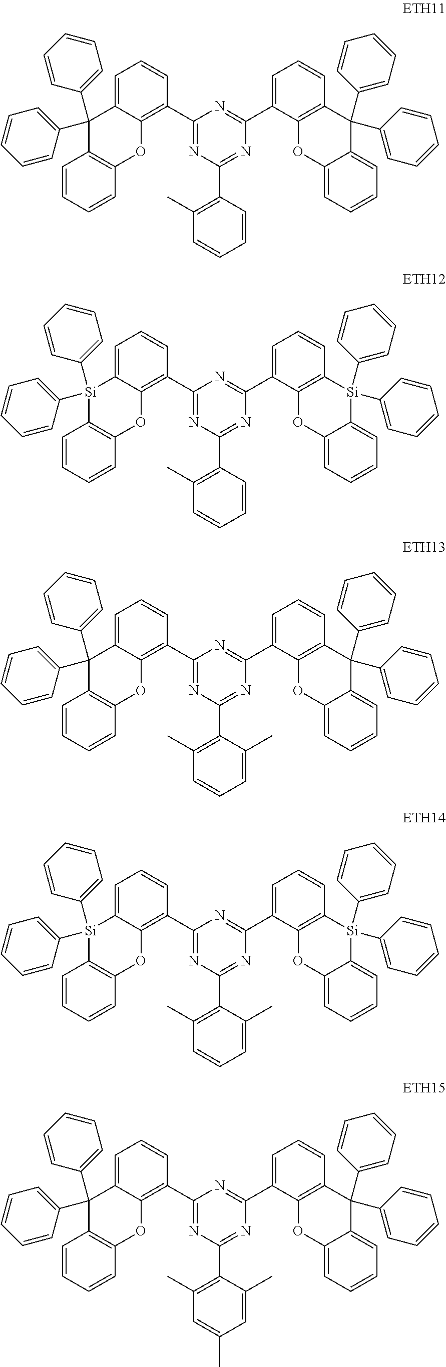

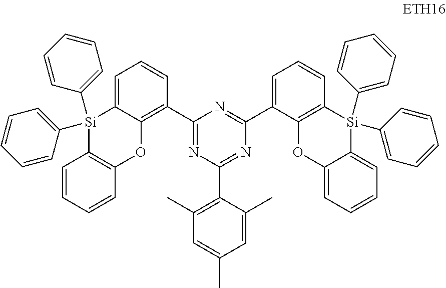 [SMILES: Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

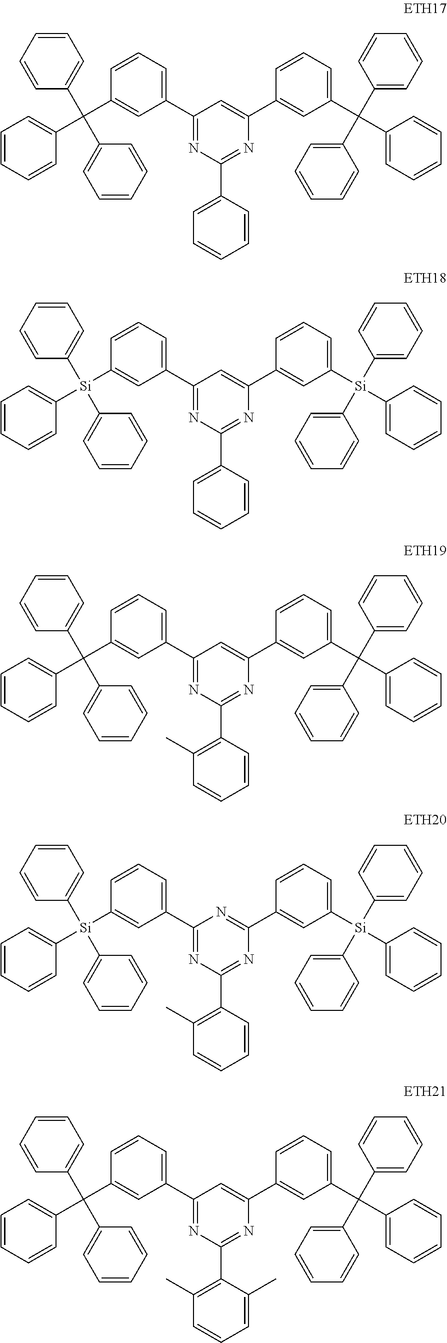

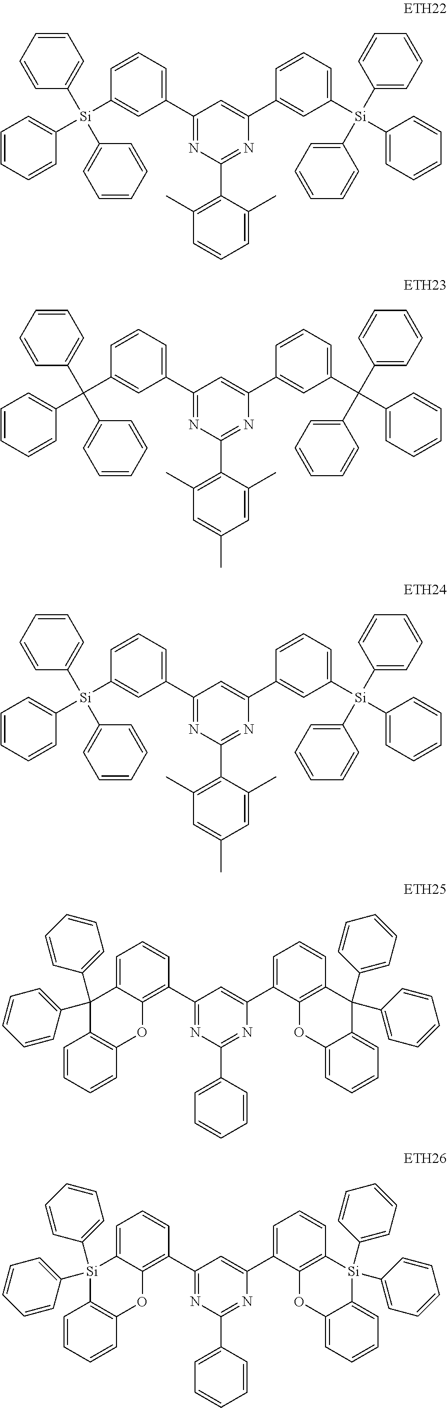

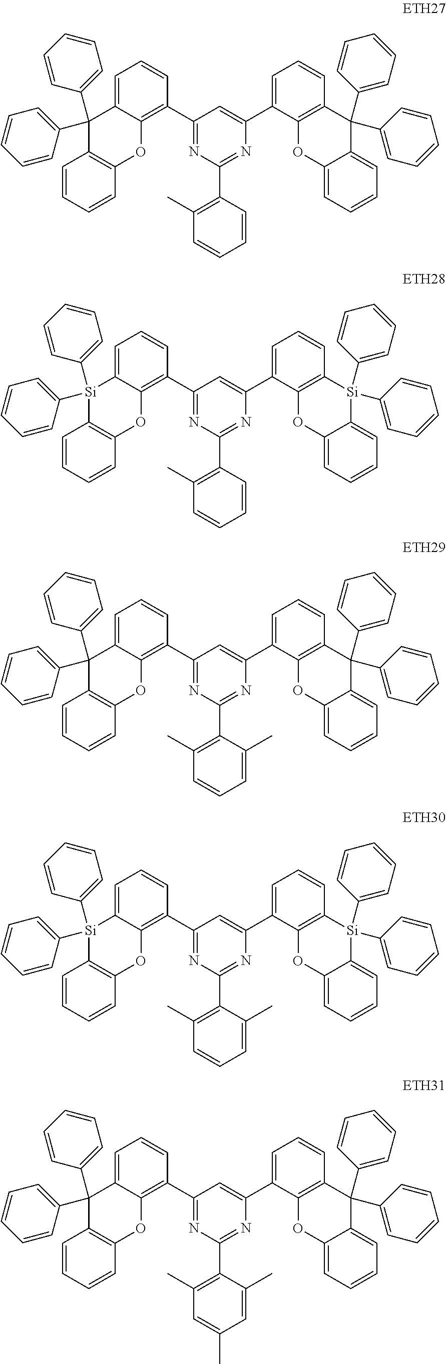

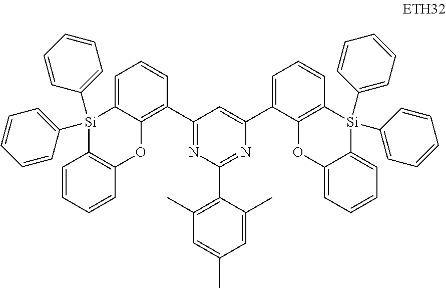 [SMILES: Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

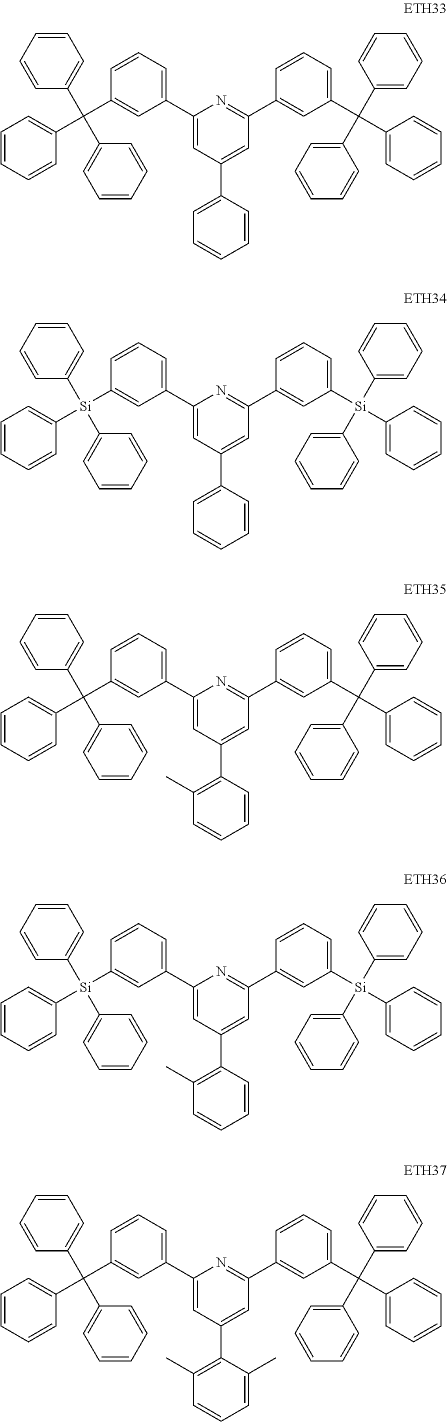

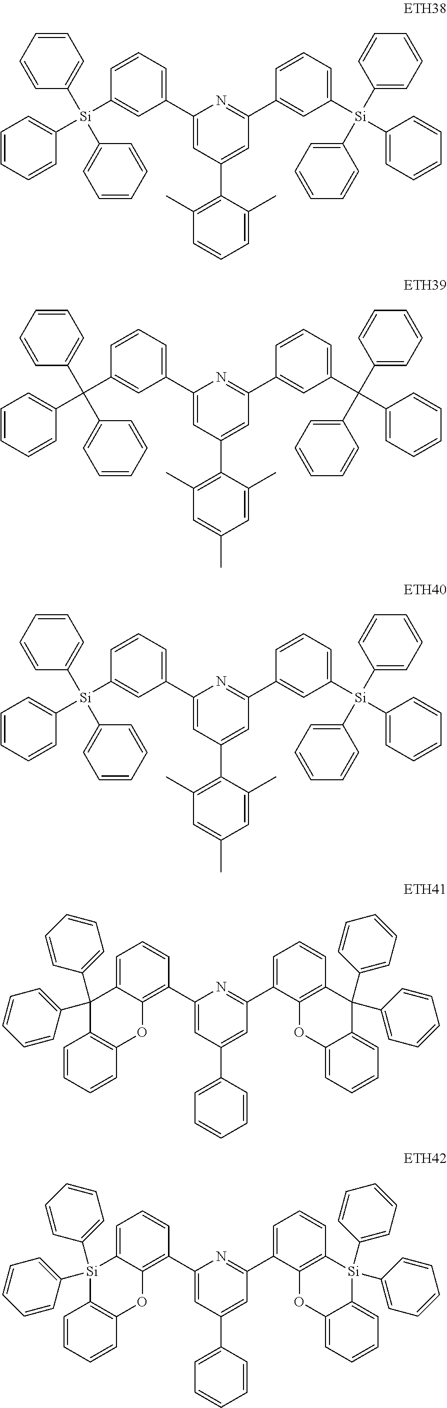

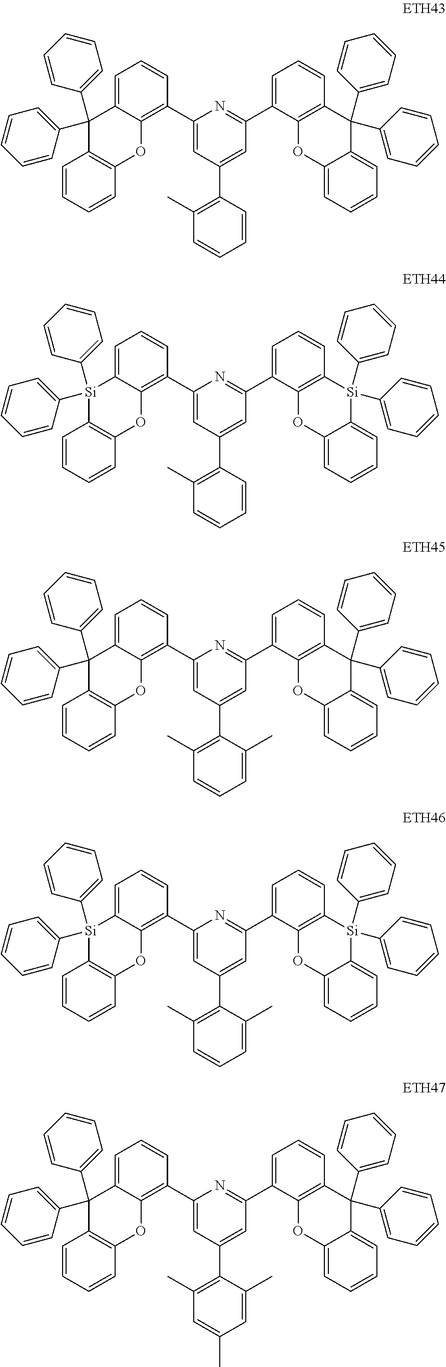

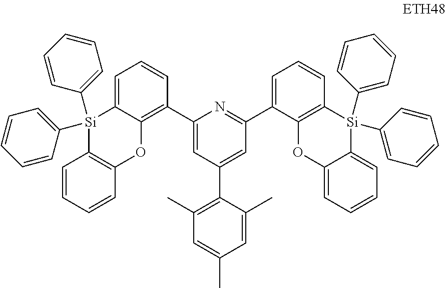 [SMILES: Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

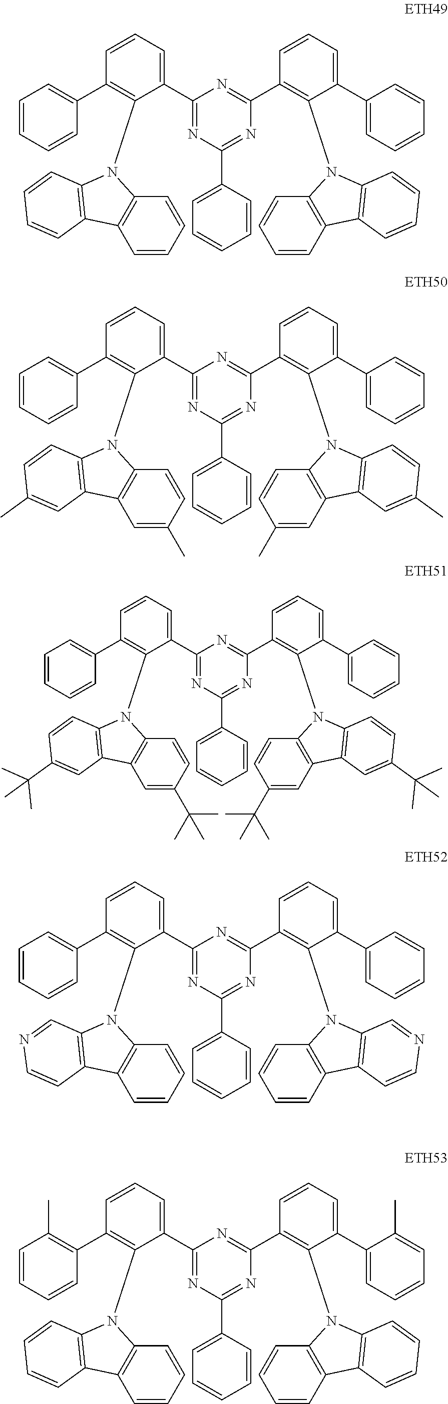

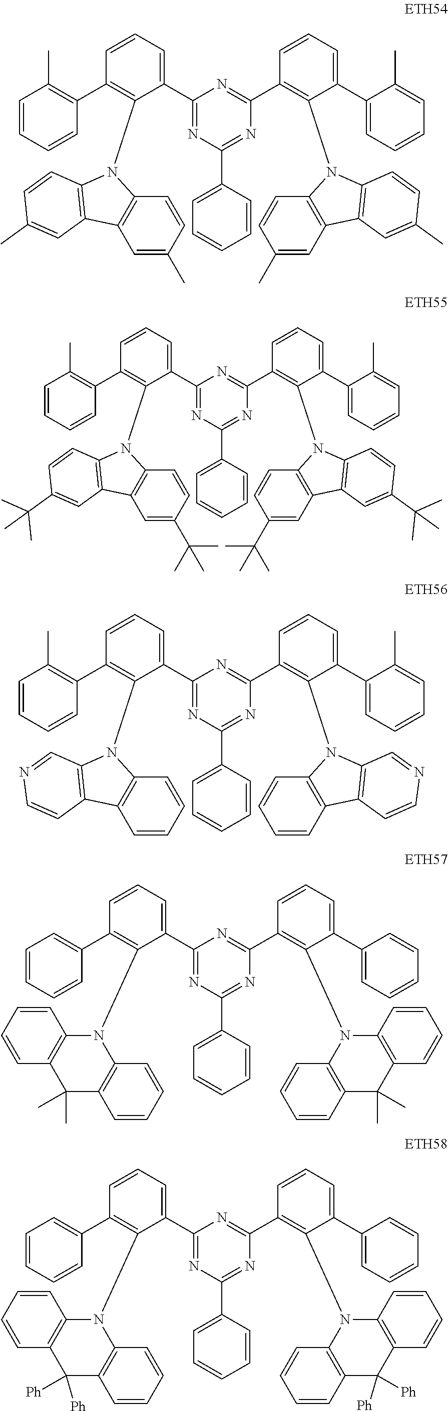

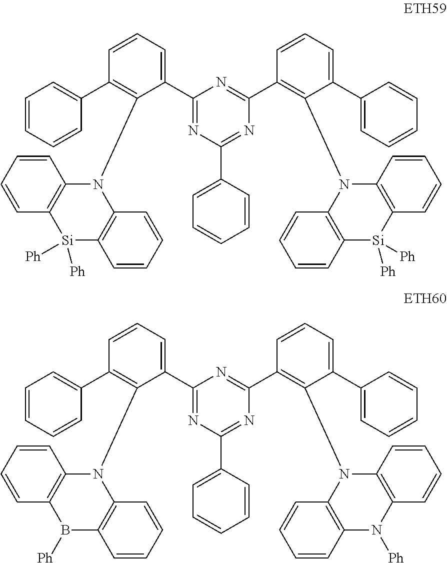 [SMILES: c1ccc(-c2nc(-c3cccc(-c4ccccc4)c3N3c4ccccc4[Si](c4ccccc4)(c4ccccc4)c4ccccc43)nc(-c3cccc(-c4ccccc4)c3N3c4ccccc4[Si](c4ccccc4)(c4ccccc4)c4ccccc43)n2)cc1 ; c1ccc(B2c3ccccc3N(c3c(-c4ccccc4)cccc3-c3nc(-c4ccccc4)nc(-c4cccc(-c5ccccc5)c4N4c5ccccc5N(c5ccccc5)c5ccccc54)n3)c3ccccc32)cc1]

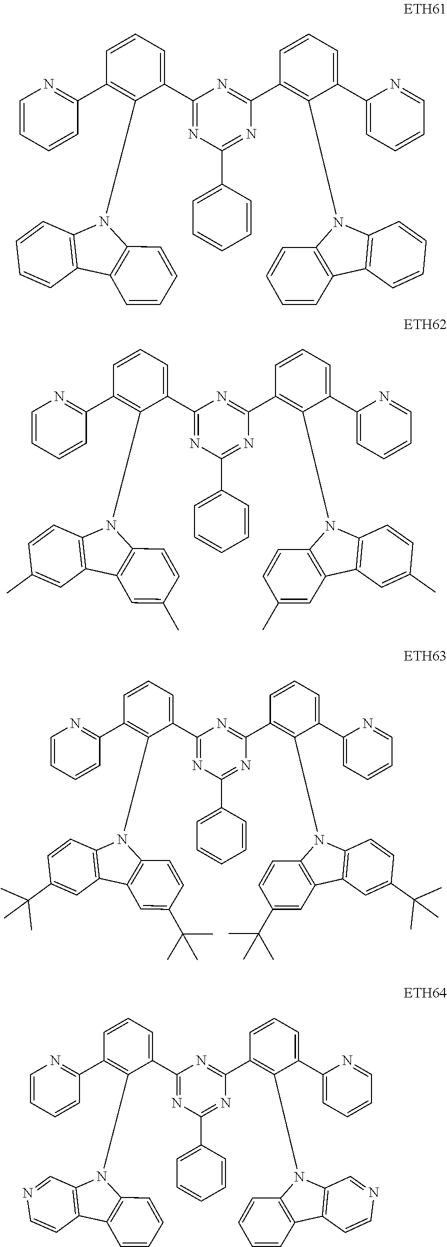

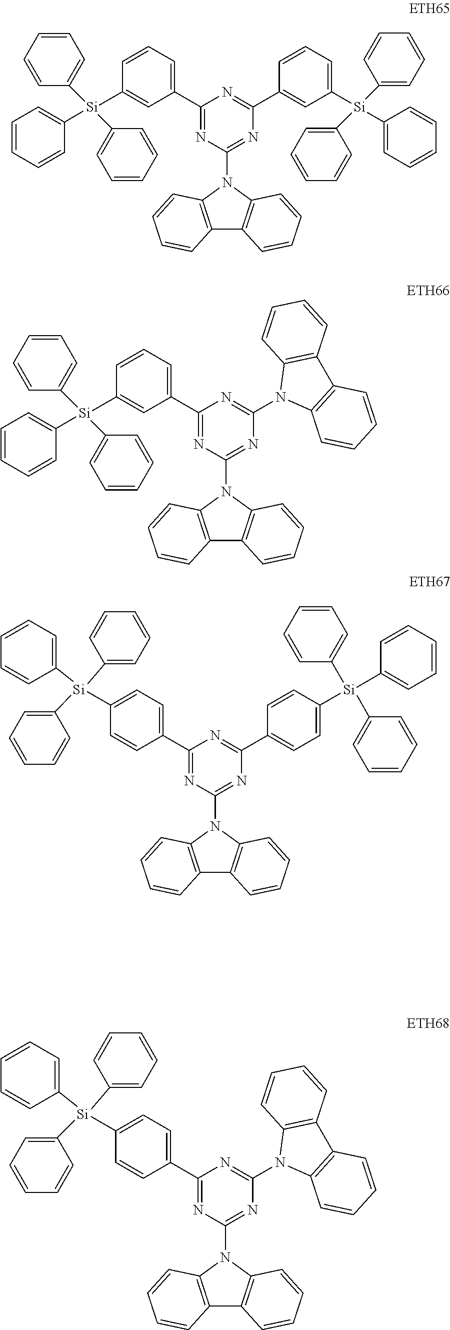 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

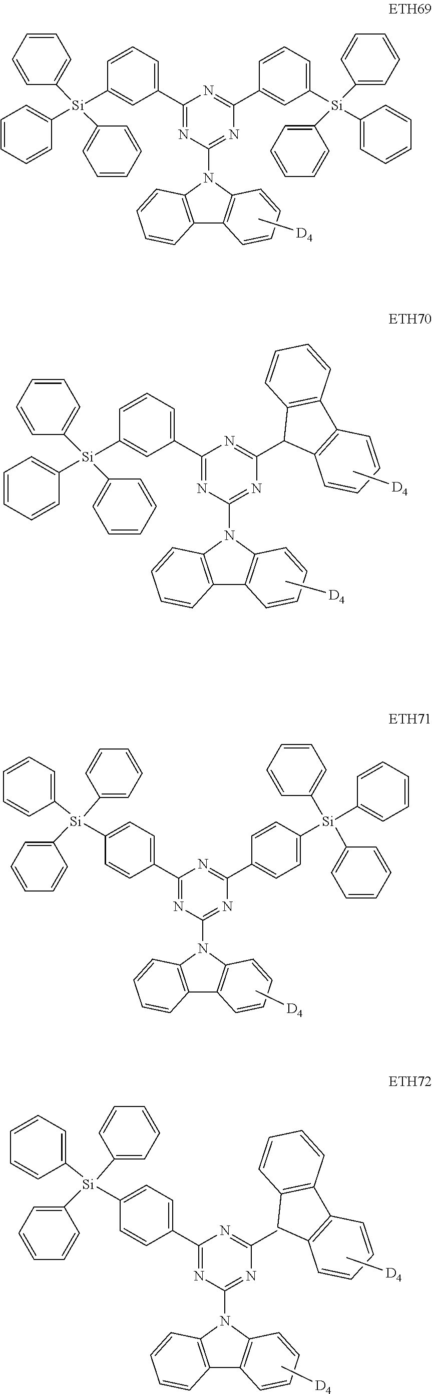

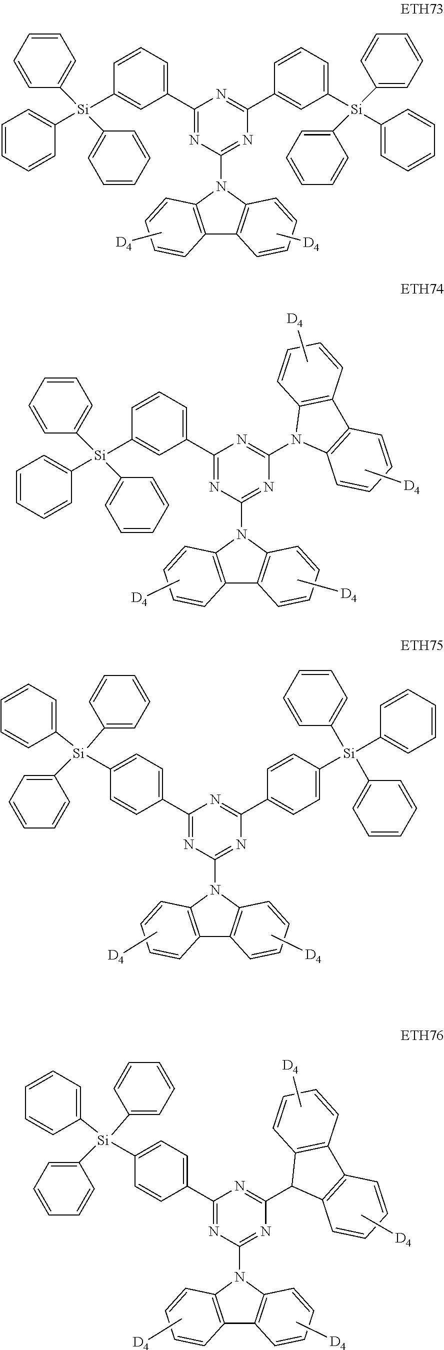

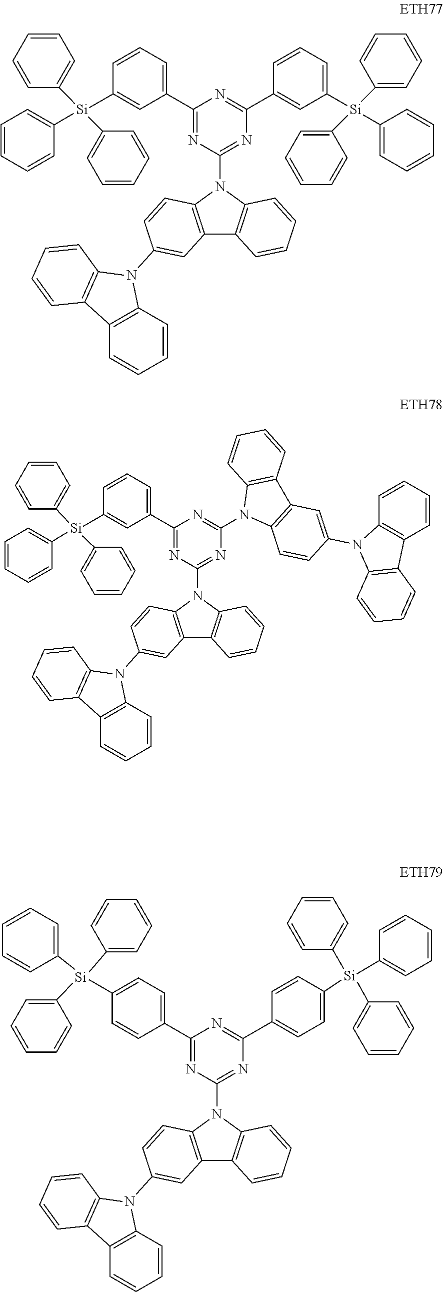 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

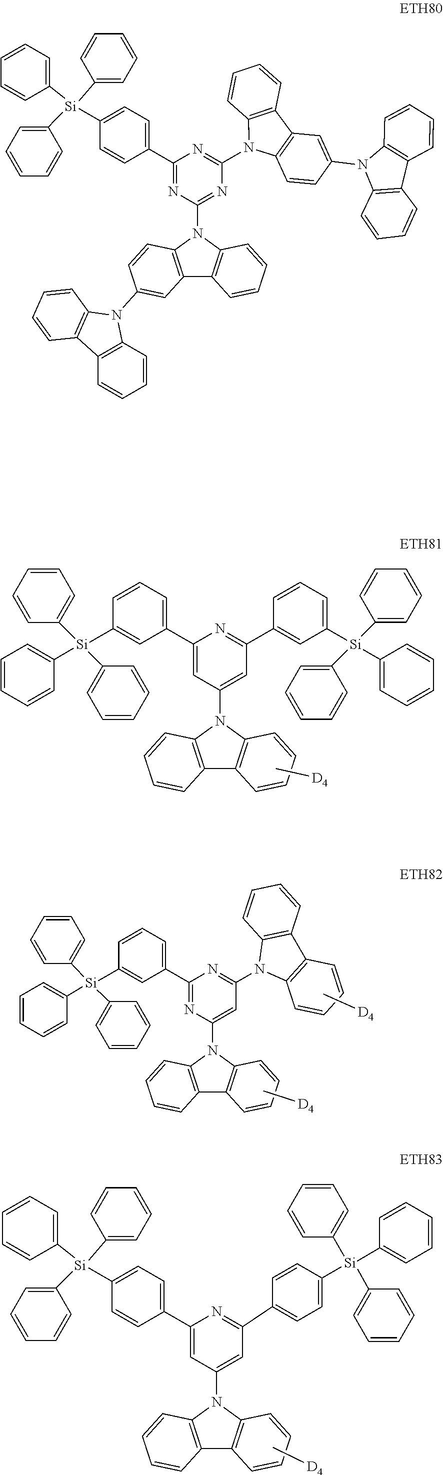

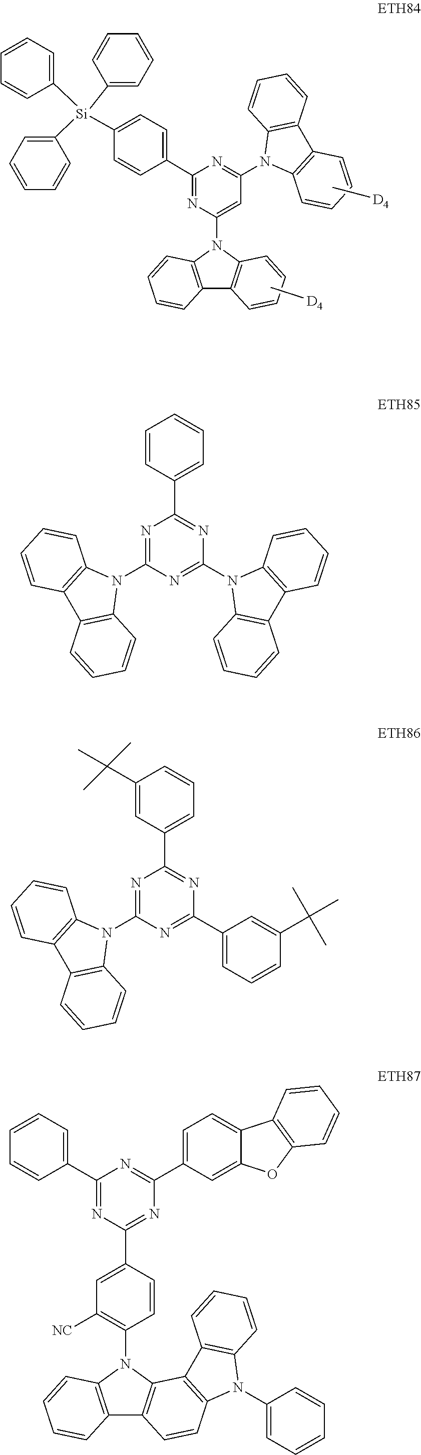

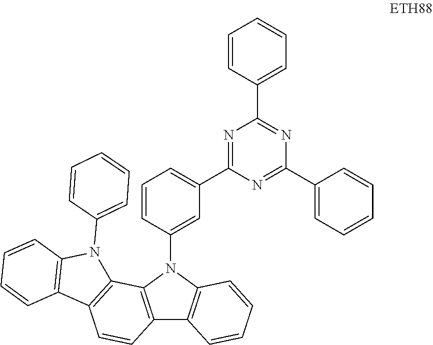 [SMILES: c1ccc(-c2nc(-c3ccccc3)nc(-c3cccc(-n4c5ccccc5c5ccc6c7ccccc7n(-c7ccccc7)c6c54)c3)n2)cc1]

In example compounds suggested in Compound Group 3, “D” means a deuterium atom, and “Ph” means an unsubstituted phenyl group.

The emission layer EML may include the second compound and the third compound, and the second compound and the third compound may form an exciplex. The exciplex may be formed in the emission layer EML by a hole-transporting host and an electron-transporting host. In this case, a triplet energy of the exciplex formed by the hole-transporting host and the electron-transporting host may correspond to a difference between a lowest unoccupied molecular orbital (LUMO) energy level of the electron-transporting host and a highest occupied molecular orbital (HOMO) energy level of the hole-transporting host.

For example, an absolute value of the triplet energy level (T1) of the exciplex formed by the hole-transporting host and the electron-transporting host may be about 2.4 eV to about 3.0 eV. In addition, the triplet energy of the exciplex may be smaller than an energy gap of each host material. The exciplex may have the triple energy equal to or less than about 3.0 eV, which is an energy gap between the hole-transporting host and the electron-transporting host.

According to some example embodiments, the emission layer EML may include a fourth compound as well as the first compound to the third compound described above. The fourth compound may be used as a phosphorescence sensitizer of the emission layer EML. Luminescence may occur by transferring energy from the fourth compound to the first compound.

For example, the emission layer EML may include, as the fourth compound, an organometallic complex including platinum (Pt) as a central metal atom, and including ligands combined with the central metal atom. The emission layer EML may include a compound represented by Formula D-1 below as the fourth compound in the light-emitting element ED according to some example embodiments.

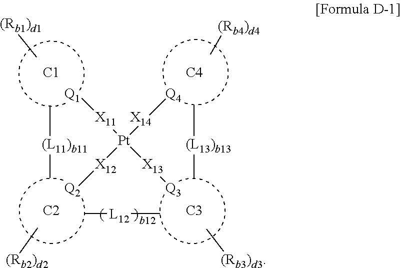

In Formula D-1, Q₁ to Q₄ may be each independently C or N.

In Formula D-1, C1 to C4 may be each independently a substituted or unsubstituted hydrocarbon ring having a carbon number of 5 to 30, or a substituted or unsubstituted heterocycle having a ring-forming carbon number of 2 to 30.

X₁₁ to X₁₄ may be each independently a direct linkage or [symbol] . For example, any one of X₁₁ to X₁₄ may be [symbol] , and the rest thereof may be a direct linkage.

In Formula D-1, L₁₁ to L₁₃ may be each independently a direct linkage,

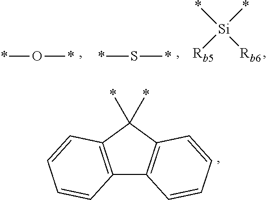

a substituted or unsubstituted alkyl group having a carbon number of 1 to 20, a substituted or unsubstituted arylene group having a ring-forming carbon number of 6 to 30, or a substituted or unsubstituted heteroarylene group having a ring-forming carbon number of 2 to 30. In L₁₁ to L₁₃, “ [symbol] ” means a position connected to C1 to C4.

In Formula D-1, b11 to b13 may be each independently 0 or 1. When b11 is 0, C1 and C2 may not be connected to each other. When b12 is 0, C2 and C3 may not be connected to each other. When b13 is 0, C3 and C4 may not be connected to each other.

In Formula D-1, R_{b1} to R_{b4} may be each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having a carbon number of 1 to 20, a substituted or unsubstituted alkenyl group having a carbon number of 2 to 20, a substituted or unsubstituted aryl group having a ring-forming carbon number of 6 to 60, or a substituted or unsubstituted heteroaryl group having a ring-forming carbon number of 2 to 60. In some example embodiments, each of R_{b1} to R_{b4} may be combined with an adjacent group to form a ring. R_{b1} to R_{b4} may be each independently a substituted or unsubstituted methyl group or a substituted or unsubstituted t-butyl group.

In Formula D-1, d1 to d4 are each independently an integer of 0 to 4. In Formula D-1, when each of d1 to d4 is 0, the fourth compound may not be substituted with R_{b1} to R_{b4}. A case in which each of d1 to d4 is 4, and each of R_{b1} to R_{b4} is a hydrogen atom is the same as a case in which each of d1 to d4 is 0. When each of d1 to d4 is an integer of 2 or more, all of R_{b1} to R_{b4} provided in plurality may be the same as each other, or at least one of a plurality of R_{b1} to R_{b4} is different from the other (or others).

In Formula D-1, C1 to C4 may be each independently a substituted or unsubstituted heterocycle or a substituted or unsubstituted hydrocarbon ring represented by any one of C-1 to C-5 below.

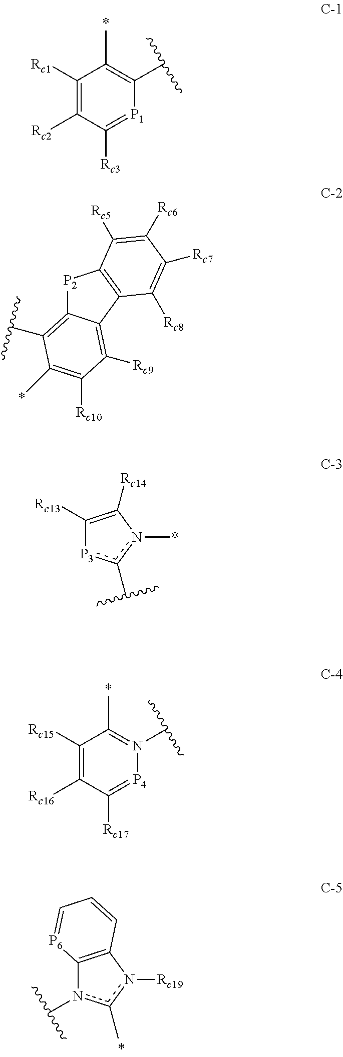

In C-1 to C-4, P₁ may be [symbol] or CR_{c4}, P₂ may be [symbol] or NR_{c11}, P₃ may be [symbol] or NR_{c12}, P4 may be [symbol] or CR_{c18}, P6 may be [symbol] or CR_{c20}. R_{c1} to R_{c20} may be each independently a substituted or unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30, or may be combined with an adjacent group to form a ring.

In addition, in C-1 to C-4,

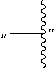

is a part connected to Pt which is a central metal atom, and “ [symbol] ” corresponds to a part connected to an adjacent ring group (C1 to C4) or a linker (L₁₁ to L₁₃).

The emission layer EML according to some example embodiments may include at least one among the first compound and the second to fourth compounds, which are the fused polycyclic compound. For example, the emission layer EML may include the first compound, the second compound and the third compound. The second compound and the third compound may form the exciplex in the emission layer EML, and energy may be transferred to the first compound in the exciplex so that luminescence may occur.

In addition, the emission layer EML may include the first compound, the second compound, the third compound and the fourth compound. The second compound and the third compound may form the exciplex in the emission layer EML, and the energy may be transferred to the fourth compound and the first compound in the exciplex so that luminescence may occur. According to some example embodiments, the fourth compound may be a sensitizer. The fourth compound included in the emission layer EML may function as the sensitizer in the light-emitting element ED according to some example embodiments to serve to transfer the energy from a host to the first compound which is a light-emitting dopant. That is, the fourth compound that serves as an auxiliary dopant may accelerate energy transfer to the first compound which is the light-emitting dopant to increase luminous ratio of the first compound. Accordingly, the emission layer EML according to some example embodiments may improve the luminous efficiency, thereby increasing the light emission performance, light emission efficiency, power consumption efficiency, or any combination of a light-emitting element ED that includes the emission layer EML, and any device including same. In addition, when the energy transfer to the first compound increases, an exciton formed in the emission layer EML may not be accumulated inside the emission layer EML, and may emit light rapidly to reduce element degradation. Accordingly, the light-emitting element ED according to some example embodiments may have increased lifespan and thus may exhibit increased reliability, thereby increasing the reliability of the light-emitting element ED and any device including same.

Since the light-emitting element ED according to some example embodiments includes all of the first compound, the second compound, the third compound and the fourth compound, the emission layer EML may include a combination of two host materials and two dopant materials. Since the emission layer EML in the light-emitting element ED according to some example embodiments simultaneously includes the second compound and the third compound which are two different hosts, the first compound that emits delayed fluorescence, and the fourth compound that includes the organometallic complex, excellent luminous efficiency characteristics may be exhibited, thereby increasing the light emission performance, light emission efficiency, power consumption efficiency, or any combination of a light-emitting element ED that includes the emission layer EML, and any device including same.

The fourth compound represented by Formula D-1 according to some example embodiments may be represented by at least one among compounds represented by Compound Group 4 below. The emission layer EML may include, as a sensitizer material, at least one among compounds represented by Compound Group 4 below (e.g., at least one of Compounds AD-01 to AD-42).

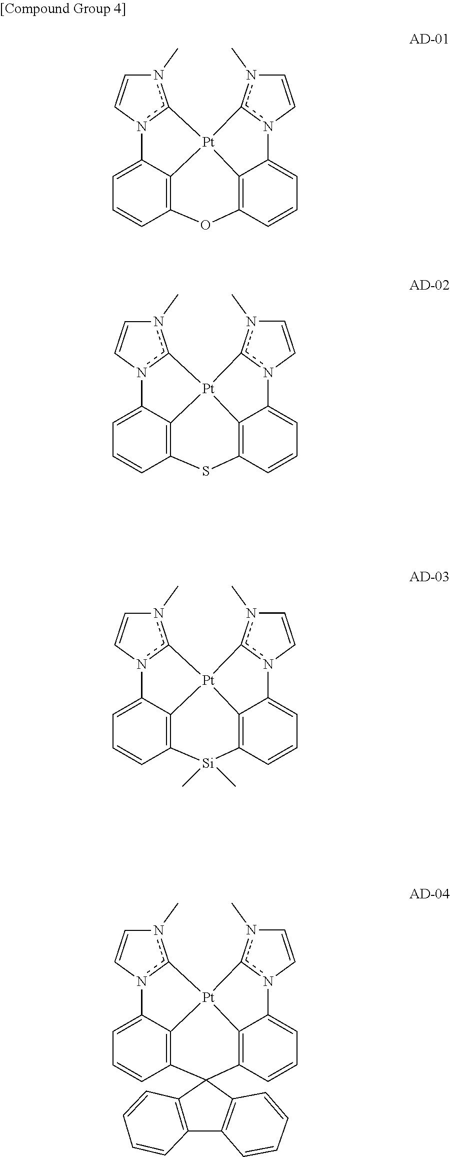

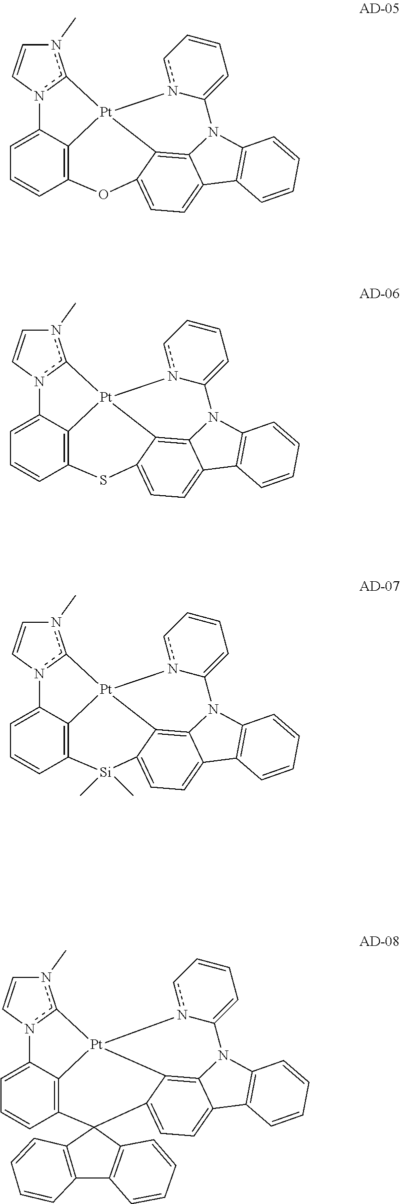

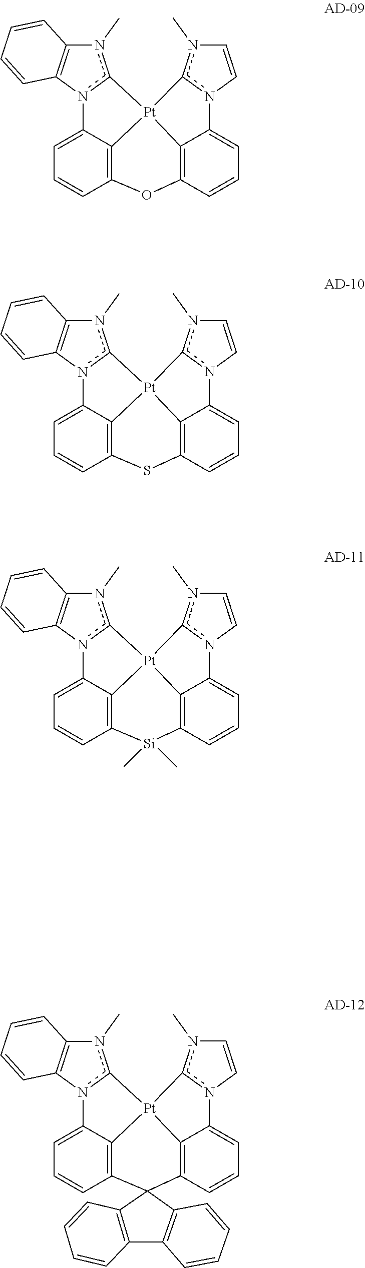

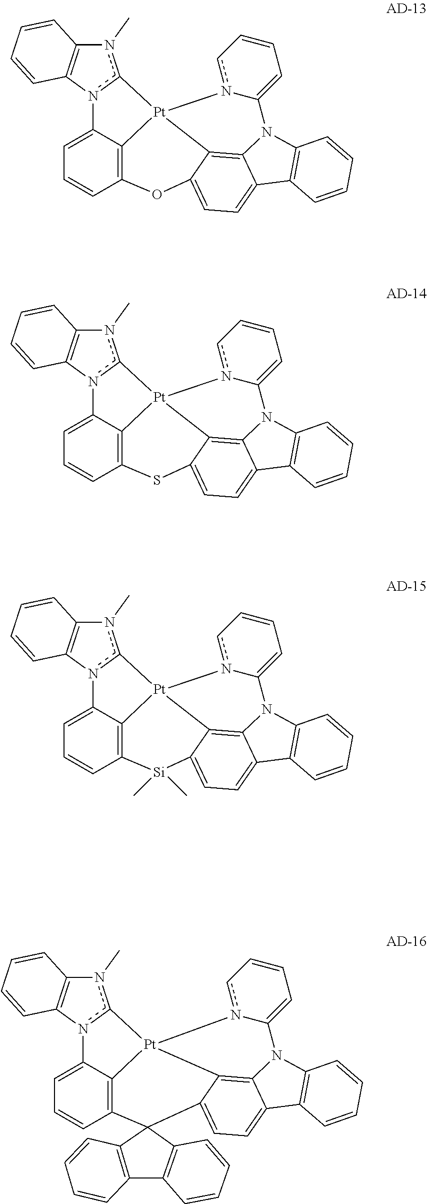

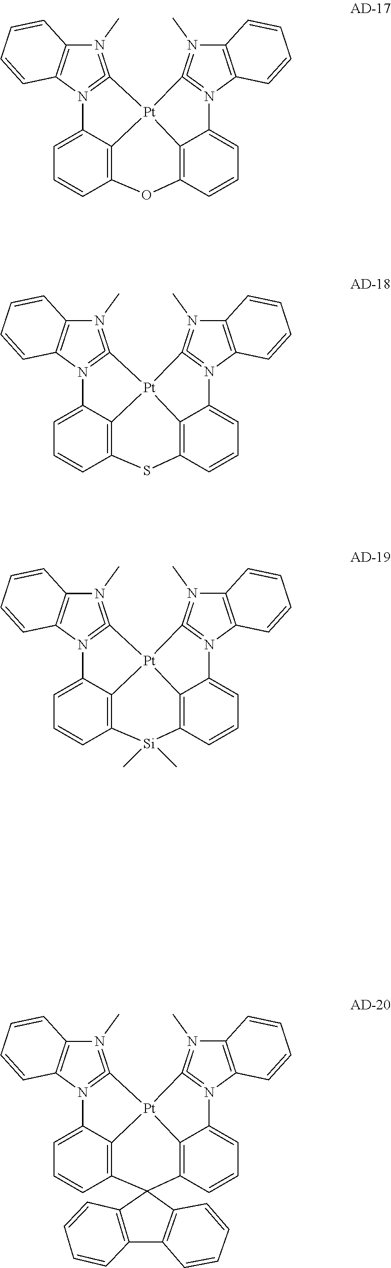

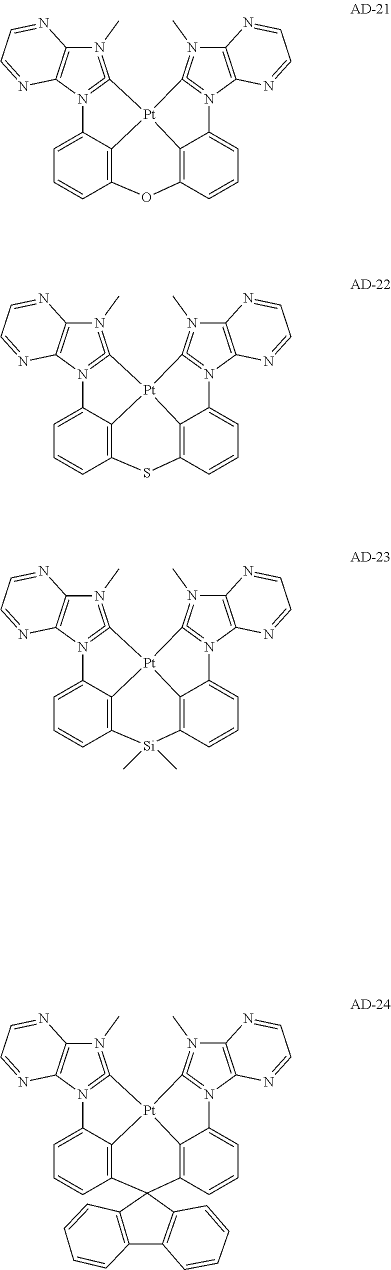

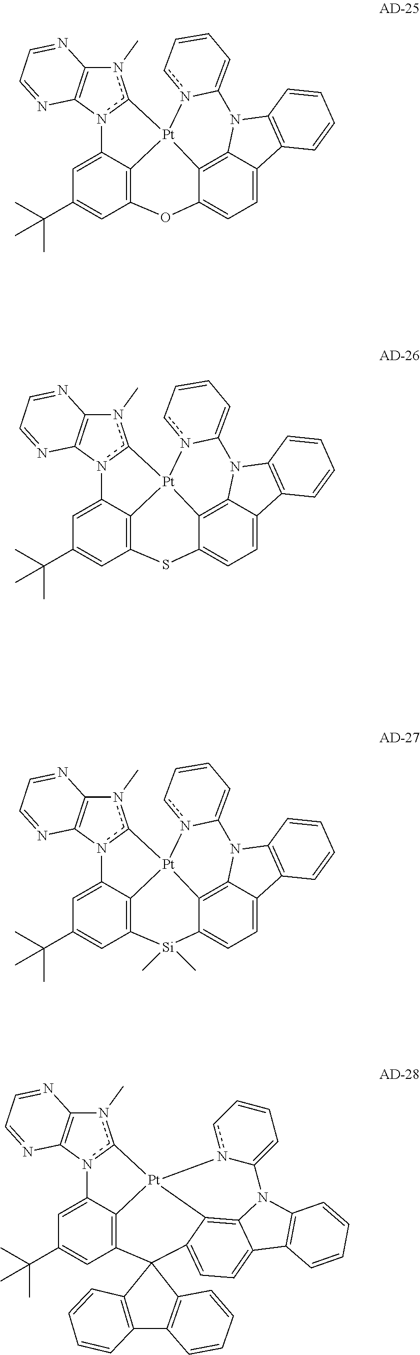

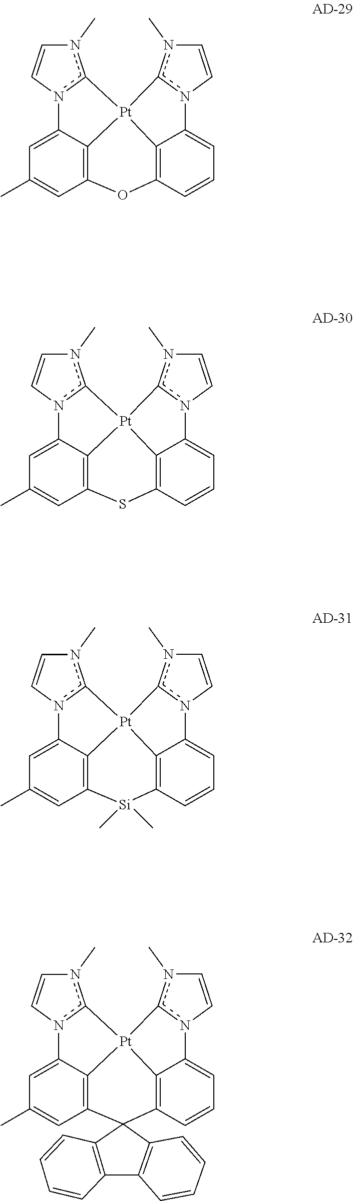

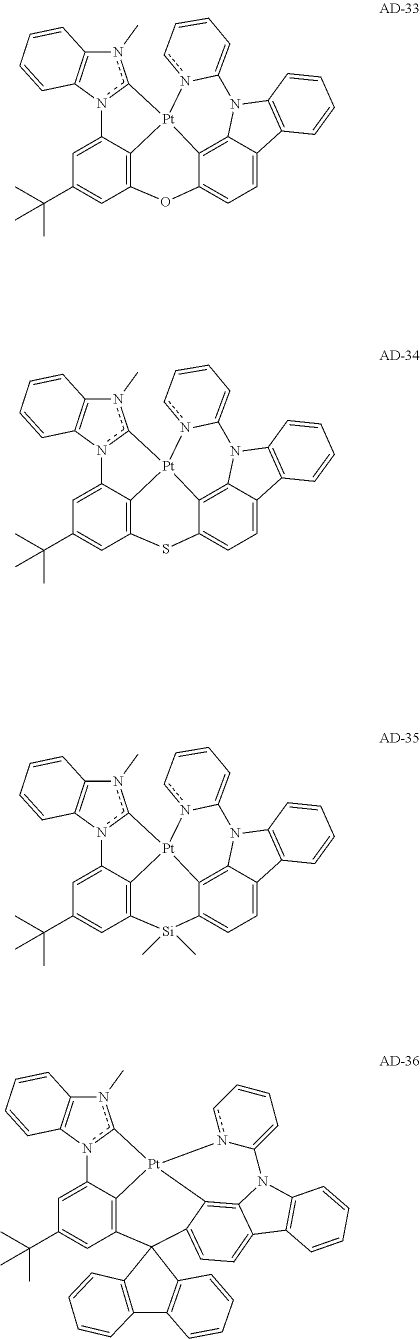

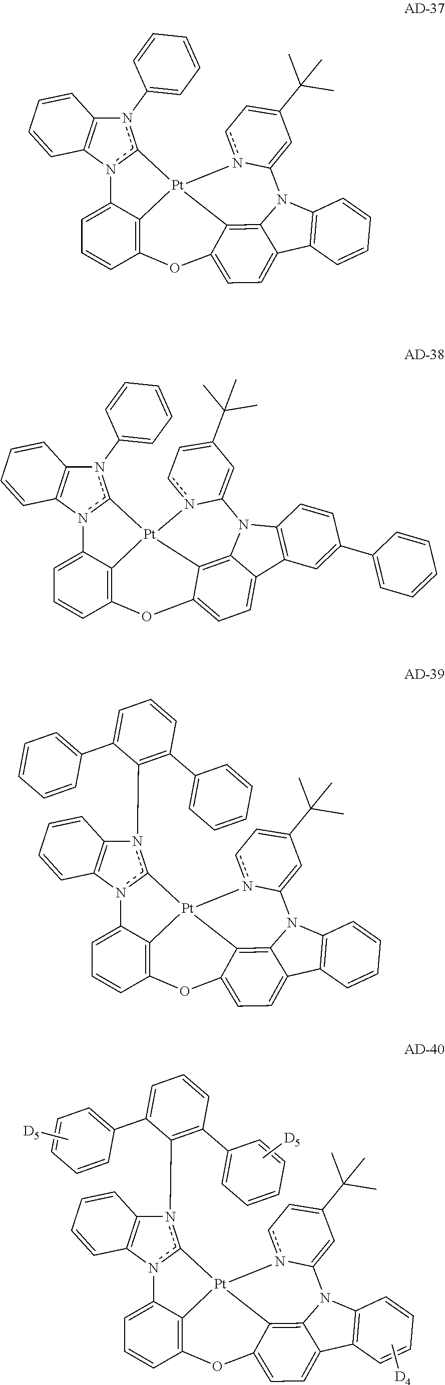

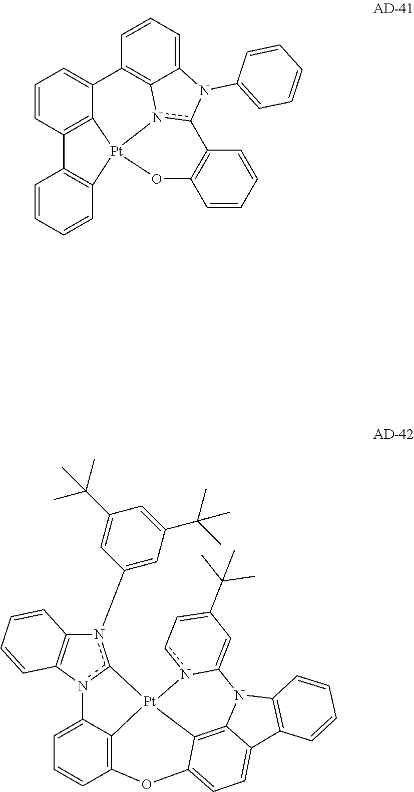

In example compounds suggested in Compound Group 4, “D” means a deuterium atom.

The light-emitting element ED according to some example embodiments may include a plurality of emission layers. The plurality of emission layers may be sequentially stacked and may be provided, and for example, the light-emitting element ED including the plurality of emission layers may emit white light. The light-emitting element including the plurality of emission layers may be a light-emitting element having a tandem structure. When the light-emitting element ED includes the plurality of emission layers, at least one emission layer EML may include the first compound represented by Formula 1 according to some example embodiments. In addition, when the light-emitting element ED includes the plurality of emission layers, at least one emission layer EML may include all of the first compound, the second compound, the third compound and the fourth compound as described above.

When the emission layer EML includes all of the first compound, the second compound, and the third compound described above in the light-emitting element ED according to some example embodiments, a content of the first compound may be about 0.1 wt % to about 5 wt % with respect to the total weight of the first compound, the second compound, and the third compound, but example embodiments of the inventive concepts are not limited thereto. When the content of the first compound satisfies the ratio described above, energy transfer from the second compound and the third compound to the first compound may increase, and thus luminous efficiency and element lifespan may increase and thus a light-emitting element ED and any device including same may exhibit increased reliability, thereby increasing the reliability based on including the emission layer EML.

The contents of the second compound and the third compound in the emission layer EML may be the rest except for the weight of the first compound described above. For example, the contents of the second compound and the third compound in the emission layer EML may be about 65 wt % to about 95 wt % with respect to the total weight of the first compound, the second compound, and the third compound.

A weight ratio of the second compound and the third compound in the total weight of the second compound and the third compound may be about 3:7 to about 7:3.

When the contents of the second compound and the third compound satisfy the ratio described above, charge balance characteristics in the emission layer EML may be improved to increase luminous efficiency and element lifespan. When the contents of the second compound and the third compound do not satisfy the ratio range described above, the charge balance in the emission layer EML may be broken to deteriorate the luminous efficiency and to easily degrade the element.

When the emission layer EML includes the fourth compound, a content of the fourth compound may be about 4 wt % to about 30 wt % with respect to the total weight of the first compound, the second compound, the third compound and the fourth compound in the emission layer EML, but example embodiments of the inventive concepts are not limited thereto. When the content of the fourth compound satisfies the content described above, energy transfer from the host to the first compound which is a light-emitting dopant may increase to improve the luminous efficiency, and thus to improve the luminous efficiency of the emission layer EML. When the first compound, the second compound, the third compound and the fourth compound included in the emission layer EML satisfy the content ratio range described above, excellent luminous efficiency and long lifespan may be achieved, and thus a light-emitting element ED and any device including same may exhibit increased light emission performance, light emission efficiency, power consumption efficiency, reliability, or any combination thereof based on including the emission layer EML.

The emission layer EML in the light-emitting element ED according to some example embodiments may include an anthracene derivative, a pyrene derivative, a fluoranthene derivative, a chrysene derivative, a dihydrobenzanthracene derivative, or a triphenylene derivative. Specifically, the emission layer EML may include an anthracene derivative or a pyrene derivative.

The emission layer EML in the light-emitting element ED according to some example embodiments illustrated in FIGS. 6 to 8 may further include a well-known host and dopant as well as the host and dopant described above, and for example, may include a compound represented by Formula E-1 below. The compound represented by Formula E-1 below may be used as a fluorescence host material.

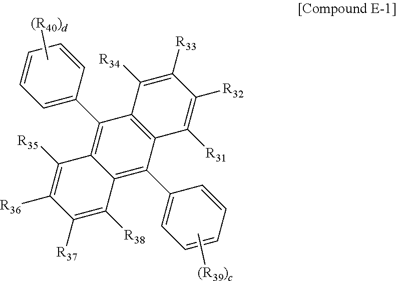

In Formula E-1, R₃₁ to R₄₀ may be each independently a hydrogen atom, a deuterium atom, a halogen atom, a substituted or unsubstituted silyl group, a substituted or unsubstituted thio group, a substituted or unsubstituted oxy group, a substituted or unsubstituted alkyl group having a carbon number of 1 to 10, a substituted or unsubstituted alkenyl group having a carbon number of 2 to 10, a substituted or unsubstituted aryl group having a ring-forming carbon number of 6 to 30, or a substituted or unsubstituted heteroaryl group having a ring-forming carbon number of 2 to 30, or may be combined with an adjacent group to form a ring. R₃₁ to R₄₀ may be combined with an adjacent group to form a saturated hydrocarbon ring, an unsaturated hydrocarbon ring, a saturated heterocycle or an unsaturated heterocycle.

In Formula E-1, c and d may be each independently an integer of 0 to 5.

Formula E-1 may be represented by any one among Compound E1 to Compound E21 below.

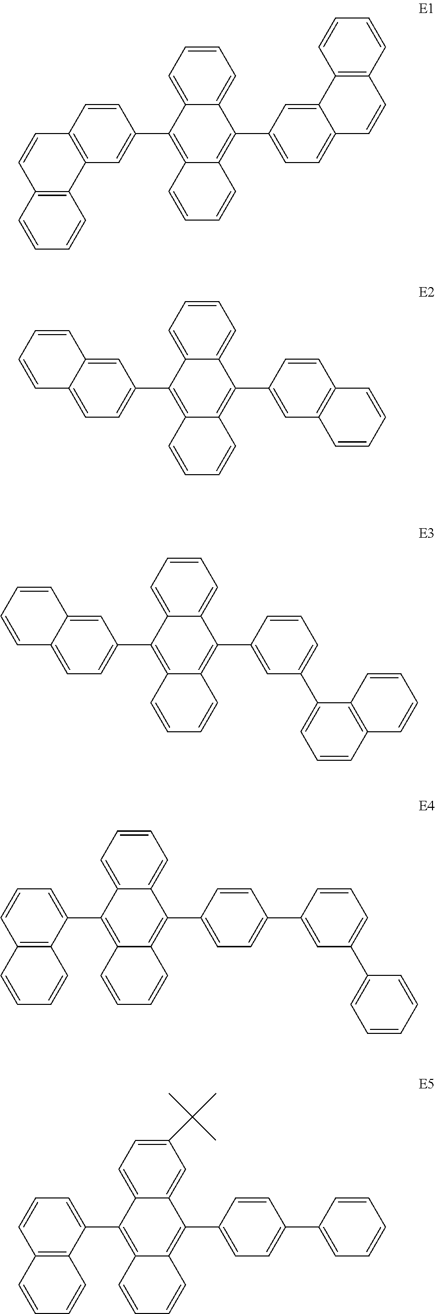

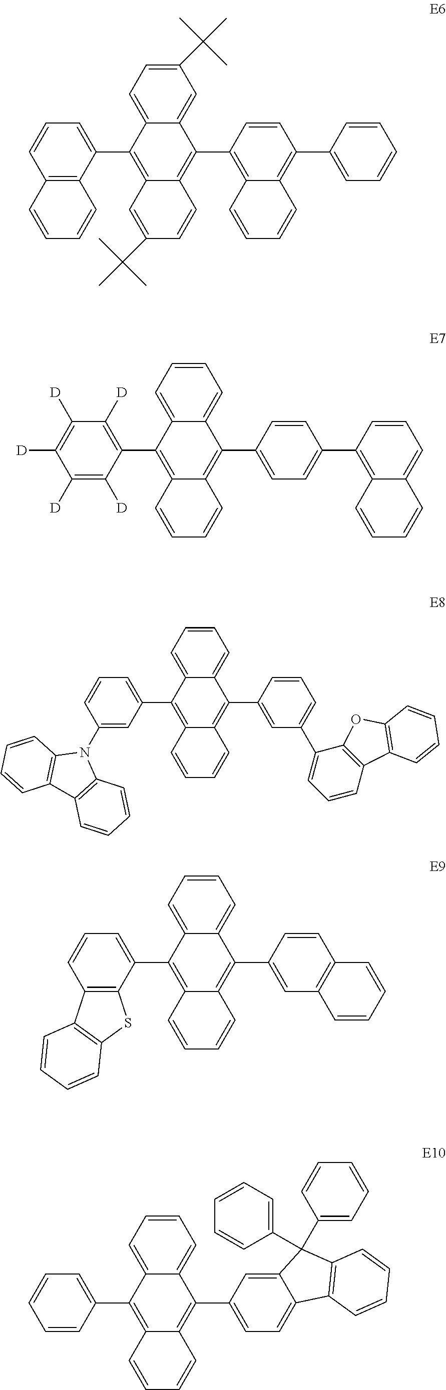

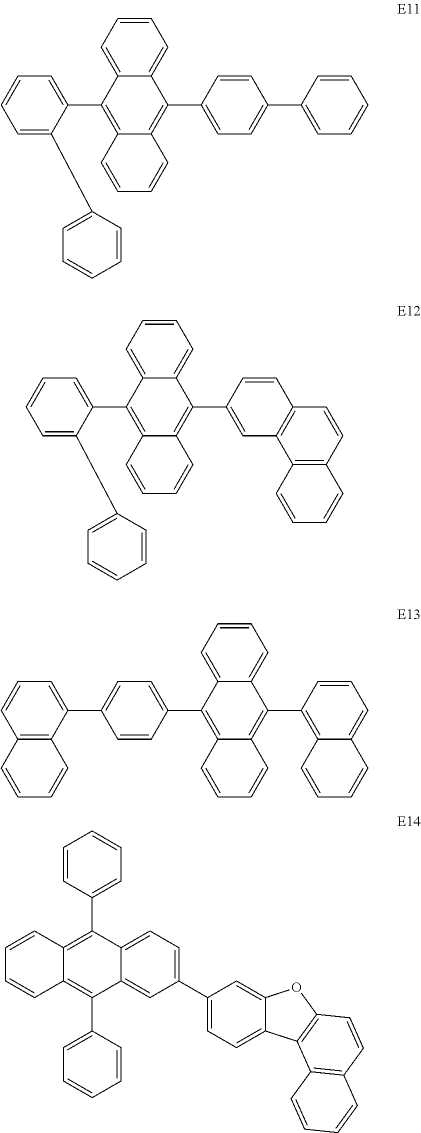

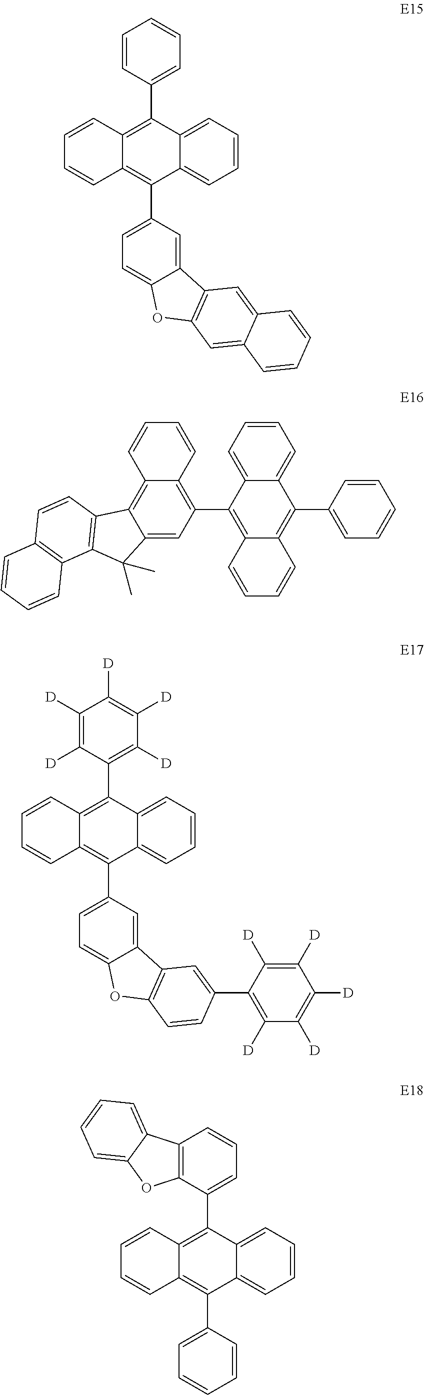

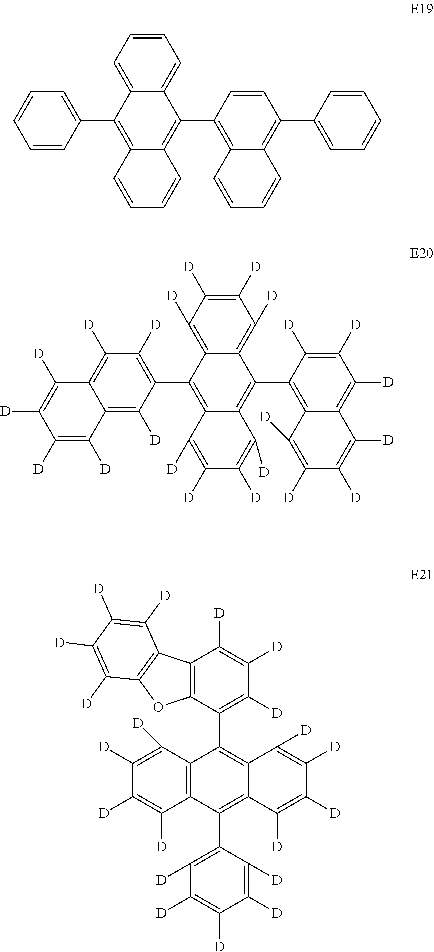

The emission layer EML according to some example embodiments may include a compound represented by Formula E-2a or Formula E-2b below. The compound represented by Formula E-2a or Formula E-2b below may be used as a phosphorescence host material.

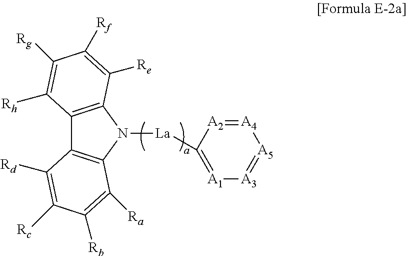

In Formula E-2a, a may be an integer of 0 to 10, and Lₐ may be a direct linkage, a substituted or unsubstituted arylene group having a ring-forming carbon number of 6 to 30, or a substituted or unsubstituted heteroarylene group having a ring-forming carbon number of 2 to 30. When a is an integer of 2 or more, a plurality of Lₐ may be each independently a substituted or unsubstituted arylene group having a ring-forming carbon number of 6 to 30, or a substituted or unsubstituted heteroarylene group having a ring-forming carbon number of 2 to 30.

In addition, in Formula E-2a, A₁ to A₅ may be each independently N or CRᵢ. Rₐ to Rᵢ may be each independently a hydrogen atom, a deuterium atom, a substituted or unsubstituted amine group, a substituted or unsubstituted thio group, a substituted or unsubstituted oxy group, a substituted or unsubstituted alkyl group having a carbon number of 1 to 20, a substituted or unsubstituted alkenyl group having a carbon number of 2 to 20, a substituted or unsubstituted aryl group having a ring-forming carbon number of 6 to 30, or a substituted or unsubstituted heteroaryl group having a ring-forming carbon number of 2 to 30, or may be combined with an adjacent group to form a ring. Rₐ to Rᵢ may be combined with an adjacent group to form a hydrocarbon ring or a heterocycle including N, O, S or the like as a ring-forming atom.

In Formula E-2a, two or three selected from A₁ to A₅ may be N, and the rest thereof (e.g., a remainder of A₁ to A₅) may be CRᵢ.

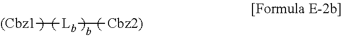

In Formula E-2b, Cbz1 and Cbz2 may be each independently an unsubstituted carbazole group, or a carbazole group substituted with an aryl group having a ring-forming carbon number of 6 to 30. L_{b} may be a direct linkage, a substituted or unsubstituted arylene group having a ring-forming carbon number of 6 to 30, or a substituted or unsubstituted heteroarylene group having a ring-forming carbon number of 2 to 30. b may be an integer of 0 to 10, and when b is an integer of 2 or more, a plurality of L_{b} may be each independently a substituted or unsubstituted arylene group having a ring-forming carbon number of 6 to 30, or a substituted or unsubstituted heteroarylene group having a ring-forming carbon number of 2 to 30.

A compound represented by Formula E-2a or Formula E-2b may be represented by any one among compounds of Compound Group E-2 below (e.g., at least one of Compounds E-2-1 to E-2-24). However, the compounds listed in Compound Group E-2 below are examples, and the compound represented by Formula E-2a or Formula E-2b is not limited to what is represented in Compound Group E-2 below.

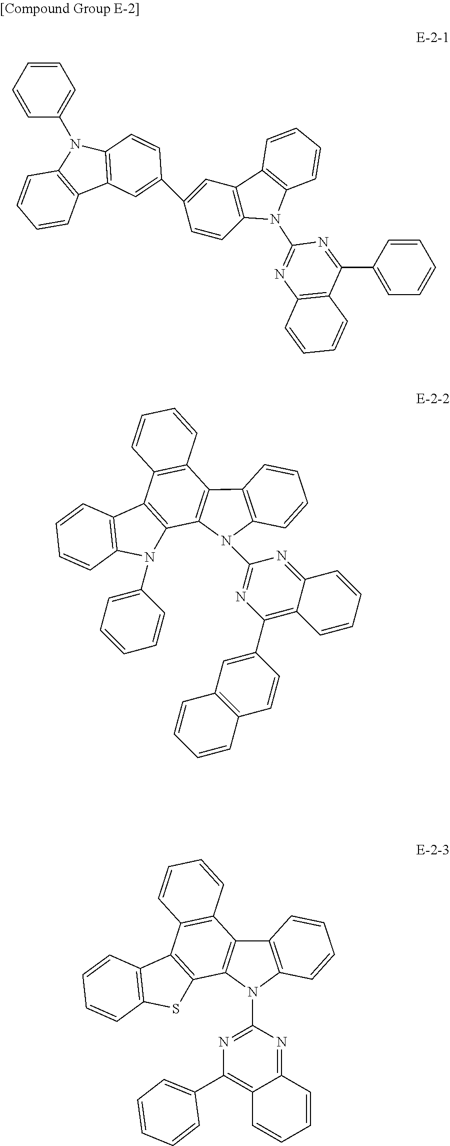 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

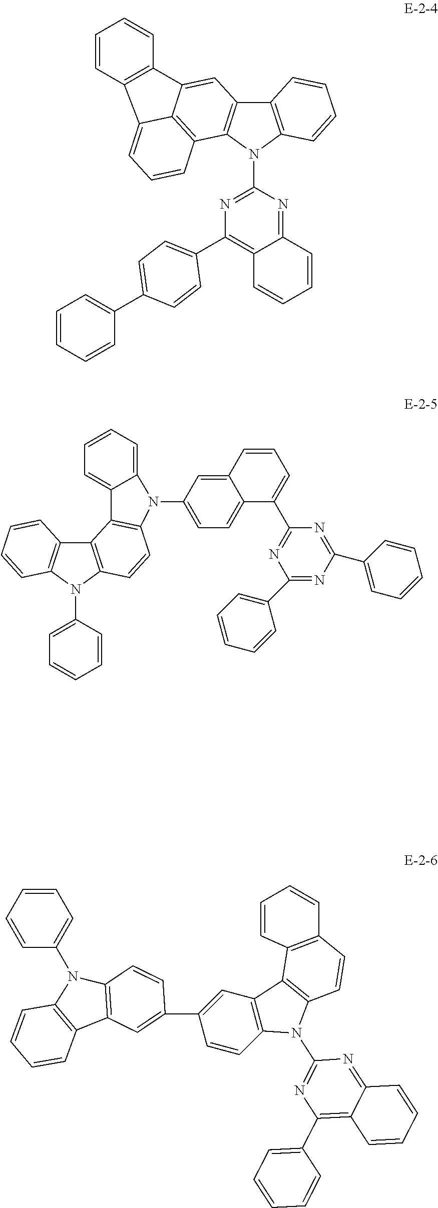 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

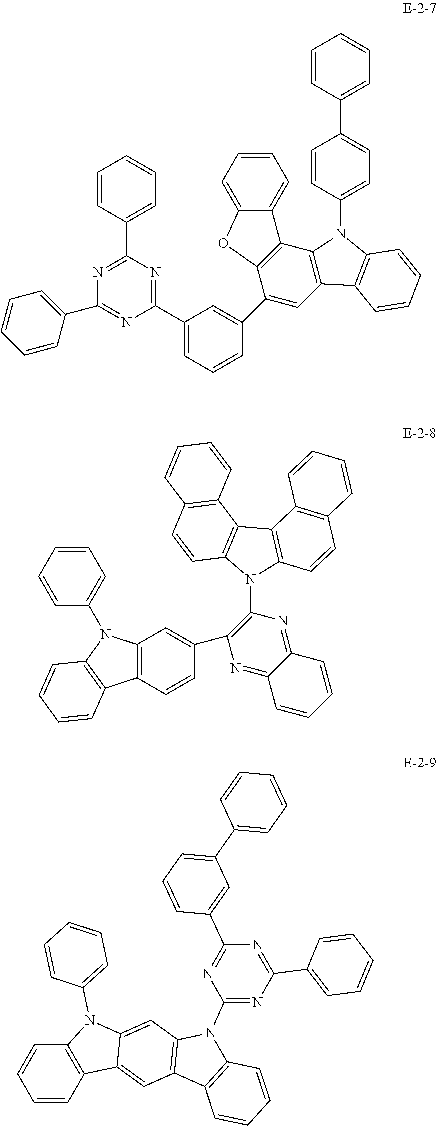 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

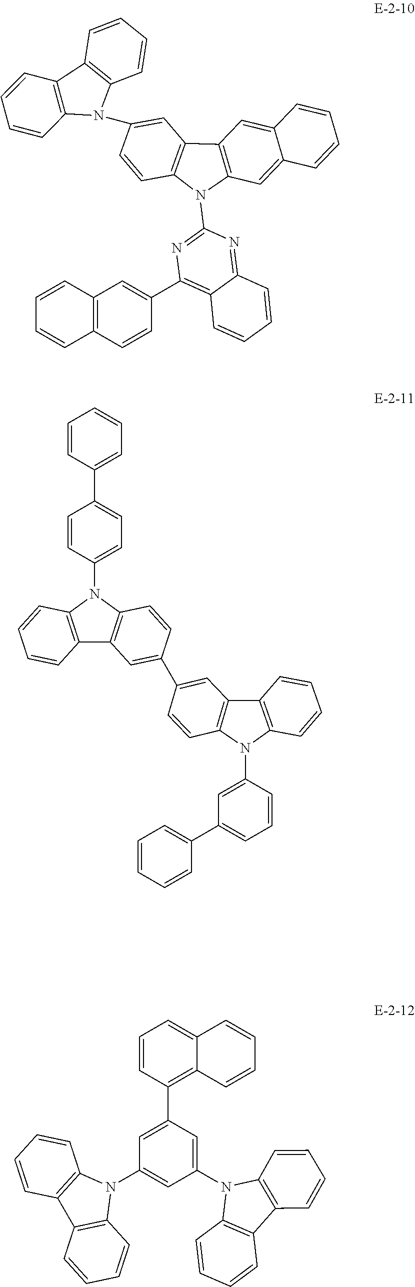 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

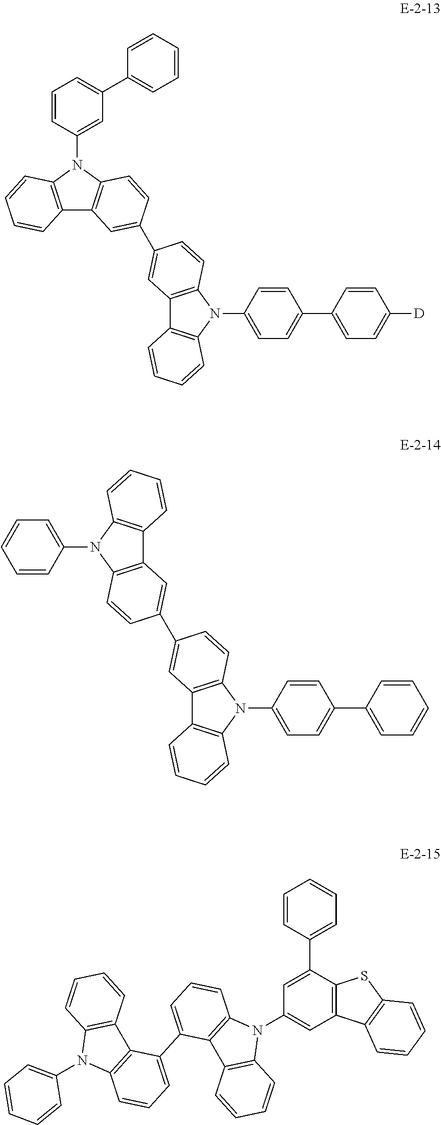 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

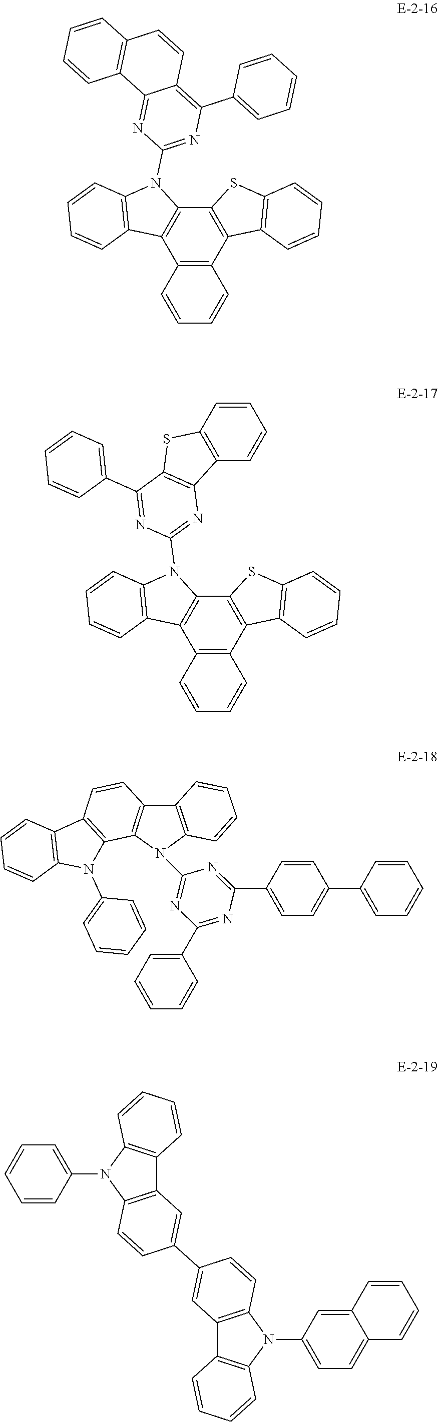 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1]

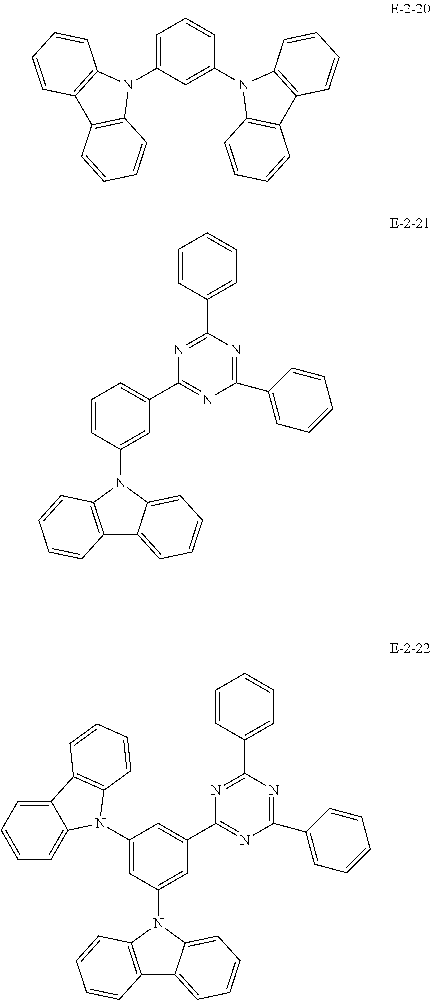 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

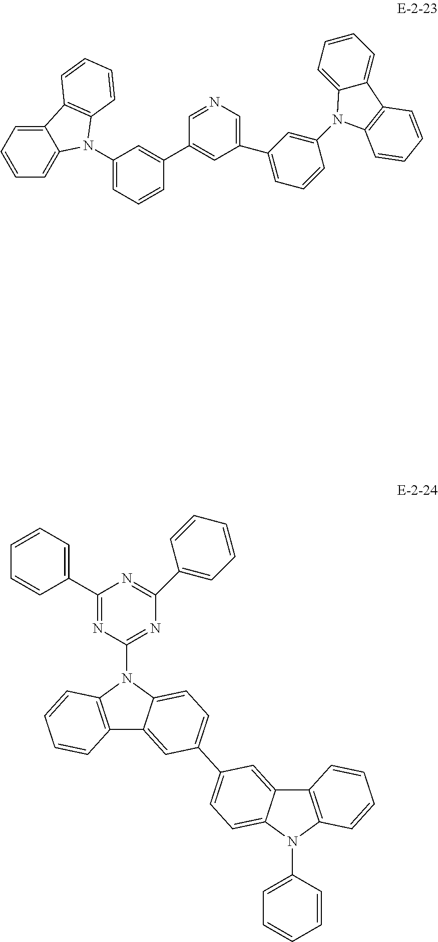 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a general material well-known in the art as a host material. For example, the emission layer EML may include, as a host material, at least one of bis(4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl]ether oxide (DPEPO), 4,4′-bis(carbazol-9-yl)biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, example embodiments of the inventive concepts are not limited thereto. For example, tris(8-hydroxyquinolino)aluminum (Alq3), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO3), octaphenylcyclotetra siloxane (DPSiO4), etc. may be used as the host material.

The emission layer EML may include a compound represented by Formula M-a below. The compound represented by Formula M-a below may be used as a phosphorescence dopant material.

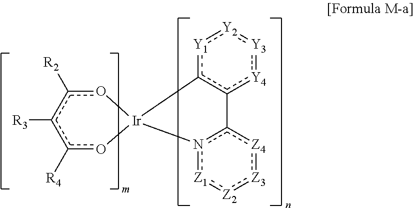

In Formula M-a, Y₁ to Y₄, an Z₁ to Z₄ may be each independently CR₁ or N, and R₁ to R₄ may be each independently a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. In Formula M-a, m is 0 or 1, and n is 2 or 3. In Formula M-a, when m is 0, n is 3, and when m is 1, n is 2.

The compound represented by Formula M-a may be used as a phosphorescence dopant.

The compound represented by Formula M-a may be represented by any one among Compounds M-a1 to M-a25 below. However, Compounds M-al to M-a25 below are examples, and the compound represented by Formula M-a is not limited to the compounds represented by Compounds M-a1 to M-a25 below.

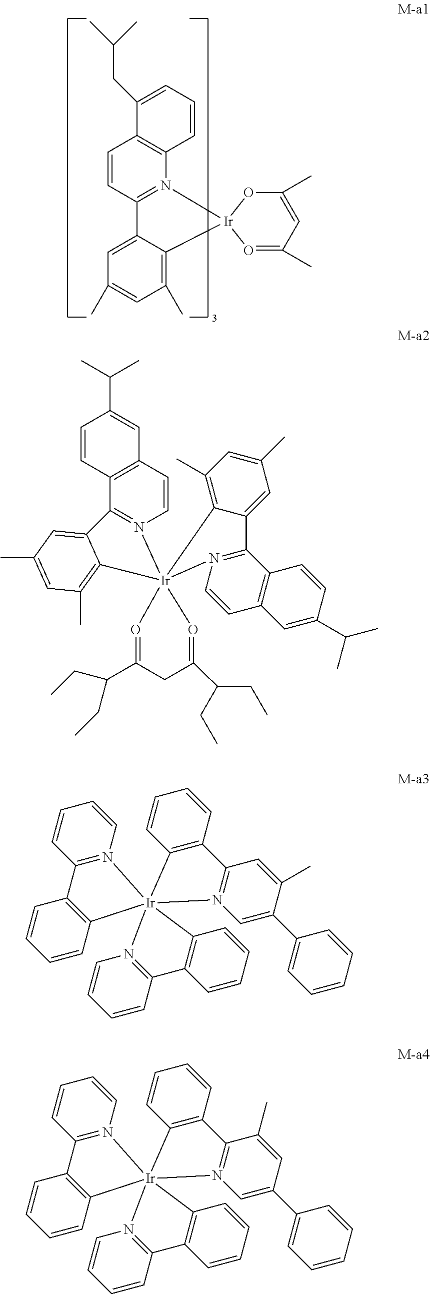

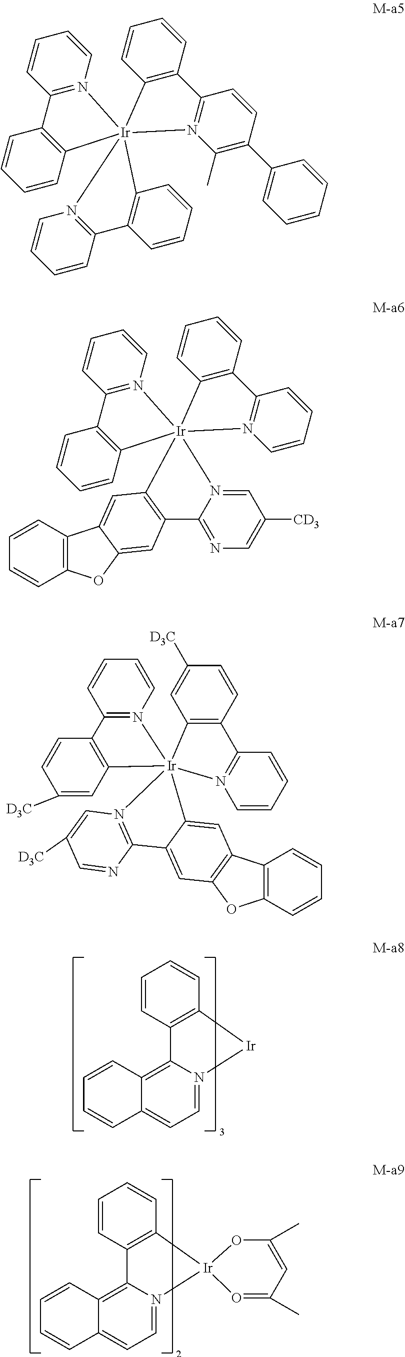

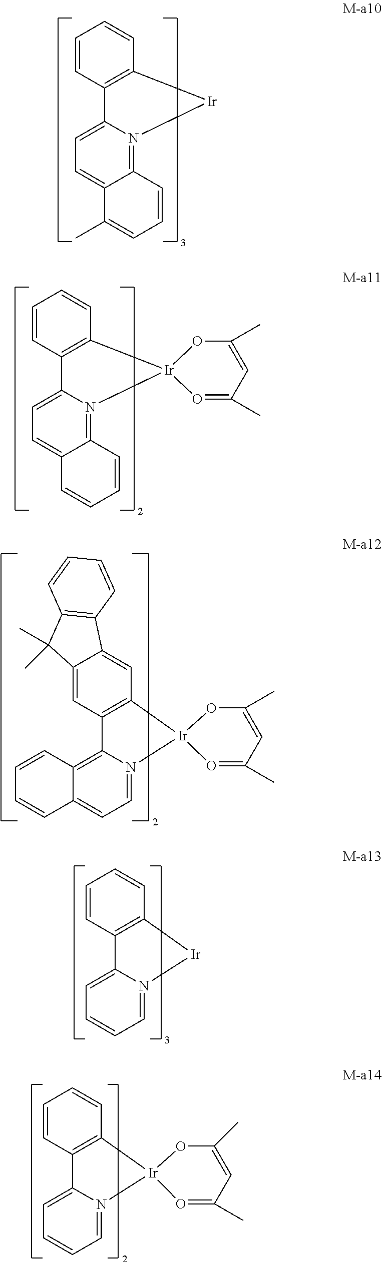

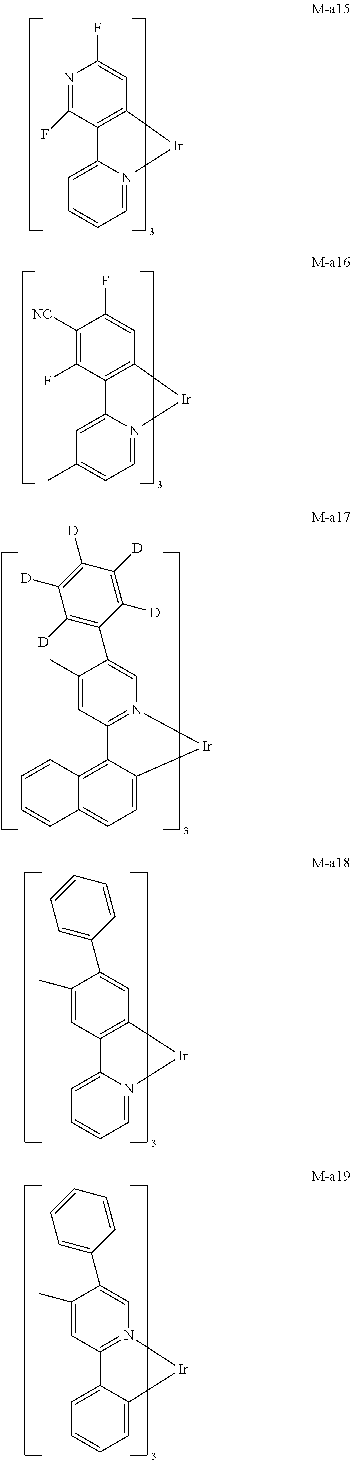

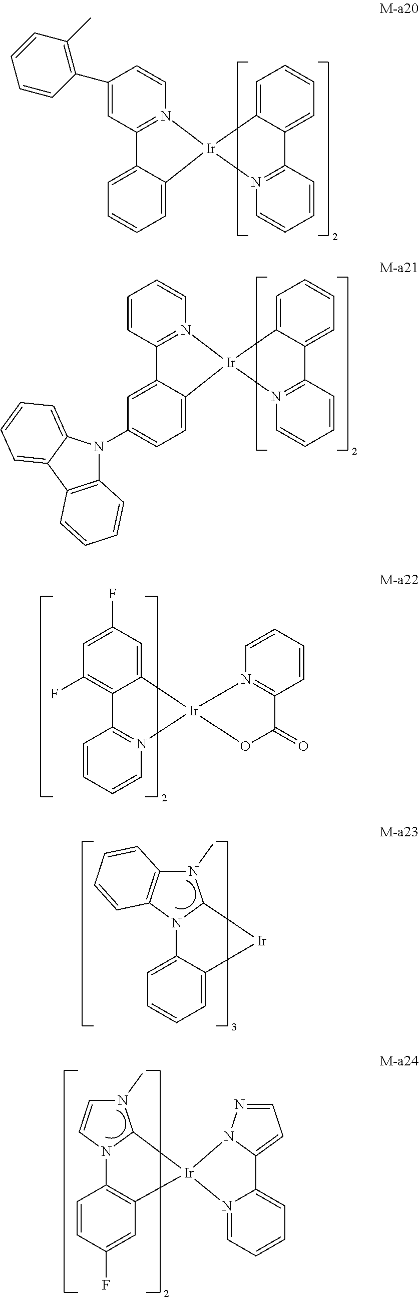

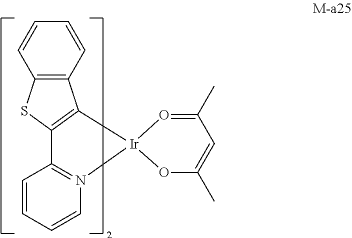

The emission layer EML may include a compound represented by any one among Formula F-a to Formula F-c below. The compound represented by Formula F-a to Formula F-c below may be used as a fluorescence dopant material.

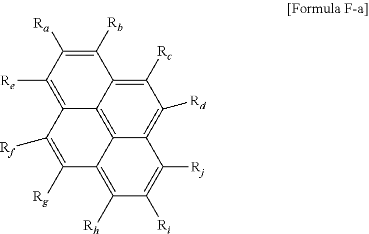

In Formula F-a, two selected from Rₐ to Rⱼ may be each independently substituted with

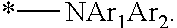

The rest not substituted with

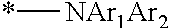

among Rₐ to Rⱼ may be each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In

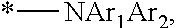

Ar₁ and Ar₂ may be each independently a substituted or unsubstituted aryl group of 6 to 30 ring-forming carbon atoms, or a substituted or unsubstituted heteroaryl group of 2 to 30 ring-forming carbon atoms. For example, at least one of Ar₁ or Ar₂ may be a heteroaryl group including O or S as a ring-forming atom.

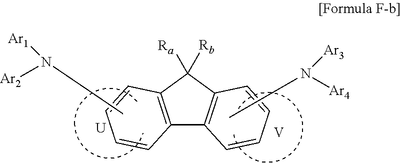

In Formula F-b, Rₐ and R_{b} may be each independently a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. Ar₁ to Ar₄ may be each independently a substituted or unsubstituted aryl group of 6 to 30 ring-forming carbon atoms, or a substituted or unsubstituted heteroarylene group of 2 to 30 ring-forming carbon atoms.

In Formula F-b, U and V may be each independently a substituted or unsubstituted hydrocarbon ring of 5 to 30 ring-forming carbon atoms, or a substituted or unsubstituted heterocycle of 2 to 30 ring-forming carbon atoms. At least one among Ar₁ to Ar₄ may be a heteroaryl group including O or S as a ring-forming atom.

In Formula F-b, the number of rings represented by U and V may be each independently 0 or 1. For example, in Formula F-b, when the number of U or V is 1, one ring forms a condensed ring at a part designated by U or V, and when the number of U or V is 0, a ring is not present at the part designated by U or V. Specifically, when the number of U is 0, and the number of V is 1, or when the number of U is 1, and the number of V is 0, a condensed ring having a fluorene core of Formula F-b may be a ring compound having four rings. In addition, when the numbers of both U and V are all 0, the condensed ring of Formula F-b may be a ring compound having three rings. In addition, when the numbers of both U and V are all 1, a condensed ring having the fluorene core of Formula F-b may be a ring compound having five rings.

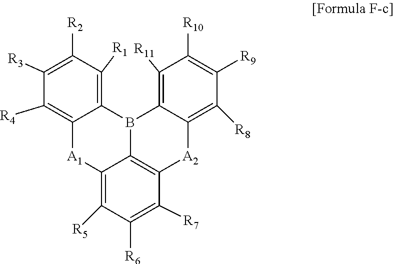

In Formula F-c, A₁ and A₂ may be each independently O, S, Se, or NRₘ, and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. R₁ to R₁₁ are each independently a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring.

In Formula F-c, A₁ and A₂ may be each independently combined with an adjacent ring substituent to form a condensed ring. For example, when A₁ and A₂ are each independently NRₘ, A₁ may be combined with R₄ or R₅ to form a ring. In addition, A₂ may be combined with R₇ or R₈ to form a ring.

According to some example embodiments, the emission layer EML may include, as a well-known dopant material, styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene and the derivatives thereof (for example, 2,5,8,11-tetra-t-butylperylene (TBP)), pyrene and the derivatives thereof (for example, 1,1-dipyrene, 1,4-dipyrenylbenzene, and 1,4-bis(N,N-diphenylamino)pyrene), etc.

The emission layer EML may further include a well-known phosphorescence dopant material. For example, a metal complex including iridium (Ir), platinum (Pt), osmium (Os), gold (Au), titanium (Ti), zirconium (Zr), hafnium (Hf), europium (Eu), terbium (Tb) or thulium (Tm) may be used as the phosphorescence dopant. Specifically, iridium(III) bis(4,6-difluorophenylpyridinato-N,C2′)picolinate (FIrpic), bis(2,4-difluorophenylpyridinato)-tetrakis(1-pyrazolyl)borate iridium(III) (Fir6), or platinum octaethyl porphyrin (PtOEP) may be used as the phosphorescence dopant. However, example embodiments of the inventive concepts are not limited thereto.

The emission layer may include a quantum dot.

In the present specification, the quantum dot means a crystal of a semiconductor compound. The quantum dot may emit light having various wavelengths according to a crystal size thereof. The quantum dot may also emit light having various wavelengths by controlling a ratio of elements in the quantum dot compound.

The quantum dot may have a diameter of, for example, about 1 nm to about 10 nm.

The quantum dot may be synthesized in a wet chemical process, a metal organic chemical vapor deposition process, a molecular beam epitaxy process, or a process similar thereto.

The wet chemical process is a process of mixing an organic solvent and a precursor material, and then growing a quantum dot particle crystal. When the crystal is grown, an organic solvent may naturally serve as a dispersant coordinated to a quantum dot crystal surface, and may control growth of the crystal. Accordingly, the wet chemical process may control growth of the quantum dot particle as a process easier and cheaper than a vapor deposition process such as the metal organic chemical vapor deposition (MOCVD), or the molecular beam epitaxy (MBE).

The emission layer EML according to the inventive concepts may include a quantum dot material. A core of the quantum dot may be selected from a II-VI group compound, a III-VI group compound, a III-VI group compound, a 1-II-VI group compound, a IV-VI group compound, a IV group element, a IV group compound, and a combination thereof.

The II-VI group compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. The II-VI group semiconductor compound may further include a group I metal and/or a group IV element. The I-II-VI group compound may be selected from CuSnS or CuZnS, and the II-IV-VI group compound may be selected from ZnSnS or the like. The I-II-IV-VI group compound may be selected from a quaternary compound selected from the group consisting of Cu₂ZnSnS₂, Cu₂ZnSnS₄, Cu₂ZnSnSe₄, Ag₂ZnSnS₂ and a mixture thereof.

The III-VI group compound may include a binary compound such as In₂S₃, and In₂Se₃, a ternary compound such as InGaS₃, and InGaSe₃, or an arbitrary combination thereof.

The I-III-VI group compound may be selected from a ternary compound selected from the group consisting of AgInS, AgInS₂, CuInS, CuInS₂, AgGaS₂, CuGaS₂, CuGaO₂, AgGaO₂, AgAlO₂ and a mixture thereof, or a quaternary compound such as AgInGaS₂, and CuInGaS₂.

The III-V group compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. The III-V group compound may further include a group II metal. For example, InZnP, etc. may be selected as a III-II-V group compound.

The IV-VI group compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof.

Examples of the II-IV-V group semiconductor compound may be a ternary compound selected from the group consisting of ZnSnP, ZnSnP₂, ZnSnAs₂, ZnGeP₂, ZnGeAs₂, CdSnP₂, CdGeP₂ and a mixture thereof.

The group IV element may be selected from the group consisting of Si, Ge and a mixture thereof. The IV group compound may be a binary compound selected from the group consisting of SiC, SiGe and a mixture thereof.

Each of the elements included in the multi-element compound such as the binary compound, the ternary compound and the quaternary compound may be present at a uniform or non-uniform concentration. That is, Formulae above mean a kind of elements included in the compound, and a ratio of the elements in the compound may be different. For example, AgInGaS₂ may mean AgInₓGa₁₋ₓS₂ (where x is a real number between 0 and 1).

In this case, the binary compound, the ternary compound or the quaternary compound may be present at a uniform concentration in a particle, or may be present in a partially different concentration distribution state in the same particle. In addition, there may be a core/shell structure in which one quantum dot wraps another quantum dot. The core/shell structure may have a concentration gradient in which a concentration of an element present in the shell decreases in a direction getting closer to the core.

In some example embodiments, the quantum dot may have the core-shell structure, described above, including a core including a nanocrystal and a shell wrapping the core. The shell of the quantum dot may serve as a protection layer for preventing a chemical change of the core to maintain semiconductor characteristics and/or a charging layer for imparting the quantum dot with electrophoretic characteristics. The shell may have a single layer or a multilayer. Examples of the shell of the quantum dot may include a metal or non-metal oxide, a semiconductor compound, or a combination thereof.

For example, the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and NiO, or a ternary compound such as MgAl₂O₄, CoFe₂O₄, NiFe₂O₄ and CoMn₂O₄, but example embodiments of the inventive concepts are not limited thereto.

Also, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but example embodiments of the inventive concepts are not limited thereto.

The quantum dot may have a full width of half maximum (FWHM) of luminescence wavelength spectrum of about 45 nm or less, preferably, about 40 nm or less, more preferably, about 30 nm or less. Within this range, color purity or color reproducibility may be improved. In addition, light emitted through such a quantum dot is emitted in all directions, and a light view angle may be improved.

In addition, a shape of the quantum dot may have a generally-used shape in the art, without specific limitation. More specifically, the quantum dot having a shape of a sphere, a pyramid, a multi-arm, or a cubic nanoparticle, a nanotube, a nanowire, a nanofiber, a nanoplate-like particle, etc. may be used.

An energy bandgap of the quantum dot may be controlled by controlling a quantum dot size or a ratio of elements in the quantum dot compound to obtain light having various wavelength range in a quantum dot emission layer. Accordingly, a light-emitting element that emits light having various wavelengths may be performed by using the above quantum dot (using the quantum dot having different sizes and differing the ratios of the elements in the quantum dot compound). Specifically, the quantum dot size or the ratio of the elements in the quantum dot compound may be selected so as to emit red, green and/or blue light. In addition, the quantum dots may be configured so as to emit white light by combining various light.

In the light-emitting element ED according to some example embodiments illustrated in FIGS. 5 to 8, the electron transport region ETR is provided on the emission layer EML. The electron transport region ETR may include at least one of an electron blocking layer HBL, an electron transport layer ETL or an electron injection layer EIL. However, example embodiments of the inventive concepts are not limited thereto.

The electron transport region ETR may have a single layer formed of a single material, a single layer formed of a plurality of different materials, or a multi-layered structure having a plurality of layers formed of a plurality of different materials.

For example, the electron transport region ETR may have a single-layered structure of an electron injection layer EIL or an electron transport layer ETL, or a single-layered structure formed of an electron injection material and an electron transport material. In addition, the electron transport region ETR may have a single-layered structure formed of a plurality of different materials, or a structure of an electron transport layer ETL/an electron injection layer EIL, or a hole blocking layer HBL/an electron transport layer ETL/an electron injection layer EIL stacked from the emission layer EML, without limitation. For example, the electron transport region ETR may have a thickness of about 1000 Å to about 1500 Å.

The electron transport region ETR may be formed using various processes such as vacuum deposition, spin coating, casting, a Langmuir-Blodgett (LB) process, inkjet printing, laser printing, and laser induced thermal imaging (LITI).

The electron transport region ETR may include a compound represented by Formula ET-2 below.

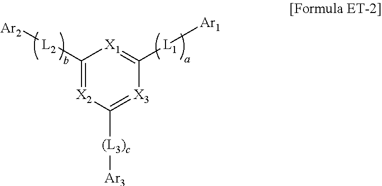

In Formula ET-2, at least one among X₁ to X₃ is N, and the rest thereof (e.g., a remainder of X₁ to X₃) is CRₐ. Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. Ar₁ to Ar₃ may be each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-2, a to c may be each independently an integer of 0 to 10. In Formula ET-2, L₁ to L₃ may be each independently a direct linkage, a substituted or unsubstituted arylene group of 6 to 30 ring-forming carbon atoms, or a substituted or unsubstituted heteroarylene group of 2 to 30 ring-forming carbon atoms. When a to c are integers of 2 or more, L₁ to L₃ may be each independently a substituted or unsubstituted arylene group of 6 to 30 ring-forming carbon atoms, or a substituted or unsubstituted heteroarylene group of 2 to 30 ring-forming carbon atoms.

The electron transport region ETR may include an anthracene-based compound. However, example embodiments of the inventive concepts are not limited thereto, and the electron transport region ETR may include, for example, tris(8-hydroxyquinolinato)aluminum (Alq3), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), berylliumbis(benzoquinolin-10-olate (Bebg2), 9,10-di(naphthalene-2-yl)anthracene (ADN), 1,3-bis[3,5-di(pyridin-3-yl)phenyl]benzene (BmPyPhB), 4′-(4-(4-(4,6-diphenyl-1,3,5-triazin-2-yl)phenyl)naphthalen-1-yl)-[1,1′-biphenyl]-4-carbonitrile (CNNPTRZ) and a mixture thereof.

According to some example embodiments, the electron transport region ETR may include any one among compounds of Compound Group 3 above.

The electron transport region ETR may include at least one among Compounds ET1 to ET36 below.

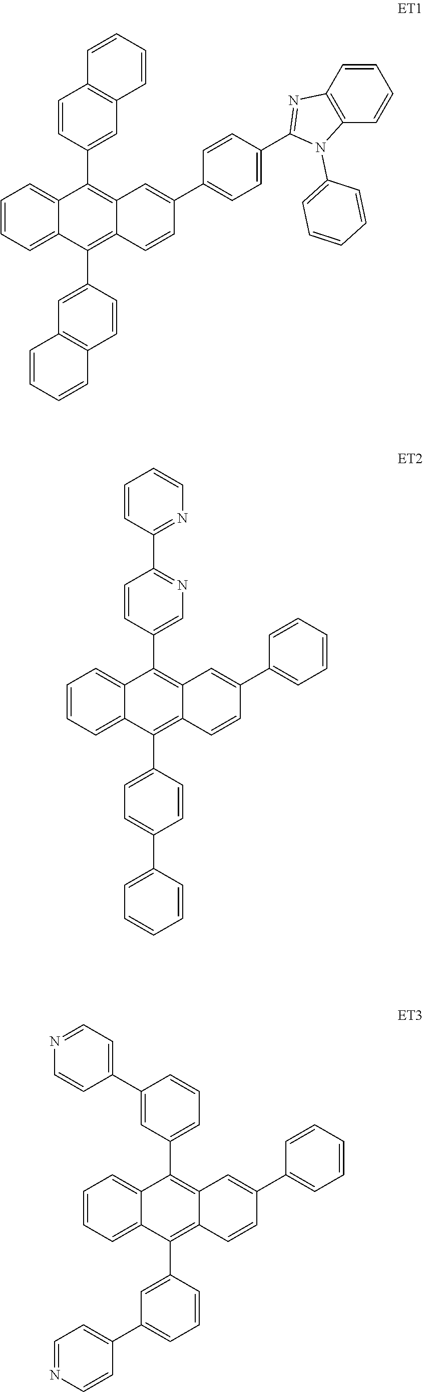 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc(-c3c4ccccc4c(-c4ccc(-c5ccccn5)nc4)c4cc(-c5ccccc5)ccc34)cc2)cc1 ; c1ccc(-c2ccc3c(-c4cccc(-c5ccncc5)c4)c4ccccc4c(-c4cccc(-c5ccncc5)c4)c3c2)cc1]

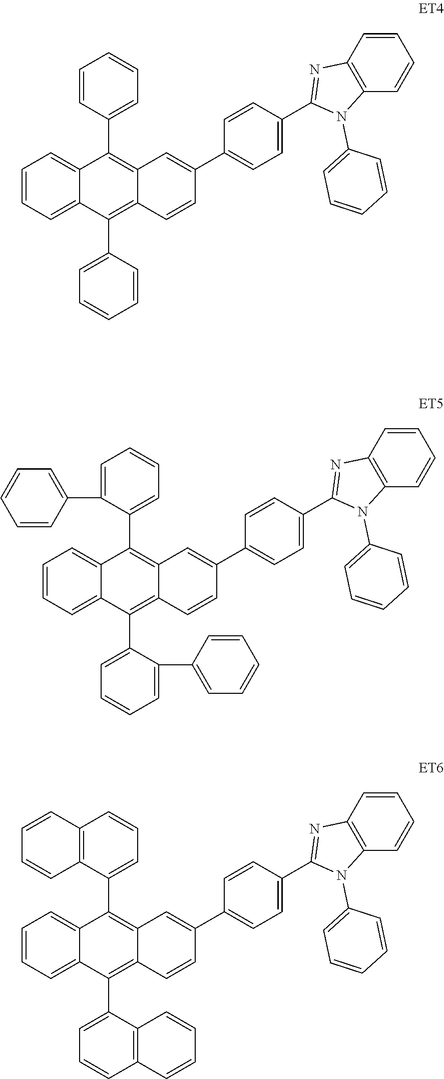 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

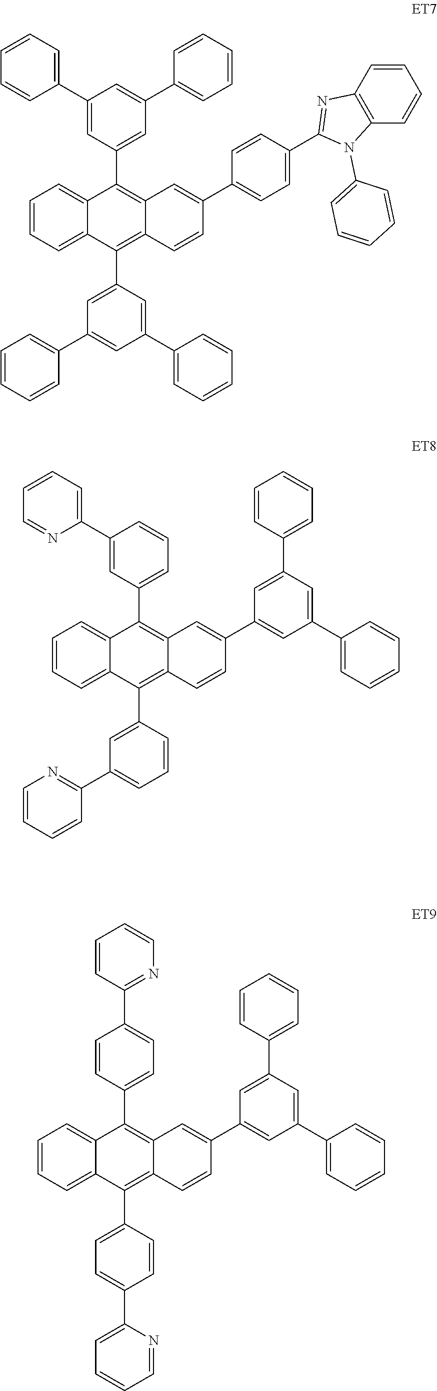 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

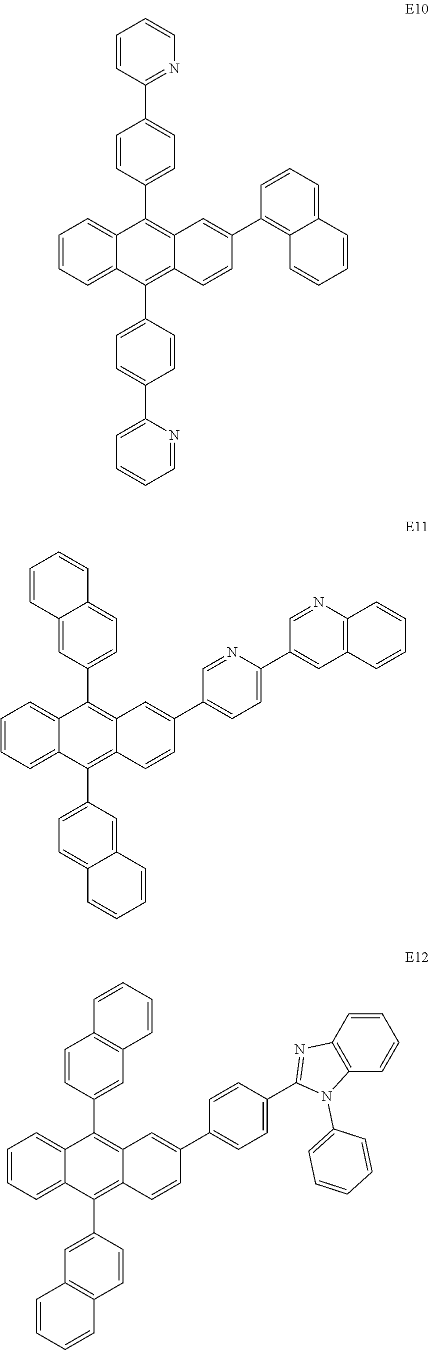 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc(-c4ccc5c(-c6ccc7ccccc7c6)c6ccccc6c(-c6ccc7ccccc7c6)c5c4)cc3)nc3ccccc32)cc1]

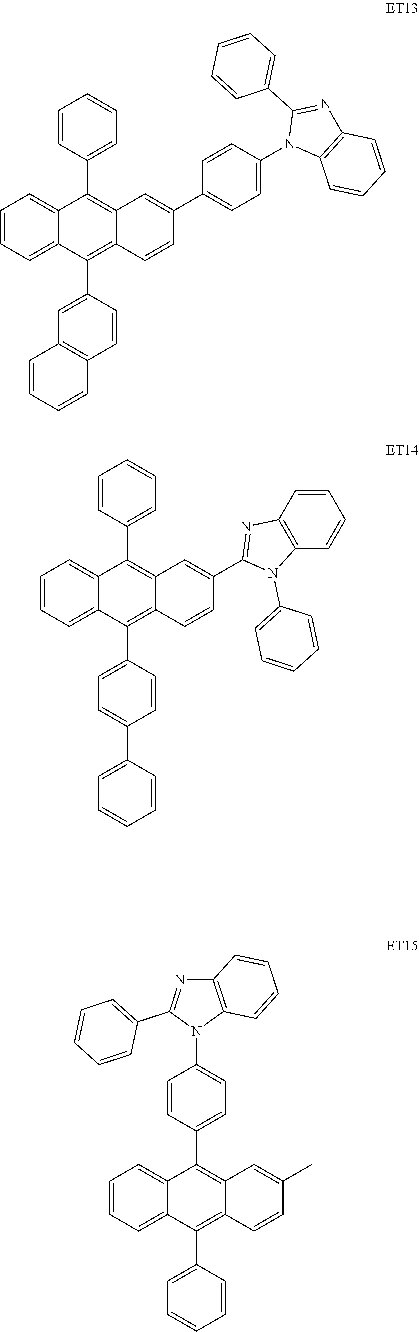 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

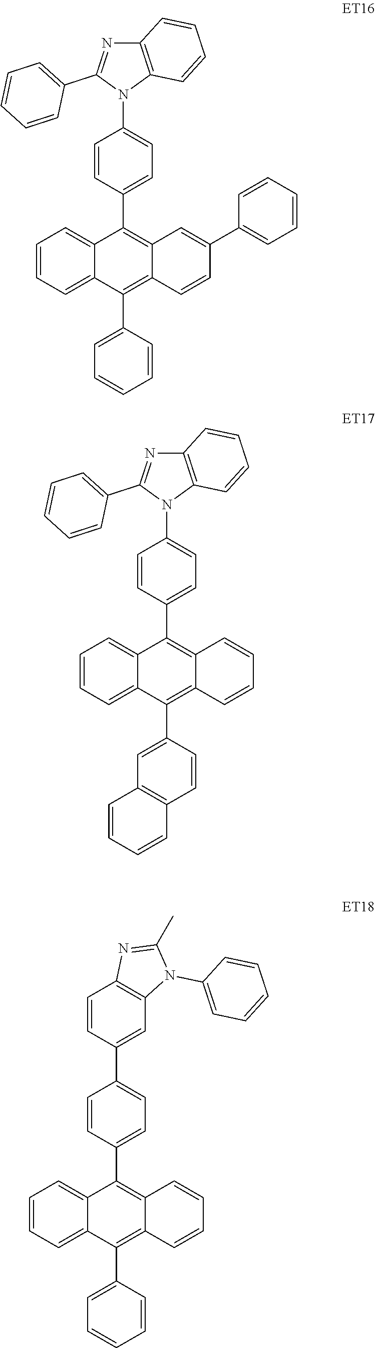 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

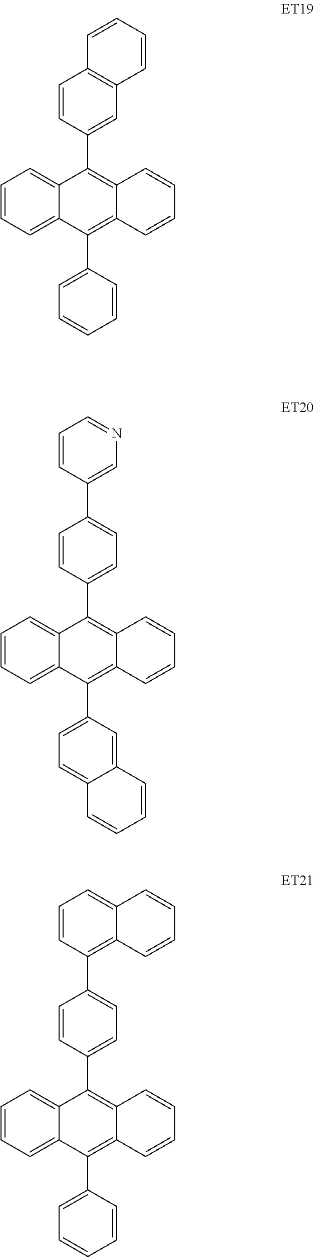

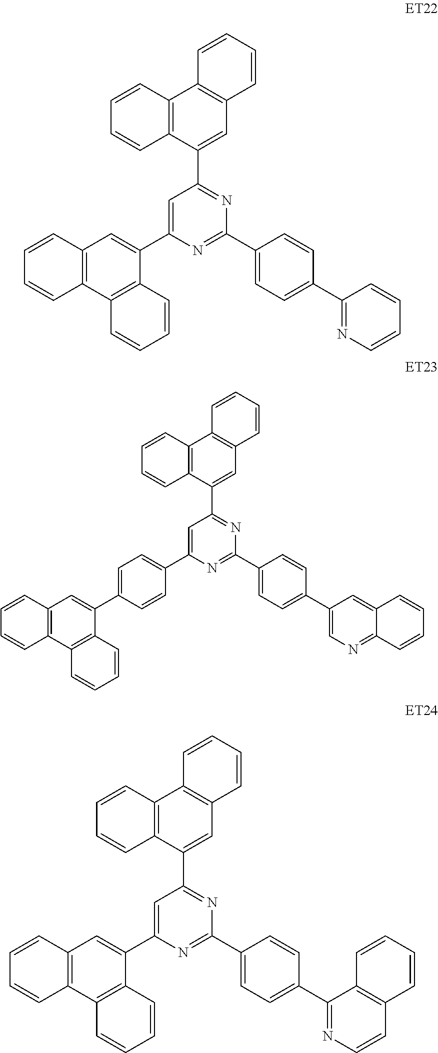 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

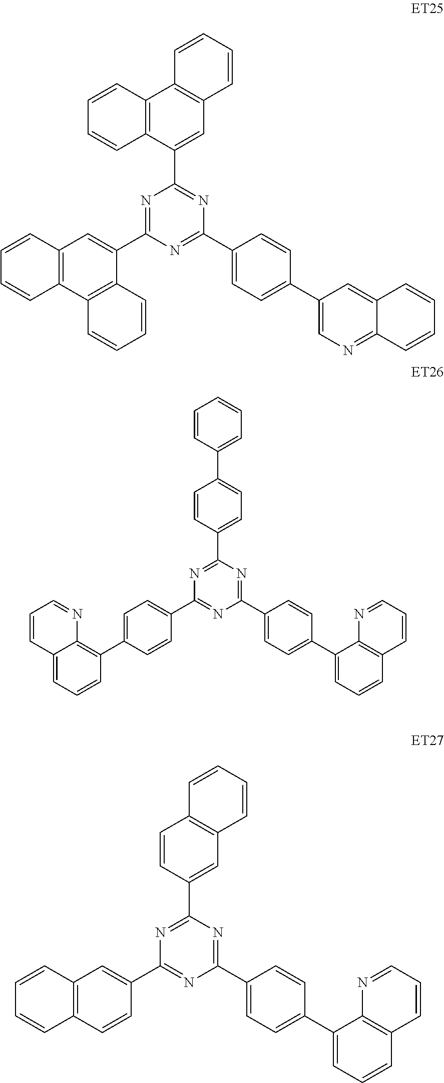 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

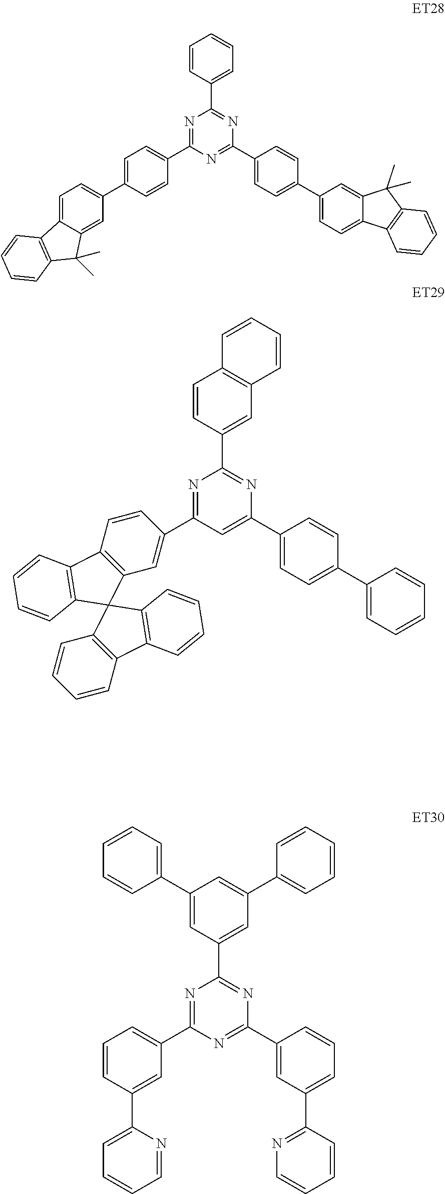 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

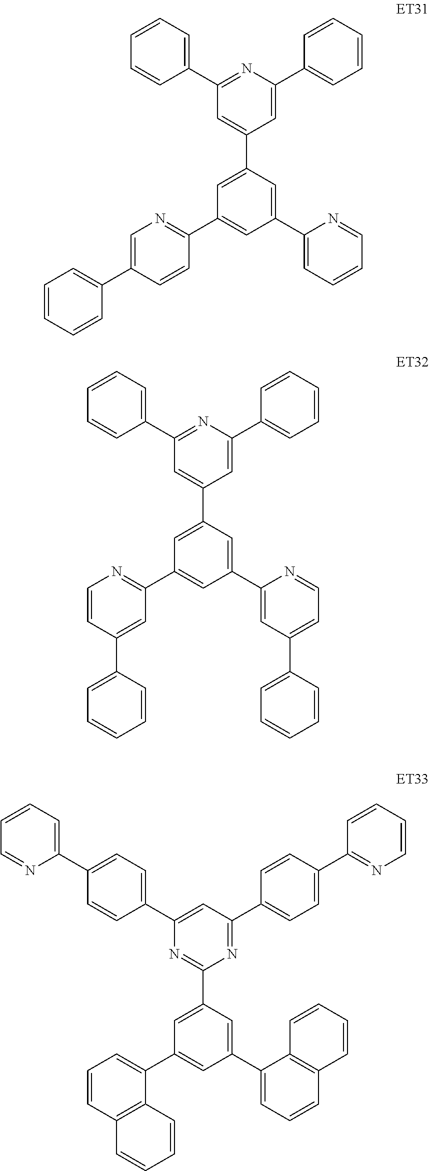 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

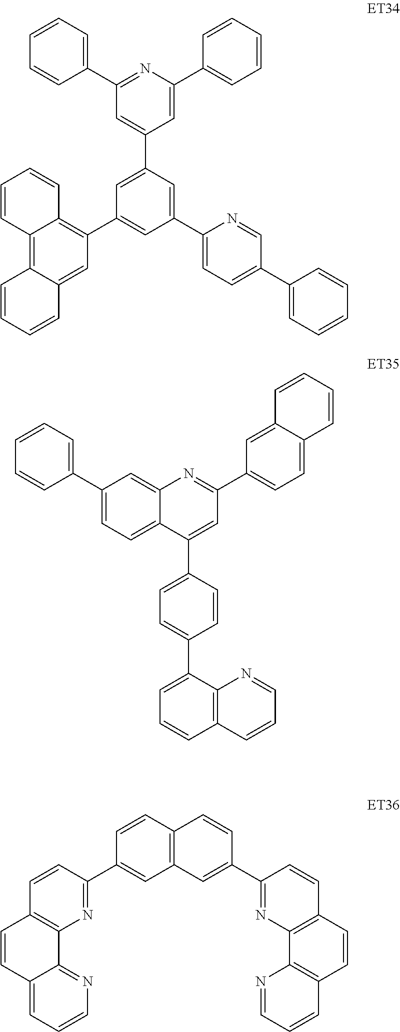

In addition, the electron transport region ETR may include a metal halide such as LiF, NaCl, CsF, RbCl, RbI, CuI and KI, a lanthanum group metal such as Yb, or a co-depositing material of the metal halide and the lanthanum group metal. For example, the electron transport region ETR may include KI:Yb, RbI:Yb, etc., as the co-depositing material. The electron transport region ETR may use a metal oxide such as Li₂O and BaO, 8-hydroxy-lithium quinolate (Liq) or the like, but example embodiments of the inventive concepts are not limited thereto. The electron transport region ETR may be also formed of a material in which an electron transport material and an insulating organo metal salt are mixed. The organo metal salt may be a material having an energy band gap of about 4 eV or more. Specifically, for example, the organo metal salt may include metal acetate, metal benzoate, metal acetoacetate, metal acetylacetonate, or metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1) or 4,7-diphenyl-1,10-phenanthroline (Bphen) as well as the aforementioned materials, but example embodiments of the inventive concepts are not limited thereto.

The electron transport region ETR may include the compounds of the electron transport region described above in at least one among an electron injection layer EIL, an electron transport layer ETL, and a hole blocking layer HBL.

When the electron transport region ETR includes the electron transport layer ETL, the thickness of the electron transport layer ETL may be from about 100 Å to about 1000 Å, for example, from about 150 Å to about 500 Å. When the thickness of the electron transport layer ETL satisfies the above-described range, satisfactory electron transport characteristics may be obtained without substantial increase of a driving voltage. When the electron transport region ETR includes the electron injection layer EIL, the thickness of the electron injection layer EIL may be from about 1 Å to about 100 Å, or from about 3 Å to about 90 Å. When the thickness of the electron injection layer EIL satisfies the above-described range, satisfactory electron injection properties may be obtained without inducing substantial increase of a driving voltage.

The second electrode EL2 is provided on the electron transport region ETR. The second electrode EL2 may be a common electrode. The second electrode EL2 may be a cathode or an anode, but example embodiments of the inventive concepts are not limited thereto. For example, when the first electrode EL1 is an anode, the second cathode EL2 may be a cathode, and when the first electrode EL1 is a cathode, the second electrode EL2 may be an anode.

The second electrode EL2 may be a transmissive electrode, a semi-transmissive electrode or a reflective electrode. When the second electrode EL2 is the transmissive electrode, the second electrode EL2 may be formed of a transparent metal oxide, for example, indium-tin oxide (ITO), indium-zinc oxide (IZO), zinc oxide (ZnO) indium-tin-zinc oxide (ITZO) or the like.

When the second electrode EL2 is the semi-transmissive electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound including the same, or a mixture thereof (for example, AgMg, AgYb, or MgAg). In some example embodiments, the second electrode EL2 may have a multi-layered structure including the reflective layer or the semi-transmissive layer formed of the above-described material, and a transparent conductive layer formed of indium-tin oxide (ITO), indium-zinc oxide (IZO), zinc oxide (ZnO) indium-tin-zinc oxide (ITZO) or the like. For example, the second electrode EL2 may include the aforementioned metal material, a combination of two or more metal materials selected from the aforementioned metal materials, or an oxide of the aforementioned metal materials.

Although not shown, the second electrode EL2 may be connected to an auxiliary electrode. When the second electrode EL2 is connected to the auxiliary electrode, resistance of the second electrode EL2 may decrease.

A capping layer CPL may be further disposed on the second electrode EL2 of the light-emitting element ED according to some example embodiments. The capping layer CPL may be multi-layered or single-layered.

According to some example embodiments, the capping layer CPL may be an organic layer or an inorganic layer. For example, when the capping layer CPL includes an inorganic material, the inorganic material may include an alkali metal compound such as LiF, an alkaline earth metal compound such as MgF₂, SiON, SiNₓ, SiO_{y}, etc.

For example, when the capping layer CPL may include an organic material, the organic material may include α-NPD, NPB, TPD, m-MTDATA, Alq3, CuPc, N4,N4,N4′,N4′-tetra(biphenyl-4-yl) biphenyl-4,4′-diamine (TPD15), 4,4′,4″-tris(carbazol sol-9-yl) triphenylamine (TCTA), etc., or may include an epoxy resin, or acrylate such as methacrylate, but example embodiments of the inventive concepts are not limited thereto. The capping layer CPL may include at least one among Compounds P1 to P5 below.

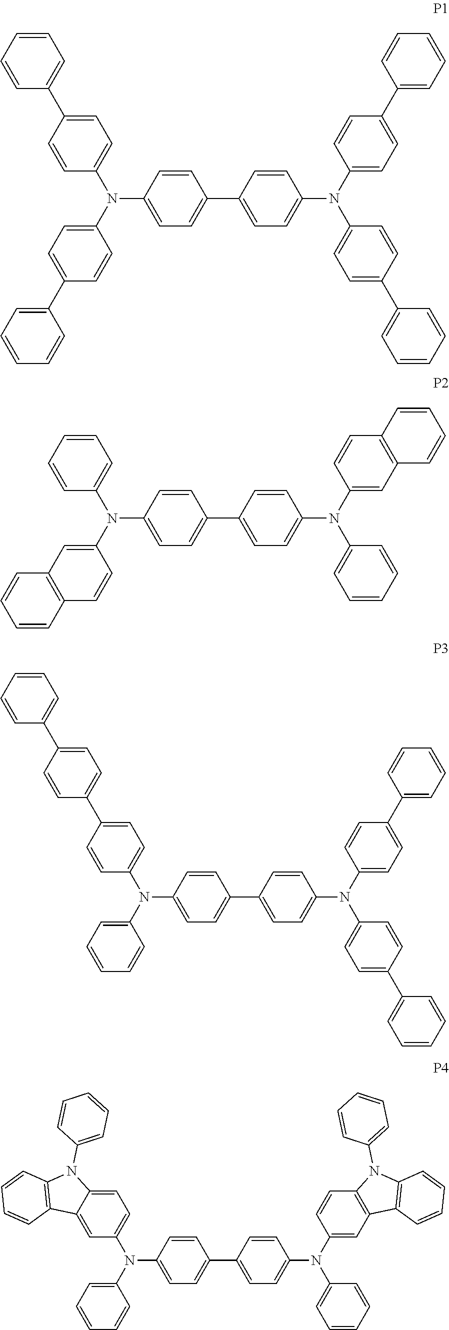 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

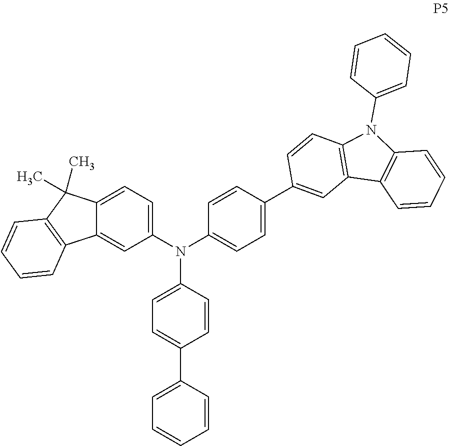 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

The refractive index of the capping layer CPL may be about 1.6 or more. Specifically, the refractive index of the capping layer CPL with respect to light having a wavelength range of about 550 nm to about 660 nm may be about 1.6 or more.

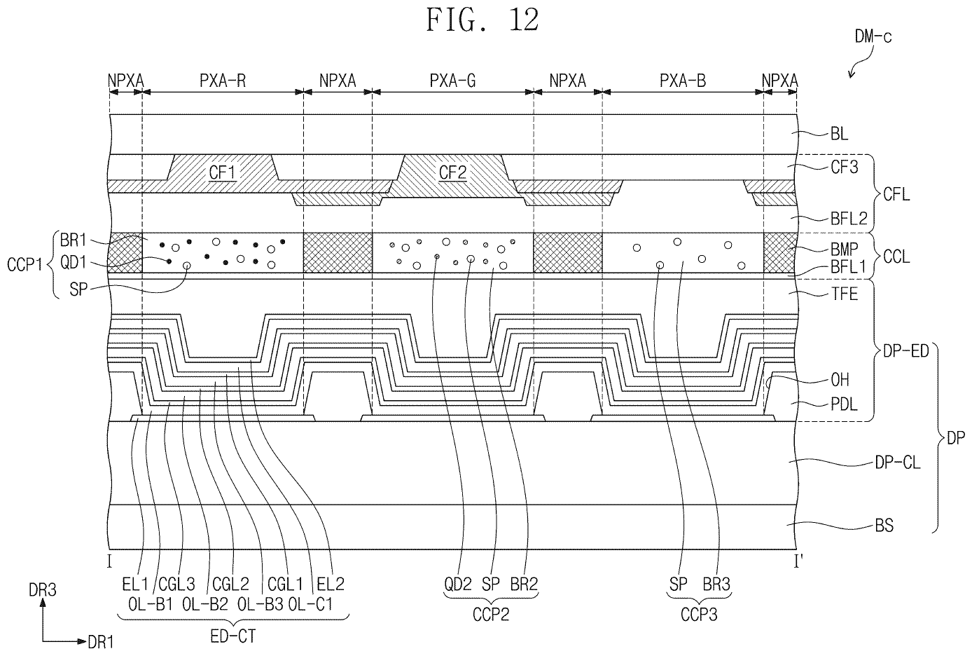

FIG. 9 and FIG. 12 are cross-sectional views on display modules according to some example embodiments, respectively. Hereinafter, when description is made with reference to FIGS. 9 to 12, duplicate description made in FIGS. 3 to 8 will not be made again, and a difference will be mainly described.

Referring to FIG. 9, a display module DD-a according to some example embodiments may include a display panel DP including a display element layer DP-ED, an optical control layer CCL disposed on the display panel DP and a color filter layer CFL. According to some example embodiments illustrated in FIG. 9, the display panel DP may include a base layer BS, a circuit layer DP-CL provided on the base layer BS and a display element layer DP-ED, and the display element layer DP-ED may include a light-emitting element ED.

The light-emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. The same structures of the light-emitting elements of FIG. 5 to FIG. 8 may be applied to the structure of the light-emitting element ED illustrated in FIG. 9.

The emission layer EML of the light-emitting element ED included in the display module DM-a according to some example embodiments may include the fused polycyclic compound according to some example embodiments described above.

Referring to FIG. 9, the emission layer EML may be disposed in an opening OH defined in a pixel-defining film PDL. For example, the emission layer EML divided by the pixel-defining film PDL and provided corresponding to each of luminous areas PXA-R, PXA-G and PXA-B may emit light having the same wavelength region. In the display module DM-a according to some example embodiments, the emission layer EML may emit blue light. Unlike what is illustrated, according to some example embodiments, the emission layer EML may be provided as a common layer for all luminous areas PXA-R, PXA-G and PXA-B.

The optical control layer CCL may be disposed on the display panel DP. The optical control layer CCL may include an optical converter. The optical converter may be a quantum dot or a phosphor. The optical converter may change a wavelength of provided light, and then emit light having a changed wavelength. That is, the optical control layer CCL may be a layer including the quantum dot or the phosphor.

The optical control layer CCL may include a plurality of optical control portions CCP1, CCP2 and CCP3. The optical control portions CCP1, CCP2 and CCP3 may be spaced apart from one another.

Referring to FIG. 9, a partition pattern BMP may be disposed between the optical control portions CCP1, CCP2 and CCP3 spaced apart from one another, but example embodiments of the inventive concepts are not limited thereto. FIG. 9 illustrates that the partition pattern BMP does not overlap the optical control portions CCP1, CCP2 and CCP3, but edges of the optical control portions CCP1, CCP2 and CCP3 may at least partially overlap the partition pattern BMP.

The optical control layer CCL may include a first optical control portion CCP1 including a first quantum dot QD1 converting first light provided from the light-emitting element ED into second light, a second optical control portion CCP2 including a second quantum dot QD2 converting first light into third light, and a third optical control portion CCP3 transmitting first light. According to some example embodiments, the first optical control portion CCP1 may provide red light which is the second light, and the second optical control portion CCP2 may provide green light which is the third light. The third optical control portion CCP3 may transmit and provide blue light which is the first light provided from the light-emitting element ED. For example, the first quantum dot QD1 may be a red quantum dot, and the second quantum dot QD2 may be a green quantum dot. On the quantum dots QD1 and QD2, the same contents as those described above may be applied.

In addition, the optical control layer CCL may further include a scatterer SP. The first optical control portion CCP1 may include the first quantum dot QD1 and the scatterer SP, the second optical control portion CCP2 may include the second quantum dot QD2 and the scatterer SP, and the third optical control portion CCP3 may not include a quantum dot but may include the scatterer SP.

The scatterer SP may be an inorganic particle. For example, the scatterer SP may include at least one among TiO₂, ZnO, Al₂O₃, SiO₂, and hollow silica. The scatterer SP may include any one among TiO₂, ZnO, Al₂O₃, SiO₂, and hollow silica, or may be a mixture of two or more materials selected from TiO₂, ZnO, Al₂O₃, SiO₂, and hollow silica.

Each of the first optical control portion CCP1, the second optical control portion CCP2, and the third optical control portion CCP3 may include base resins BR1, BR2 and BR3 dispersing the quantum dots QD1 and QD2 and the scatterer SP. According to some example embodiments, the first optical control portion CCP1 may include the first quantum dot QD1 and the scatterer SP dispersed in the first base resin BR1, the second optical control portion CCP2 may include the second quantum dot QD2 and the scatterer SP dispersed in the second base resin BR2, and the third optical control portion CCP3 may include the scatterer SP dispersed in the third base resin BR3.

The base resins BR1, BR2 and BR3 are mediums in which the quantum dots QD1 and QD2 and the scatterer SP are dispersed, and may be composed of various resin compositions which may be generally referred to as binders. For example, the base resins BR1, BR2 and BR3 may be acrylic resins, urethane-based resins, silicone-based resins, epoxy-based resins, etc. The base resins BR1, BR2 and BR3 may be transparent resins. According to some example embodiments, the first base resin BR1, the second base resin BR2 and the third base resin BR3 may be the same as or different from each other.

The optical control layer CCL may include a barrier layer BFL1. The barrier layer BFL1 may serve to block penetration of moisture and/or oxygen (hereinafter, will be referred to as ‘humidity/oxygen’). The barrier layer BFL1 may block the optical control portions CCP1, CCP2 and CCP3 from being exposed to humidity/oxygen. The barrier layer BFL1 may cover the optical control portions CCP1, CCP2 and CCP3. In addition, a barrier layer BFL2 may be provided between the optical control portions CCP1, CCP2 and CCP3 and the color filter layer CFL.

The barrier layers BFL1 and BFL2 may include at least one inorganic layer. That is, the barrier layers BFL1 and BFL2 may be formed by including an inorganic material. For example, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide and silicon oxynitride or a metal thin film securing light transmittance. The barrier layers BFL1 and BFL2 may further include an organic layer. The barrier layers BFL1 and BFL2 may be composed of a single layer of a plurality of layers.

In the display module DD-a according to some example embodiments, the color filter layer CFL may be disposed on the optical control layer CCL. For example, the color filter layer CFL may be disposed directly on the optical control layer CCL. In this case, the barrier layer BFL2 may be omitted.

The color filter layer CFL may include filters CF1, CF2 and CF3. Each of the first to third filters CF1, CF2, and CF3 may be disposed corresponding to each of the red luminous area PXA-R, the green luminous area PXA-G and the blue luminous area PXA-B.

The color filter layer CFL may include the first filter CF1 transmitting (e.g, selectively transmitting) second light, the second filter CF2 transmitting (e.g, selectively transmitting) third light, and the third filter CF3 transmitting (e.g, selectively transmitting) first light. For example, the first filter CF1 may be a red filter, the second filter CF2 may be a green filter, and the third filter CF3 may be a blue filter. Each of the filters CF1, CF2 and CF3 may include a polymer photosensitive resin and a pigment or dye. The first filter CF1 may include a red pigment or dye, the second filter CF2 may include a green pigment or dye, and the third filter CF3 may include a blue pigment or dye.

Example embodiments of the inventive concepts are not limited thereto, and the third filter CF3 may not include the pigment or dye. The third filter CF3 may include a polymer photosensitive resin and may not include a pigment or dye. The third filter CF3 may be transparent. The third filter CF3 may be formed of a transparent photosensitive resin.

In addition, according to some example embodiments, the first filter CF1 and the second filter CF2 may be yellow filters. The first filter CF1 and the second filter CF2 may be integrally provided without distinction.

Although not shown, the color filter layer CFL may further include a light-blocking portion (not shown). The light-blocking portion may be a black matrix. The light-blocking portion may be formed including an organic light-blocking material or an inorganic light-blocking material including a black pigment or black dye. The light-blocking portion may prevent a light-leak phenomenon, and may demarcate boundaries between adjacent filters CF1, CF2, and CF3.

A base substrate BL may be disposed on the color filter layer CFL. The base substrate BL may be a member providing a base surface on which the color filter layer CFL, the optical control layer CCL, etc., are disposed. The base substrate BL may be a glass substrate, a metal substrate, a plastic substrate, or the like. However, example embodiments of the inventive concepts are not limited thereto, and the base substrate BL may be an inorganic layer, an organic layer, or a composite material layer. In addition, unlike what is illustrated, according to some example embodiments, the base substrate BL may be omitted.

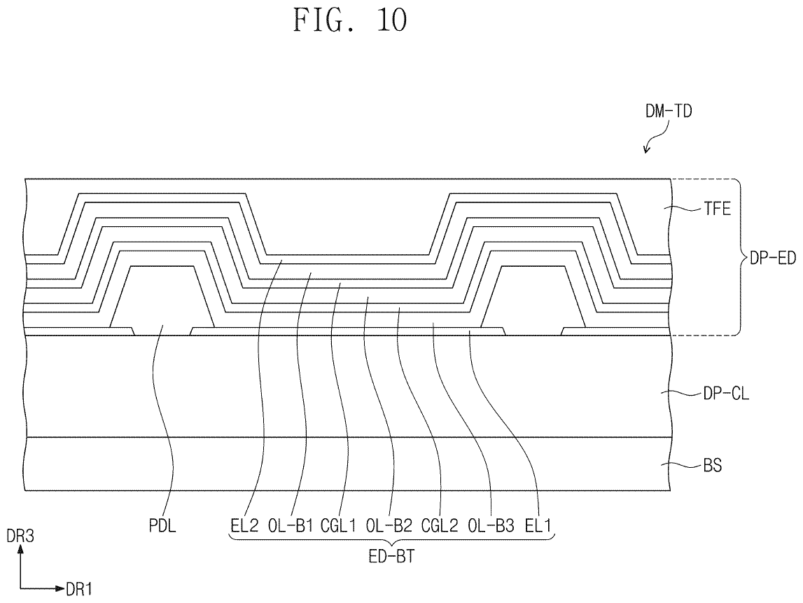

FIG. 10 is a cross-sectional view partially illustrating a display module according to some example embodiments. In a display module DD-TD according to some example embodiments, a light-emitting element ED-BT may include a plurality of light-emitting structures OL-B1, OL-B2 and OL-B3. At least one among the light emitting structures OL-B1, OL-B2 and OL-B3 may include the fused polycyclic compound of some example embodiments. The light-emitting element ED-BT including the fused polycyclic compound of some example embodiments may exhibit high emission efficiency and long lifespan. In addition, the light-emitting element ED-BT according to some example embodiments may exhibit high light efficiency and long lifespan characteristics in the blue light emission region.

The light-emitting element ED-BT may include the first electrode EL1 and the second electrode EL2 facing each other, and a plurality of light-emitting structures OL-B1, OL-B2 and OL-B3 sequentially stacked between the first electrode EL1 and the second electrode EL2 in a thickness direction and provided. Each of the light-emitting structures OL-B1, OL-B2 and OL-B3 may include the emission layer EML (see FIG. 8), and the hole transport region HTR and the electron transport region ETR disposed with the emission layer EML (see FIG. 8) therebetween. That is, the light-emitting element ED-BT included in the display module DD-TD according to some example embodiments may be a light-emitting element having a tandem structure including a plurality of emission layers.

According to some example embodiments illustrated in FIG. 10, light emitted by each of the light-emitting structures OL-B1, OL-B2 and OL-B3 may be all blue light. However, example embodiments of the inventive concepts are not limited thereto, the light emitted by each of the light-emitting structures OL-B1, OL-B2 and OL-B3 may have different wavelength regions. For example, the light-emitting element ED-BT including the plurality of light-emitting structures OL-B1, OL-B2 and OL-B3 that emit light having the different wavelength regions may emit white light.

Charge generation layers CGL1 and CGL2 may be disposed between the light-emitting structures OL-B1, OL-B2 and OL-B3 next to each other. In some example embodiments illustrated in FIG. 10, the charge generation layers CGL1 and CGL2 may include a first charge generation layer CGL1 disposed between a first light-emitting structure OL-B1 and a second light-emitting structure OL-B2, and a second charge generation layer CGL2 disposed between a second light-emitting structure OL-B2 and a third light-emitting structure OL-B3. The charge generation layers CGL1 and CGL2 may include a P-type charge generation layer and/or an N-type charge generation layer.

The above-described fused polycyclic compound according to some example embodiments may be included at least one emission structures OL-B1, OL-B2, and OL-B3 included in a display module DD-TD according to some example embodiments. That is, at least one among a plurality of emission layers included in a light-emitting element ED-BT may include the fused polycyclic compound according to some example embodiments.

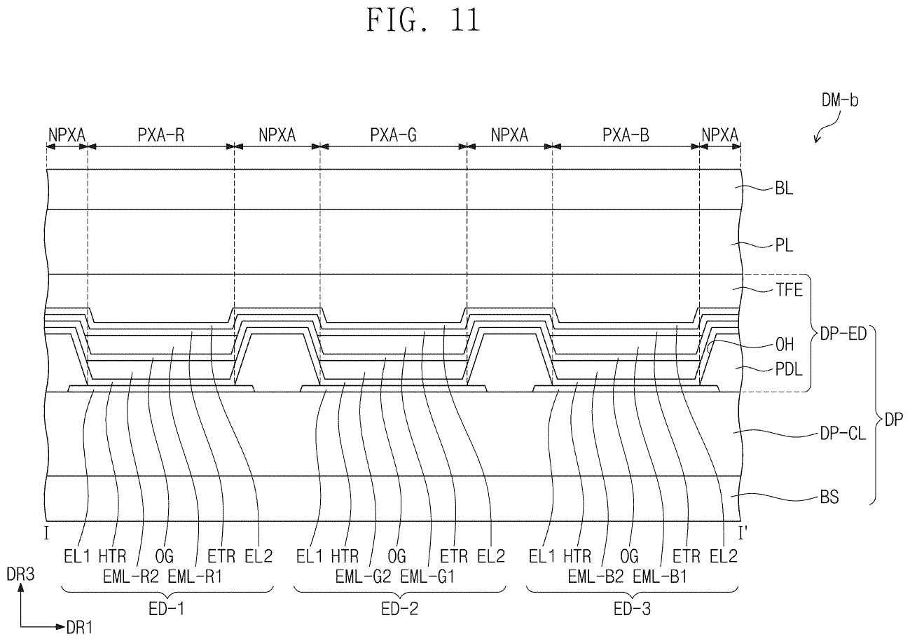

FIG. 11 is a cross-sectional view illustrating a display module according to some example embodiments of the inventive concepts. FIG. 12 is a cross-sectional view illustrating a display module according to some example embodiments of the inventive concepts.

Referring to FIG. 11, a display module DD-b according to some example embodiments may include light-emitting elements ED-1, ED-2, and ED-3 in which two emission layers are stacked. The display module according to some example embodiments illustrated in FIG. 11 has a difference that each of the first to third light-emitting elements ED-1, ED-2, and ED-3 include two emission layers stacked in a thickness direction, compared with the display module DD according to some example embodiments illustrated in FIG. 4. The two emission layers of each of the first to third light-emitting elements ED-1, ED-2, and ED-3 may emit light having the same wavelength region as each other.

The first light-emitting element ED-1 may include a first red emission layer EML-R1 and a second red emission layer EML-R2. The second light-emitting element ED-2 may include a first green emission layer EML-G1 and a second green emission layer EML-G2. In addition, the third light-emitting element ED-3 may include a first blue emission layer EML-B1 and a second blue emission layer EML-B2. An auxiliary light-emitting portion OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The auxiliary light-emitting portion OG may include a single layer or a plurality of layers. The auxiliary light-emitting portion OG may include a charge generation layer. More specifically, the auxiliary light-emitting portion OG may include an electron transport region, a charge generation layer and a hole transport region sequentially stacked. The auxiliary light-emitting portion OG may be provided as a common layer in all first to third light-emitting elements ED-1, ED-2, and ED-3. However, example embodiments of the inventive concepts are not limited thereto, and the auxiliary light-emitting portion OG may be patterned in the opening OH defined in the pixel-defining film PDL and may be provided.

The first red emission layer EML-R1, the first green emission layer EML-G1 and the first blue emission layer EML-B1 may be disposed between the auxiliary light-emitting portion OG and the electron transport region ETR. The second red emission layer EML-R2, the second green emission layer EML-G2 and the second blue emission layer EML-B2 may be disposed between the hole transport region HTR and the auxiliary light-emitting portion OG.

That is, the first light-emitting element ED-1 may include the first electrode EL1, the hole transport region HTR, the second red emission layer EML-R2, the auxiliary light-emitting portion OG, the first red emission layer EML-R1, the electron transport region ETR and the second electrode EL2 sequentially stacked. The second light-emitting element ED-2 may include the first electrode EL1, the hole transport region HTR, the second green emission layer EML-G2, the auxiliary light-emitting portion OG, the first green emission layer EML-G1, the electron transport region ETR and the second electrode EL2 sequentially stacked. The third light-emitting element ED-3 may include the first electrode EL1, the hole transport region HTR, the second blue emission layer EML-B2, the auxiliary light-emitting portion OG, the first blue emission layer EML-B1, the electron transport region ETR and the second electrode EL2 sequentially stacked.

An optical auxiliary layer PL may be disposed on the display element layer DP-ED. The optical auxiliary layer PL may include a polarization layer. The optical auxiliary layer PL may be disposed on the display panel DP to control reflected light in the display panel DP by external light. Unlike what is illustrated, the optical auxiliary layer PL may be omitted in the display module according to some example embodiments.

At least one emission layer included in a display module DD-b according to some example embodiments, illustrated in FIG. 11 may include the fused polycyclic compound according to some example embodiments. For example, in some example embodiments, at least one among a first blue emission layer EML-B1 and a second blue emission layer EML-B2 may include the fused polycyclic compound according to some example embodiments.

Unlike FIGS. 10 and 11, FIG. 12 illustrates that a display module DD-c includes four light-emitting structures OL-B1, OL-B2, OL-B3 and OL-C1. A light-emitting element ED-CT may include the first electrode EL1 and the second electrode EL2 facing each other, and the first to fourth light-emitting structures OL-B1, OL-B2, OL-B3 and OL-C1 sequentially stacked between the first electrode EL1 and the second electrode EL2 in a thickness direction. Charge generation layers CGL1, CGL2 and CGL3 may be disposed between the first to fourth light-emitting structures OL-B1, OL-B2, OL-B3 and OL-C1. The first to third light-emitting structures OL-B1, OL-B2 and OL-B3 among the four light-emitting structures may emit blue light, and the fourth light-emitting structure OL-C1 may emit green light. However, example embodiments of the inventive concepts are not limited thereto, and the first to fourth light-emitting structures OL-B1, OL-B2, OL-B3 and OL-C1 may emit light having different wavelength regions.

The charge generation layers CGL1, CGL2 and CGL3 disposed between the light-emitting structures OL-B1, OL-B2, OL-B3 and OL-C1 next to each other may include a P-type charge generation layer and/or an N-type charge generation layer.

At least one among emission structures OL-B1, OL-B2, OL-B3, and OL-C1 included in a display module DD-c according to some example embodiments may include the above-described fused polycyclic compound according to some example embodiments. For example, in some example embodiments, at least one among the first to third emission structures OL-B1, OL-B2, and OL-B3 may include the above-described fused polycyclic compound according to some example embodiments.

The light-emitting element ED according to some example embodiments of the inventive concepts may include the fused polycyclic compound according to some example embodiments, represented by Formula 1 described previously, in at least one functional layer disposed between the first electrode EL1 and the second electrode EL2 and thus may exhibit excellent emission efficiency and improved lifespan characteristics. For example, the fused polycyclic compound according to some example embodiments may be included in the emission layer EML of the light-emitting element ED according to some example embodiments, and the light-emitting element according to some example embodiments may exhibit long lifespan characteristics.

In some example embodiments, the electronic apparatus may include a display device including a plurality of light-emitting elements, and a control part controlling the display device. In the electronic apparatus according to some example embodiments, at least one among the plurality of light-emitting elements may include the above-described fused polycyclic compound according to some example embodiments in an emission layer.

The electronic apparatus according to some example embodiments may be activated in response to an electrical signal. The electronic apparatus according to some example embodiments may include display devices including the display module according to some example embodiments, described with reference to FIG. 3, FIG. 9 to FIG. 12, or the like. For example, the electronic apparatus may be a medium- and small-sized display device such as a personal computer, a laptop computer, a personal digital assistant, a vehicular display device, a game console, a portable electronic device, or a camera in addition to a large-sized display device such a television, a monitor, or an outdoor billboard.

The electronic apparatus according to some example embodiments may exhibit high efficiency and long lifespan characteristics by including a display module that contains the fused polycyclic compound according to some example embodiments. The electronic apparatus according to some example embodiments may have improved display efficiency and display lifespan and may exhibit excellent display quality.

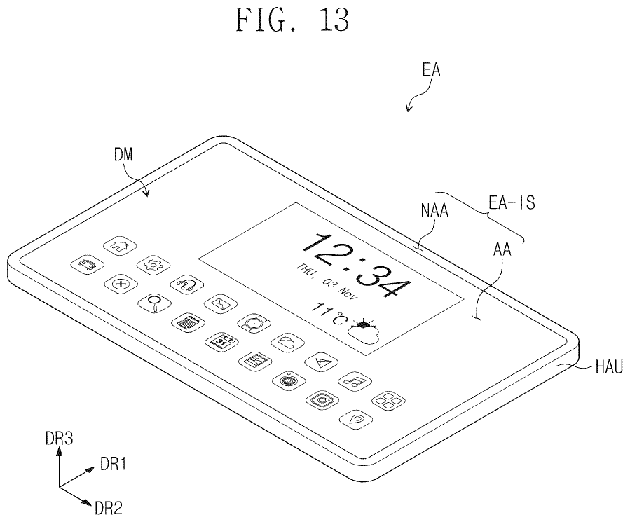

FIG. 13 illustrates a tablet computer as an example of an electronic apparatus EA. The electronic apparatus EA according to some example embodiments may include a display module DM according to some example embodiments. For example, the tablet computer is configured by disposing, in a bracket/housing HAU, etc., electronic modules, a camera module, a power module, or the like, mounted in a main board with the display module DM.

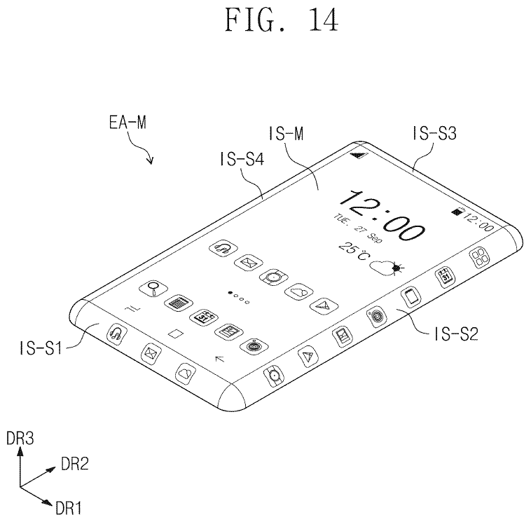

An electronic apparatus EA according to some example embodiments, illustrated in FIG. 14 may include the display module according to some example embodiments, described with reference to FIG. 3, FIG. 9 to FIG. 12, or the like.

In some example embodiments, the electronic apparatus EA including a display module DM, in which a flat display surface is provided, is illustrated, but example embodiments are not limited thereto. For example, the electronic apparatus EA may also include a curved display surface or a three-dimensional display surface. For example, the three-dimensional display surface may include a plurality of display regions indicating different directions from each other and may also include a bent display surface. The electronic apparatus EA according to the present embodiment may be a flexible electronic apparatus. The flexible electronic apparatus may be a foldable electronic apparatus which is capable of being folded.

As illustrated in FIG. 13, a display surface EA-IS includes an active region AA in which an image is displayed, and a bezel region NAA which is adjacent to the active region AA. The bezel region NAA is a region where no image is displayed. FIG. 13 illustrates icon images as an example of an image. The active region AA may be referred to as a display region of the display module DM, and the bezel region NAA may be referred to as a non-display region of the display module DM.

FIG. 14 illustrates a portable terminal as an example of an electronic apparatus EA-M according to some example embodiments. Referring to FIG. 14, the electronic apparatus EA-M according to some example embodiments may include a plurality of display surfaces. The electronic apparatus EA-M according to some example embodiments may include display surfaces IS-M, IS-S1, IS-S2, IS-S3, and IS-S4, having different main display directions from each other.

In some example embodiments, the display device EA-M may be a three-dimensional display device including an upper display surface IS-M and a plurality of side display surfaces IS-S1, IS-S2, IS-S3, and IS-S4. The plurality of side display surfaces IS-S1, IS-S2, IS-S3, and IS-S4 may each be a display surface extending from one side of the upper display surface IS-M. In some example embodiments, the electronic apparatus EA-M may include a main display surface which provides an image in the one direction and a plurality of sub display surfaces which provide an image in a different direction from the one direction. In the electronic apparatus EA-M according to some example embodiments, illustrated in FIG. 14, the main display surface may be the upper display surface IS-M, and the sub display surfaces may be the side display surfaces IS-S1, IS-S2, IS-S3, and IS-S4.

The side display surfaces IS-S1, IS-S2, IS-S3, and IS-S4 may each have a display surface which is not parallel to the upper display surface IS-M. The plurality of side display surfaces IS-S1, IS-S2, IS-S3, and IS-S4 are display regions which are respectively bent from sides of the upper display surface IS-M and extended, and for example, the plurality of side display surfaces IS-S1, IS-S2, IS-S3, and IS-S4 may be bent display regions.

The electronic apparatus EA-M according to some example embodiments, illustrated in FIG. 14, may include the display module according to some example embodiments, described with reference to FIG. 3, FIG. 9 to FIG. 12, or the like.

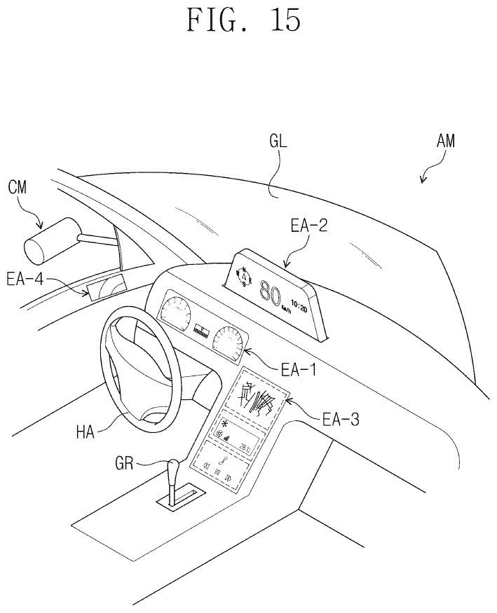

FIG. 15 is a diagram illustrating a vehicle AM in which first to fourth electronic apparatus EA-1, EA-2, EA-3, and EA-4 are disposed. At least one among the first to fourth electronic apparatus EA-1, EA-2, EA-3, and EA-4 may include the same configuration as the display module according to some example embodiments described with reference to FIGS. 3, and 9 to 12.

FIG. 15 illustrates a car as the vehicle AM, but this is an example, and the first to fourth electronic apparatus EA-1, EA-2, EA-3, and EA-4 may be disposed on another transportation means such as a bicycle, a motorcycle, a train, a ship or an airplane.

At least one among first to fourth electronic apparatuses EA-1, EA-2, EA-3, and EA-4 may include the light-emitting element ED described with reference to FIG. 5 to FIG. 8. At least one among the first to fourth electronic apparatuses EA-1, EA-2, EA-3, and EA-4 may include the fused polycyclic compound according to some example embodiments. Therefore, the first to fourth electronic apparatuses EA-1, EA-2, EA-3, and EA-4 including the fused polycyclic compound according to some example embodiments may have improved display efficiency and display lifespan. In addition, the first to fourth electronic apparatuses EA-1, EA-2, EA-3, and EA-4 including the fused polycyclic compound according to some example embodiments may exhibit excellent display quality.

Referring to FIG. 15, the vehicle AM may include a gear GR and a handle HA for operating the vehicle AM. In addition, the vehicle AM may include a front window GL disposed toward a driver.

The first electronic apparatus EA-1 may be disposed in a first region overlapping the handle HA. For example, the first electronic apparatus EA-1 may be a digital cluster that displays first information of the vehicle AM. The first information may include a first scale showing a driving speed of the vehicle AM, a second scale showing a revolution of an engine (that is, revolutions per minute (RPM)), and an image showing a fuel status. The first scale and the second scale may be displayed as digital images.

The first electronic apparatus EA-1 may be disposed in a first region overlapping the handle HA. For example, the first electronic apparatus EA-1 may be a digital cluster that displays first information of the vehicle AM. The first information may include a first scale showing a driving speed of the vehicle AM, a second scale showing a revolution of an engine (that is, revolutions per minute (RPM)), and an image showing a fuel status. The first scale and the second scale may be displayed as digital images. In some example embodiments, including the example embodiments illustrated in FIG. 15, the first electronic apparatus EA-1 may be positioned in a first area overlapping the handle HA. However, the example embodiments are not limited thereto, and the first electronic apparatus EA-1 may be positioned across the entire dashboard, or may be positioned separately on a portion facing the driver's seat and a portion facing the passenger's seat.

The second electronic apparatus EA-2 may be disposed in a second region facing a driver's seat and overlapping the front window GL. The driver's seat may be a seat in which the handle HA is disposed. For example, the second electronic apparatus EA-2 may be a head up display (HUD) that displays second information of the vehicle AM. The second electronic apparatus EA-2 may be optically transparent. The second information may include a digital number that shows the driving speed of the vehicle AM, and may further include information such as current time. Unlike what is illustrated, the second information of the second electronic apparatus EA-2 may be projected onto the front window GL and may be displayed.

The third electronic apparatus EA-3 may be disposed in a third region adjacent to the gear GR. For example, the third electronic apparatus EA-3 may be a center information display (CID) for a vehicle disposed between the driver's seat and a passenger's seat, and displaying third information. The passenger's seat may be a seat spaced apart from the driver's seat with the gear GR therebetween. The third information may include a road status (for example, navigation information), playing music or a radio, playing a dynamic video (or an image), information on a temperature or the like inside the vehicle AM.

The fourth electronic apparatus DD-4 may be disposed in a fourth region spaced apart from the handle HA and the gear GR, and adjacent to a side portion of the vehicle AM. For example, the fourth electronic apparatus DD-4 may be a digital side-mirror that displays fourth information. The fourth electronic apparatus DD-4 may display an exterior video of the vehicle AM captured by a camera module CM disposed outside the vehicle AM. The fourth information may include the exterior video of the vehicle AM.

The first to fourth information described above are examples, and the first to fourth electronic apparatus EA-1, EA-2, EA-3, and EA-4 may further display information inside and outside the vehicle AM. The first to fourth information may include different information. However, example embodiments of the inventive concepts are not limited thereto, and some of the first to fourth information may include the same information as each other.

FIG. 13 to FIG. 15 illustrate some example embodiments of an electronic apparatus, or some example embodiments including an electronic apparatus, and a display module that includes the fused polycyclic compound according to some example embodiments may be applied to other electronic apparatuses without departing from the concept of the inventive concepts.

Hereinafter, with reference to Examples and Comparative Examples, the fused polycyclic compound according to some example embodiments of the inventive concepts and the light-emitting element according to some example embodiments will be described in detail. In addition, Examples shown below are exemplified only for helping the understanding of the inventive concepts, and the scope of the inventive concepts is not limited thereto.

### EXAMPLES

### 1. Synthesis of Fused Polycyclic Compound

First, a synthetic method of the fused polycyclic compounds according to some example embodiments of the present inventive concepts will be explained by exemplifying the synthetic methods of Compounds 1 to 12, and 14 to 16. In addition, the synthetic methods of the fused polycyclic compounds explained hereinafter are examples, and a synthetic method of the compound according to some example embodiments of the inventive concepts is not limited to the examples below.

### (1) Synthesis of Compound 1

### Synthesis of Intermediate 1C

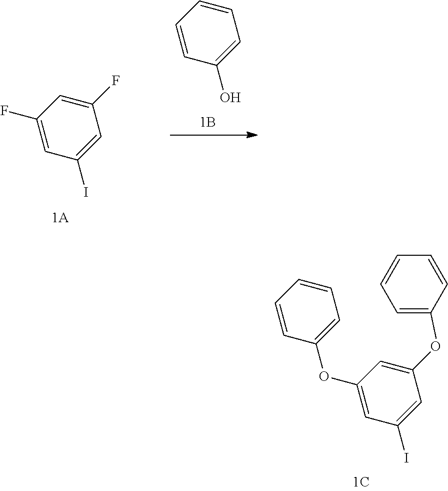 [SMILES: Fc1cc(F)cc(I)c1 ; Oc1ccccc1 ; Ic1cc(Oc2ccccc2)cc(Oc2ccccc2)c1]

Under argon (Ar) atmosphere, Intermediate 1A (1,3-difluoro-5-iodobenzene, 50 g), Intermediate 1B (phenol, 50 g), K₂CO₃ (87 g), and 1-methyl-2-pyrrolidone (400 ml) were added to a 1000 ml three-necked flask, and the resultant mixture was heated and stirred for about 16 hours at about 160° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 67 g of Intermediate 1C (yield of about 80%). A molecular weight of Intermediate 1C, as measured by FAB-MS, was about 404.

### Synthesis of Intermediate 1F

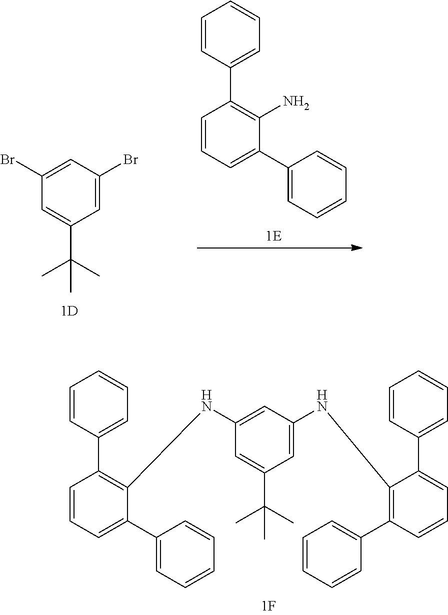 [SMILES: CC(C)(C)c1cc(Br)cc(Br)c1 ; Nc1c(-c2ccccc2)cccc1-c1ccccc1 ; CC(C)(C)c1cc(Nc2c(-c3ccccc3)cccc2-c2ccccc2)cc(Nc2c(-c3ccccc3)cccc2-c2ccccc2)c1]

Under Ar atmosphere, Intermediate 1D (1,3-dibromo-5-tert-butylbenzene, 30 g), Intermediate 1E (51 g), bis(dibenzylideneacetone)palladium(0) (Pd(dba)₂, 0.6 g), tri-tert-butylphosphine tetrafluoroborate (0.6 g), sodium tert-butoxide (NaOtBu, 25 g), and toluene (800 ml) were added to a 2000 ml three-necked flask, and the resultant mixture was heated and stirred for about 24 hours at about 80° C. After returning to a room temperature, water was added, the mixture was subjected to extraction with toluene, combined organic layers were dried over MgSO₄, and then a solvent was removed by distillation under reduced pressure. The obtained product was purified through silica gel column chromatography to obtain 58 g of Intermediate 1F (yield of about 91%). A molecular weight of Intermediate 1F, as measured by FAB-MS, was about 621.

### Synthesis of Intermediate 1G

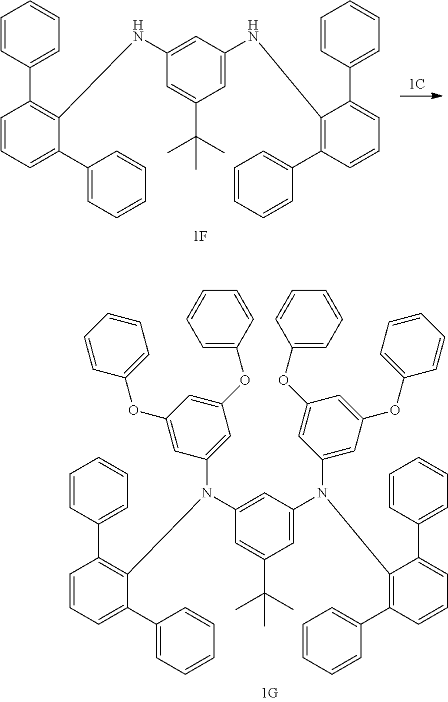 [SMILES: CC(C)(C)c1cc(Nc2c(-c3ccccc3)cccc2-c2ccccc2)cc(Nc2c(-c3ccccc3)cccc2-c2ccccc2)c1 ; CC(C)(C)c1cc(N(c2cc(Oc3ccccc3)cc(Oc3ccccc3)c2)c2c(-c3ccccc3)cccc2-c2ccccc2)cc(N(c2cc(Oc3ccccc3)cc(Oc3ccccc3)c2)c2c(-c3ccccc3)cccc2-c2ccccc2)c1]

Under Ar atmosphere, Intermediate 1F (12 g), Intermediate 1C (31 g), CuI (7.5 g), and K₂CO₃ (20 g) were added to a 200 ml three-necked flask, and the resultant mixture was heated and stirred for about 48 hours at about 230° C. After cooling to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 7.1 g of Intermediate 1G (yield of about 32%). A molecular weight of Intermediate 1G, as measured by FAB-MS, was about 1141.

### Synthesis of Compound 1

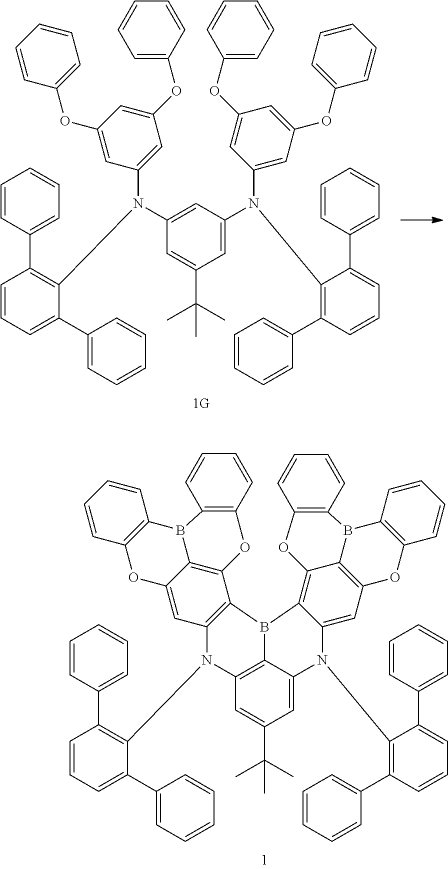 [SMILES: CC(C)(C)c1cc(N(c2cc(Oc3ccccc3)cc(Oc3ccccc3)c2)c2c(-c3ccccc3)cccc2-c2ccccc2)cc(N(c2cc(Oc3ccccc3)cc(Oc3ccccc3)c2)c2c(-c3ccccc3)cccc2-c2ccccc2)c1 ; CC(C)(C)c1cc2c3c(c1)N(c1c(-c4ccccc4)cccc1-c1ccccc1)c1cc4c5c(c1B3c1c(cc3c6c1Oc1ccccc1B6c1ccccc1O3)N2c1c(-c2ccccc2)cccc1-c1ccccc1)Oc1ccccc1B5c1ccccc1O4]

Under Ar atmosphere, Intermediate 1G (7.1 g) was added to a 500 ml three-necked flask and was dissolved in o-dichlorobenzene (ODCB, 150 mL), the flask was cooled to about 0° C. in an ice bath, boron triiodide (BI₃, 14.7 g) was added, then the resultant mixture was heated and stirred at about 140° C. for about 6 hours, the flask was cooled to about 0° C. in an ice bath, and N,N-diisopropylethylamine (DIPEA, 30 mL) was added. After returning to a room temperature, the reaction solution was filtered through silica gel, and a filtrate solvent was removed by distillation under reduced pressure. The obtained crude product was purified through silica gel column chromatography to obtain 3 g of Compound 1 (yield of about 42%). A molecular weight of Compound 1, as measured by FAB-MS, was about 1165.

### (2) Synthesis of Compound 2

### Synthesis of Intermediate 2B

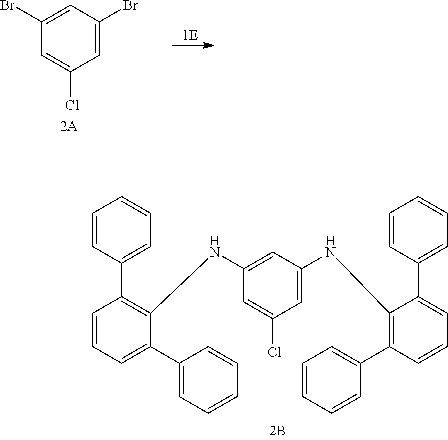 [SMILES: Clc1cc(Br)cc(Br)c1 ; Clc1cc(Nc2c(-c3ccccc3)cccc2-c2ccccc2)cc(Nc2c(-c3ccccc3)cccc2-c2ccccc2)c1]

Under Ar atmosphere, Intermediate 2A (1,3-dibromo-5-chlorobenzene, 20 g), Intermediate 1E (37 g), bis(dibenzylideneacetone)palladium(0) (Pd(dba)₂, 0.4 g), tri-tert-butylphosphine tetrafluoroborate (0.4 g), sodium tert-butoxide (NaOtBu, 18 g), and toluene (500 ml) were added to a 1000 ml three-necked flask, and the resultant mixture was heated and stirred for about 24 hours at about 60° C. After returning to a room temperature, water was added, the mixture was subjected to extraction with toluene, combined organic layers were dried over MgSO₄, and then a solvent was removed by distillation under reduced pressure. The obtained product was purified through silica gel column chromatography to obtain 35.3 g of Intermediate 2B (yield of about 80%). A molecular weight of Intermediate 2B, as measured by FAB-MS, was about 599.

### Synthesis of Intermediate 2C

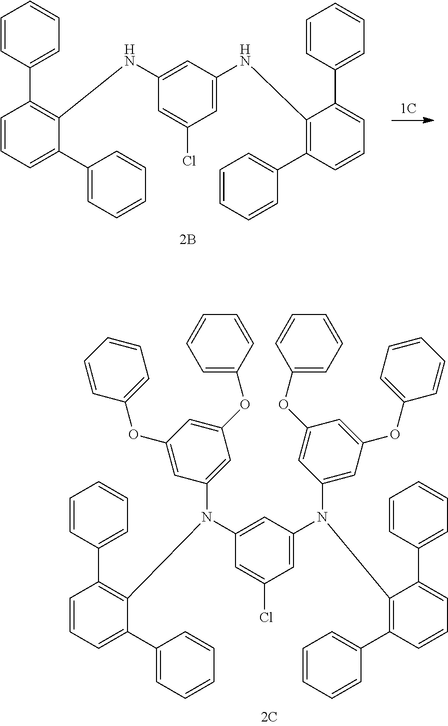 [SMILES: Clc1cc(Nc2c(-c3ccccc3)cccc2-c2ccccc2)cc(Nc2c(-c3ccccc3)cccc2-c2ccccc2)c1 ; Clc1cc(N(c2cc(Oc3ccccc3)cc(Oc3ccccc3)c2)c2c(-c3ccccc3)cccc2-c2ccccc2)cc(N(c2cc(Oc3ccccc3)cc(Oc3ccccc3)c2)c2c(-c3ccccc3)cccc2-c2ccccc2)c1]

Under Ar atmosphere, Intermediate 2B (12 g), Intermediate 1C (32 g), CuI (7.6 g), and K₂CO₃ (20 g) were added to a 200 ml three-necked flask, and the resultant mixture was heated and stirred for about 48 hours at about 230° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 7.6 g of Intermediate 2C (yield of about 34%). A molecular weight of Intermediate 2C, as measured by FAB-MS, was about 1120.

### Synthesis of Intermediate 2D

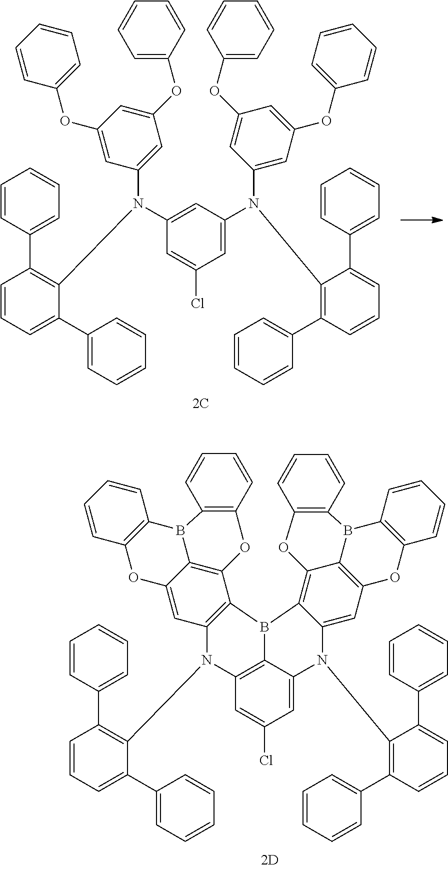 [SMILES: Clc1cc(N(c2cc(Oc3ccccc3)cc(Oc3ccccc3)c2)c2c(-c3ccccc3)cccc2-c2ccccc2)cc(N(c2cc(Oc3ccccc3)cc(Oc3ccccc3)c2)c2c(-c3ccccc3)cccc2-c2ccccc2)c1 ; Clc1cc2c3c(c1)N(c1c(-c4ccccc4)cccc1-c1ccccc1)c1cc4c5c(c1B3c1c(cc3c6c1Oc1ccccc1B6c1ccccc1O3)N2c1c(-c2ccccc2)cccc1-c1ccccc1)Oc1ccccc1B5c1ccccc1O4]

Under Ar atmosphere, Intermediate 2C (7.6 g) was added to a 500 ml three-necked flask and was dissolved in o-dichlorobenzene (ODCB, 150 ml), the flask was cooled to about 0° C. in an ice bath, boron triiodide (BI₃, 16 g) was added, then the resultant mixture was heated and stirred at about 140° C. for about 6 hours, the flask was cooled to about 0° C. in an ice bath, and N,N-diisopropylethylamine (DIPEA, 30 ml) was added. After returning to a room temperature, the reaction solution was filtered through silica gel, and a filtrate solvent was removed by distillation under reduced pressure. The obtained crude product was purified through silica gel column chromatography to obtain 1.1 g of Intermediate 2D (yield of about 14%). A molecular weight of Intermediate 2D, as measured by FAB-MS, was about 1143.

### Synthesis of Compound 2

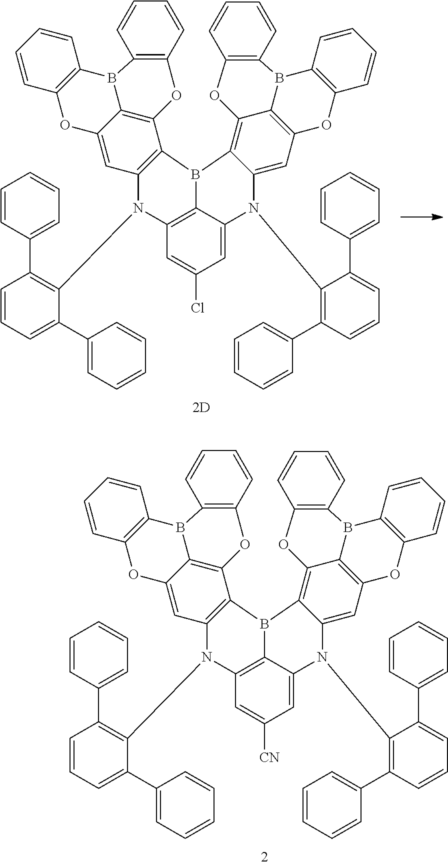 [SMILES: Clc1cc2c3c(c1)N(c1c(-c4ccccc4)cccc1-c1ccccc1)c1cc4c5c(c1B3c1c(cc3c6c1Oc1ccccc1B6c1ccccc1O3)N2c1c(-c2ccccc2)cccc1-c1ccccc1)Oc1ccccc1B5c1ccccc1O4 ; N#Cc1cc2c3c(c1)N(c1c(-c4ccccc4)cccc1-c1ccccc1)c1cc4c5c(c1B3c1c(cc3c6c1Oc1ccccc1B6c1ccccc1O3)N2c1c(-c2ccccc2)cccc1-c1ccccc1)Oc1ccccc1B5c1ccccc1O4]

Under Ar atmosphere, Intermediate 2D (1.1 g), bis[di-tert-butyl(4-dimethylaminophenyl)phosphine]dichloropalladium(II) (PdCl₂(Amphos)2, 0.07 g), potassium hexacyanoferrate (K₄Fe(CN)₆, 0.6 g), Na₂CO₃ (0.4 g), and N,N-dimethylacetamide (DMA, 10 ml) were added to a 200 ml three-necked flask, and the resultant mixture was heated and stirred for about 24 hours at about 140° C. After returning to a room temperature, water was added, the mixture was subjected to extraction with toluene, combined organic layers were dried over MgSO₄, and then a solvent was removed by distillation under reduced pressure. The obtained product was purified through silica gel column chromatography to obtain 0.93 g of Compound 2 (yield of about 85%). A molecular weight of Compound 2, as measured by FAB-MS, was about 1137.

### (3) Synthesis of Compound 3

### Synthesis of Intermediate 3B3

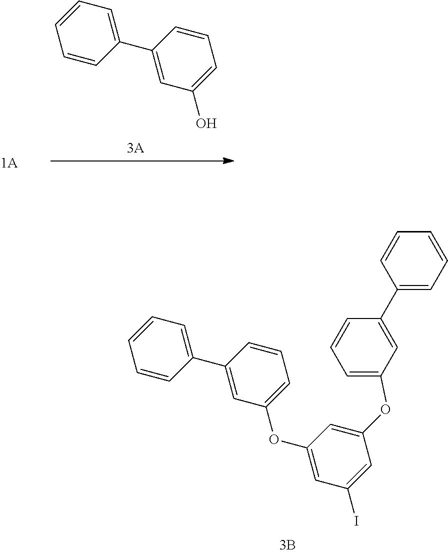 [SMILES: Oc1cccc(-c2ccccc2)c1 ; Ic1cc(Oc2cccc(-c3ccccc3)c2)cc(Oc2cccc(-c3ccccc3)c2)c1]

Under Ar atmosphere, Intermediate 1A (50 g), Intermediate 3A (90 g), K₂CO₃ (87 g), and 1-methyl-2-pyrrolidone (400 ml) were added to a 1000 ml three-necked flask, and the resultant mixture was heated and stirred for about 16 hours at about 160° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 79 g of Intermediate 3B (yield of about 70%). A molecular weight of Intermediate 3B, as measured by FAB-MS, was about 540.

### Synthesis of Intermediate 3C

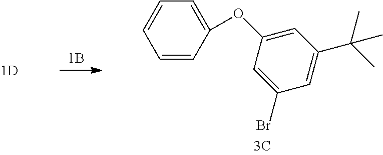 [SMILES: CC(C)(C)c1cc(Br)cc(Oc2ccccc2)c1]

Under Ar atmosphere, Intermediate 1D (25 g), Intermediate 1B (8 g), CuI (3.2 g), dipivaloylmethene (6.3 g), Cs₂CO₃ (42 g), and 1-methyl-2-pyrrolidone (200 ml) were added to a 500 ml three-necked flask, and the resultant mixture was heated and stirred for about 16 hours at about 80° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 10 g of Intermediate 3C (yield of about 39%). A molecular weight of Intermediate 3C, as measured by FAB-MS, was about 309.

### Synthesis of Intermediate 3E

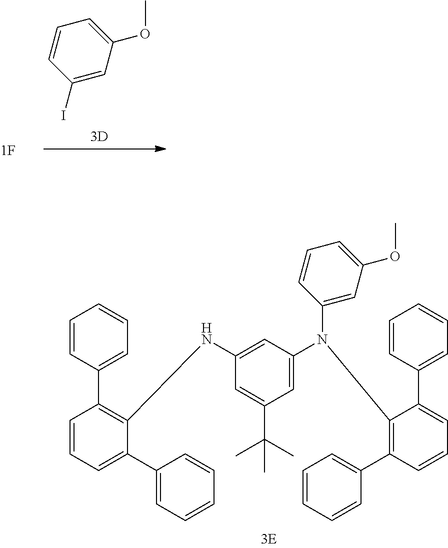

Under Ar atmosphere, Intermediate 1F (24 g), Intermediate 3D (36 g), CuI (7.3 g), and K₂CO₃ (32 g) were added to a 300 ml three-necked flask, and the resultant mixture was heated and stirred for about 48 hours at about 210° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 7 g of Intermediate 3E (yield of about 25%). A molecular weight of Intermediate 3E, as measured by FAB-MS, was about 727.

### Synthesis of Intermediate 3F

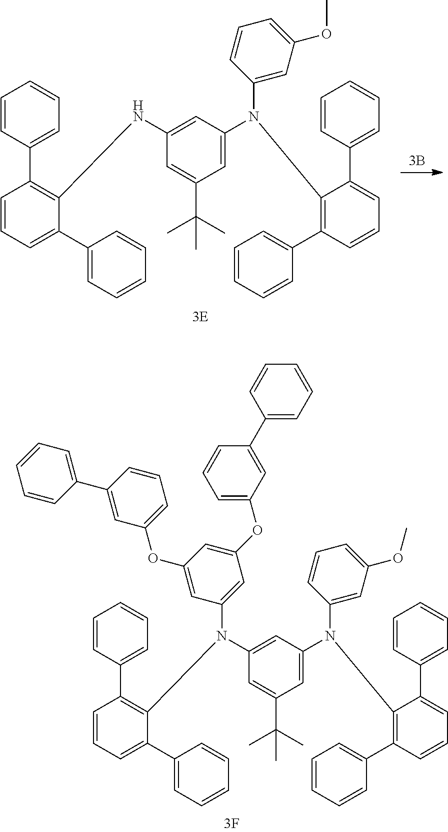 [SMILES: COc1cccc(N(c2cc(Nc3c(-c4ccccc4)cccc3-c3ccccc3)cc(C(C)(C)C)c2)c2c(-c3ccccc3)cccc2-c2ccccc2)c1 ; COc1cccc(N(c2cc(N(c3cc(Oc4cccc(-c5ccccc5)c4)cc(Oc4cccc(-c5ccccc5)c4)c3)c3c(-c4ccccc4)cccc3-c3ccccc3)cc(C(C)(C)C)c2)c2c(-c3ccccc3)cccc2-c2ccccc2)c1]

Under Ar atmosphere, Intermediate 3E (7 g), Intermediate 3B (21 g), CuI (1.8 g), and K₂CO₃ (6 g) were added to a 200 ml three-necked flask, and the resultant mixture was heated and stirred for about 48 hours at about 230° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 4.6 g of Intermediate 3F (yield of about 42%). A molecular weight of Intermediate 3F, as measured by FAB-MS, was about 1139.

### Synthesis of Intermediate 3G

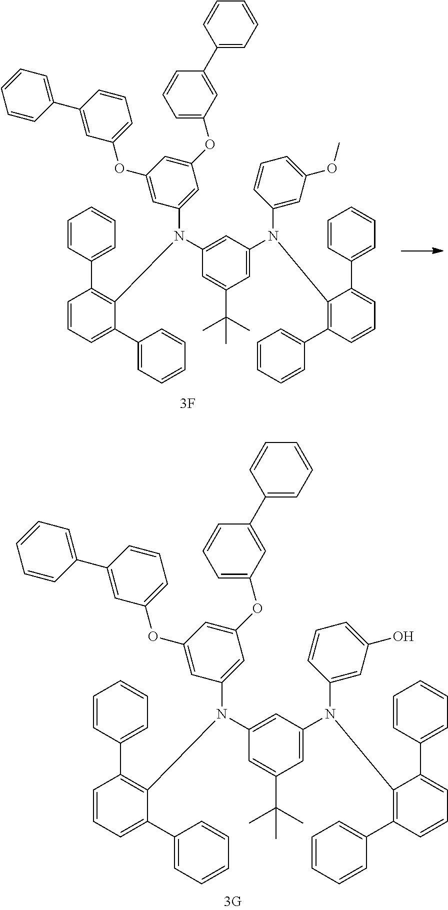 [SMILES: COc1cccc(N(c2cc(N(c3cc(Oc4cccc(-c5ccccc5)c4)cc(Oc4cccc(-c5ccccc5)c4)c3)c3c(-c4ccccc4)cccc3-c3ccccc3)cc(C(C)(C)C)c2)c2c(-c3ccccc3)cccc2-c2ccccc2)c1 ; CC(C)(C)c1cc(N(c2cccc(O)c2)c2c(-c3ccccc3)cccc2-c2ccccc2)cc(N(c2cc(Oc3cccc(-c4ccccc4)c3)cc(Oc3cccc(-c4ccccc4)c3)c2)c2c(-c3ccccc3)cccc2-c2ccccc2)c1]

Under Ar atmosphere, Intermediate 3F (4.6 g) was added to a 200 ml three-necked flask and was dissolved in dichloromethane (100 ml), the flask was cooled to about 0° C. in an ice bath, boron tribromide (BBr₃, 2.9 g) was added, then the resultant mixture was heated and stirred at a room temperature for about 24 hours. Ice water was added to a reaction solution, and the resultant was extracted with CH₂Cl₂, and a solvent was removed by distillation under reduced pressure. The obtained crude product was purified through silica gel column chromatography to obtain 3.8 g of Intermediate 3G (yield of about 84%). A molecular weight of Intermediate 3G, as measured by FAB-MS, was about 1125.

### Synthesis of Intermediate 3H

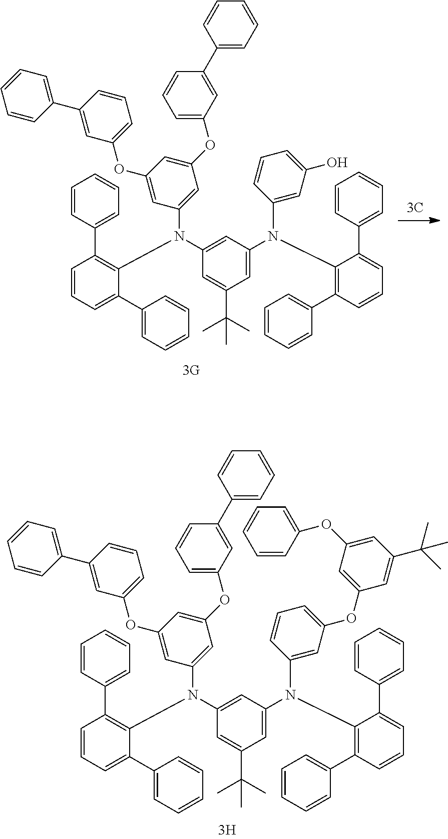 [SMILES: CC(C)(C)c1cc(N(c2cccc(O)c2)c2c(-c3ccccc3)cccc2-c2ccccc2)cc(N(c2cc(Oc3cccc(-c4ccccc4)c3)cc(Oc3cccc(-c4ccccc4)c3)c2)c2c(-c3ccccc3)cccc2-c2ccccc2)c1 ; CC(C)(C)c1cc(Oc2ccccc2)cc(Oc2cccc(N(c3cc(N(c4cc(Oc5cccc(-c6ccccc6)c5)cc(Oc5cccc(-c6ccccc6)c5)c4)c4c(-c5ccccc5)cccc4-c4ccccc4)cc(C(C)(C)C)c3)c3c(-c4ccccc4)cccc3-c3ccccc3)c2)c1]

Under Ar atmosphere, Intermediate 3G (3.8 g), Intermediate 3C (2 g), CuI (0.6 g), K₂CO₃ (1.2 g), and o-dichlorobenzene (ODCB, 30 ml) were added to a 200 ml three-necked flask, and the resultant mixture was heated and stirred for about 16 hours at about 180° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 4 g of Intermediate 3H (yield of about 88%). A molecular weight of Intermediate 3H, as measured by FAB-MS, was about 1350.

### Synthesis of Compound 3

Under Ar atmosphere, Intermediate 3H (4 g) was added to a 300 ml three-necked flask and was dissolved in o-dichlorobenzene (ODCB, 100 ml), the flask was cooled to about 0° C. in an ice bath, boron triiodide (BI₃, 7 g) was added, then the resultant mixture was heated and stirred at about 140° C. for about 6 hours, the flask was cooled to about 0° C. in an ice bath, and N,N-diisopropylethylamine (DIPEA, 15 ml) was added. After returning to a room temperature, the reaction solution was filtered through silica gel, and a filtrate solvent was removed by distillation under reduced pressure. The obtained crude product was purified through silica gel column chromatography to obtain 1.5 g of Compound 3 (yield of about 37%). A molecular weight of Compound 3, as measured by FAB-MS, was about 1373.

### (4) Synthesis of Compound 4

### Synthesis of Intermediate 4A

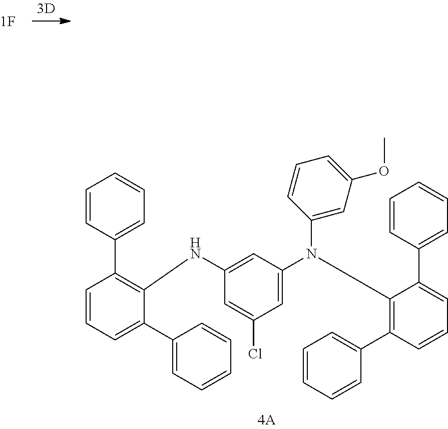 [SMILES: COc1cccc(N(c2cc(Cl)cc(Nc3c(-c4ccccc4)cccc3-c3ccccc3)c2)c2c(-c3ccccc3)cccc2-c2ccccc2)c1]

Under Ar atmosphere, Intermediate 1F (40 g), Intermediate 3D (62 g), CuI (13 g), and K₂CO₃ (56 g) were added to a 300 ml three-necked flask, and the resultant mixture was heated and stirred for about 48 hours at about 210° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 19.8 g of Intermediate 4A (yield of about 38%). A molecular weight of Intermediate 4A, as measured by FAB-MS, was about 705.

### Synthesis of Intermediate 4B

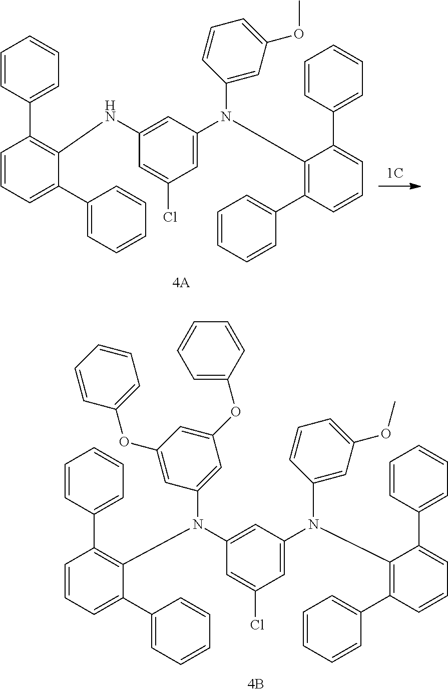 [SMILES: COc1cccc(N(c2cc(Cl)cc(Nc3c(-c4ccccc4)cccc3-c3ccccc3)c2)c2c(-c3ccccc3)cccc2-c2ccccc2)c1 ; COc1cccc(N(c2cc(Cl)cc(N(c3cc(Oc4ccccc4)cc(Oc4ccccc4)c3)c3c(-c4ccccc4)cccc3-c3ccccc3)c2)c2c(-c3ccccc3)cccc2-c2ccccc2)c1]

Under Ar atmosphere, Intermediate 4A (19.8 g), Intermediate 1C (40 g), CuI (4.8 g), and K₂CO₃ (14 g) were added to a 200 ml three-necked flask, and the resultant mixture was heated and stirred for about 48 hours at about 230° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 12.6 g of Intermediate 4B (yield of about 52%). A molecular weight of Intermediate 4B, as measured by FAB-MS, was about 966.

### Synthesis of Intermediate 4C

Under Ar atmosphere, Intermediate 4B (12.6 g) was added to a 300 ml three-necked flask and was dissolved in dichloromethane (150 ml), the flask was cooled to about 0° C. in an ice bath, boron tribromide (BBr₃, 6.4 g) was added, then the resultant mixture was heated and stirred at a room temperature for about 24 hours. Ice water was added to a reaction solution, the mixture was subjected to extraction with CH₂Cl₂, and a solvent was removed by distillation under reduced pressure. The obtained crude product was purified through silica gel column chromatography to obtain 10.8 g of Intermediate 4C (yield of about 87%). A molecular weight of Intermediate 4C, as measured by FAB-MS, was about 952.

### Synthesis of Intermediate 4D

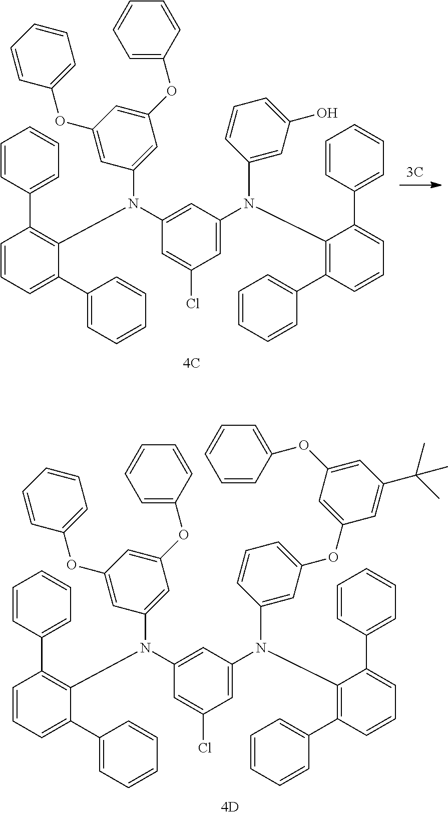 [SMILES: Oc1cccc(N(c2cc(Cl)cc(N(c3cc(Oc4ccccc4)cc(Oc4ccccc4)c3)c3c(-c4ccccc4)cccc3-c3ccccc3)c2)c2c(-c3ccccc3)cccc2-c2ccccc2)c1 ; CC(C)(C)c1cc(Oc2ccccc2)cc(Oc2cccc(N(c3cc(Cl)cc(N(c4cc(Oc5ccccc5)cc(Oc5ccccc5)c4)c4c(-c5ccccc5)cccc4-c4ccccc4)c3)c3c(-c4ccccc4)cccc3-c3ccccc3)c2)c1]

Under Ar atmosphere, Intermediate 4C (10.8 g), Intermediate 3C (6.4 g), CuI (2 g), K₂CO₃ (3 g), and o-dichlorobenzene (ODCB, 60 ml) were added to a 200 ml three-necked flask, and the resultant mixture was heated and stirred for about 16 hours at about 180° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 12.4 g of Intermediate 4D (yield of about 93%). A molecular weight of Intermediate 4D, as measured by FAB-MS, was about 1179.

### Synthesis of Intermediate 4E

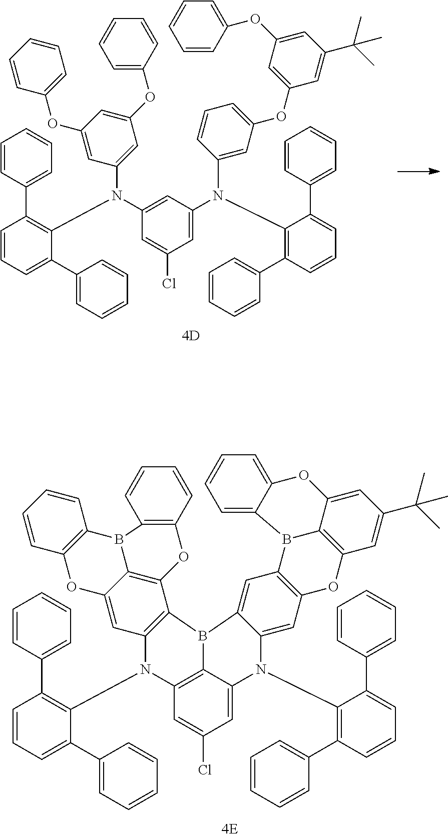 [SMILES: CC(C)(C)c1cc(Oc2ccccc2)cc(Oc2cccc(N(c3cc(Cl)cc(N(c4cc(Oc5ccccc5)cc(Oc5ccccc5)c4)c4c(-c5ccccc5)cccc4-c4ccccc4)c3)c3c(-c4ccccc4)cccc3-c3ccccc3)c2)c1 ; CC(C)(C)c1cc2c3c(c1)Oc1cc4c(cc1B3c1ccccc1O2)B1c2c(cc(Cl)cc2N(c2c(-c3ccccc3)cccc2-c2ccccc2)c2cc3c5c(c21)Oc1ccccc1B5c1ccccc1O3)N4c1c(-c2ccccc2)cccc1-c1ccccc1]

Under Ar atmosphere, Intermediate 4D (12.4 g) was added to a 500 ml three-necked flask and was dissolved in o-Dichlorobenzene (ODCB, 200 ml), the flask was cooled to about 0° C. in an ice bath, boron triiodide (BI₃, 25 g) was added, then the resultant mixture was heated and stirred at about 140° C. for about 6 hours, the flask was cooled to about 0° C. in an ice bath, and N,N-diisopropylethylamine (DIPEA, 50 ml) was added. After returning to a room temperature, the reaction solution was filtered through silica gel, and a filtrate solvent was removed by distillation under reduced pressure. The obtained crude product was purified through silica gel column chromatography to obtain 2 g of Intermediate 4E (yield of about 16%). A molecular weight of Intermediate 4E, as measured by FAB-MS, was about 1199.

### Synthesis of Compound 4

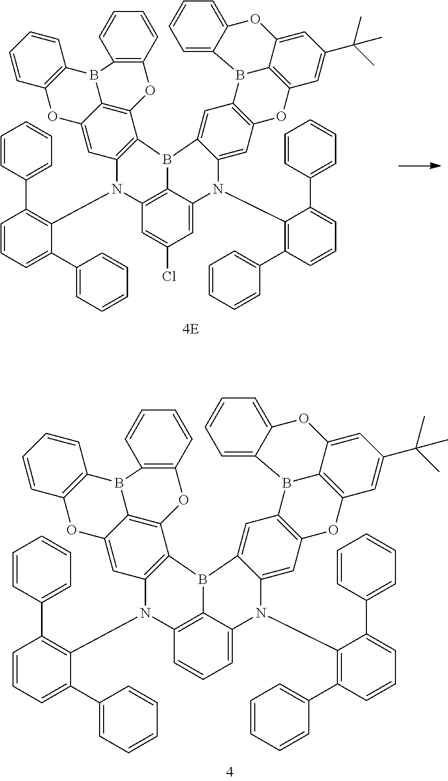 [SMILES: CC(C)(C)c1cc2c3c(c1)Oc1cc4c(cc1B3c1ccccc1O2)B1c2c(cc(Cl)cc2N(c2c(-c3ccccc3)cccc2-c2ccccc2)c2cc3c5c(c21)Oc1ccccc1B5c1ccccc1O3)N4c1c(-c2ccccc2)cccc1-c1ccccc1 ; CC(C)(C)c1cc2c3c(c1)Oc1cc4c(cc1B3c1ccccc1O2)B1c2c(cccc2N(c2c(-c3ccccc3)cccc2-c2ccccc2)c2cc3c5c(c21)Oc1ccccc1B5c1ccccc1O3)N4c1c(-c2ccccc2)cccc1-c1ccccc1]

Under Ar atmosphere, Intermediate 4E (2 g), 2-biphenylboronic acid (1 g), palladium(II) acetate (Pd(OAc)₂, 75 mg), 2-dicyclohexylphosphino-2′,6′-dimethoxybiphenyl (SPhos, 0.27 g), K₃PO₄ (1 g), and toluene (30 ml) were added to a 100 ml three-necked flask, and the resultant mixture was heated and stirred for about 24 hours at about 110° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 0.83 g of Compound 4 (yield of about 43%). A molecular weight of Compound 4, as measured by FAB-MS, was about 1165.

### (5) Synthesis of Compound 5

### Synthesis of Intermediate 5A

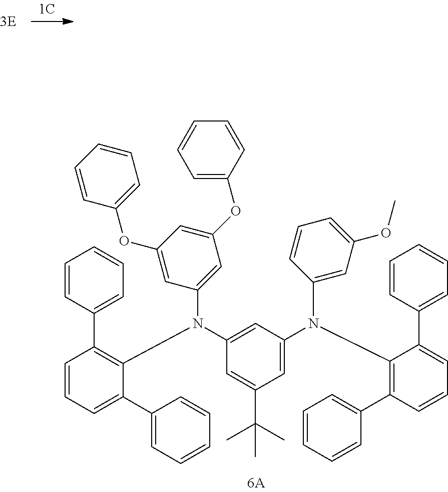 [SMILES: COc1cccc(N(c2cc(N(c3cc(Oc4ccccc4)cc(Oc4ccccc4)c3)c3c(-c4ccccc4)cccc3-c3ccccc3)cc(C(C)(C)C)c2)c2c(-c3ccccc3)cccc2-c2ccccc2)c1]

Under Ar atmosphere, Intermediate 3E (12 g), Intermediate 1C (26 g), CuI (3.1 g), and K₂CO₃ (14 g) were added to a 200 ml three-necked flask, and the resultant mixture was heated and stirred for about 48 hours at about 230° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 8.6 g of Intermediate 5A (yield of about 53%). A molecular weight of Intermediate 5A, as measured by FAB-MS, was about 987.

### Synthesis of Intermediate 5B

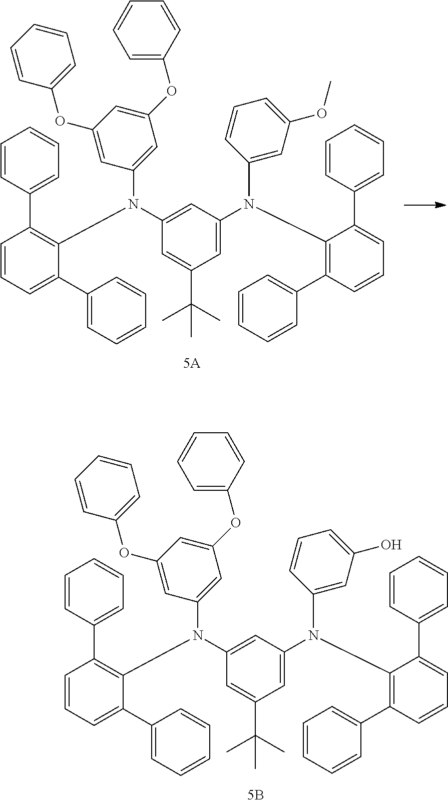 [SMILES: COc1cccc(N(c2cc(N(c3cc(Oc4ccccc4)cc(Oc4ccccc4)c3)c3c(-c4ccccc4)cccc3-c3ccccc3)cc(C(C)(C)C)c2)c2c(-c3ccccc3)cccc2-c2ccccc2)c1 ; CC(C)(C)c1cc(N(c2cccc(O)c2)c2c(-c3ccccc3)cccc2-c2ccccc2)cc(N(c2cc(Oc3ccccc3)cc(Oc3ccccc3)c2)c2c(-c3ccccc3)cccc2-c2ccccc2)c1]

Under Ar atmosphere, Intermediate 5A (8.6 g) was added to a 300 ml three-necked flask and was dissolved in dichloromethane (100 ml), the flask was cooled to about 0° C. in an ice bath, boron tribromide (BBr₃, 4.3 g) was added, then the resultant mixture was heated and stirred at a room temperature for about 24 hours. Ice water was added to a reaction solution, the mixture was subjected to extraction with CH₂Cl₂, and a solvent was removed by distillation under reduced pressure. The obtained crude product was purified through silica gel column chromatography to obtain 7.8 g of Intermediate 5B (yield of about 92%). A molecular weight of Intermediate 5B, as measured by FAB-MS, was about 973.

### Synthesis of Intermediate 5C

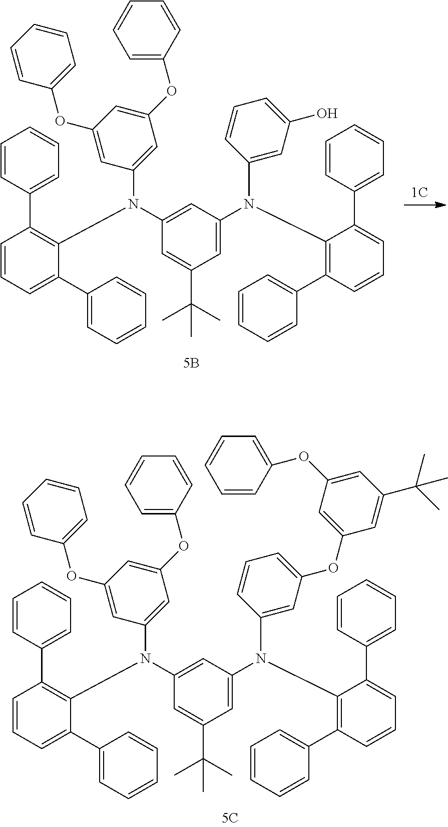 [SMILES: CC(C)(C)c1cc(N(c2cccc(O)c2)c2c(-c3ccccc3)cccc2-c2ccccc2)cc(N(c2cc(Oc3ccccc3)cc(Oc3ccccc3)c2)c2c(-c3ccccc3)cccc2-c2ccccc2)c1 ; CC(C)(C)c1cc(Oc2ccccc2)cc(Oc2cccc(N(c3cc(N(c4cc(Oc5ccccc5)cc(Oc5ccccc5)c4)c4c(-c5ccccc5)cccc4-c4ccccc4)cc(C(C)(C)C)c3)c3c(-c4ccccc4)cccc3-c3ccccc3)c2)c1]

Under Ar atmosphere, Intermediate 5B (7.8 g), Intermediate 1C (4.9 g), CuI (1.5 g), K₂CO₃ (3 g), and o-dichlorobenzene (ODCB, 50 ml) were added to a 200 ml three-necked flask, and the resultant mixture was heated and stirred for about 16 hours at about 180° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 8.6 g of Intermediate 5C (yield of about 90%). A molecular weight of Intermediate 5C, as measured by FAB-MS, was about 1198.

### Synthesis of Compound 5

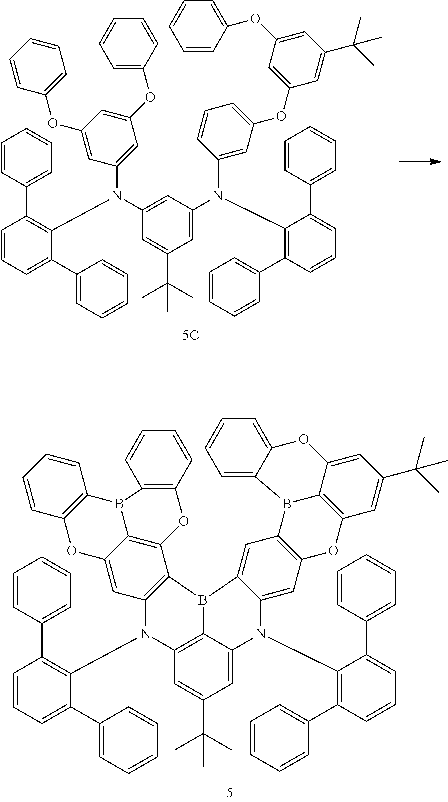 [SMILES: CC(C)(C)c1cc(Oc2ccccc2)cc(Oc2cccc(N(c3cc(N(c4cc(Oc5ccccc5)cc(Oc5ccccc5)c4)c4c(-c5ccccc5)cccc4-c4ccccc4)cc(C(C)(C)C)c3)c3c(-c4ccccc4)cccc3-c3ccccc3)c2)c1 ; CC(C)(C)c1cc2c3c(c1)Oc1cc4c(cc1B3c1ccccc1O2)B1c2c(cc(C(C)(C)C)cc2N(c2c(-c3ccccc3)cccc2-c2ccccc2)c2cc3c5c(c21)Oc1ccccc1B5c1ccccc1O3)N4c1c(-c2ccccc2)cccc1-c1ccccc1]

Under Ar atmosphere, Intermediate 5C (8.6 g) was added to a 500 ml three-necked flask and was dissolved in o-dichlorobenzene (ODCB, 200 ml), the flask was cooled to about 0° C. in an ice bath, boron triiodide (BI₃, 17 g) was added, then the resultant mixture was heated and stirred at about 140° C. for about 6 hours, the flask was cooled to about 0° C. in an ice bath, and N,N-diisopropylethylamine (DIPEA, 30 ml) was added. After returning to a room temperature, a reaction solution was filtered through silica gel, and a filtrate solvent was removed by distillation under reduced pressure. The obtained crude product was purified through silica gel column chromatography to obtain 2.2 g of Compound 5 (yield of about 22%). A molecular weight of Compound 5, as measured by FAB-MS, was about 1220.

### (6) Synthesis of Compound 6

### Synthesis of Intermediate 6B

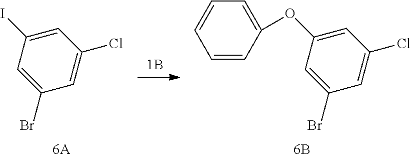 [SMILES: Clc1cc(Br)cc(I)c1 ; Clc1cc(Br)cc(Oc2ccccc2)c1]

Under Ar atmosphere, Intermediate 6A (50 g), Intermediate 1B (15 g), CuI (6 g), dipivaloylmethene (11.6 g), Cs₂CO₃ (77 g), and 1-methyl-2-pyrrolidone (400 ml) were added to a 1000 ml three-necked flask, and the resultant mixture was heated and stirred for about 16 hours at about 50° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 22 g of Intermediate 6B (yield of about 49%). A molecular weight of Intermediate 6B, as measured by FAB-MS, was about 284.

### Synthesis of Intermediate 6C

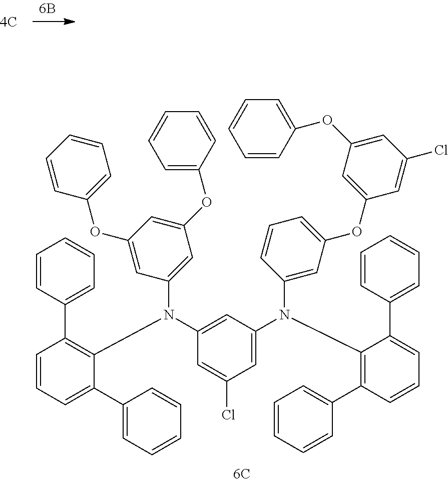 [SMILES: Clc1cc(Oc2ccccc2)cc(Oc2cccc(N(c3cc(Cl)cc(N(c4cc(Oc5ccccc5)cc(Oc5ccccc5)c4)c4c(-c5ccccc5)cccc4-c4ccccc4)c3)c3c(-c4ccccc4)cccc3-c3ccccc3)c2)c1]

Under Ar atmosphere, Intermediate 4C (30 g), Intermediate 6B (18 g), CuI (6 g), K₂CO₃ (16 g), and o-dichlorobenzene (ODCB, 200 ml) were added to a 500 ml three-necked flask, and the resultant mixture was heated and stirred for about 16 hours at about 180° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 33 g of Intermediate 6C (yield of about 92%). A molecular weight of Intermediate 6C, as measured by FAB-MS, was about 1154.

### Synthesis of Intermediate 6D

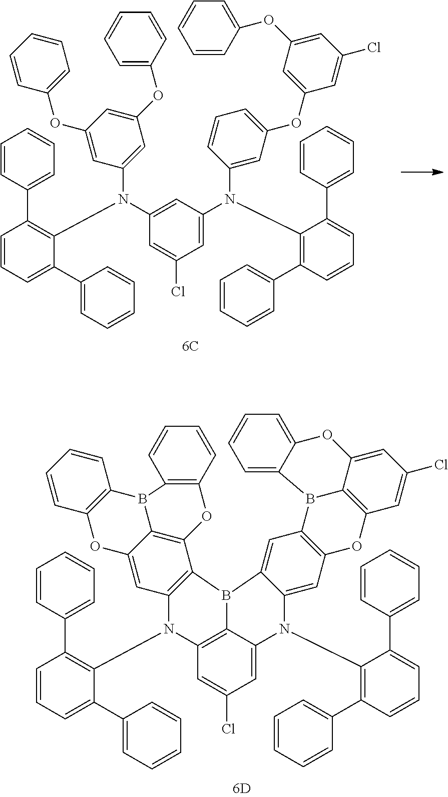 [SMILES: Clc1cc(Oc2ccccc2)cc(Oc2cccc(N(c3cc(Cl)cc(N(c4cc(Oc5ccccc5)cc(Oc5ccccc5)c4)c4c(-c5ccccc5)cccc4-c4ccccc4)c3)c3c(-c4ccccc4)cccc3-c3ccccc3)c2)c1 ; Clc1cc2c3c(c1)Oc1cc4c(cc1B3c1ccccc1O2)B1c2c(cc(Cl)cc2N(c2c(-c3ccccc3)cccc2-c2ccccc2)c2cc3c5c(c21)Oc1ccccc1B5c1ccccc1O3)N4c1c(-c2ccccc2)cccc1-c1ccccc1]

Under Ar atmosphere, Intermediate 6C (33 g) was added to a 1000 ml three-necked flask and was dissolved in o-dichlorobenzene (ODCB, 400 ml), the flask was cooled to about 0° C. in an ice bath, boron triiodide (BI₃, 67 g) was added, then the resultant mixture was heated and stirred at about 140° C. for about 6 hours, the flask was cooled to about 0° C. in an ice bath, and N,N-diisopropyl ethyl amine (DIPEA, 100 ml) was added. After returning to a room temperature, a reaction solution was filtered through silica gel, and a filtrate solvent was removed by distillation under reduced pressure. The obtained crude product was purified through silica gel column chromatography to obtain 4 g of Intermediate 6D (yield of about 12%). A molecular weight of Intermediate 6D, as measured by FAB-MS, was about 1178.

### Synthesis of Compound 6

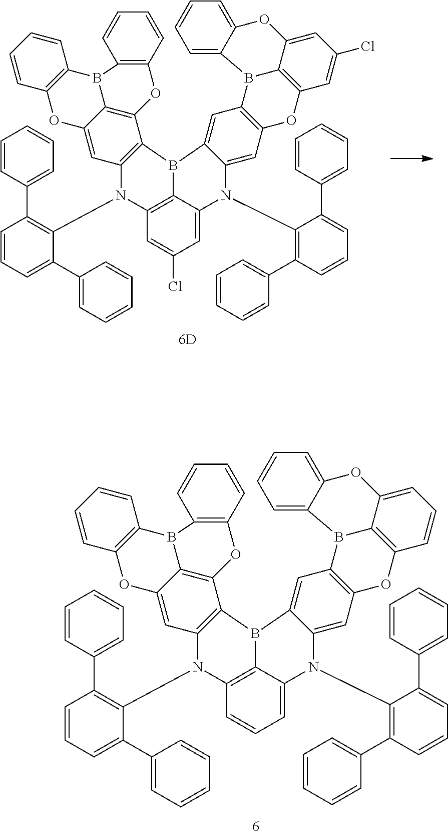 [SMILES: Clc1cc2c3c(c1)Oc1cc4c(cc1B3c1ccccc1O2)B1c2c(cc(Cl)cc2N(c2c(-c3ccccc3)cccc2-c2ccccc2)c2cc3c5c(c21)Oc1ccccc1B5c1ccccc1O3)N4c1c(-c2ccccc2)cccc1-c1ccccc1 ; c1ccc(-c2cccc(-c3ccccc3)c2N2c3cc4c(cc3B3c5c2cccc5N(c2c(-c5ccccc5)cccc2-c2ccccc2)c2cc5c6c(c23)Oc2ccccc2B6c2ccccc2O5)B2c3ccccc3Oc3cccc(c32)O4)cc1]

Under Ar atmosphere, Intermediate 6D (4 g), 2-biphenylboronic acid (4 g), palladium(II) acetate (Pd(OAc)₂, 0.15 g), 2-dicyclohexylphosphino-2′,6′-dimethoxybiphenyl (SPhos, 0.56 g), K₃PO₄ (4.3 g), and toluene (80 ml) were added to a 200 ml three-necked flask, and the resultant mixture was heated and stirred for about 24 hours at about 110° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 0.79 g of Compound 6 (yield of about 21%). A molecular weight of Compound 6, as measured by FAB-MS, was about 1109.

### (7) Synthesis of Compound 7

### Synthesis of Intermediate 7A

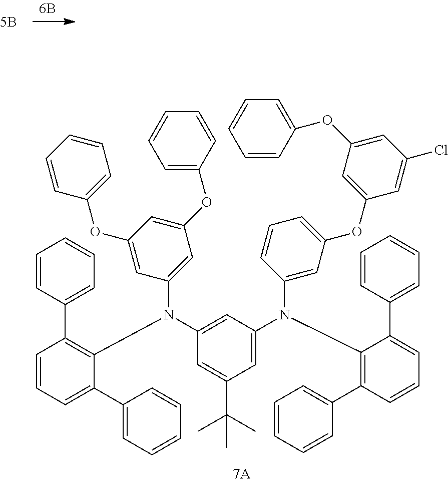 [SMILES: CC(C)(C)c1cc(N(c2cccc(Oc3cc(Cl)cc(Oc4ccccc4)c3)c2)c2c(-c3ccccc3)cccc2-c2ccccc2)cc(N(c2cc(Oc3ccccc3)cc(Oc3ccccc3)c2)c2c(-c3ccccc3)cccc2-c2ccccc2)c1]

Under Ar atmosphere, Intermediate 5B (30 g), Intermediate 6B (18 g), CuI (3 g), K₂CO₃ (6 g), and o-dichlorobenzene (ODCB, 120 ml) were added to a 300 ml three-necked flask, and the resultant mixture was heated and stirred for about 16 hours at about 180° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 16 g of Intermediate 7A (yield of about 88%). A molecular weight of Intermediate 7A, as measured by FAB-MS, was about 1176.

### Synthesis of Intermediate 7B

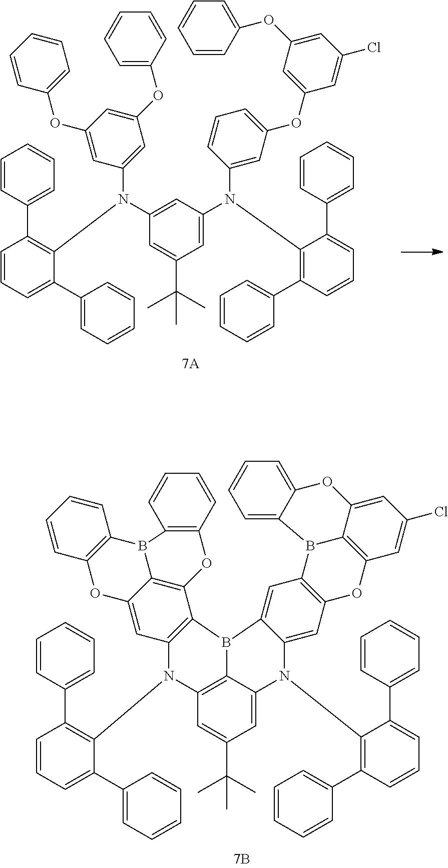 [SMILES: CC(C)(C)c1cc(N(c2cccc(Oc3cc(Cl)cc(Oc4ccccc4)c3)c2)c2c(-c3ccccc3)cccc2-c2ccccc2)cc(N(c2cc(Oc3ccccc3)cc(Oc3ccccc3)c2)c2c(-c3ccccc3)cccc2-c2ccccc2)c1 ; CC(C)(C)c1cc2c3c(c1)N(c1c(-c4ccccc4)cccc1-c1ccccc1)c1cc4c5c(c1B3c1cc3c(cc1N2c1c(-c2ccccc2)cccc1-c1ccccc1)Oc1cc(Cl)cc2c1B3c1ccccc1O2)Oc1ccccc1B5c1ccccc1O4]

Under Ar atmosphere, Intermediate 7A (16 g) was added to a 500 ml three-necked flask and was dissolved in o-dichlorobenzene (ODCB, 200 ml), the flask was cooled to about 0° C. in an ice bath, boron triiodide (BI₃, 32 g) was added, then the resultant mixture was heated and stirred at about 140° C. for about 6 hours, the flask was cooled to about 0° C. in an ice bath, and N,N-diisopropylethylamine (DIPEA, 50 ml) was added. After returning to a room temperature, a reaction solution was filtered through silica gel, and a filtrate solvent was removed by distillation under reduced pressure. The obtained crude product was purified through silica gel column chromatography to obtain 2.9 g of Intermediate 7B (yield of about 19%). A molecular weight of Intermediate 7B, as measured by FAB-MS, was about 1200.

### Synthesis of Compound 7

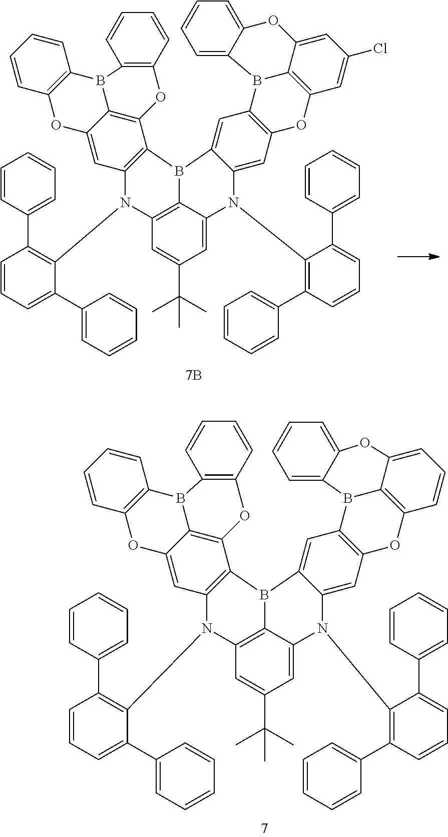 [SMILES: CC(C)(C)c1cc2c3c(c1)N(c1c(-c4ccccc4)cccc1-c1ccccc1)c1cc4c5c(c1B3c1cc3c(cc1N2c1c(-c2ccccc2)cccc1-c1ccccc1)Oc1cc(Cl)cc2c1B3c1ccccc1O2)Oc1ccccc1B5c1ccccc1O4 ; CC(C)(C)c1cc2c3c(c1)N(c1c(-c4ccccc4)cccc1-c1ccccc1)c1cc4c5c(c1B3c1cc3c(cc1N2c1c(-c2ccccc2)cccc1-c1ccccc1)Oc1cccc2c1B3c1ccccc1O2)Oc1ccccc1B5c1ccccc1O4]

Under Ar atmosphere, Intermediate 7B (2.9 g), 2-biphenylboronic acid (1.4 g), palladium(II) acetate (Pd(OAc)₂, 0.11 g), 2-dicyclohexylphosphino-2′,6′-dimethoxybiphenyl (SPhos, 0.39 g), K₃PO₄ (1.5 g), and toluene (40 ml) were added to a 100 ml three-necked flask, and the resultant mixture was heated and stirred for about 24 hours at about 110° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 0.85 g of Compound 7 (yield of about 30%). A molecular weight of Compound 7, as measured by FAB-MS, was about 1165.

### (8) Synthesis of Compound 8

### Synthesis of Intermediate 8B

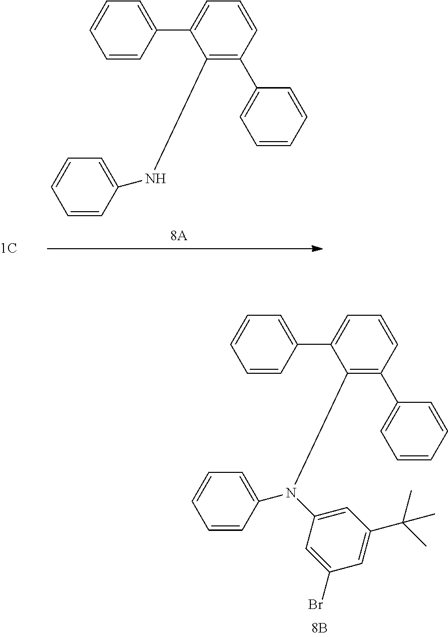 [SMILES: c1ccc(Nc2c(-c3ccccc3)cccc2-c2ccccc2)cc1 ; CC(C)(C)c1cc(Br)cc(N(c2ccccc2)c2c(-c3ccccc3)cccc2-c2ccccc2)c1]

Under Ar atmosphere, Intermediate 1C (33 g), Intermediate 8A (18 g), CuI (11 g), and K₂CO₃ (23 g) were added to a 300 ml three-necked flask, and the resultant mixture was heated and stirred for about 48 hours at about 230° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 9.8 g of Intermediate 8B (yield of about 33%). A molecular weight of Intermediate 8B, as measured by FAB-MS, was about 533.

### Synthesis of Intermediate 8C

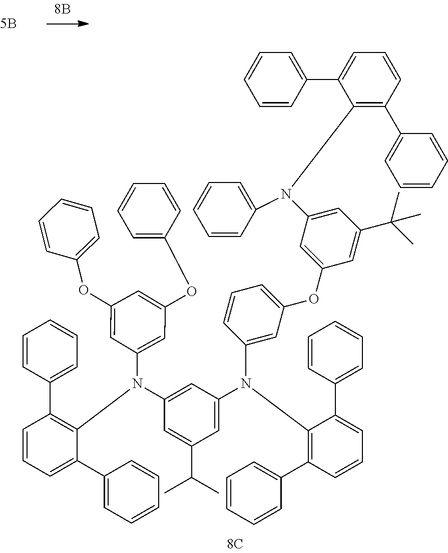 [SMILES: CC(C)c1cc(N(c2cccc(Oc3cc(N(c4ccccc4)c4c(-c5ccccc5)cccc4-c4ccccc4)cc(C(C)(C)C)c3)c2)c2c(-c3ccccc3)cccc2-c2ccccc2)cc(N(c2cc(Oc3ccccc3)cc(Oc3ccccc3)c2)c2c(-c3ccccc3)cccc2-c2ccccc2)c1]

Under Ar atmosphere, Intermediate 5B (10 g), Intermediate 8B (9.8 g), CuI (1.9 g), K₂CO₃ (3.9 g), and o-dichlorobenzene (ODCB, 100 ml) were added to a 300 ml three-necked flask, and the resultant mixture was heated and stirred for about 16 hours at about 180° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 12.4 g of Intermediate 8C (yield of about 88%). A molecular weight of Intermediate 8C, as measured by FAB-MS, was about 1425.

### Synthesis of Compound 8

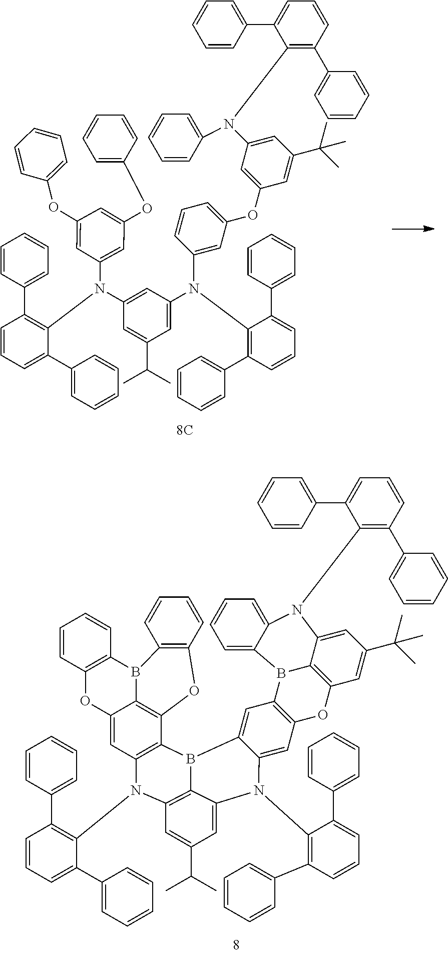 [SMILES: CC(C)c1cc(N(c2cccc(Oc3cc(N(c4ccccc4)c4c(-c5ccccc5)cccc4-c4ccccc4)cc(C(C)(C)C)c3)c2)c2c(-c3ccccc3)cccc2-c2ccccc2)cc(N(c2cc(Oc3ccccc3)cc(Oc3ccccc3)c2)c2c(-c3ccccc3)cccc2-c2ccccc2)c1 ; CC(C)c1cc2c3c(c1)N(c1c(-c4ccccc4)cccc1-c1ccccc1)c1cc4c5c(c1B3c1cc3c(cc1N2c1c(-c2ccccc2)cccc1-c1ccccc1)Oc1cc(C(C)(C)C)cc2c1B3c1ccccc1N2c1c(-c2ccccc2)cccc1-c1ccccc1)Oc1ccccc1B5c1ccccc1O4]

Under Ar atmosphere, Intermediate 8C (12.4 g) was added to a 500 ml three-necked flask and was dissolved in o-dichlorobenzene (ODCB, 150 ml), the flask was cooled to about 0° C. in an ice bath, boron triiodide (BI₃, 20 g) was added, then the resultant mixture was heated and stirred at about 140° C. for about 6 hours, the flask was cooled to about 0° C. in an ice bath, and N,N-diisopropylethylamine (DIPEA, 35 ml) was added. After returning to a room temperature, a reaction solution was filtered through silica gel, and a filtrate solvent was removed by distillation under reduced pressure. The obtained crude product was purified through silica gel column chromatography to obtain 3.0 g of Compound 8 (yield of about 24%). A molecular weight of Compound 8 as measured by FAB-MS, was about 1448.

### (9) Synthesis of Compound 9

### Synthesis of Intermediate 9B

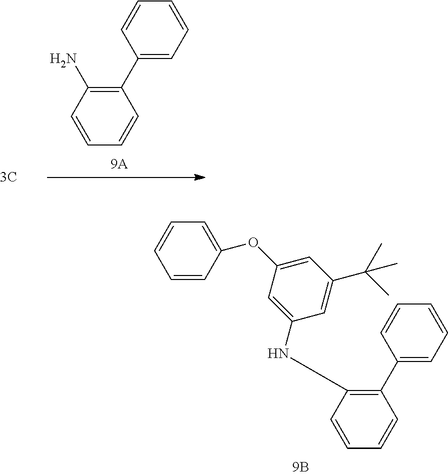 [SMILES: Nc1ccccc1-c1ccccc1 ; CC(C)(C)c1cc(Nc2ccccc2-c2ccccc2)cc(Oc2ccccc2)c1]

Under Ar atmosphere, Intermediate 3C (15 g), Intermediate 9A (11 g), bis(dibenzylideneacetone)palladium(0) (Pd(dba)₂, 0.56 g), (±)-BINAP (1.2 g), sodium tert-butoxide (NaOtBu, 7 g), and toluene (200 ml) were added to a 500 ml three-necked flask, and the resultant mixture was heated and stirred for about 12 hours at about 100° C. After returning to a room temperature, water was added, the mixture was subjected to extraction with toluene, combined organic layers were dried over MgSO₄, and then a solvent was removed by distillation under reduced pressure. The obtained product was purified through silica gel column chromatography to obtain 17 g of Intermediate 9B (yield of about 88%). A molecular weight of Intermediate 9B, as measured by FAB-MS, was about 394.

### Synthesis of Intermediate 9C

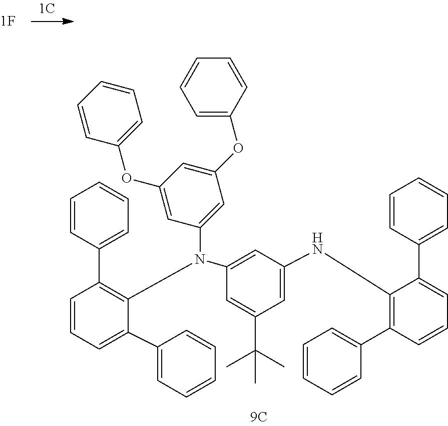 [SMILES: CC(C)(C)c1cc(Nc2c(-c3ccccc3)cccc2-c2ccccc2)cc(N(c2cc(Oc3ccccc3)cc(Oc3ccccc3)c2)c2c(-c3ccccc3)cccc2-c2ccccc2)c1]

Under Ar atmosphere, Intermediate 1F (30 g), Intermediate 1C (56 g), CuI (9.2 g), and K₂CO₃ (27 g) were added to a 300 ml three-necked flask, and the resultant mixture was heated and stirred for about 48 hours at about 230° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 13.6 g of Intermediate 9C (yield of about 32%). A molecular weight of Intermediate 9C, as measured by FAB-MS, was about 881.

### Synthesis of Intermediate 9E

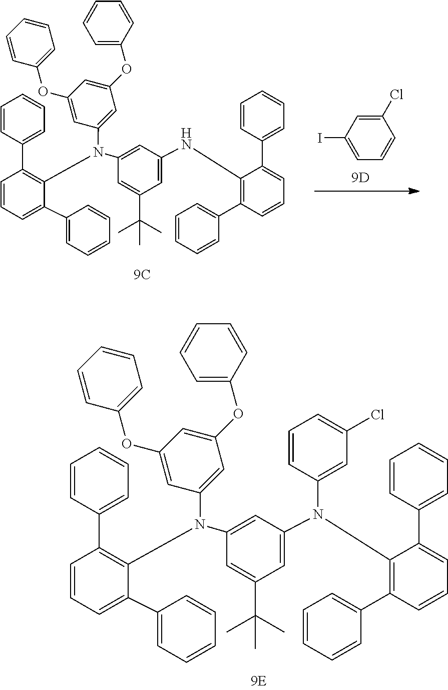

Under Ar atmosphere, Intermediate 9C (13.6 g), Intermediate 9D (22 g), CuI (2.9 g), and K₂CO₃ (8.5 g) were added to a 200 ml three-necked flask, and the resultant mixture was heated and stirred for about 48 hours at about 230° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 8.1 g of Intermediate 9E (yield of about 53%). A molecular weight of Intermediate 9E, as measured by FAB-MS, was about 992.

### Synthesis of Intermediate 9F

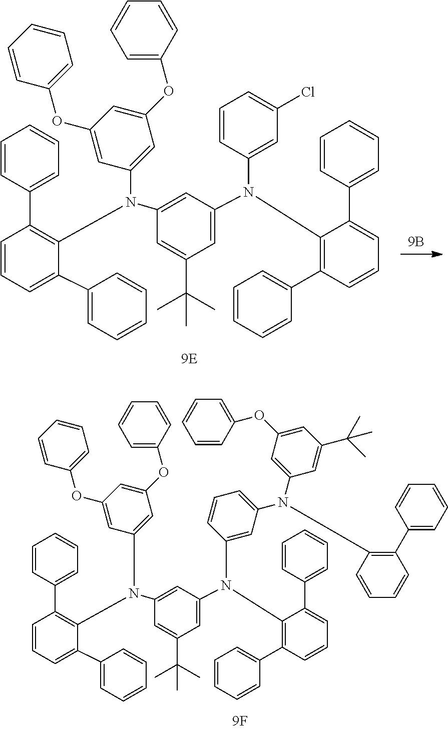 [SMILES: CC(C)(C)c1cc(N(c2cccc(Cl)c2)c2c(-c3ccccc3)cccc2-c2ccccc2)cc(N(c2cc(Oc3ccccc3)cc(Oc3ccccc3)c2)c2c(-c3ccccc3)cccc2-c2ccccc2)c1 ; CC(C)(C)c1cc(Oc2ccccc2)cc(N(c2cccc(N(c3cc(N(c4cc(Oc5ccccc5)cc(Oc5ccccc5)c4)c4c(-c5ccccc5)cccc4-c4ccccc4)cc(C(C)(C)C)c3)c3c(-c4ccccc4)cccc3-c3ccccc3)c2)c2ccccc2-c2ccccc2)c1]

Under Ar atmosphere, Intermediate 9E (8.1 g), Intermediate 9B (4.8 g), bis(dibenzylideneacetone)palladium(0) (Pd(dba)₂, 0.14 g), tri-tert-butylphosphine tetrafluoroborate (0.14 g), sodium tert-butoxide (NaOtBu, 1.6 g), and toluene (80 ml) were added to a 200 ml three-necked flask, and the resultant mixture was heated and stirred for about 24 hours at about 110° C. After returning to a room temperature, water was added, the mixture was subjected to extraction with toluene, combined organic layers were dried over MgSO₄, and then a solvent was removed by distillation under reduced pressure. The obtained product was purified through silica gel column chromatography to obtain 7.9 g of Intermediate 9F (yield of about 72%). A molecular weight of Intermediate 9F, as measured by FAB-MS, was about 1349.

### Synthesis of Compound 9

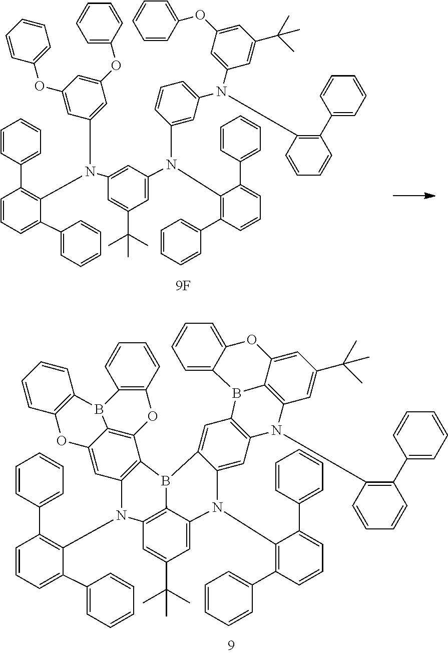 [SMILES: CC(C)(C)c1cc(Oc2ccccc2)cc(N(c2cccc(N(c3cc(N(c4cc(Oc5ccccc5)cc(Oc5ccccc5)c4)c4c(-c5ccccc5)cccc4-c4ccccc4)cc(C(C)(C)C)c3)c3c(-c4ccccc4)cccc3-c3ccccc3)c2)c2ccccc2-c2ccccc2)c1 ; CC(C)(C)c1cc2c3c(c1)N(c1ccccc1-c1ccccc1)c1cc4c(cc1B3c1ccccc1O2)B1c2c(cc(C(C)(C)C)cc2N(c2c(-c3ccccc3)cccc2-c2ccccc2)c2cc3c5c(c21)Oc1ccccc1B5c1ccccc1O3)N4c1c(-c2ccccc2)cccc1-c1ccccc1]

Under Ar atmosphere, Intermediate 9F (12.4 g) was added to a 300 ml three-necked flask and was dissolved in o-dichlorobenzene (ODCB, 100 ml), the flask was cooled to about 0° C. in an ice bath, boron triiodide (BI₃, 14 g) was added, then the resultant mixture was heated and stirred at about 140° C. for about 6 hours, the flask was cooled to about 0° C. in an ice bath, and N,N-diisopropylethylamine (DIPEA, 20 ml) was added. After returning to a room temperature, a reaction solution was filtered through silica gel, and a filtrate solvent was removed by distillation under reduced pressure. The obtained crude product was purified through silica gel column chromatography to obtain 2.9 g of Compound 9 (yield of about 36%). A molecular weight of Compound 9, as measured by FAB-MS, was about 1372.

### (10) Synthesis of Compound 10

### Synthesis of Intermediate 10B

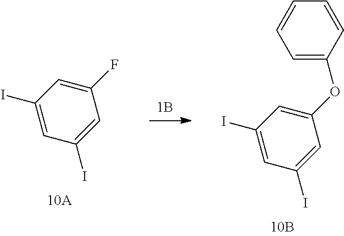 [SMILES: Fc1cc(I)cc(I)c1 ; Ic1cc(I)cc(Oc2ccccc2)c1]

Under Ar atmosphere, Intermediate 10A (50 g), Intermediate 1B (34 g), K₂CO₃ (60 g), and 1-methyl-2-pyrrolidone (400 ml) were added to a 1000 ml three-necked flask, and the resultant mixture was heated and stirred for about 16 hours at about 140° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 51 g of Intermediate 10B (yield of about 84%). A molecular weight of Intermediate 10B, as measured by FAB-MS, was about 422.

### Synthesis of Intermediate 10D

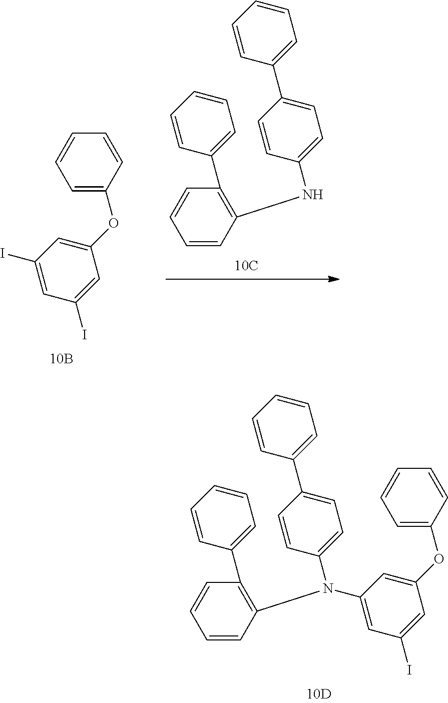 [SMILES: Ic1cc(I)cc(Oc2ccccc2)c1 ; c1ccc(-c2ccc(Nc3ccccc3-c3ccccc3)cc2)cc1 ; Ic1cc(Oc2ccccc2)cc(N(c2ccc(-c3ccccc3)cc2)c2ccccc2-c2ccccc2)c1]

Under Ar atmosphere, Intermediate 10B (51 g), Intermediate 10C (39 g), bis(dibenzylideneacetone)palladium(0) (Pd(dba)₂, 0.69 g), (±)-BINAP (1.5 g), sodium tert-butoxide (NaOtBu, 17.4 g), and toluene (400 ml) were added to a 1000 ml three-necked flask, and the resultant mixture was heated and stirred for about 12 hours at about 100° C. After returning to a room temperature, water was added, the mixture was subjected to extraction with toluene, combined organic layers were dried over MgSO₄, and then a solvent was removed by distillation under reduced pressure. The obtained product was purified through silica gel column chromatography to obtain 23 g of Intermediate 10D (yield of about 31%). A molecular weight of Intermediate 10D, as measured by FAB-MS, was about 616.

### Synthesis of Intermediate 10E

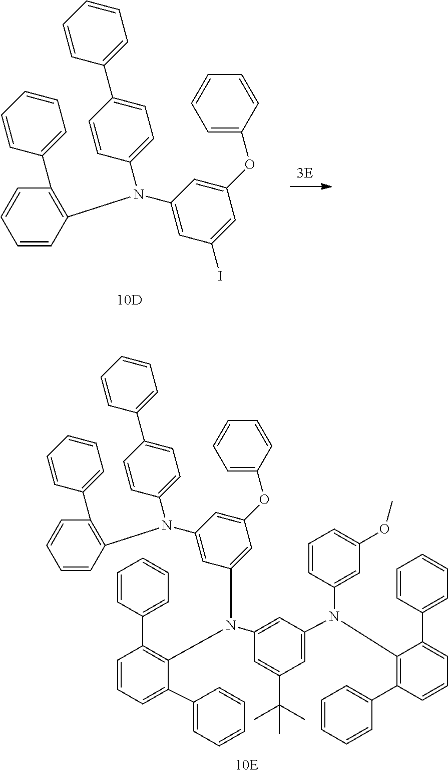 [SMILES: Ic1cc(Oc2ccccc2)cc(N(c2ccc(-c3ccccc3)cc2)c2ccccc2-c2ccccc2)c1 ; COc1cccc(N(c2cc(N(c3cc(Oc4ccccc4)cc(N(c4ccc(-c5ccccc5)cc4)c4ccccc4-c4ccccc4)c3)c3c(-c4ccccc4)cccc3-c3ccccc3)cc(C(C)(C)C)c2)c2c(-c3ccccc3)cccc2-c2ccccc2)c1]

Under Ar atmosphere, Intermediate 10D (23 g), Intermediate 3E (13 g), CuI (3.4 g), and K₂CO₃ (7.4 g) were added to a 200 ml three-necked flask, and the resultant mixture was heated and stirred for about 48 hours at about 230° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 6.5 g of Intermediate 10E (yield of about 30%). A molecular weight of Intermediate 10E, as measured by FAB-MS, was about 1215.

### Synthesis of Intermediate 10F

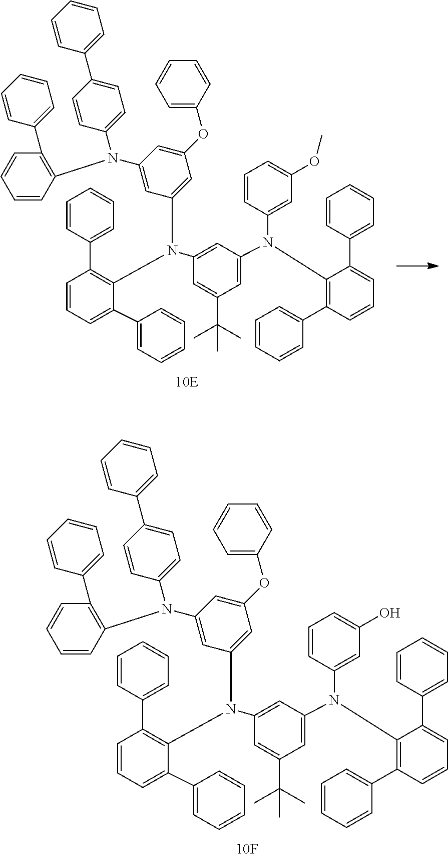 [SMILES: COc1cccc(N(c2cc(N(c3cc(Oc4ccccc4)cc(N(c4ccc(-c5ccccc5)cc4)c4ccccc4-c4ccccc4)c3)c3c(-c4ccccc4)cccc3-c3ccccc3)cc(C(C)(C)C)c2)c2c(-c3ccccc3)cccc2-c2ccccc2)c1 ; CC(C)(C)c1cc(N(c2cccc(O)c2)c2c(-c3ccccc3)cccc2-c2ccccc2)cc(N(c2cc(Oc3ccccc3)cc(N(c3ccc(-c4ccccc4)cc3)c3ccccc3-c3ccccc3)c2)c2c(-c3ccccc3)cccc2-c2ccccc2)c1]

Under Ar atmosphere, Intermediate 10E (6.5 g) was added to a 300 ml three-necked flask and was dissolved in dichloromethane (100 ml), the flask was cooled to about 0° C. in an ice bath, boron tribromide (BBr₃, 2.7 g) was added, then the resultant mixture was heated and stirred at a room temperature for about 24 hours. Ice water was added to a reaction solution, the mixture was subjected to extraction with CH₂Cl₂, and a solvent was removed by distillation under reduced pressure. The obtained crude product was purified through silica gel column chromatography to obtain 5.5 g of Intermediate 10F (yield of about 86%). A molecular weight of Intermediate 10F, as measured by FAB-MS, was about 1201.

### Synthesis of Intermediate 10G

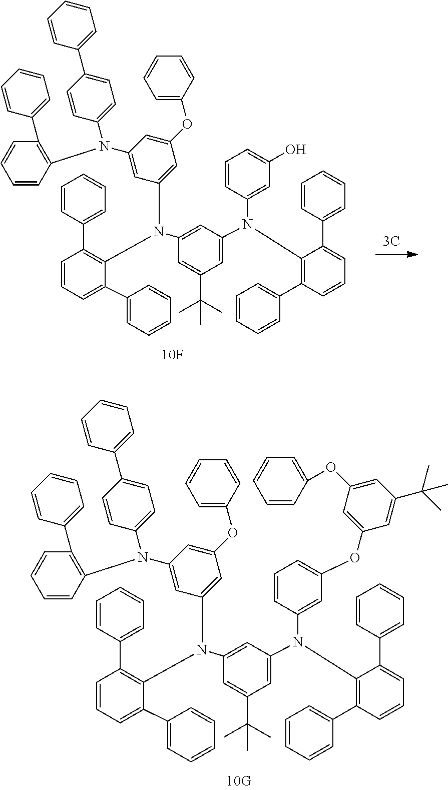 [SMILES: CC(C)(C)c1cc(N(c2cccc(O)c2)c2c(-c3ccccc3)cccc2-c2ccccc2)cc(N(c2cc(Oc3ccccc3)cc(N(c3ccc(-c4ccccc4)cc3)c3ccccc3-c3ccccc3)c2)c2c(-c3ccccc3)cccc2-c2ccccc2)c1 ; CC(C)(C)c1cc(Oc2ccccc2)cc(Oc2cccc(N(c3cc(N(c4cc(Oc5ccccc5)cc(N(c5ccc(-c6ccccc6)cc5)c5ccccc5-c5ccccc5)c4)c4c(-c5ccccc5)cccc4-c4ccccc4)cc(C(C)(C)C)c3)c3c(-c4ccccc4)cccc3-c3ccccc3)c2)c1]

Under Ar atmosphere, Intermediate 10F (5.5 g), Intermediate 3C (2.8 g), CuI (0.8 g), K₂CO₃ (2 g), and o-dichlorobenzene (ODCB, 60 ml) were added to a 200 ml three-necked flask, and the resultant mixture was heated and stirred for about 16 hours at about 180° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 5.7 g of Intermediate 10G (yield of about 88%). A molecular weight of Intermediate 10G, as measured by FAB-MS, was about 1425.

### Synthesis of Compound 10

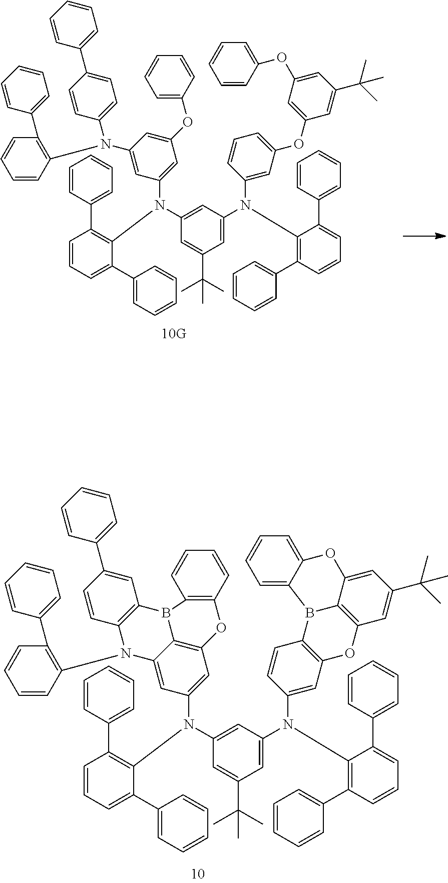 [SMILES: CC(C)(C)c1cc(Oc2ccccc2)cc(Oc2cccc(N(c3cc(N(c4cc(Oc5ccccc5)cc(N(c5ccc(-c6ccccc6)cc5)c5ccccc5-c5ccccc5)c4)c4c(-c5ccccc5)cccc4-c4ccccc4)cc(C(C)(C)C)c3)c3c(-c4ccccc4)cccc3-c3ccccc3)c2)c1 ; CC(C)(C)c1cc(N(c2ccc3c(c2)Oc2cc(C(C)(C)C)cc4c2B3c2ccccc2O4)c2c(-c3ccccc3)cccc2-c2ccccc2)cc(N(c2cc3c4c(c2)N(c2ccccc2-c2ccccc2)c2ccc(-c5ccccc5)cc2B4c2ccccc2O3)c2c(-c3ccccc3)cccc2-c2ccccc2)c1]

Under Ar atmosphere, Intermediate 10G (5.7 g) was added to a 300 ml three-necked flask and was dissolved in o-dichlorobenzene (ODCB, 100 ml), the flask was cooled to about 0° C. in an ice bath, boron triiodide (BI₃, 9.4 g) was added, then the resultant mixture was heated and stirred at about 140° C. for about 6 hours, the flask was cooled to about 0° C. in an ice bath, and N,N-diisopropylethylamine (DIPEA, 15 ml) was added. After returning to a room temperature, a reaction solution was filtered through silica gel, and a filtrate solvent was removed by distillation under reduced pressure. The obtained crude product was purified through silica gel column chromatography to obtain 1.8 g of Compound 10 (yield of about 31%). A molecular weight of Compound 10, as measured by FAB-MS, was about 1448.

### (11) Synthesis of Compound 11

### Synthesis of Intermediate 111B

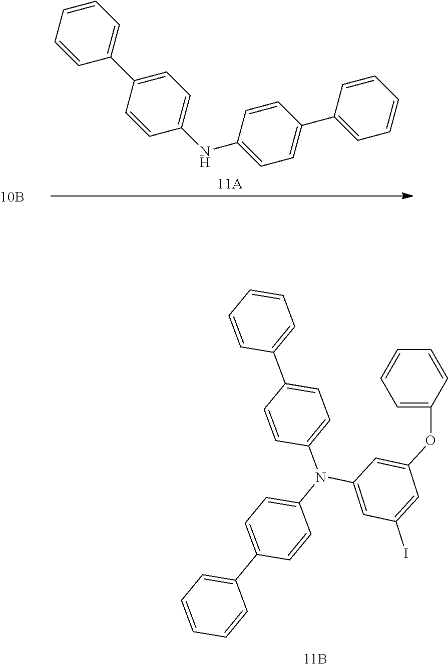 [SMILES: c1ccc(-c2ccc(Nc3ccc(-c4ccccc4)cc3)cc2)cc1 ; Ic1cc(Oc2ccccc2)cc(N(c2ccc(-c3ccccc3)cc2)c2ccc(-c3ccccc3)cc2)c1]

Under Ar atmosphere, Intermediate 10B (30 g), Intermediate 11A (23 g), bis(dibenzylideneacetone)palladium(0) (Pd(dba)₂, 0.41 g), (±)-BINAP (0.88 g), sodium tert-butoxide (NaOtBu, 10 g), and toluene (400 ml) were added to a 1000 ml three-necked flask, and the resultant mixture was heated and stirred for about 12 hours at about 100° C. After returning to a room temperature, water was added, the mixture was subjected to extraction with toluene, combined organic layers were dried over MgSO₄, and then a solvent was removed by distillation under reduced pressure. The obtained product was purified through silica gel column chromatography to obtain 14.9 g of Intermediate 11B (yield of about 34%). A molecular weight of Intermediate 111B, as measured by FAB-MS, was about 616.

### Synthesis of Intermediate 11C

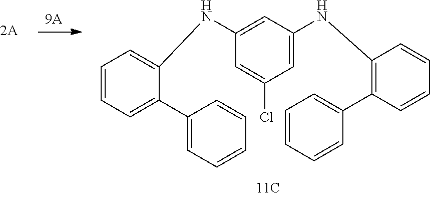 [SMILES: Clc1cc(Nc2ccccc2-c2ccccc2)cc(Nc2ccccc2-c2ccccc2)c1]

Under Ar atmosphere, Intermediate 2A (10 g), Intermediate 9A (12.5 g), bis(dibenzylideneacetone)palladium(0) (Pd(dba)₂, 0.43 g), (±)-BINAP (0.92 g), sodium tert-butoxide (NaOtBu, 9 g), and toluene (250 ml) were added to a 500 ml three-necked flask, and the resultant mixture was heated and stirred for about 12 hours at about 100° C. After returning to a room temperature, water was added, the mixture was subjected to extraction with toluene, combined organic layers were dried over MgSO₄, and then a solvent was removed by distillation under reduced pressure. The obtained product was purified through silica gel column chromatography to obtain 13.2 g of Intermediate 11C (yield of about 80%). A molecular weight of Intermediate 11C, as measured by FAB-MS, was about 447.

### Synthesis of Intermediate 11D

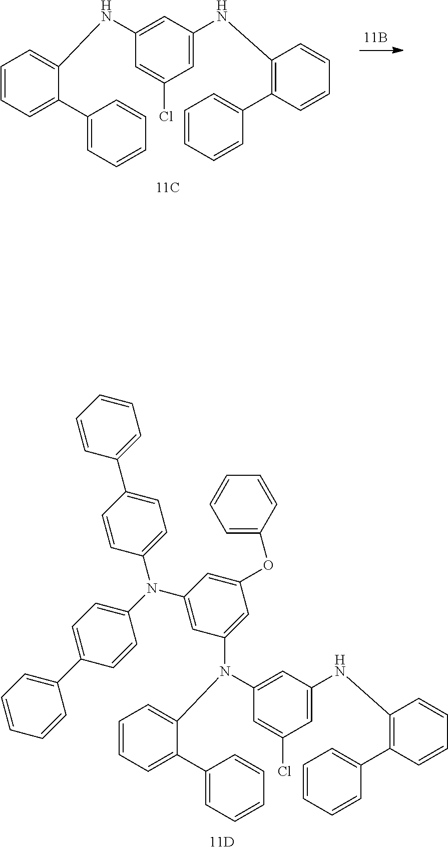 [SMILES: Clc1cc(Nc2ccccc2-c2ccccc2)cc(Nc2ccccc2-c2ccccc2)c1 ; Clc1cc(Nc2ccccc2-c2ccccc2)cc(N(c2cc(Oc3ccccc3)cc(N(c3ccc(-c4ccccc4)cc3)c3ccc(-c4ccccc4)cc3)c2)c2ccccc2-c2ccccc2)c1]

Under Ar atmosphere, Intermediate 11C (10 g), Intermediate 11B3 (13.8 g), bis(dibenzylideneacetone)palladium(0) (Pd(dba)₂, 0.13 g), tri-tert-butylphosphine tetrafluoroborate (0.13 g), sodium tert-butoxide (NaOtBu, 3.2 g), and toluene (100 ml) were added to a 300 ml three-necked flask, and the resultant mixture was heated and stirred for about 24 hours at about 60° C. After returning to a room temperature, water was added, the mixture was subjected to extraction with toluene, combined organic layers were dried over MgSO₄, and then a solvent was removed by distillation under reduced pressure. The obtained product was purified through silica gel column chromatography to obtain 6.7 g of Intermediate 11D (yield of about 32%). A molecular weight of Intermediate 11D, as measured by FAB-MS, was about 935.

### Synthesis of Intermediate 11E

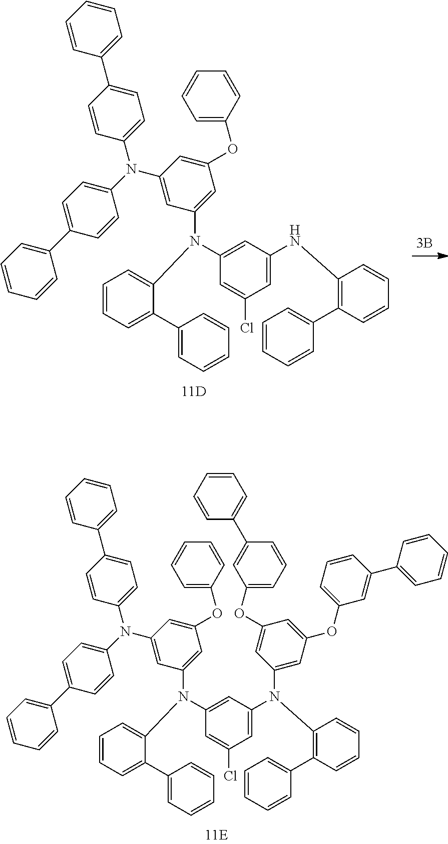 [SMILES: Clc1cc(Nc2ccccc2-c2ccccc2)cc(N(c2cc(Oc3ccccc3)cc(N(c3ccc(-c4ccccc4)cc3)c3ccc(-c4ccccc4)cc3)c2)c2ccccc2-c2ccccc2)c1 ; Clc1cc(N(c2cc(Oc3cccc(-c4ccccc4)c3)cc(Oc3cccc(-c4ccccc4)c3)c2)c2ccccc2-c2ccccc2)cc(N(c2cc(Oc3ccccc3)cc(N(c3ccc(-c4ccccc4)cc3)c3ccc(-c4ccccc4)cc3)c2)c2ccccc2-c2ccccc2)c1]

Under Ar atmosphere, Intermediate 111D (6.7 g), Intermediate 3B (3.9 g), bis(dibenzylideneacetone)palladium(0) (Pd(dba)₂, 0.04 g), tri-tert-butylphosphine tetrafluoroborate (0.04 g), sodium tert-butoxide (NaOtBu, 1 g), and toluene (60 ml) were added to a 200 ml three-necked flask, and the resultant mixture was heated and stirred for about 24 hours at about 60° C. After returning to a room temperature, water was added, the mixture was subjected to extraction with toluene, combined organic layers were dried over MgSO₄, and then a solvent was removed by distillation under reduced pressure. The obtained product was purified through silica gel column chromatography to obtain 8.3 g of Intermediate 11E (yield of about 86%). A molecular weight of Intermediate 11E, as measured by FAB-MS, was about 1347.

### Synthesis of Intermediate 11G

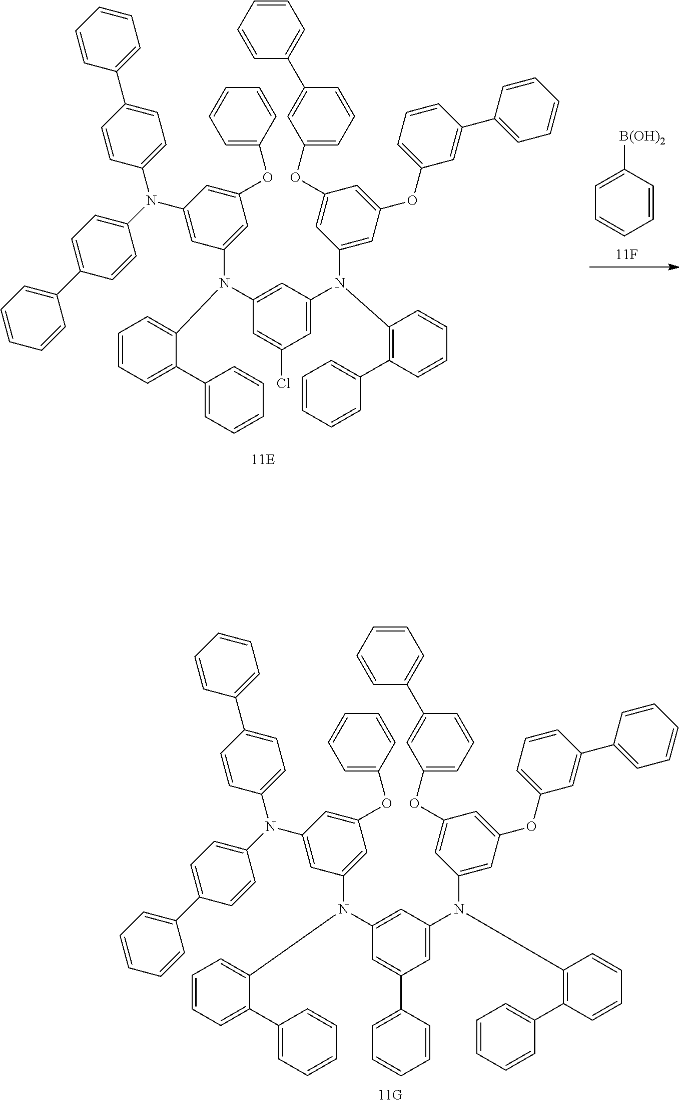 [SMILES: Clc1cc(N(c2cc(Oc3cccc(-c4ccccc4)c3)cc(Oc3cccc(-c4ccccc4)c3)c2)c2ccccc2-c2ccccc2)cc(N(c2cc(Oc3ccccc3)cc(N(c3ccc(-c4ccccc4)cc3)c3ccc(-c4ccccc4)cc3)c2)c2ccccc2-c2ccccc2)c1 ; OB(O)c1ccccc1 ; c1ccc(Oc2cc(N(c3ccc(-c4ccccc4)cc3)c3ccc(-c4ccccc4)cc3)cc(N(c3cc(-c4ccccc4)cc(N(c4cc(Oc5cccc(-c6ccccc6)c5)cc(Oc5cccc(-c6ccccc6)c5)c4)c4ccccc4-c4ccccc4)c3)c3ccccc3-c3ccccc3)c2)cc1]

Under Ar atmosphere, Intermediate 11E (8.3 g), Intermediate 11F (2.3 g), palladium(II) acetate (Pd(OAc)₂, 0.069 g), 2-dicyclohexylphosphino-2′,6′-dimethoxybiphenyl (SPhos, 0.25 g), K₃PO₄ (3.9 g), and toluene (80 ml) were added to a 200 ml three-necked flask, and the resultant mixture was heated and stirred for about 24 hours at about 100° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 5.6 g of Intermediate 11G (yield of about 65%). A molecular weight of Intermediate 11G, as measured by FAB-MS, was about 1389.

### Synthesis of Compound 11

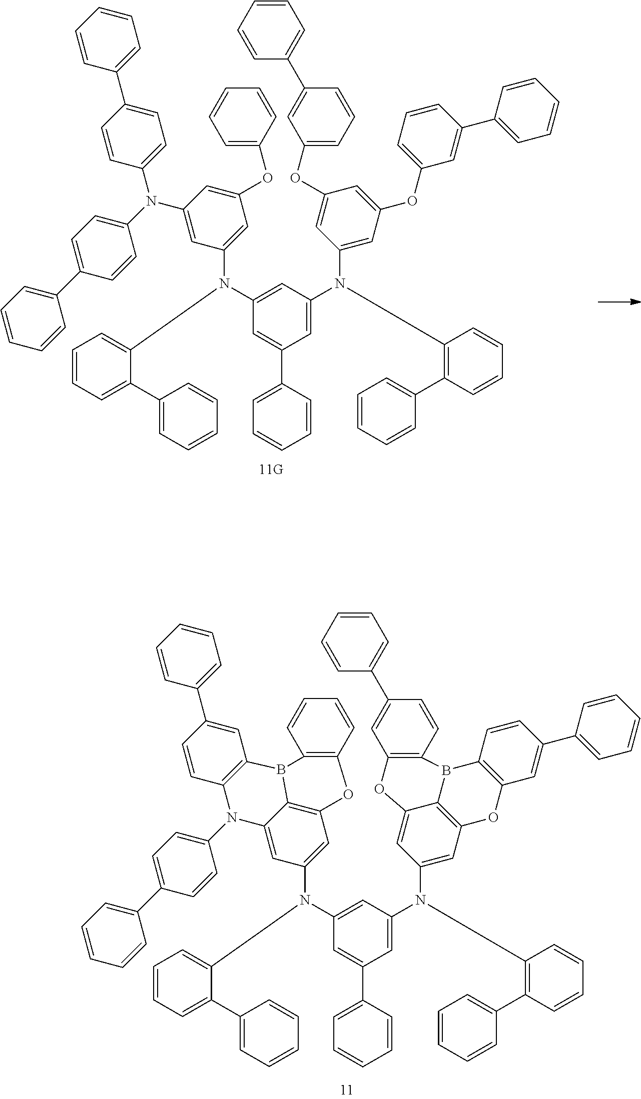 [SMILES: c1ccc(Oc2cc(N(c3ccc(-c4ccccc4)cc3)c3ccc(-c4ccccc4)cc3)cc(N(c3cc(-c4ccccc4)cc(N(c4cc(Oc5cccc(-c6ccccc6)c5)cc(Oc5cccc(-c6ccccc6)c5)c4)c4ccccc4-c4ccccc4)c3)c3ccccc3-c3ccccc3)c2)cc1 ; c1ccc(-c2ccc(N3c4ccc(-c5ccccc5)cc4B4c5ccccc5Oc5cc(N(c6cc(-c7ccccc7)cc(N(c7cc8c9c(c7)Oc7cc(-c%10ccccc%10)ccc7B9c7ccc(-c9ccccc9)cc7O8)c7ccccc7-c7ccccc7)c6)c6ccccc6-c6ccccc6)cc3c54)cc2)cc1]

Under Ar atmosphere, Intermediate 11G (5.6 g) was added to a 300 ml three-necked flask and was dissolved in o-dichlorobenzene (ODCB, 100 ml), the flask was cooled to about 0° C. in an ice bath, boron triiodide (BI₃, 9.5 g) was added, then the resultant mixture was heated and stirred at about 140° C. for about 6 hours, the flask was cooled to about 0° C. in an ice bath, and N,N-diisopropylethylamine (DIPEA, 15 ml) was added. After returning to a room temperature, a reaction solution was filtered through silica gel, and a filtrate solvent was removed by distillation under reduced pressure. The obtained crude product was purified through silica gel column chromatography to obtain 2.4 g of Compound 11 (yield of about 42%). A molecular weight of Compound 11, as measured by FAB-MS, was about 1412.

### (12) Synthesis of Compound 12

### Synthesis of Intermediate 12A

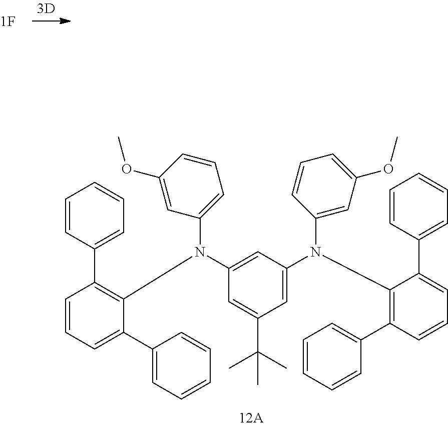 [SMILES: COc1cccc(N(c2cc(N(c3cccc(OC)c3)c3c(-c4ccccc4)cccc3-c3ccccc3)cc(C(C)(C)C)c2)c2c(-c3ccccc3)cccc2-c2ccccc2)c1]

Under Ar atmosphere, Intermediate 1F (15 g), Intermediate 3D (45 g), CuI (9.2 g), and K₂CO₃ (27 g) were added to a 300 ml three-necked flask, and the resultant mixture was heated and stirred for about 48 hours at about 210° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 9.3 g of Intermediate 12A (yield of about 46%). A molecular weight of Intermediate 12A, as measured by FAB-MS, was about 833.

### Synthesis of Intermediate 12B

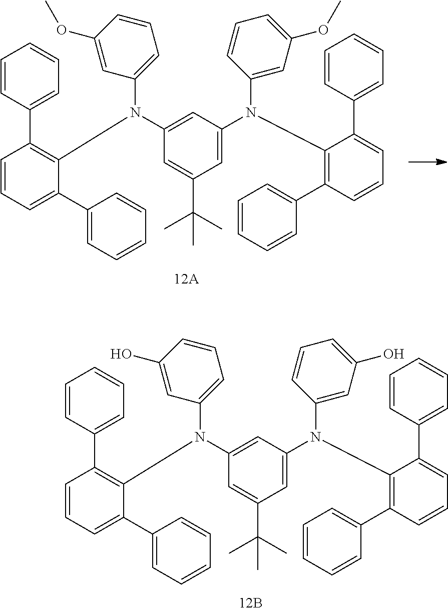 [SMILES: COc1cccc(N(c2cc(N(c3cccc(OC)c3)c3c(-c4ccccc4)cccc3-c3ccccc3)cc(C(C)(C)C)c2)c2c(-c3ccccc3)cccc2-c2ccccc2)c1 ; CC(C)(C)c1cc(N(c2cccc(O)c2)c2c(-c3ccccc3)cccc2-c2ccccc2)cc(N(c2cccc(O)c2)c2c(-c3ccccc3)cccc2-c2ccccc2)c1]

Under Ar atmosphere, Intermediate 12A (9.3 g) was added to a 500 ml three-necked flask and was dissolved in dichloromethane (200 ml), the flask was cooled to about 0° C. in an ice bath, boron tribromide (BBr₃, 11 g) was added, then the resultant mixture was heated and stirred at a room temperature for about 24 hours. Ice water was added to a reaction solution, the mixture was subjected to extraction with CH₂Cl₂, and a solvent was removed by distillation under reduced pressure. The obtained crude product was purified through silica gel column chromatography to obtain 4.6 g of Intermediate 12B (yield of about 52%). A molecular weight of Intermediate 12B, as measured by FAB-MS, was about 805.

### Synthesis of Intermediate 12C

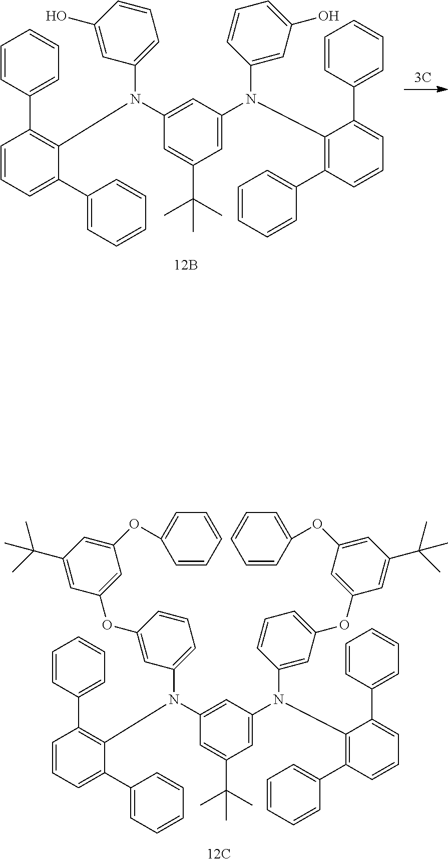 [SMILES: CC(C)(C)c1cc(N(c2cccc(O)c2)c2c(-c3ccccc3)cccc2-c2ccccc2)cc(N(c2cccc(O)c2)c2c(-c3ccccc3)cccc2-c2ccccc2)c1 ; CC(C)(C)c1cc(Oc2ccccc2)cc(Oc2cccc(N(c3cc(N(c4cccc(Oc5cc(Oc6ccccc6)cc(C(C)(C)C)c5)c4)c4c(-c5ccccc5)cccc4-c4ccccc4)cc(C(C)(C)C)c3)c3c(-c4ccccc4)cccc3-c3ccccc3)c2)c1]

Under Ar atmosphere, Intermediate 12B (4.6 g), Intermediate 3C (7 g), CuI (2.2 g), K₂CO₃ (5 g), and o-dichlorobenzene (ODCB, 80 ml) were added to a 200 ml three-necked flask, and the resultant mixture was heated and stirred for about 16 hours at about 180° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 5.6 g of Intermediate 12C (yield of about 78%). A molecular weight of Intermediate 12C, as measured by FAB-MS, was about 1254.

### Synthesis of Compound 12

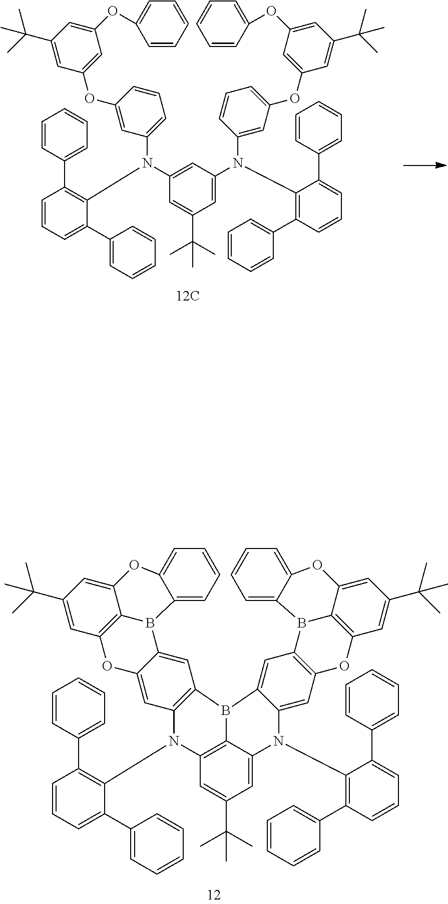

Under Ar atmosphere, Intermediate 12C (5.6 g) was added to a 300 ml three-necked flask and was dissolved in o-dichlorobenzene (ODCB, 100 ml), the flask was cooled to about 0° C. in an ice bath, boron triiodide (BI₃, 10.5 g) was added, then the resultant mixture was heated and stirred at about 140° C. for about 6 hours, the flask was cooled to about 0° C. in an ice bath, and N,N-diisopropylethylamine (DIPEA, 20 ml) was added. After returning to a room temperature, a reaction solution was filtered through silica gel, and a filtrate solvent was removed by distillation under reduced pressure. The obtained crude product was purified through silica gel column chromatography to obtain 2.2 g of Compound 12 (yield of about 39%). A molecular weight of Compound 12, as measured by FAB-MS, was about 1277.

### (13) Synthesis of Compound 14

### Synthesis of Intermediate 14B

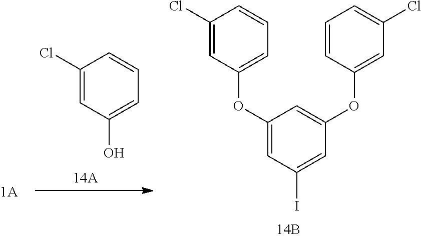 [SMILES: Oc1cccc(Cl)c1 ; Clc1cccc(Oc2cc(I)cc(Oc3cccc(Cl)c3)c2)c1]

Under Ar atmosphere, Intermediate 1A (20 g), Intermediate 14A (27 g), K₂CO₃ (35 g), and 1-methyl-2-pyrrolidone (200 ml) were added to a 500 ml three-necked flask, and the resultant mixture was heated and stirred for about 16 hours at about 140° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 23 g of Intermediate 14B (yield of about 61%). A molecular weight of Intermediate 14B, as measured by FAB-MS, was about 457.

### Synthesis of Intermediate 14D

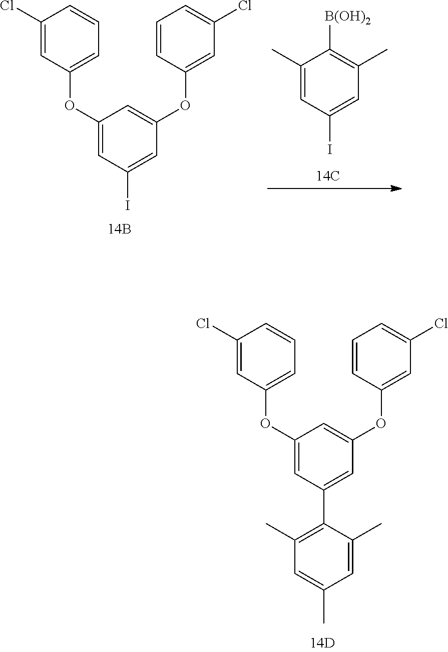

Under Ar atmosphere, Intermediate 14B (23 g), Intermediate 14C (17 g), tetrakis(triphenylphosphine)palladium(0) (Pd(PPh₃)₄, 1.1 g), K₂CO₃ (14 g), and toluene/ethanol/H₂O (150/60/30 ml) were added to a 500 ml three-necked flask, and the resultant mixture was heated and stirred for about 24 hours at about 80° C. After returning to a room temperature, water was added, the mixture was subjected to extraction with toluene, combined organic layers were dried over MgSO₄, and then a solvent was removed by distillation under reduced pressure. The obtained product was purified through silica gel column chromatography to obtain 9.5 g of Intermediate 14D (yield of about 42%). A molecular weight of Intermediate 14D, as measured by FAB-MS, was about 449.

### Synthesis of Intermediate 14F

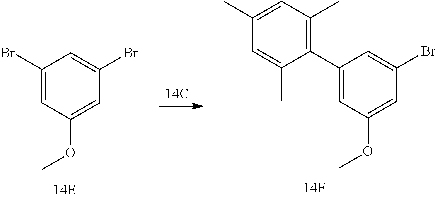

Under Ar atmosphere, Intermediate 14E (20 g), Intermediate 14C (12.3 g), Tetrakis(triphenylphosphine)palladium(O) (Pd(PPh₃)₄, 0.9 g), K₂CO₃ (21 g), and toluene/ethanol/H₂O (150/60/30 ml) were added to a 500 ml three-necked flask, and the resultant mixture was heated and stirred for about 24 hours at about 80° C. After returning to a room temperature, water was added, the mixture was subjected to extraction with toluene, combined organic layers were dried over MgSO₄, and then a solvent was removed by distillation under reduced pressure. The obtained product was purified through silica gel column chromatography to obtain 6.9 g of Intermediate 14F (yield of about 30%). A molecular weight of Intermediate 14F, as measured by FAB-MS, was about 305.

### Synthesis of Intermediate 14H

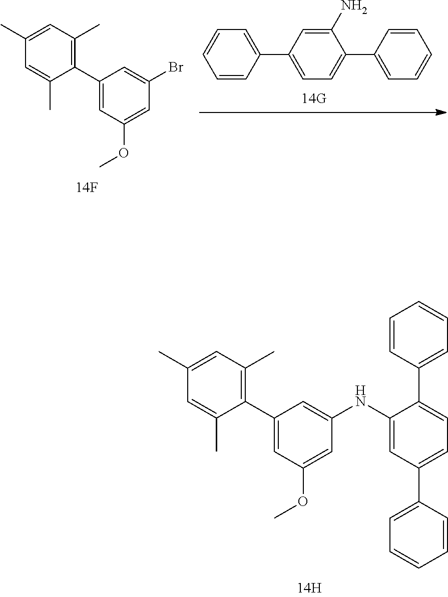

Under Ar atmosphere, Intermediate 14F (6.9 g), Intermediate 14G (6.1 g), bis(dibenzylideneacetone)palladium(O) (Pd(dba)₂, 0.13 g), (±)-BINAP (0.28 g), sodium tert-butoxide (NaOtBu, 3.3 g), and toluene (80 ml) were added to a 300 ml three-necked flask, and the resultant mixture was heated and stirred for about 12 hours at about 100° C. After returning to a room temperature, water was added, the mixture was subjected to extraction with toluene, combined organic layers were dried over MgSO₄, and then a solvent was removed by distillation under reduced pressure. The obtained product was purified through silica gel column chromatography to obtain 8.4 g of Intermediate 14H (yield of about 80%). A molecular weight of Intermediate 14H, as measured by FAB-MS, was about 470.

### Synthesis of Intermediate 14I

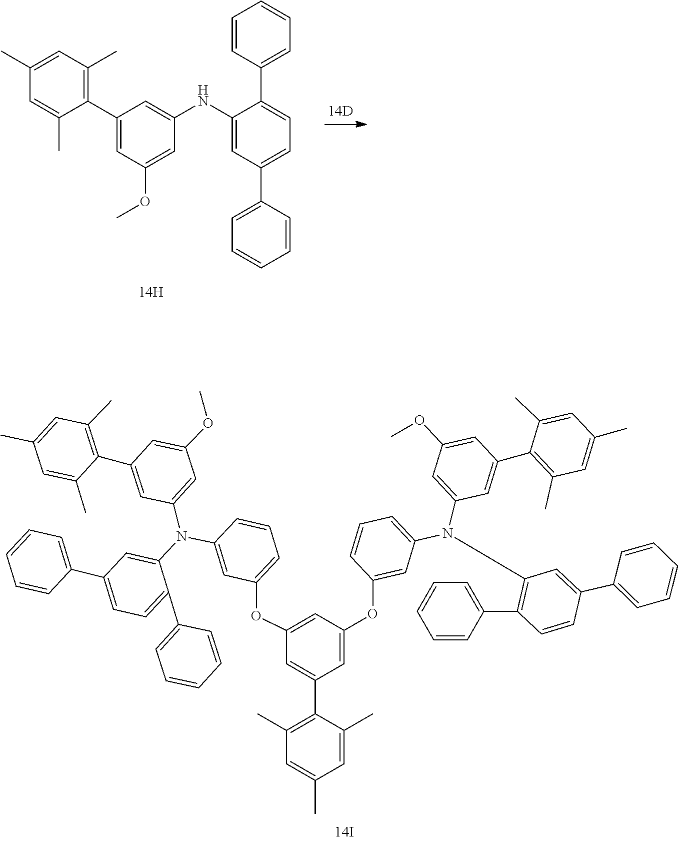 [SMILES: COc1cc(Nc2cc(-c3ccccc3)ccc2-c2ccccc2)cc(-c2c(C)cc(C)cc2C)c1 ; COc1cc(-c2c(C)cc(C)cc2C)cc(N(c2cccc(Oc3cc(Oc4cccc(N(c5cc(OC)cc(-c6c(C)cc(C)cc6C)c5)c5cc(-c6ccccc6)ccc5-c5ccccc5)c4)cc(-c4c(C)cc(C)cc4C)c3)c2)c2cc(-c3ccccc3)ccc2-c2ccccc2)c1]

Under Ar atmosphere, Intermediate 14H (8.4 g), Intermediate 14D (4 g), bis(dibenzylideneacetone)palladium(0) (Pd(dba)₂, 0.15 g), tri-tert-butylphosphine tetrafluoroborate (0.15 g), sodium tert-butoxide (NaOtBu, 3.4 g), and toluene (100 ml) were added to a 300 ml three-necked flask, and the resultant mixture was heated and stirred for about 24 hours at about 110° C. After returning to a room temperature, water was added, the mixture was subjected to extraction with toluene, combined organic layers were dried over MgSO₄, and then a solvent was removed by distillation under reduced pressure. The obtained product was purified through silica gel column chromatography to obtain 8.2 g of Intermediate 14I (yield of about 70%). A molecular weight of Intermediate 14I, as measured by FAB-MS, was about 1316.

### Synthesis of Intermediate 14J

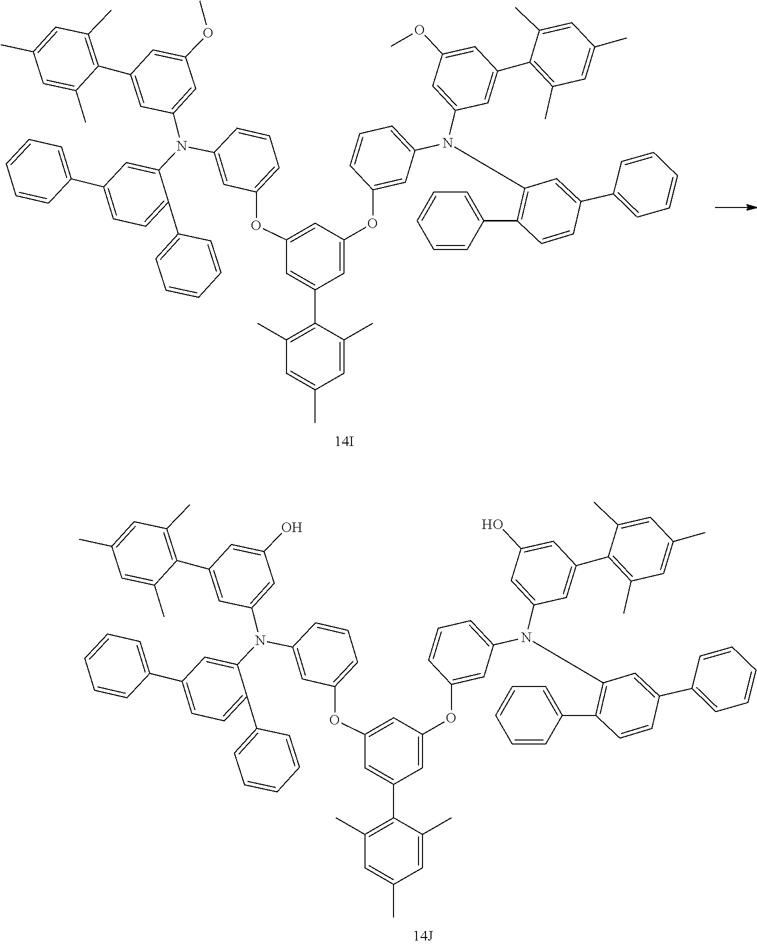 [SMILES: COc1cc(-c2c(C)cc(C)cc2C)cc(N(c2cccc(Oc3cc(Oc4cccc(N(c5cc(OC)cc(-c6c(C)cc(C)cc6C)c5)c5cc(-c6ccccc6)ccc5-c5ccccc5)c4)cc(-c4c(C)cc(C)cc4C)c3)c2)c2cc(-c3ccccc3)ccc2-c2ccccc2)c1 ; Cc1cc(C)c(-c2cc(Oc3cccc(N(c4cc(O)cc(-c5c(C)cc(C)cc5C)c4)c4cc(-c5ccccc5)ccc4-c4ccccc4)c3)cc(Oc3cccc(N(c4cc(O)cc(-c5c(C)cc(C)cc5C)c4)c4cc(-c5ccccc5)ccc4-c4ccccc4)c3)c2)c(C)c1]

Under Ar atmosphere, Intermediate 14I (8.2 g) was added to a 500 ml three-necked flask and was dissolved in dichloromethane (200 ml), the flask was cooled to about 0° C. in an ice bath, boron tribromide (BBr₃, 6.2 g) was added, then the resultant mixture was heated and stirred at a room temperature for about 24 hours. Ice water was added to a reaction solution, the mixture was subjected to extraction with CH₂Cl₂, and a solvent was removed by distillation under reduced pressure. The obtained crude product was purified through silica gel column chromatography to obtain 4.4 g of Intermediate 14J (yield of about 55%). A molecular weight of Intermediate 14J, as measured by FAB-MS, was about 1288.

### Synthesis of Intermediate 14L

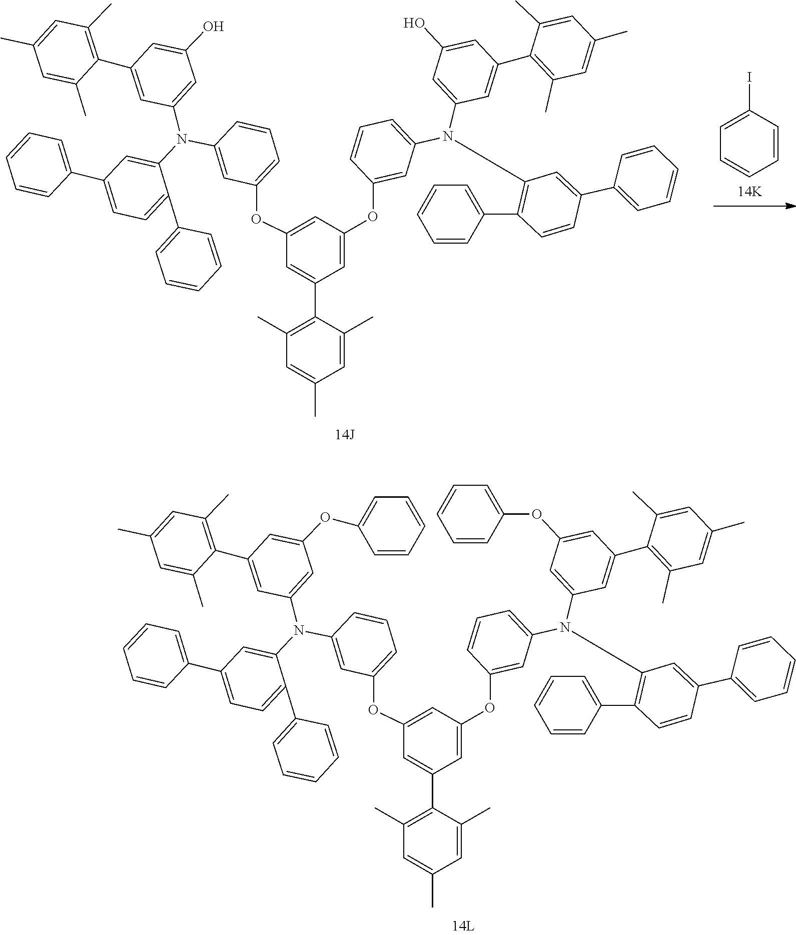

Under Ar atmosphere, Intermediate 14J (4.4 g), Intermediate 14K (2.1 g), CuI (1.3 g), K₂CO₃ (3 g), and o-dichlorobenzene (ODCB, 80 ml) were added to a 200 ml three-necked flask, and the resultant mixture was heated and stirred for about 16 hours at about 180° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 4.5 g of Intermediate 14L (yield of about 91%). A molecular weight of Intermediate 14L, as measured by FAB-MS, was about 1440.

### Synthesis of Compound 14

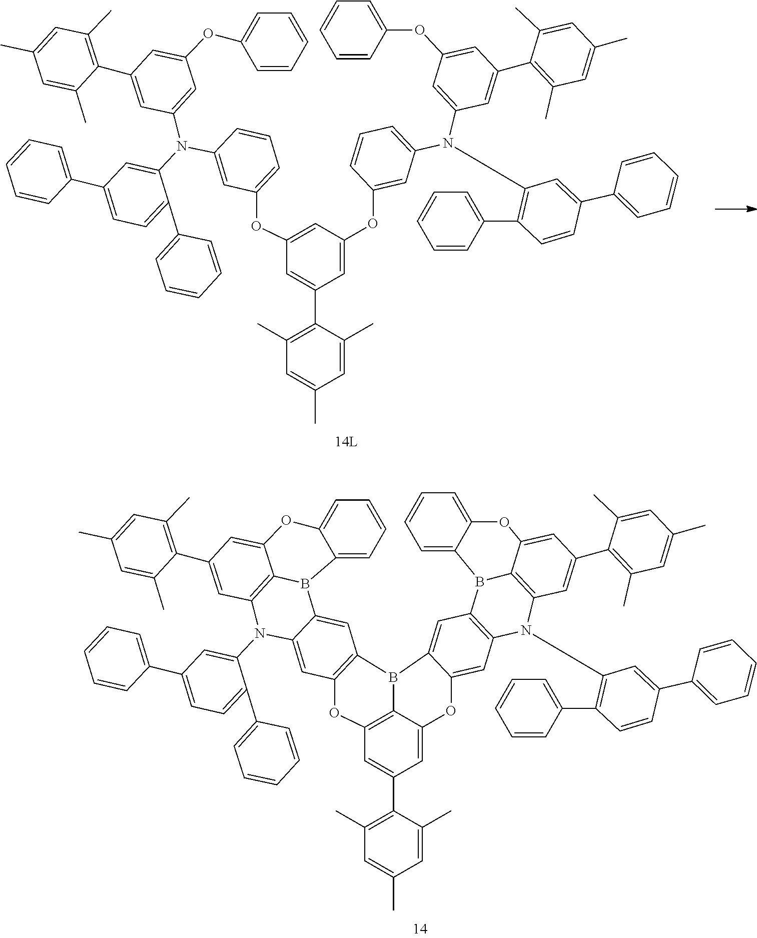 [SMILES: Cc1cc(C)c(-c2cc(Oc3cccc(N(c4cc(Oc5ccccc5)cc(-c5c(C)cc(C)cc5C)c4)c4cc(-c5ccccc5)ccc4-c4ccccc4)c3)cc(Oc3cccc(N(c4cc(Oc5ccccc5)cc(-c5c(C)cc(C)cc5C)c4)c4cc(-c5ccccc5)ccc4-c4ccccc4)c3)c2)c(C)c1 ; Cc1cc(C)c(-c2cc3c4c(c2)Oc2cc5c(cc2B4c2cc4c(cc2O3)N(c2cc(-c3ccccc3)ccc2-c2ccccc2)c2cc(-c3c(C)cc(C)cc3C)cc3c2B4c2ccccc2O3)B2c3ccccc3Oc3cc(-c4c(C)cc(C)cc4C)cc(c32)N5c2cc(-c3ccccc3)ccc2-c2ccccc2)c(C)c1]

Under Ar atmosphere, Intermediate 14L (4.2 g) was added to a 300 ml three-necked flask and was dissolved in o-dichlorobenzene (ODCB, 100 ml), the flask was cooled to about 0° C. in an ice bath, boron triiodide (BI₃, 6.8 g) was added, then the resultant mixture was heated and stirred at about 140° C. for about 6 hours, the flask was cooled to about 0° C. in an ice bath, and N,N-diisopropylethylamine (DIPEA, 15 ml) was added. After returning to a room temperature, a reaction solution was filtered through silica gel, and a filtrate solvent was removed by distillation under reduced pressure. The obtained crude product was purified through silica gel column chromatography to obtain 1.5 g of Compound 14 (yield of about 35%). A molecular weight of Compound 14, as measured by FAB-MS, was about 1463.

### (14) Synthesis of Compound 15

### Synthesis of Intermediate 15C

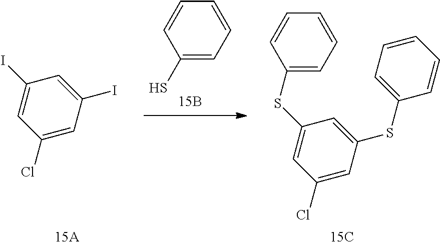

Under Ar atmosphere, Intermediate 15A (10 g), Intermediate 15B (7.3 g), CuI (10.5 g), K₂CO₃ (15 g), and o-dichlorobenzene (ODCB, 150 ml) were added to a 500 ml three-necked flask, and the resultant mixture was heated and stirred for about 16 hours at about 120° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 7.1 g of Intermediate 15C (yield of about 78%). A molecular weight of Intermediate 15C, as measured by FAB-MS, was about 329.

### Synthesis of Intermediate 15F

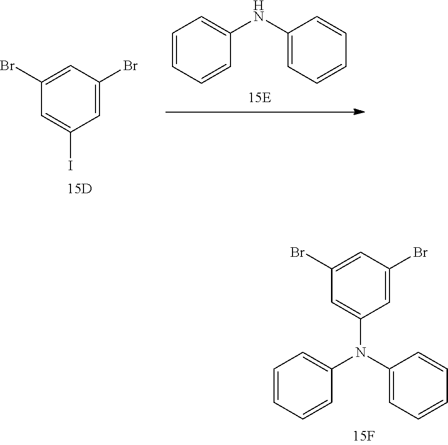

Under Ar atmosphere, Intermediate 15D (17 g), Intermediate 15E (8 g), palladium(II) acetate (Pd(OAc)₂, 0.27 g), 4,5-bis(diphenylphosphino)-9,9-dimethylxanthene (Xantphos, 0.73 g), sodium tert-butoxide (NaOtBu, 6.8 g), and toluene (200 ml) were added to a 500 ml three-necked flask, and the resultant mixture was heated and stirred for about 24 hours at about 80° C. After returning to a room temperature, water was added, the mixture was subjected to extraction with toluene, combined organic layers were dried over MgSO₄, and then a solvent was removed by distillation under reduced pressure. The obtained product was purified through silica gel column chromatography to obtain 14.9 g of Intermediate 15F (yield of about 78%). A molecular weight of Intermediate 15F, as measured by FAB-MS, was about 403.

### Synthesis of Intermediate 15H

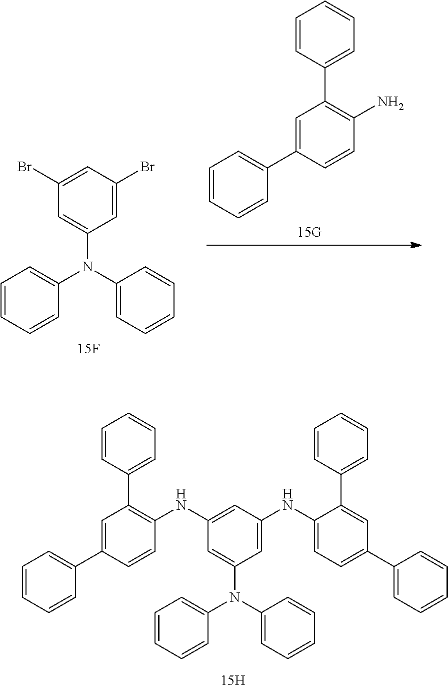 [SMILES: Brc1cc(Br)cc(N(c2ccccc2)c2ccccc2)c1 ; Nc1ccc(-c2ccccc2)cc1-c1ccccc1 ; c1ccc(-c2ccc(Nc3cc(Nc4ccc(-c5ccccc5)cc4-c4ccccc4)cc(N(c4ccccc4)c4ccccc4)c3)c(-c3ccccc3)c2)cc1]

Under Ar atmosphere, Intermediate 15F (9 g), Intermediate 15G (11 g), bis(dibenzylideneacetone)palladium(0) (Pd(dba)₂, 0.26 g), (±)-BINAP (0.56 g), sodium tert-butoxide (NaOtBu, 5.4 g), and toluene (150 ml) were added to a 500 ml three-necked flask, and the resultant mixture was heated and stirred for about 12 hours at about 100° C. After returning to a room temperature, water was added, the mixture was subjected to extraction with toluene, combined organic layers were dried over MgSO₄, and then a solvent was removed by distillation under reduced pressure. The obtained product was purified through silica gel column chromatography to obtain 13.4 g of Intermediate 15H (yield of about 82%). A molecular weight of Intermediate 15H, as measured by FAB-MS, was about 732.

### Synthesis of Intermediate 151

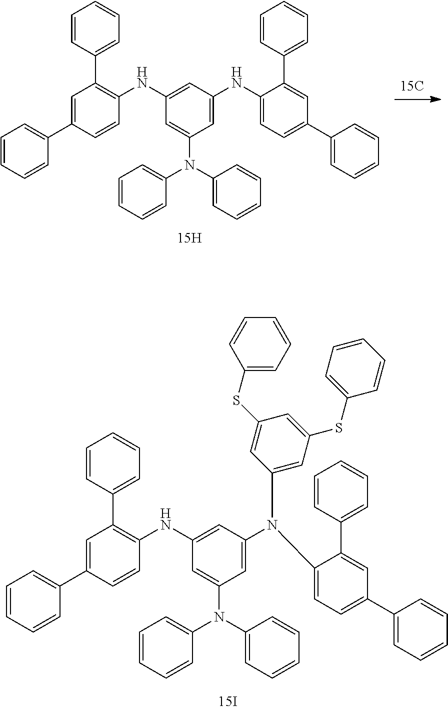 [SMILES: c1ccc(-c2ccc(Nc3cc(Nc4ccc(-c5ccccc5)cc4-c4ccccc4)cc(N(c4ccccc4)c4ccccc4)c3)c(-c3ccccc3)c2)cc1 ; c1ccc(Sc2cc(Sc3ccccc3)cc(N(c3cc(Nc4ccc(-c5ccccc5)cc4-c4ccccc4)cc(N(c4ccccc4)c4ccccc4)c3)c3ccc(-c4ccccc4)cc3-c3ccccc3)c2)cc1]

Under Ar atmosphere, Intermediate 15H (13.4 g), Intermediate 15C (6 g), bis(dibenzylideneacetone)palladium(0) (Pd(dba)₂, 0.21 g), Tri-tert-butylphosphine tetrafluoroborate (0.21 g), sodium tert-butoxide (NaOtBu, 2.6 g), and toluene (100 ml) were added to a 300 ml three-necked flask, and the resultant mixture was heated and stirred for about 24 hours at about 110° C. After returning to a room temperature, water was added, the mixture was subjected to extraction with toluene, combined organic layers were dried over MgSO₄, and then a solvent was removed by distillation under reduced pressure. The obtained product was purified through silica gel column chromatography to obtain 7.5 g of Intermediate 151 (yield of about 40%). A molecular weight of Intermediate 151, as measured by FAB-MS, was about 1024.

### Synthesis of Intermediate 15J

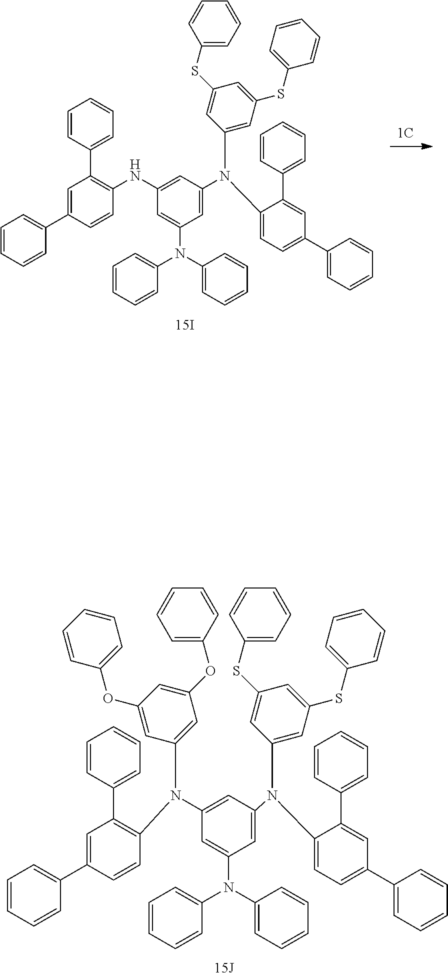 [SMILES: c1ccc(Sc2cc(Sc3ccccc3)cc(N(c3cc(Nc4ccc(-c5ccccc5)cc4-c4ccccc4)cc(N(c4ccccc4)c4ccccc4)c3)c3ccc(-c4ccccc4)cc3-c3ccccc3)c2)cc1 ; c1ccc(Oc2cc(Oc3ccccc3)cc(N(c3cc(N(c4ccccc4)c4ccccc4)cc(N(c4cc(Sc5ccccc5)cc(Sc5ccccc5)c4)c4ccc(-c5ccccc5)cc4-c4ccccc4)c3)c3ccc(-c4ccccc4)cc3-c3ccccc3)c2)cc1]

Under Ar atmosphere, Intermediate 151 (7.5 g), Intermediate 1C (2.8 g), bis(dibenzylideneacetone)palladium(0) (Pd(dba)₂, 0.04 g), tri-tert-butylphosphine tetrafluoroborate (0.04 g), sodium tert-butoxide (NaOtBu, 1 g), and toluene (80 ml) were added to a 200 ml three-necked flask, and the resultant mixture was heated and stirred for about 24 hours at about 100° C. After returning to a room temperature, water was added, the mixture was subjected to extraction with toluene, combined organic layers were dried over MgSO₄, and then a solvent was removed by distillation under reduced pressure. The obtained product was purified through silica gel column chromatography to obtain 7.9 g of Intermediate 15J (yield of about 84%). A molecular weight of Intermediate 15J, as measured by FAB-MS, was about 1284.

### Synthesis of Compound 15

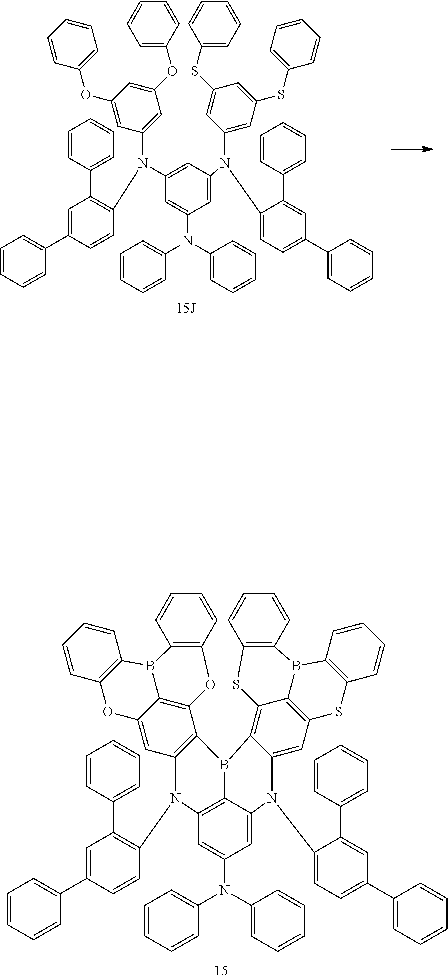 [SMILES: c1ccc(Oc2cc(Oc3ccccc3)cc(N(c3cc(N(c4ccccc4)c4ccccc4)cc(N(c4cc(Sc5ccccc5)cc(Sc5ccccc5)c4)c4ccc(-c5ccccc5)cc4-c4ccccc4)c3)c3ccc(-c4ccccc4)cc3-c3ccccc3)c2)cc1 ; c1ccc(-c2ccc(N3c4cc(N(c5ccccc5)c5ccccc5)cc5c4B(c4c3cc3c6c4Oc4ccccc4B6c4ccccc4O3)c3c(cc4c6c3Sc3ccccc3B6c3ccccc3S4)N5c3ccc(-c4ccccc4)cc3-c3ccccc3)c(-c3ccccc3)c2)cc1]

Under Ar atmosphere, Intermediate 15J (7.9 g) was added to a 500 ml three-necked flask and was dissolved in o-dichlorobenzene (ODCB, 150 ml), the flask was cooled to about 0° C. in an ice bath, boron triiodide (BI₃, 14.6 g) was added, then the resultant mixture was heated and stirred at about 140° C. for about 6 hours, the flask was cooled to about 0° C. in an ice bath, and N,N-diisopropylethylamine (DIPEA, 25 ml) was added. After returning to a room temperature, a reaction solution was filtered through silica gel, and a filtrate solvent was removed by distillation under reduced pressure. The obtained crude product was purified through silica gel column chromatography to obtain 3.9 g of Compound 15 (yield of about 48%). A molecular weight of Compound 15, as measured by FAB-MS, was about 1308.

### (15) Synthesis of Compound 16

### Synthesis of Intermediate 16A

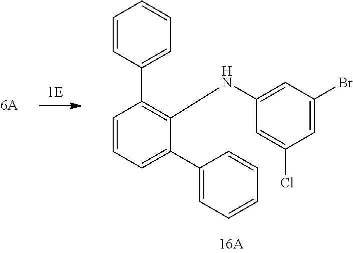 [SMILES: Clc1cc(Br)cc(Nc2c(-c3ccccc3)cccc2-c2ccccc2)c1]

Under Ar atmosphere, Intermediate 6A (19.4 g), Intermediate 1E (15 g), bis(dibenzylideneacetone)palladium(0) (Pd(dba)₂, 0.35 g), (±)-BINAP (0.76 g), sodium tert-butoxide (NaOtBu, 8.8 g), and toluene (300 ml) were added to a 1000 ml three-necked flask, and the resultant mixture was heated and stirred for about 12 hours at about 60° C. After returning to a room temperature, water was added, the mixture was subjected to extraction with toluene, combined organic layers were dried over MgSO₄, and then a solvent was removed by distillation under reduced pressure. The obtained product was purified through silica gel column chromatography to obtain 13.6 g of Intermediate 16A (yield of about 51%). A molecular weight of Intermediate 16A, as measured by FAB-MS, was about 434.

### Synthesis of Intermediate 16B

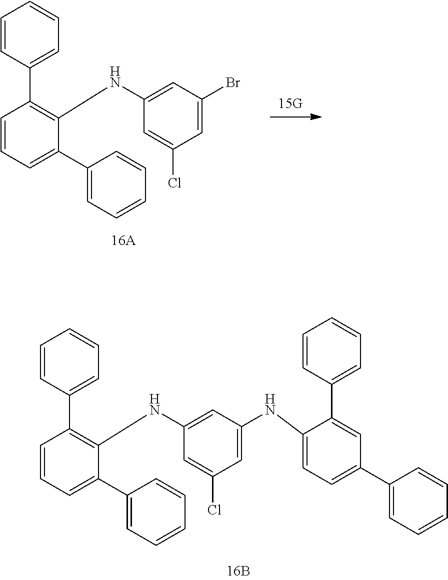 [SMILES: Clc1cc(Br)cc(Nc2c(-c3ccccc3)cccc2-c2ccccc2)c1 ; Clc1cc(Nc2ccc(-c3ccccc3)cc2-c2ccccc2)cc(Nc2c(-c3ccccc3)cccc2-c2ccccc2)c1]

Under Ar atmosphere, Intermediate 16A (13.6 g), Intermediate 15G (24.1 g), bis(dibenzylideneacetone)palladium(0) (Pd(dba)₂, 0.32 g), (±)-BINAP (0.69 g), sodium tert-butoxide (NaOtBu, 8 g), and toluene (300 ml) were added to a 1000 ml three-necked flask, and the resultant mixture was heated and stirred for about 12 hours at about 60° C. After returning to a room temperature, water was added, the mixture was subjected to extraction with toluene, combined organic layers were dried over MgSO₄, and then a solvent was removed by distillation under reduced pressure. The obtained product was purified through silica gel column chromatography to obtain 30.6 g of Intermediate 16B (yield of about 92%). A molecular weight of Intermediate 16B, as measured by FAB-MS, was about 599.

### Synthesis of Intermediate 16C

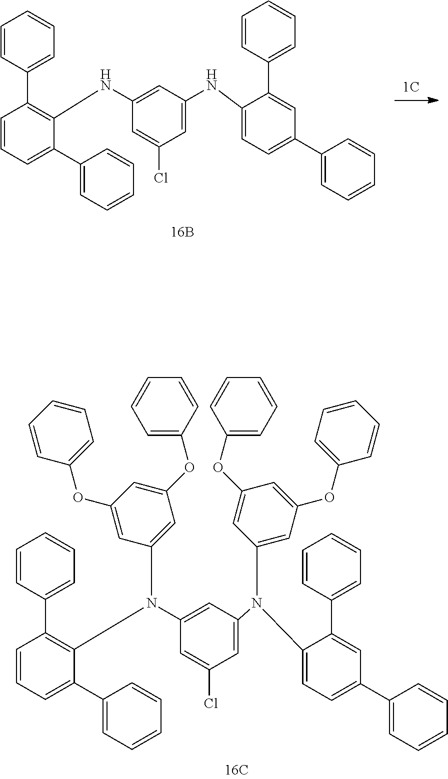 [SMILES: Clc1cc(Nc2ccc(-c3ccccc3)cc2-c2ccccc2)cc(Nc2c(-c3ccccc3)cccc2-c2ccccc2)c1 ; Clc1cc(N(c2cc(Oc3ccccc3)cc(Oc3ccccc3)c2)c2ccc(-c3ccccc3)cc2-c2ccccc2)cc(N(c2cc(Oc3ccccc3)cc(Oc3ccccc3)c2)c2c(-c3ccccc3)cccc2-c2ccccc2)c1]

Under Ar atmosphere, Intermediate 16B (20 g), Intermediate 1C (78 g), CuI (12.7 g), and K₂CO₃ (37 g) were added to a 500 ml three-necked flask, and the resultant mixture was heated and stirred for about 48 hours at about 230° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 17.2 g of Intermediate 16C (yield of about 46%). A molecular weight of Intermediate 16C, as measured by FAB-MS, was about 1120.

### Synthesis of Intermediate 16D

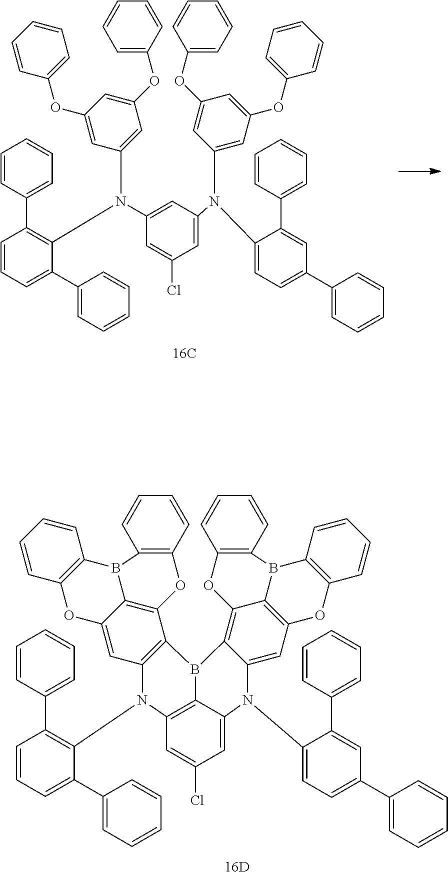 [SMILES: Clc1cc(N(c2cc(Oc3ccccc3)cc(Oc3ccccc3)c2)c2ccc(-c3ccccc3)cc2-c2ccccc2)cc(N(c2cc(Oc3ccccc3)cc(Oc3ccccc3)c2)c2c(-c3ccccc3)cccc2-c2ccccc2)c1 ; Clc1cc2c3c(c1)N(c1c(-c4ccccc4)cccc1-c1ccccc1)c1cc4c5c(c1B3c1c(cc3c6c1Oc1ccccc1B6c1ccccc1O3)N2c1ccc(-c2ccccc2)cc1-c1ccccc1)Oc1ccccc1B5c1ccccc1O4]

Under Ar atmosphere, Intermediate 16C (17.2 g) was added to a 1000 ml three-necked flask and was dissolved in o-dichlorobenzene (ODCB, 300 ml), the flask was cooled to about 0° C. in an ice bath, boron triiodide (BI₃, 36 g) was added, then the resultant mixture was heated and stirred at about 140° C. for about 6 hours, the flask was cooled to about 0° C. in an ice bath, and N,N-diisopropylethylamine (DIPEA, 60 ml) was added. After returning to a room temperature, a reaction solution was filtered through silica gel, and a filtrate solvent was removed by distillation under reduced pressure. The obtained crude product was purified through silica gel column chromatography to obtain 4 g of Intermediate 16D (yield of about 23%). A molecular weight of Intermediate 16D, as measured by FAB-MS, was about 1143.

### Synthesis of Compound 16

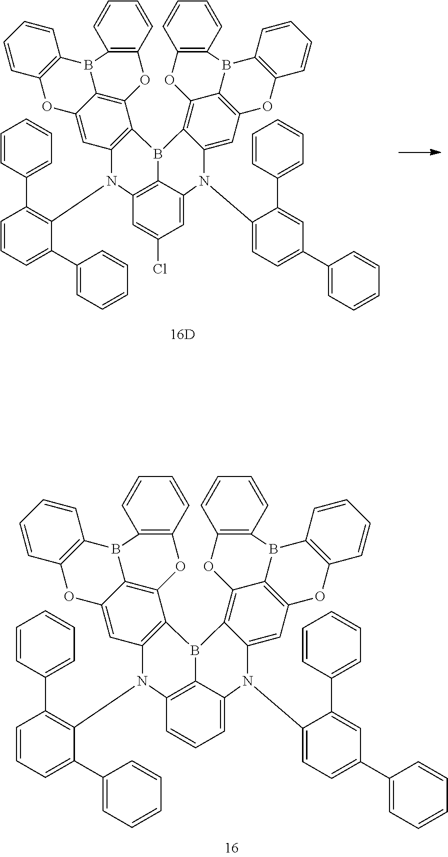 [SMILES: Clc1cc2c3c(c1)N(c1c(-c4ccccc4)cccc1-c1ccccc1)c1cc4c5c(c1B3c1c(cc3c6c1Oc1ccccc1B6c1ccccc1O3)N2c1ccc(-c2ccccc2)cc1-c1ccccc1)Oc1ccccc1B5c1ccccc1O4 ; c1ccc(-c2ccc(N3c4cccc5c4B(c4c3cc3c6c4Oc4ccccc4B6c4ccccc4O3)c3c(cc4c6c3Oc3ccccc3B6c3ccccc3O4)N5c3c(-c4ccccc4)cccc3-c3ccccc3)c(-c3ccccc3)c2)cc1]

Under Ar atmosphere, Intermediate 16D (4 g), 2-biphenylboronic acid (2.1 g), palladium(II) acetate (Pd(OAc)₂, 0.16 g), 2-dicyclohexylphosphino-2′,6′-dimethoxybiphenyl (SPhos, 0.57 g), K₃PO₄ (2.2 g), and toluene (60 ml) were added to a 200 ml three-necked flask, and the resultant mixture was heated and stirred for about 24 hours at about 110° C. After returning to a room temperature, water was added, the mixture was subjected to extraction with CH₂Cl₂, combined organic layers were dried over MgSO₄, and then a solvent was removed by distillation under reduced pressure. The obtained product was purified through silica gel column chromatography to obtain 0.7 g of Compound 16 (yield of about 18%). A molecular weight of Compound 16, as measured by FAB-MS, was about 1109.

### 2. Manufacture and Evaluation of Light-Emitting Element

The light-emitting elements including the fused polycyclic compounds according to Examples or Comparative Example Compounds in the emission layer, respectively, were manufactured by the following method. The light-emitting elements according to Examples 1 to 15 were manufactured respectively using the fused polycyclic compounds, Compounds 1 to 12, and 14 to 16, which are the above-described compounds according to Examples, as a dopant material of the emission layer. The light-emitting elements according to Comparative Examples 1 to 9 correspond to the light-emitting elements manufactured using Comparative Example Compound X-1 to Comparative Example Compound X-9 as a dopant material of the emission layer.

### Example Compounds

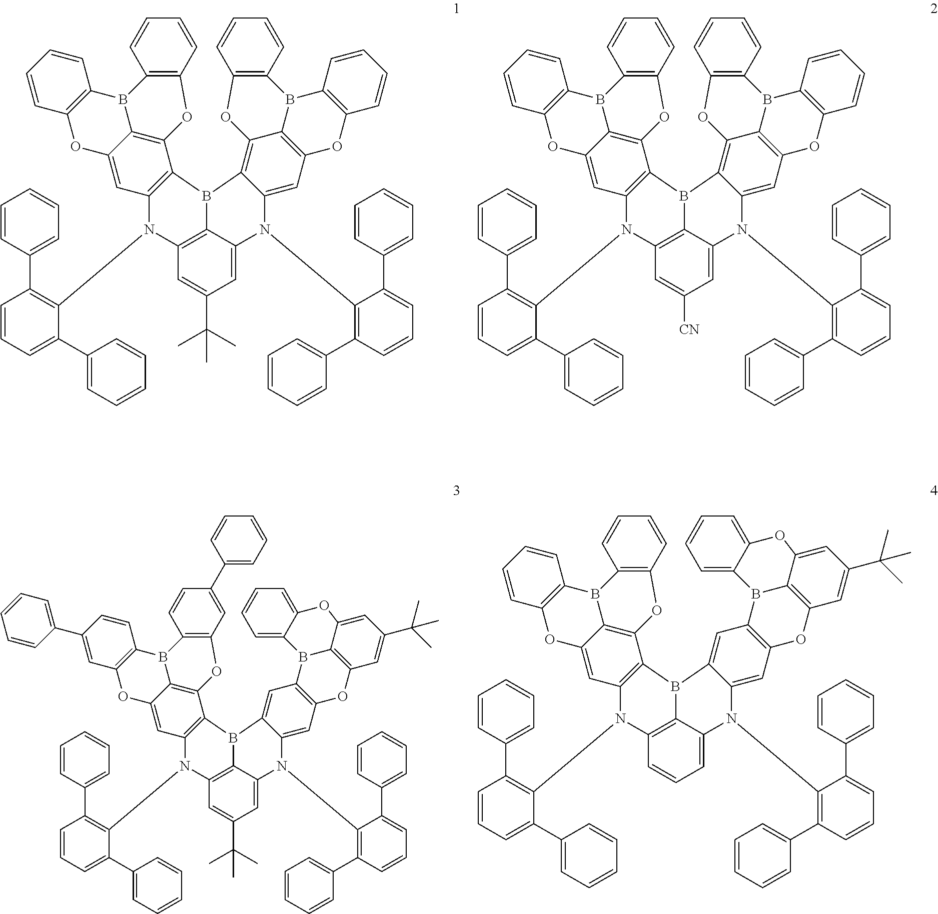

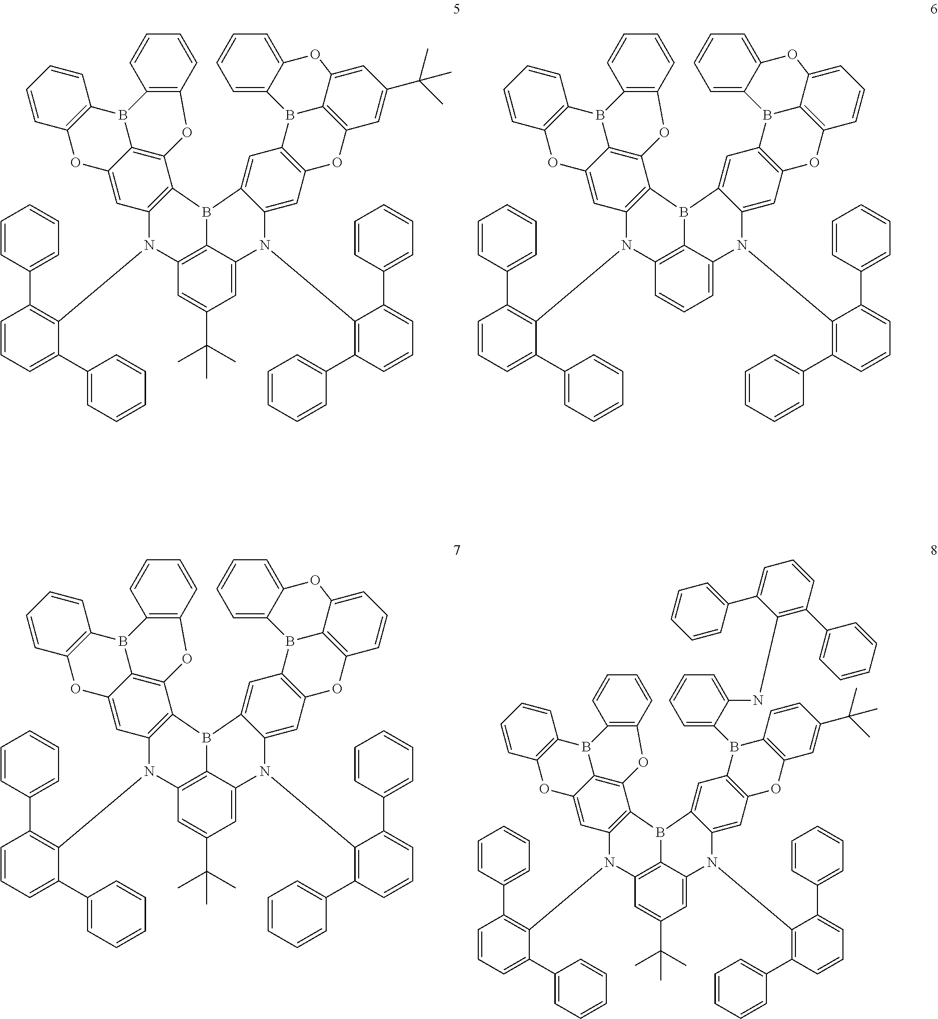

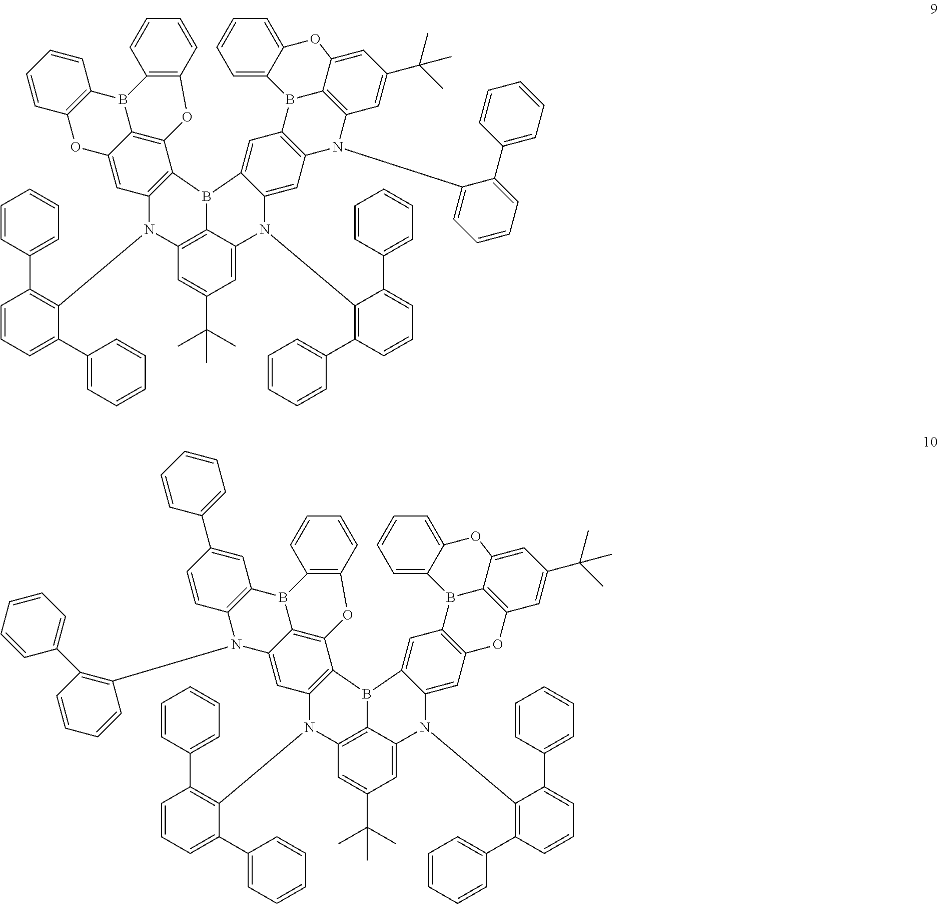 [SMILES: CC(C)(C)c1cc2c3c(c1)N(c1ccccc1-c1ccccc1)c1cc4c(cc1B3c1ccccc1O2)B1c2c(cc(C(C)(C)C)cc2N(c2c(-c3ccccc3)cccc2-c2ccccc2)c2cc3c5c(c21)Oc1ccccc1B5c1ccccc1O3)N4c1c(-c2ccccc2)cccc1-c1ccccc1 ; CC(C)(C)c1cc2c3c(c1)Oc1cc4c(cc1B3c1ccccc1O2)B1c2c(cc(C(C)(C)C)cc2N(c2c(-c3ccccc3)cccc2-c2ccccc2)c2cc3c5c(c21)Oc1ccccc1B5c1cc(-c2ccccc2)ccc1N3c1ccccc1-c1ccccc1)N4c1c(-c2ccccc2)cccc1-c1ccccc1]

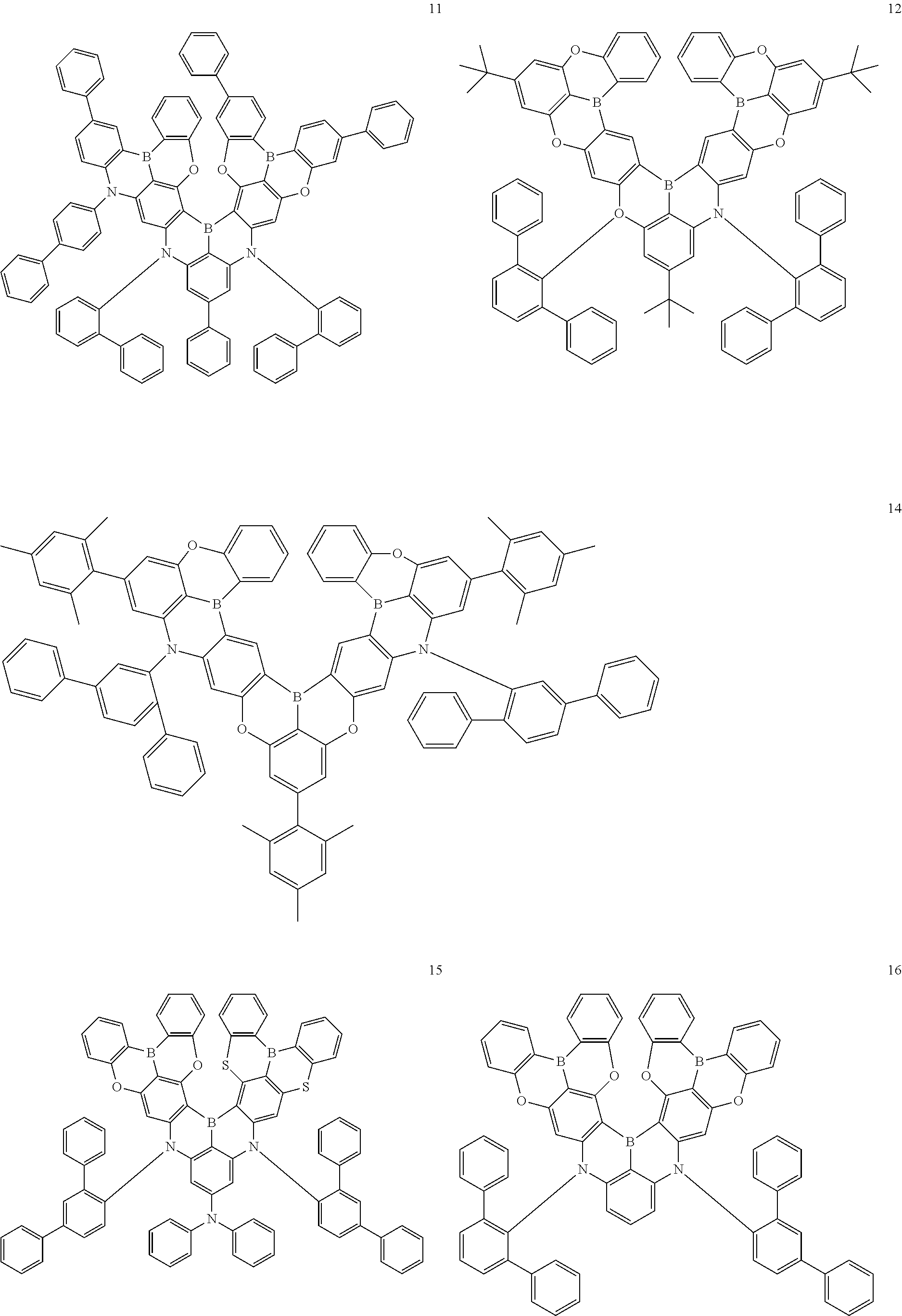

### Comparative Example Compounds

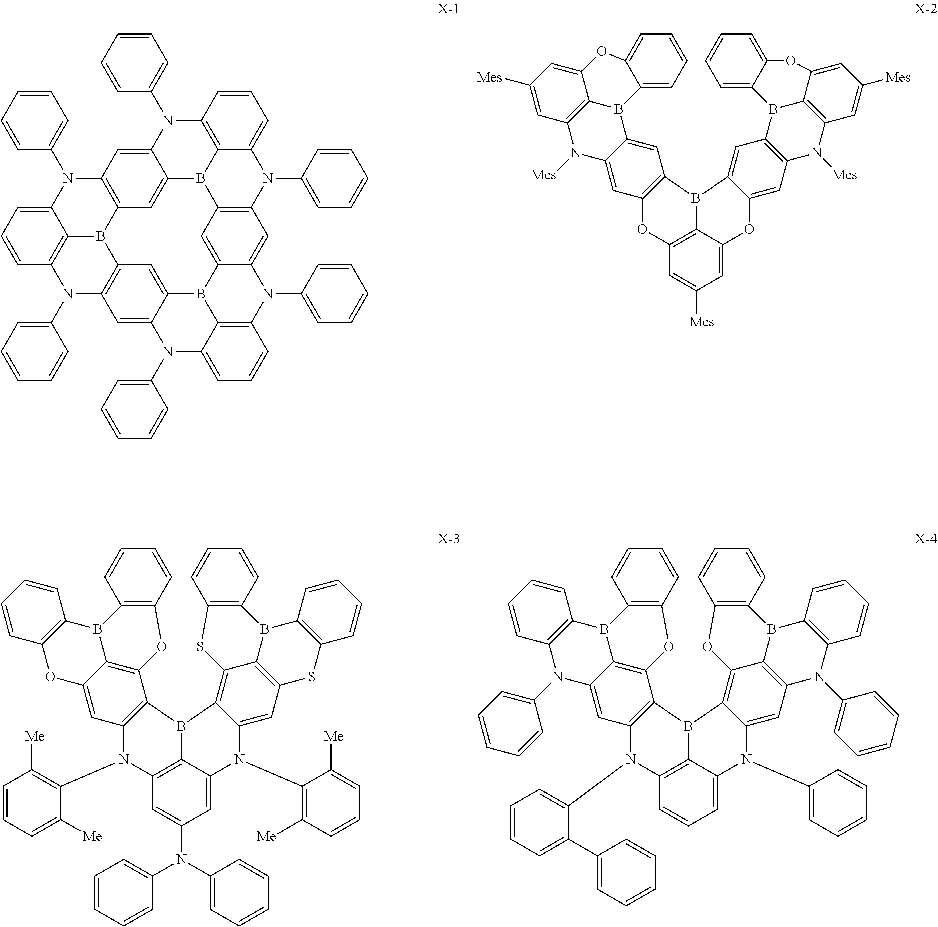

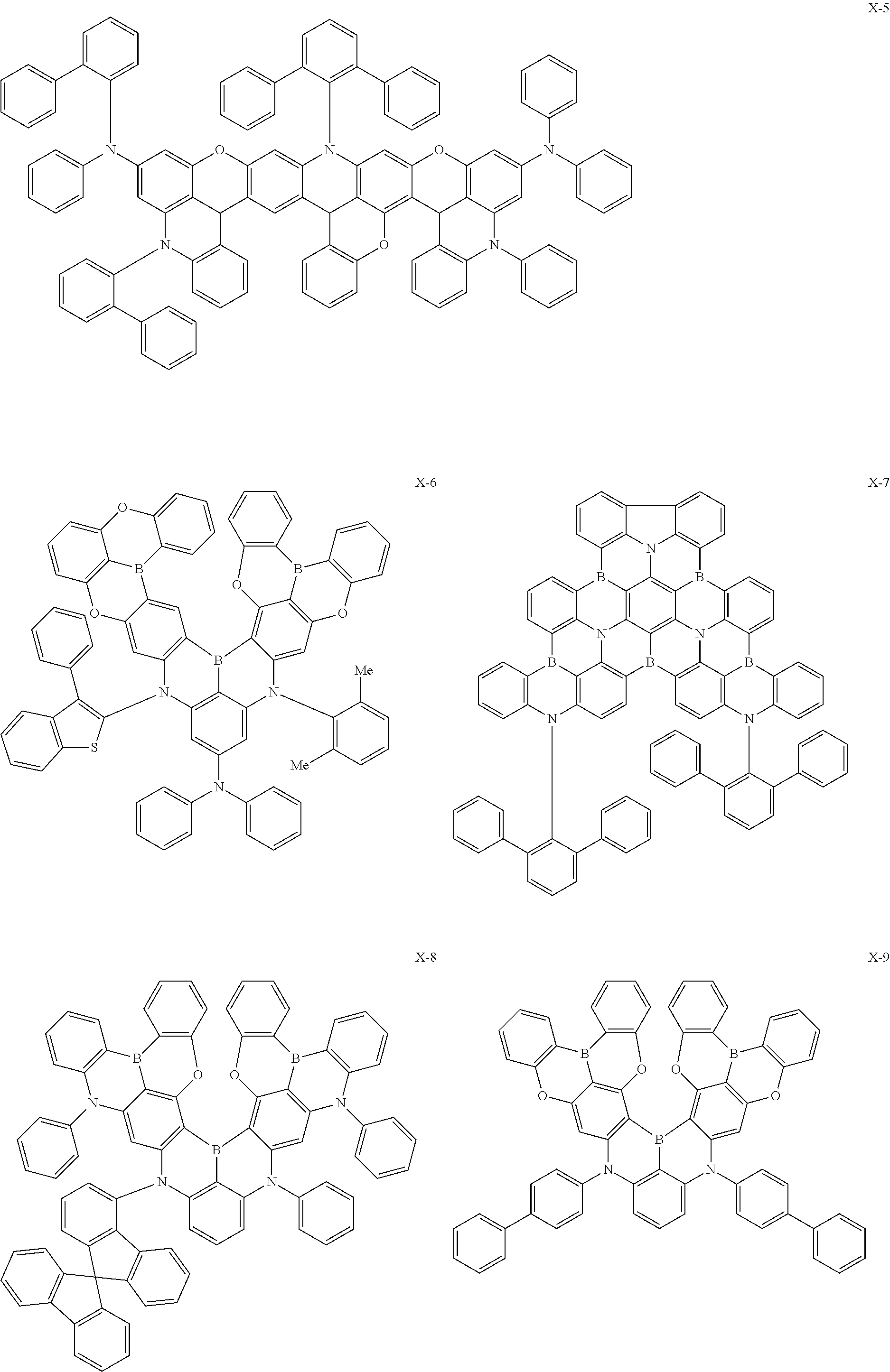

In Comparative Example Compound, “Mes” refers to an unsubstituted mesityl group (2,4,6-trimethylphenyl group), and “Me” refers to an unsubstituted methyl group.

### (Manufacture of Light-Emitting Element)

A first electrode having a thickness of about 150 nm was formed of ITO, a hole injection layer having a thickness of about 10 nm was formed of dipyrazino[2,3-f. 2′,3′-h]quinox aline-2,3,6,7,10,11-hexacarbonitrile (HATCN) on the first electrode, a hole transport layer having a thickness of about 80 nm was formed of N,N′-di(1-naphthyl)-N,N′-diphenyl-(1,1′-biphenyl)-4,4″-diamine (NPD) on the hole injection layer, an emission auxiliary layer having a thickness of about 5 nm was formed of 1,3-bis(N-carbazolyl)benzene (mCP) on the hole transport layer, an emission layer having a thickness of about 20 nm, doped with about 1% of Example Compound or Comparative Example Compound, was formed of 3,3′-di(9H-carbazol-9-yl)-1,1′-biphenyl (mCBP) on the emission auxiliary layer, an electron transport layer having a thickness of about 30 nm was formed of 2,2′,2″-(1,3,5-benzinetriyl)-tris(1-phenyl-1-H-benzimidazole) (TPBi) on the emission layer, an electron injection layer having a thickness of about 0.5 nm was formed of LiF on the electron transport layer, and a second electrode having a thickness of about 300 nm was formed of Al on the electron injection layer. Each layer was formed by a deposition method under vacuum atmosphere.

The compounds used in manufacture of the above-described light-emitting elements according to Examples and Comparative Examples are disclosed below. The materials below are known materials, and materials obtained by sublimation and purification of commercially available products were used in the manufacture of the elements.

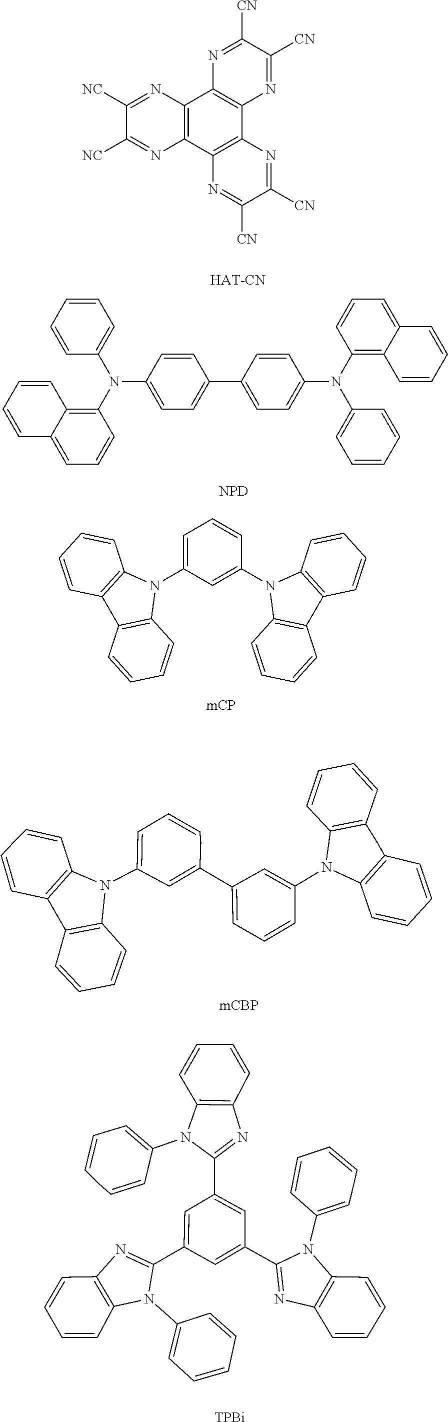

### (Evaluation of Characteristics of Light-Emitting Element)

The light-emitting elements according to Example 1 to Example 15, and Comparative Example 1 to Comparative Example 9 were evaluated and the results are listed in Table 1. In Table 1, relative lifespans (LT₅₀) of the manufactured light-emitting elements listed by comparing. Luminance half-life was evaluated from an initial luminance of about 900 cd/m² and the evaluation value is listed as the relative lifespan. The relative lifespan was expressed on the basis of the result of the light-emitting element according to Comparative Example 9.

TABLE 1

| Examples of element | | Relative element |
|---|---|---|
| manufacture | Dopant | lifespan LT₅₀ |
| Example 1 | Compound 1 | 1.8 |
| Example 2 | Compound 2 | 1.7 |
| Example 3 | Compound 3 | 1.7 |
| Example 4 | Compound 4 | 1.7 |
| Example 5 | Compound 5 | 1.8 |
| Example 6 | Compound 6 | 1.8 |
| Example 7 | Compound 7 | 1.9 |
| Example 8 | Compound 8 | 2.0 |
| Example 9 | Compound 9 | 1.7 |
| Example 10 | Compound 10 | 1.6 |
| Example 11 | Compound 11 | 1.7 |
| Example 12 | Compound 12 | 1.6 |
| Example 13 | Compound 14 | 2.0 |
| Example 14 | Compound 15 | 1.7 |
| Example 15 | Compound 16 | 1.6 |
| Comparative Example 1 | Comparative Example | 0.1 |
| | Compound X-1 | |
| Comparative Example 2 | Comparative Example | 0.6 |
| | Compound X-2 | |
| Comparative Example 3 | Comparative Example | 0.8 |
| | Compound X-3 | |
| Comparative Example 4 | Comparative Example | 0.7 |
| | Compound X-4 | |
| Comparative Example 5 | Comparative Example | 0.1 |
| | Compound X-5 | |
| Comparative Example 6 | Comparative Example | 0.6 |
| | Compound X-6 | |
| Comparative Example 7 | Comparative Example | 0.1 |
| | Compound X-7 | |
| Comparative Example 8 | Comparative Example | 0.7 |
| | Compound X-8 | |
| Comparative Example 9 | Comparative Example | 1.0 |
| | Compound X-9 | |

Referring to the results in Table 1, it can be confirmed that the light-emitting elements according to Examples using, as emission materials, the fused polycyclic compounds according to some example embodiments of the inventive concepts have improved lifespan characteristics, compared to the light-emitting elements according to Comparative Examples. Compared to this, it can be confirmed that each of Comparative Example Compounds includes a fused skeleton including at least three boron atoms within a molecule, but, compared to Example Compounds, when Comparative Example Compound is applied to the light-emitting element, the element has lowered lifespan characteristics. As shown in the light-emitting elements according to Comparative Examples 1, 5, and 7, it can be confirmed that Comparative Example Compounds X-1, X-5, and X-7 respectively included in the light-emitting elements according to Comparative Examples 1, 5, and 7 differ from the fused polycyclic compound of the inventive concepts in a cross-linking position of a fused ring, and the light-emitting elements according to Comparative Examples have significantly lowered lifespan characteristics than the light-emitting elements according to Examples. Specifically, Comparative Example Compounds X-1 and X-7 have a form in which an additional cross-link is formed between adjacent fused rings. Therefore, delocalization of a highest occupied molecular orbital (HOMO) is caused, thereby prompting hole trapping and thus making it difficult to achieve long lifespan. On the contrary, it can be confirmed that, in the fused polycyclic compounds according to Examples, the first to third fused rings have a specific fused ring form, and thus longer lifespan than that of Comparative Example Compounds X-1, X-5, and X-7 may be achieved.

As shown in the light-emitting elements according to Comparative Examples 2 and 3, Comparative Example Compounds X-2 and X-3 respectively included in the light-emitting elements according to Comparative Examples 2 and 3, have a structure in which a methyl group is substituted at an ortho position with respect to a nitrogen atom, and thus a steric shielding effect is insufficient. Therefore, when Comparative Example Compounds X-2 and X-3 are applied to the elements, the light-emitting elements according to Comparative Examples 2 and 3 have lowered lifespan characteristics.

When the light-emitting element according to Comparative Example 2 is compared with the light-emitting element according to Example 13, Comparative Example Compound C-2 differs from Example Compound 14 in which a methyl group in place of a phenyl group is connected at an ortho position with respect to a nitrogen atom at a position of X³ The methyl group is significantly smaller than an aryl group such as a phenyl group, and thus it is difficult to achieve sufficient shielding effect. Therefore, it can be confirmed that Comparative Example Compound X-2 has lower stability than that of Example Compound 14, and when Comparative Example Compound X-2 is applied to the light-emitting element, lifespan of the light-emitting element is significantly lowered.

When the light-emitting element according to Comparative Example 3 is compared with the light-emitting element according to Example 14, Comparative Example Compound X-3 differs from Example Compound 15 only in that a methyl group in place of a phenyl group is connected at an ortho position with respect to a nitrogen atom at a position of X¹ or X². Since the methyl group is significantly smaller than an aryl group such as a phenyl group, it is difficult to achieve a sufficient shielding effect. Therefore, it can be confirmed that Comparative Example Compound X-3 has lowered molecular stability than Example Compound 15, and when Comparative Example Compound X-3 is applied to the light-emitting element, the light-emitting element has a significantly lowered lifespan.

As shown in the light-emitting element according to Comparative Example 4, Comparative Example Compound X-4 corresponds to a case where any one among X¹ and X² is represented by Formula 3, and any one among R²⁰ and R²⁴ in Formula 3 is not aryl group. Comparative Example Compound X-4 corresponds to a case where any one among X¹ and X² is represented by Formula 3, and only one among R²⁰ and R²⁴ in Formula 3 is a phenyl group. In Comparative Example Compound X-4, since only one phenyl group is present at an ortho position with respect to a nitrogen atom, a steric shielding effect on a fused skeleton decreases, and thus when Comparative Example Compound X-4 is applied to the light-emitting element, the light-emitting element according to Comparative Example 4 has lowered lifespan, compared to the light-emitting elements according to Examples.

As shown in the light-emitting elements according to Comparative Examples 6 and 8, Comparative Example Compounds X-6 and X-8 included in the light-emitting element according to Comparative Examples 6 and 8 correspond to cases where X¹ and X² in Formula 1 are represented by Formula 4 and Ar in Formula 4 is a fluorenyl group or a heteroaryl group. As Comparative Example Compounds X-6 and X-8, when the substituent corresponding to Ar is a fluorenyl group or a heteroaryl group, the hole trapping is prompted, and thus element deterioration may be caused. Therefore, it can be confirmed that the light-emitting elements according to Comparative Examples 6 and 8 containing Comparative Example Compounds X-6 and X-8, respectively, have lowered emission efficiency and element lifespan, compared to the light-emitting elements according to Examples. When X¹ and X² in the fused polycyclic compound of the inventive concepts are represented by Formula 4, the case where Ar in Formula 4 is a fluorenyl group or a heteroaryl group is excluded, and thus stabilization of the compound may be achieved.

As shown in the light-emitting element according to Comparative Example 9, Comparative Example Compound X-9 included in the light-emitting element according to Comparative Example 9 has, compared to Example Compounds, no substituent represented by Formula 3, and it can be confirmed that, the light-emitting element according to Comparative Example 9 has significantly lowered lifespan characteristics, compared to the light-emitting elements according to Examples. Comparative Example Compound X-9 includes a substituted phenyl group at a para-position with respect to a nitrogen atom and has lowered steric shielding effect on a fused skeleton, compared to Example Compounds. Therefore, Comparative Example Compound X-9 has lowered molecular stability, and when Comparative Example Compound X-9 is applied to the light-emitting element, the light-emitting element has lowered lifespan. On the contrary, Example Compound includes at least one Formula 3 and thus may exhibit an excellent shielding effect. When Comparative Example Compound X-9 is applied to an element, the light-emitting element has high stability.

The light-emitting element according to some example embodiments may exhibit improved element characteristics of long lifespan.

The fused polycyclic compound according to some example embodiments may contribute to improvements in long lifespan of the light-emitting element by being included in the emission layer of the light-emitting element.

The electronic apparatus according to some example embodiments may exhibit excellent display quality and improved reliability characteristics.

As described herein, any devices, systems, modules, portions, units, controllers, circuits, and/or portions thereof according to any of the example embodiments, and/or any portions thereof (including, without limitation, electronic apparatus EA, display module DM, processor PR, memory MR, power module PM, smartphone EA_1a, tablet PC EA_1b, laptop EA_1c, TV EA_1d, desk monitor EA_1e, smart glasses EA_2a, head mounted display EA_2b, smart watch EA_2c, an electronic device for a vehicle EA 3, vehicle AM, first to fourth electronic apparatus EA-1, EA-2, EA-3, and EA-4, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

In the above, description has been made with reference to some example embodiments of the inventive concepts, but those skilled or of ordinary skill in the art may understand that various modifications and changes may be made to the inventive concepts insofar as such modifications and changes do not depart from the spirit and technical scope of the inventive concepts set forth in the claims to be described later.

Therefore, the technical scope of the inventive concepts is not to be limited to the contents stated in the detailed description of the specification, but should be determined by the claims.

What is claimed is:

1. A light-emitting element, comprising:
a first electrode;
a second electrode on the first electrode; and
an emission layer between the first electrode and the second electrode, the emission layer including a first compound represented by Formula 1: 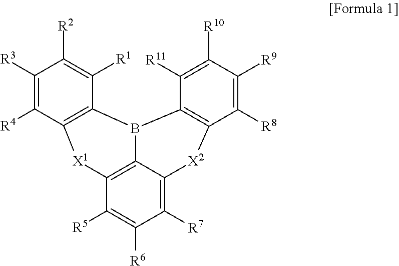
wherein, in Formula 1,
R¹ to R¹¹ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to each other to form a ring,
a continuous two or three selected from each of R¹ to R⁴ and R¹ to R¹¹ are each connected to a separate group represented by Formula 2, such that the first compound includes two separate groups that are each represented by Formula 2, one of the two separate groups is connected to a continuous two or three of R¹ to R⁴ of Formula 1, and another one of the two separate groups is connected to a continuous two or three of R⁸ to R¹¹ of Formula 1, and
X¹ and X² are each independently O, S, or Se, or represented by any one among Formula 3 to Formula 5: 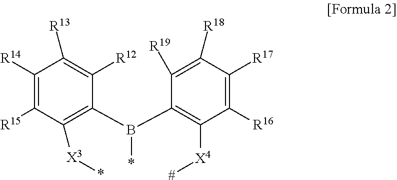
wherein, in Formula 2,
R¹² to R¹⁹ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to each other to form a ring,
X³ and X⁴ are each independently O, S, or Se, or represented by any one among Formula 3 to Formula 5, [symbol]
is a position to which Formula 1 is connected, and [symbol]
is a position to which Formula 1 is connected or R¹² in Formula 2 is connected: 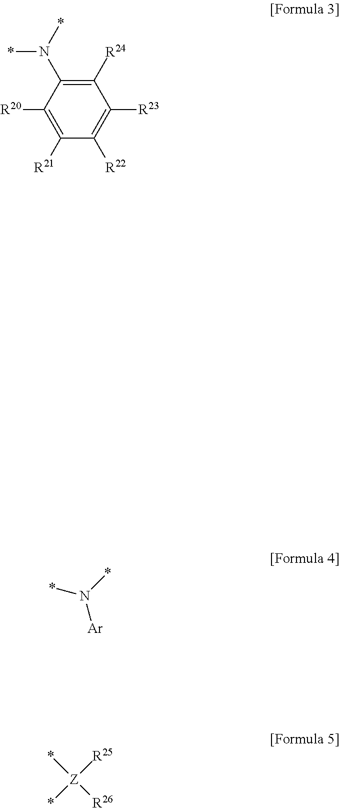
wherein, in Formula 3 to Formula 5, [symbol]
is a position to which Formula 1 or Formula 2 is connected,
R²⁰ to R²⁶ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
at least one among R²⁰ or R²⁴ is a substituted or unsubstituted aryl group having 6 to 30 ring-forming carbon atoms,
Ar is a substituted or unsubstituted aryl group having 10 to 30 ring-forming carbon atoms,
Z is a carbon atom or a silicon atom, wherein when Z is a silicon atom, R²⁵ and R²⁶ are not hydrogen atoms, and
at least one among X¹ to X⁴ is represented by Formula 3,
wherein, when X¹ and X² in Formula 1 are represented by Formula 4, Ar in Formula 4 is not a fluorenyl group or a heteroaryl group, and
wherein, when at least one of X¹ or X² in Formula 1 is represented by Formula 3, at least one of R²⁰ or R²⁴ in Formula 3 is a substituted or unsubstituted aryl group having 6 to 30 ring-forming carbon atoms.

2. The light-emitting element of claim 1, wherein
the emission layer includes a host and a dopant, and
the dopant includes a first compound represented by Formula 1.

3. The light-emitting element of claim 1, wherein, in Formula 1 and Formula 2, at least two among X¹ to X⁴ are represented by Formula 3 above.

4. The light-emitting element of claim 1, wherein Formula 3 is represented by Formula 3-1 or Formula 3-2: 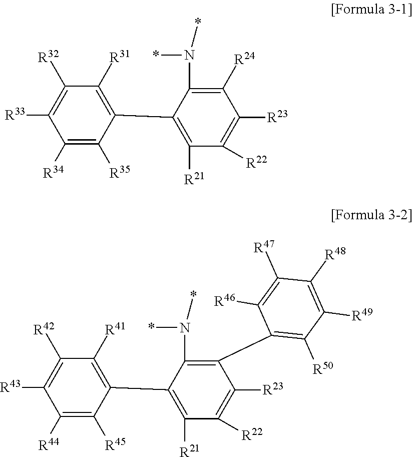
where, in Formula 3-1 and Formula 3-2, [symbol]
is a position at which Formula 2 or Formula 3 above is connected,
R³¹ to R³⁵, and R⁴¹ to R⁵⁰ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
R²¹ to R²⁴ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

5. The light-emitting element of claim 1, wherein the first compound represented by Formula 1 is represented by Formula 1-1-1 or Formula 1-1-2: 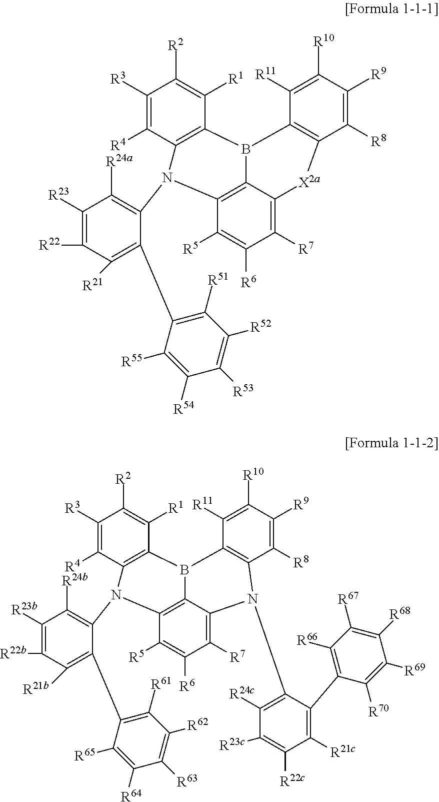
where in Formula 1-1-1 and Formula 1-1-2,
X^{2a} is O, S, or Se, or represented by Formula 4 or Formula 5,
R^{24a} is a substituted or unsubstituted aryl group having 6 to 30 ring-forming carbon atoms,
R⁵¹ to R⁵⁵, R⁶¹ to R⁷⁰, R^{21b} to R^{24b}, and R^{21c} to R^{24c} are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
R¹ to R¹¹ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to each other to form a ring.

6. The light-emitting element of claim 1, wherein the first compound represented by Formula 1 is represented by Formula 1-2: 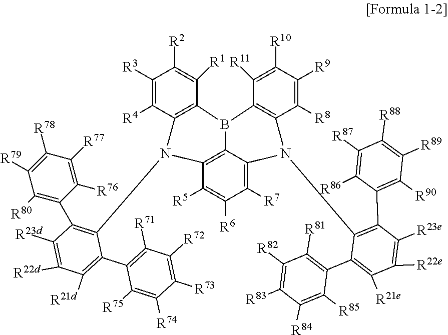
where in Formula 1-2,
R⁷¹ to R⁹⁰, R^{21d} to R^{23d}, and R^{21e} to R^{23e} are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
R¹ to R¹¹ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to each other to form a ring.

7. The light-emitting element of claim 1, wherein the first compound represented by Formula 1 is represented by any one among Formula 1-3-1 to Formula 1-3-3: 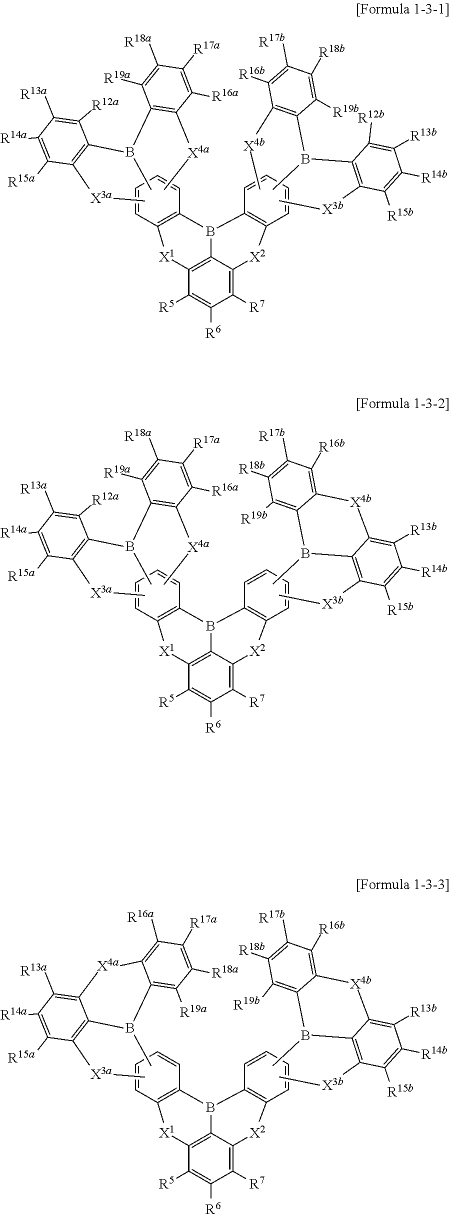
wherein, in Formula 1-3-1 to Formula 1-3-3,
X^{3a}, X^{3b}, X^{4a}, and X^{4b} are each independently O, S, or Se, or represented by any one among Formula 3 to Formula 5 above,
R^{12a} to R^{19a}, and R^{12b} to R^{19b} are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
X¹ and X² are each independently O, S, or Se, or represented by any one among Formula 3 to Formula 5, and
R⁵ to R⁷ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to each other to form a ring.

8. The light-emitting element of claim 1, wherein the first compound represented by Formula 1 is represented by any one among Formula 1-4-1 to Formula 1-4-3 below: 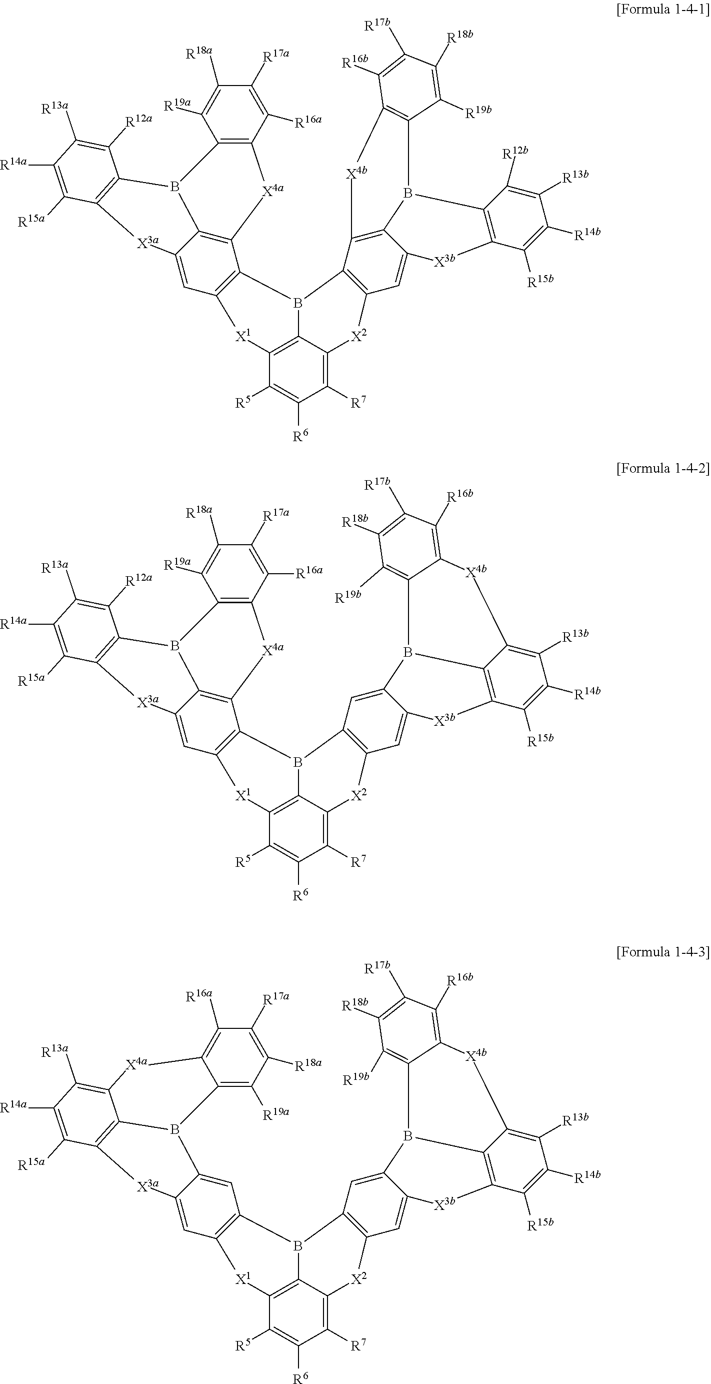
wherein, in Formula 1-4-1 to Formula 1-4-3,
X^{3a}, X^{3b}, X^{4a}, and X^{4b} are each independently O, S, or Se, or represented by any one among Formula 3 to Formula 5 above,
R^{12a} to R^{19a}, and R^{12b} to R^{19b} are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
X¹ and X² are each independently O, S, or Se, or represented by any one among Formula 3 to Formula 5, and
R⁵ to R⁷ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to each other to form a ring.

9. The light-emitting element of claim 1, wherein the emission layer further includes at least one among a second compound represented by Formula HT-1, a third compound represented by Formula ET-1, or a fourth compound represented by Formula D-1: 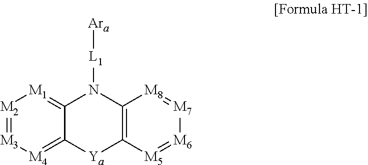
wherein, in Formula HT-1,
M₁ to M₈ are each independently N or CR₅₁,
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, CR₅₂R₅₃, or SiR₅₄R₅₅,
Arₐ is a substituted or unsubstituted aryl group having 6 to 30 ring-forming carbon atoms, or a substituted or unsubstituted heteroaryl group having 2 to 30 ring-forming carbon atoms, and
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to each other to form a ring; 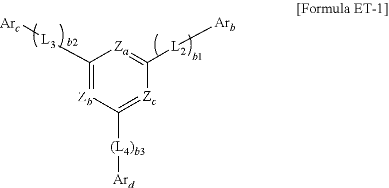
wherein, in Formula ET-1,
at least one among Zₐ to Z_{c} is N, and a remainder of Zₐ to Z_{c} are each CR₅₆,
R₅₆ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
b1 to b3 are each independently an integer of 0 to 10,
Ar_{b} to Ar_{d} are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms; 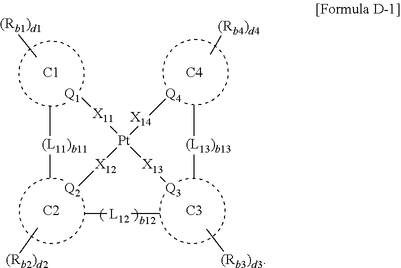
wherein, in Formula D-1,
Q₁ to Q4 are each independently C or N,
C1 to C4 are each independently a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle having 2 to 30 ring-forming carbon atoms,
X₁₁ to X₁₄ are each independently a direct linkage, or [symbol] ,
L₁₁ to L₁₃ are each independently, a direct linkage, 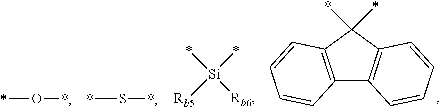
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b11 to b13 are each independently 0 or 1,
R_{b1} to R_{b4} are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and
d1 to d4 are each independently an integer of 0 to 4.

10. The light-emitting element of claim 1, wherein the first compound represented by Formula 1 includes at least one among Compounds 1 to 51 in Compound Group 1:

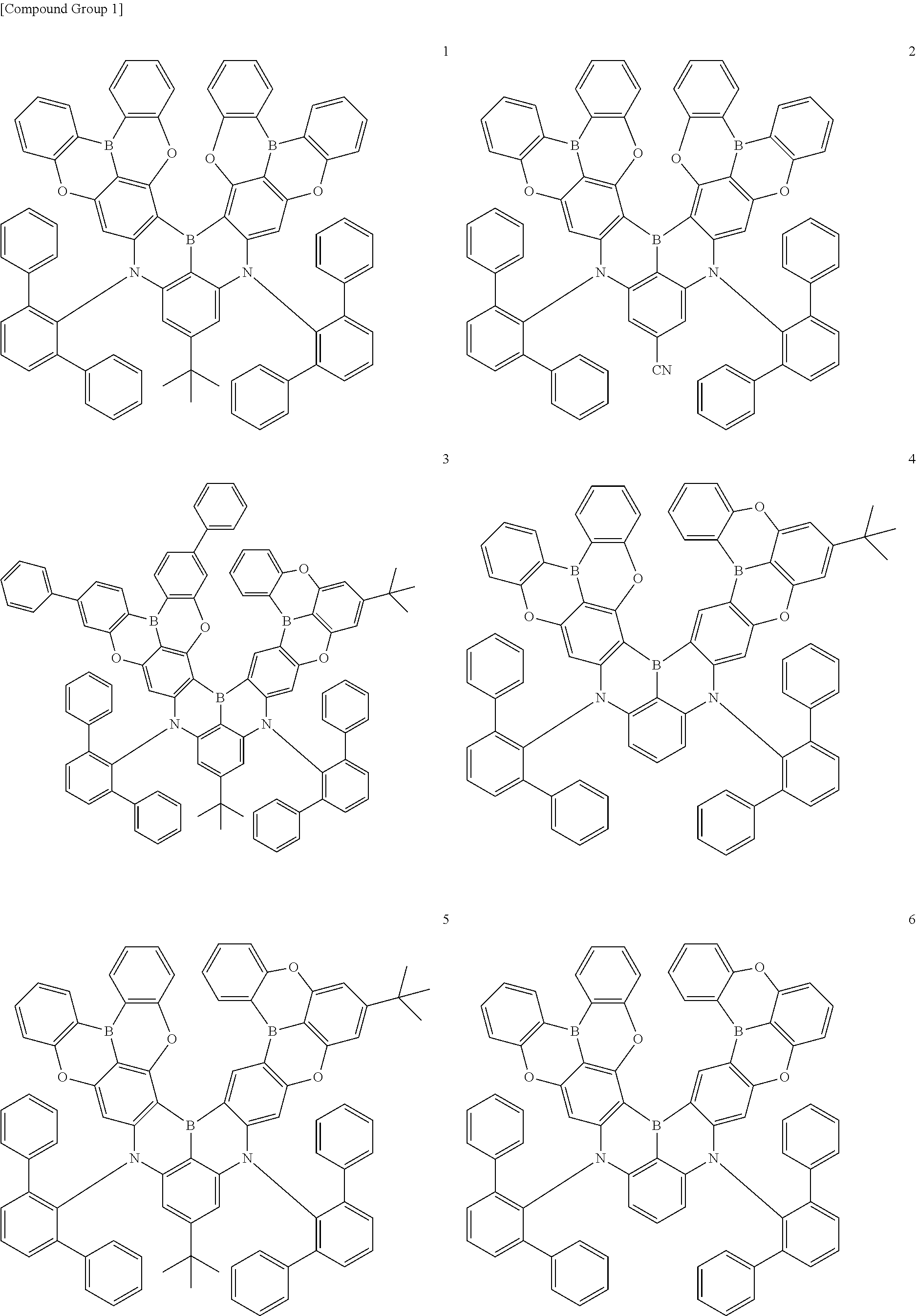

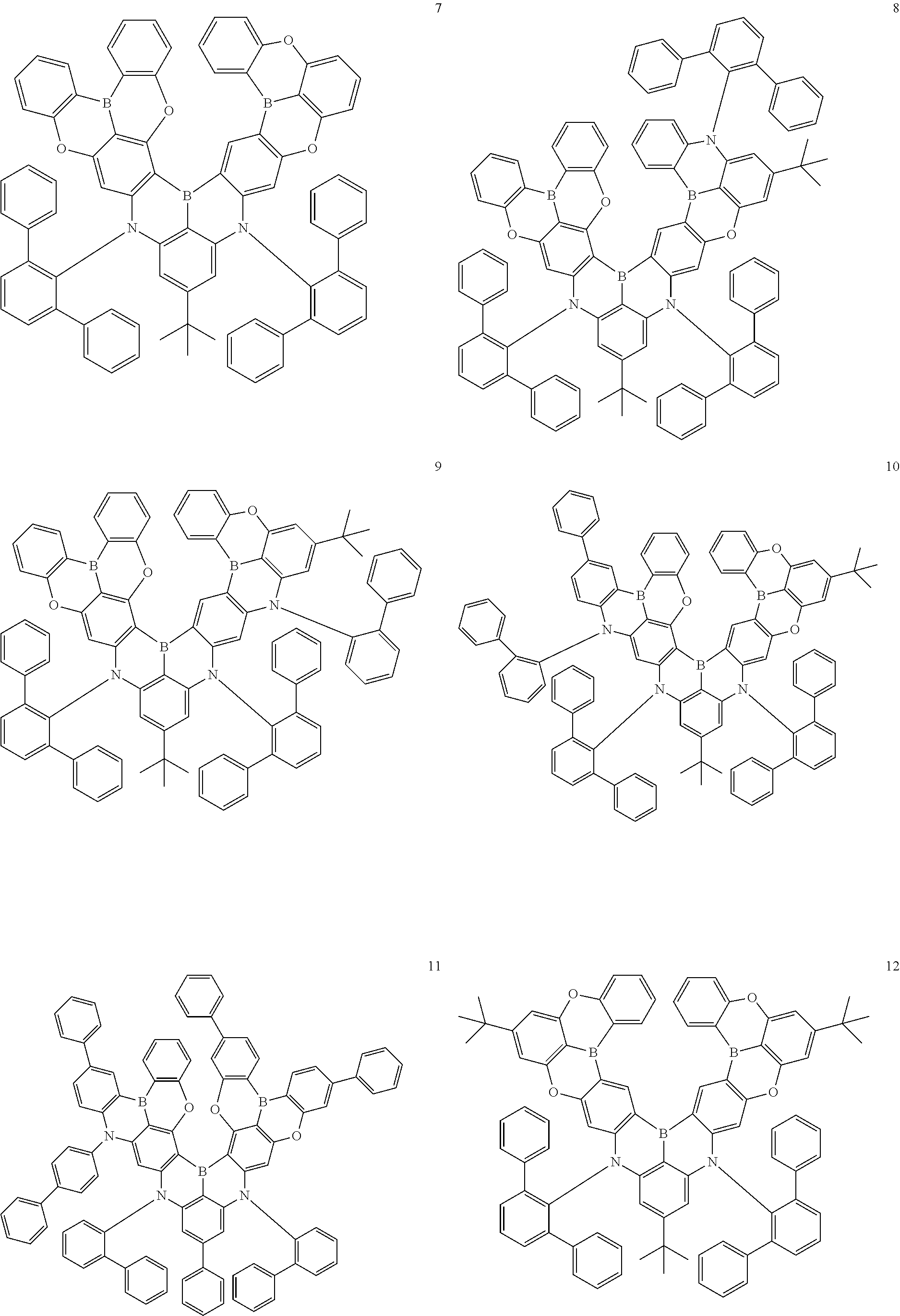

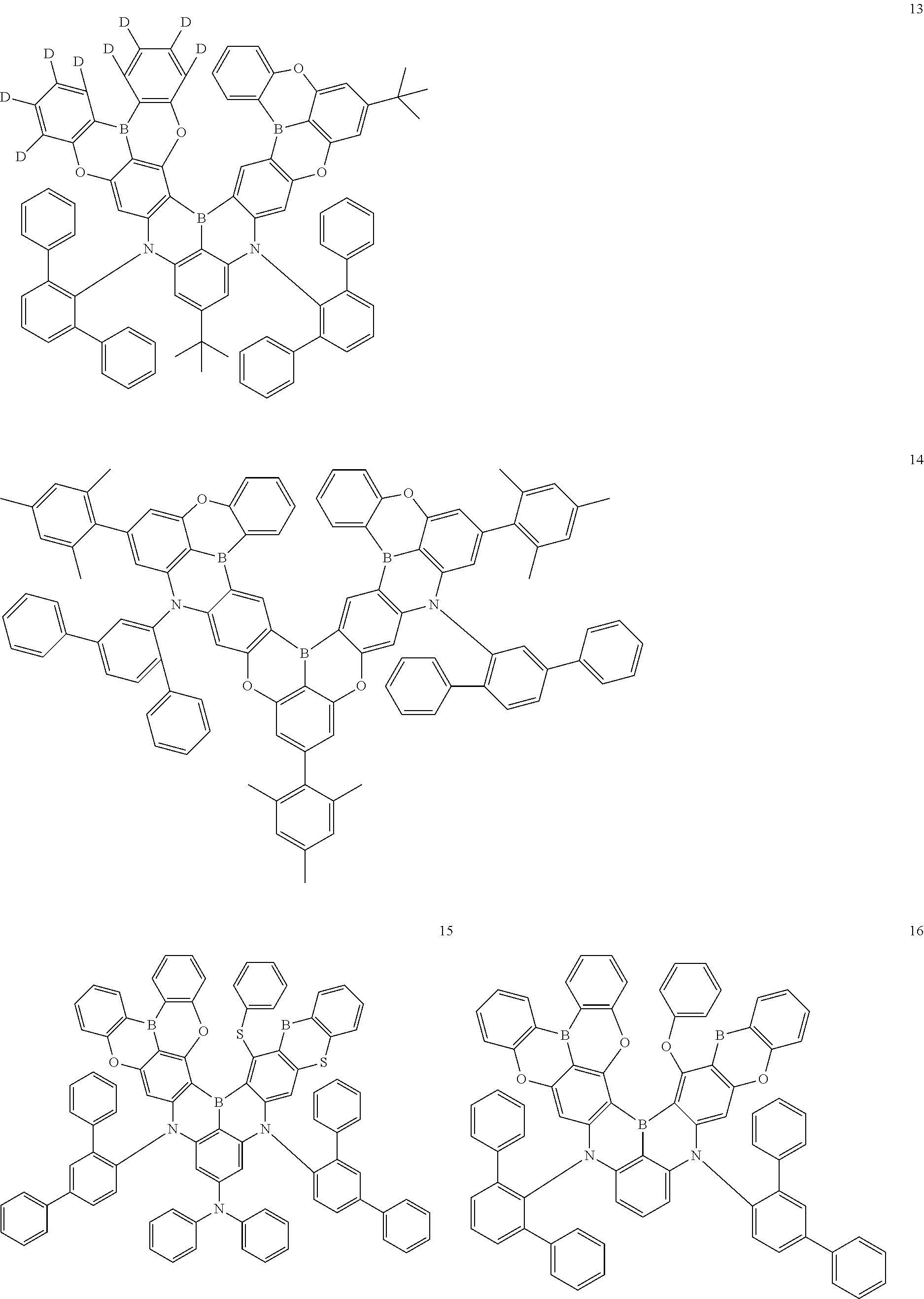

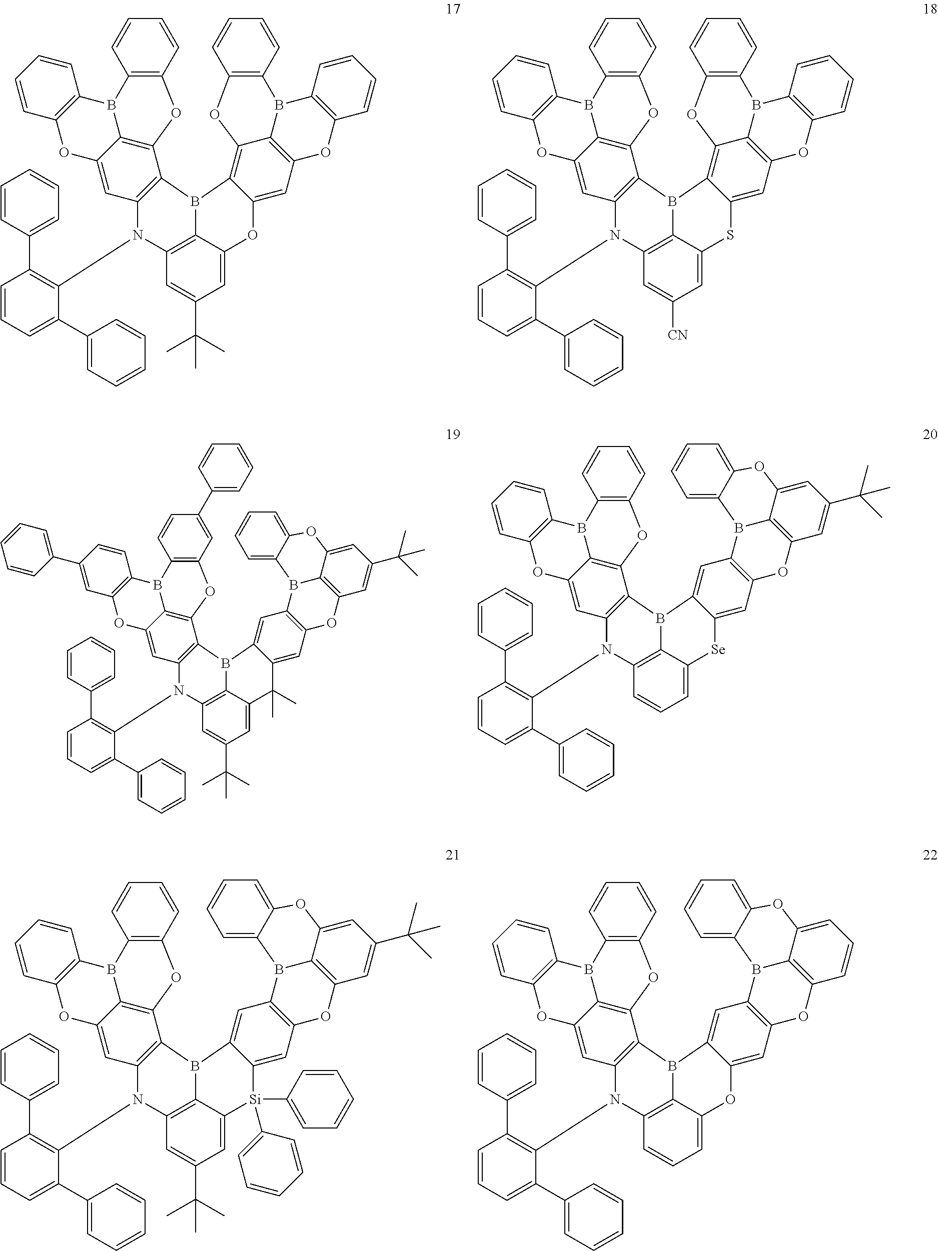

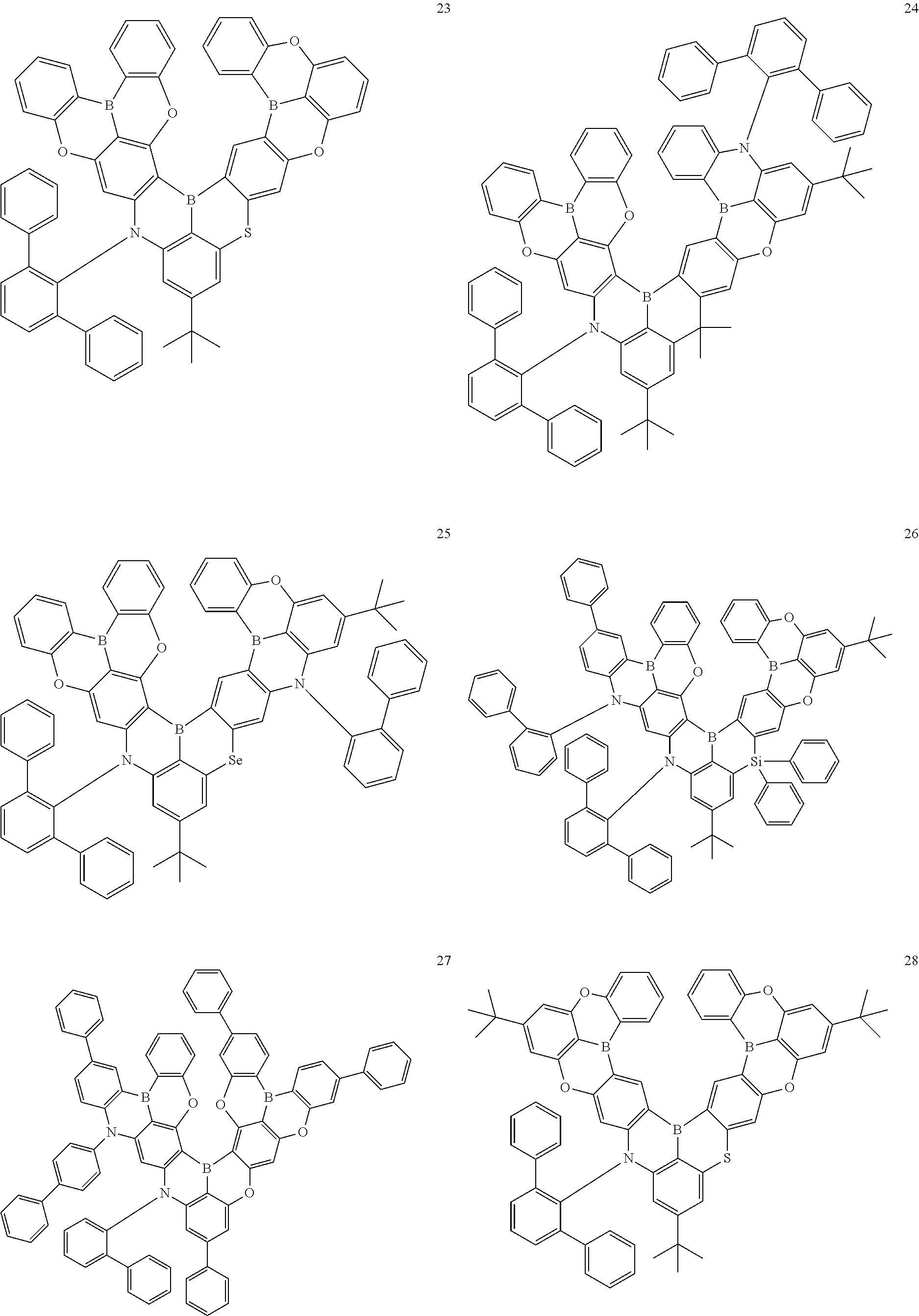

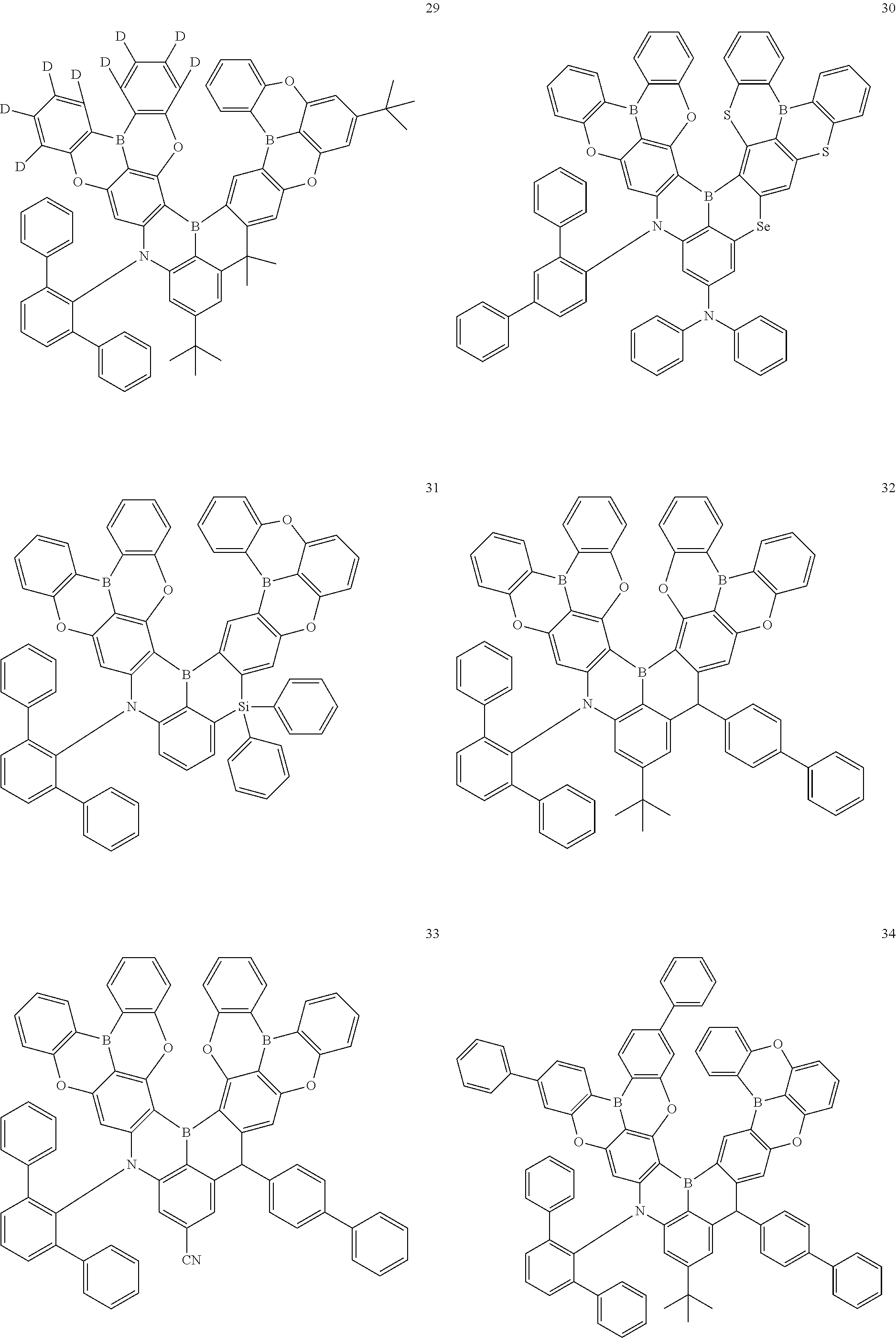

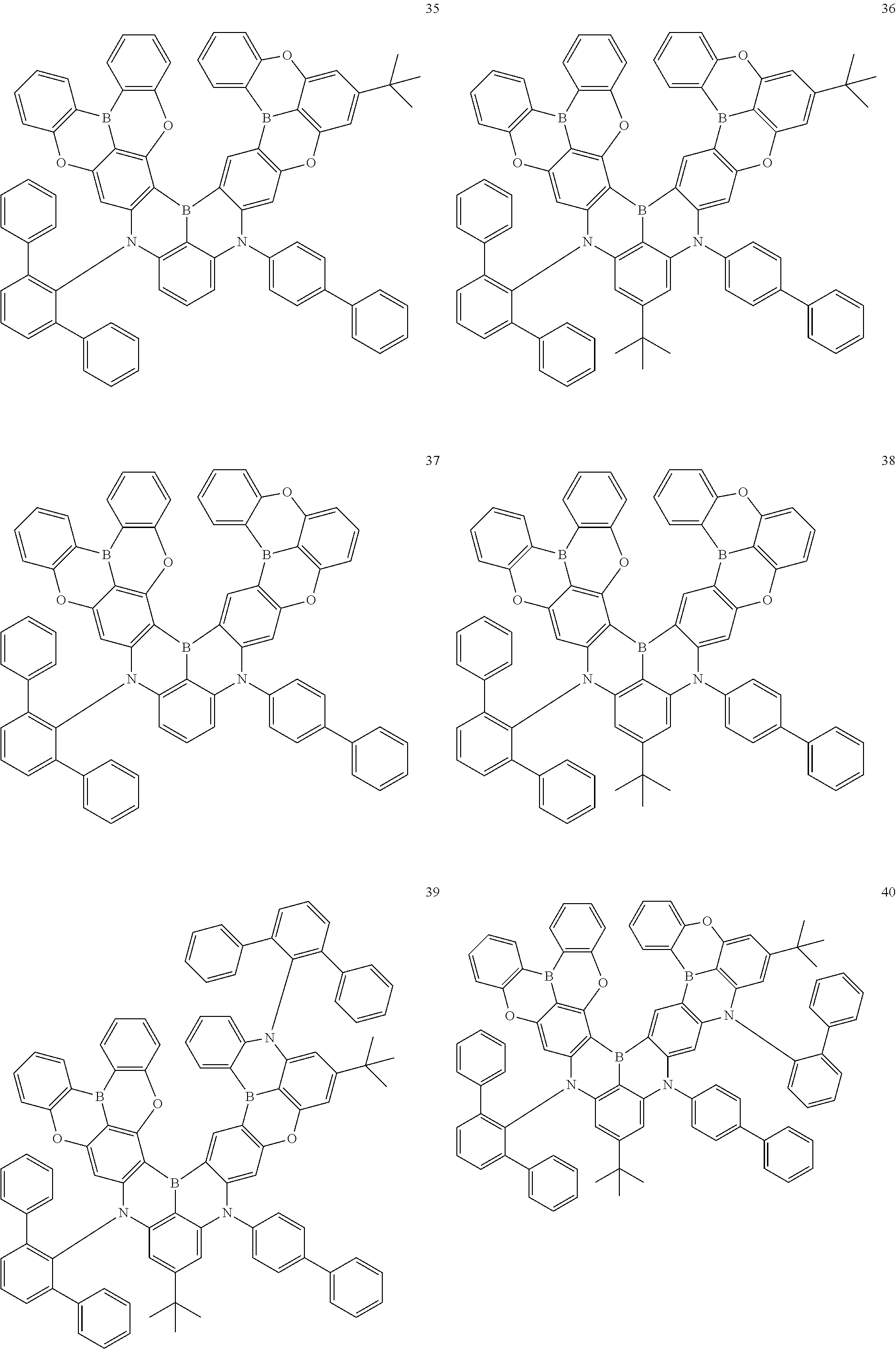

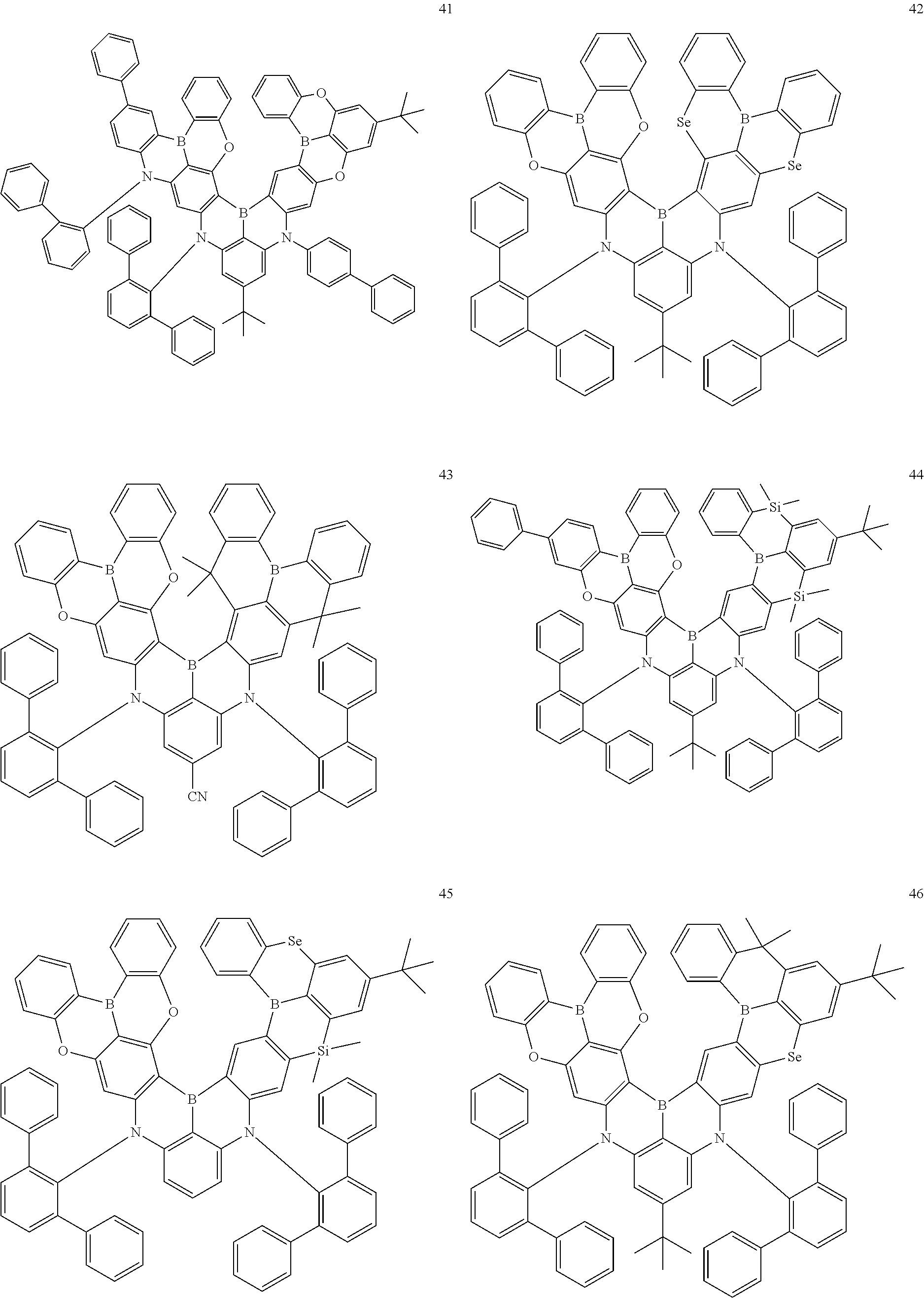

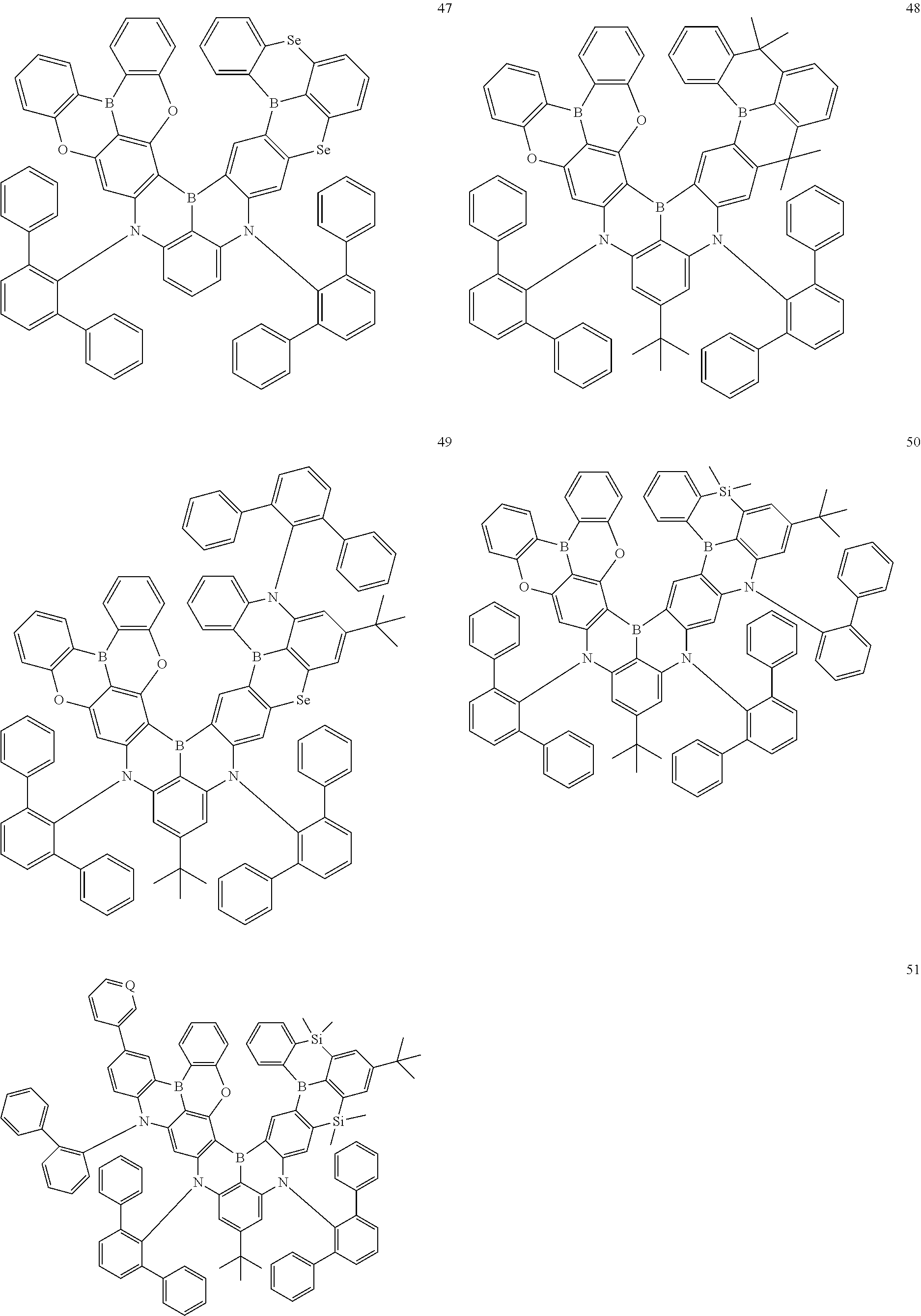

11. An electronic apparatus, comprising:
a base layer;
a circuit layer on the base layer; and
a display element layer on the circuit layer, the display element layer including a light-emitting element,
wherein the light-emitting element includes a first electrode, a second electrode on the first electrode, and an emission layer between the first electrode and the second electrode, the emission layer including a first compound represented by Formula 1: 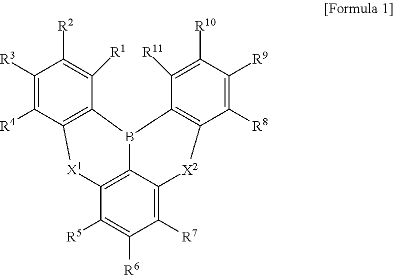
wherein, in Formula 1,
R¹ to R¹¹ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to each other to form a ring,
a continuous two or three selected from each of R¹ to R⁴, and R¹ to R¹¹ are each connected to a separate group represented by Formula 2, such that the first compound includes two separate groups that are each represented by Formula 2, one of the two separate groups is connected to a continuous two or three of R¹ to R⁴ of Formula 1, and another one of the two separate groups is connected to a continuous two or three of R⁸ to R¹¹ of Formula 1, and
X¹ and X² are each independently O, S, or Se, or represented by any one among Formula 3 to Formula 5: 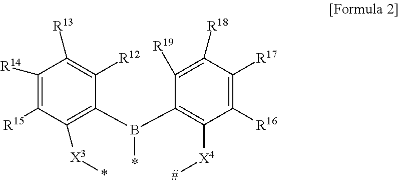
wherein, in Formula 2,
R¹² to R¹⁹ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to each other to form a ring,
X³ and X⁴ are each independently O, S, or Se, or represented by any one among Formula 3 to Formula 5, [symbol]
is a position to which Formula 1 is connected, and [symbol]
is a position to which Formula 1 is connected or R¹² in Formula 2 is connected: 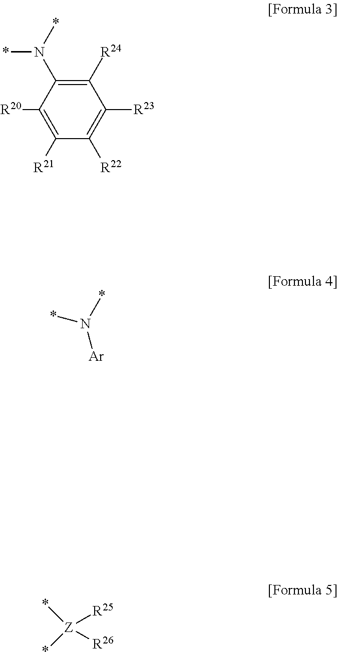
wherein, in Formula 3 to Formula 5, [symbol]
is a position to which Formula 2 or Formula 3 is connected,
R²⁰ to R²⁶ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
at least one among R²⁰ or R²⁴ is a substituted or unsubstituted aryl group having 6 to 30 ring-forming carbon atoms,
Ar is a substituted or unsubstituted aryl group having 10 to 30 ring-forming carbon atoms,
Z is a carbon atom or a silicon atom, wherein when Z is a silicon atom, R²⁵ and R²⁶ are not hydrogen atoms, and
at least one among X¹ to X⁴ is represented by Formula 3,
when X¹ and X² in Formula 1 are represented by Formula 4, Ar in Formula 4 is not a fluorenyl group or a heteroaryl group, and
when at least one of X¹ or X² in Formula 1 is represented by Formula 3, at least one of R²⁰ or R²⁴ in Formula 3 is a substituted or unsubstituted aryl group having 6 to 30 ring-forming carbon atoms.

12. The electronic apparatus of claim 11, wherein
the light-emitting element further comprises a capping layer on the second electrode, and
the capping layer has a refractive index of about 1.6 or greater for light with a wavelength in a range of about 550 nm to about 660 nm.

13. The electronic apparatus of claim 11, further comprising an optical control layer on the display element layer, the optical control layer including quantum dots,
wherein the light-emitting element is configured to emit first color light,
wherein the optical control layer includes:
a first optical control part, the first optical control part including a first quantum dot configured to convert the first color light into a second color light in a longer wavelength region than the first color light;
a second optical control part, the second optical control part including a second quantum dot configured to convert the first color light into a third color light in a longer wavelength region than the first color light and the second color light; and
a third optical control part, the third optical control part configured to transmit the first color light.

14. The electronic apparatus of claim 13, further comprising a color filter layer on the optical control layer,
wherein the color filter layer includes:
a first color filter configured to selectively transmit the second color light;
a second color filter configured to selectively transmit the third color light; and
a third color filter configured to selectively transmit the first color light.

15. The electronic apparatus of claim 11, wherein the electronic apparatus is selected from:
a large-sized display device, the large-sized display device including at least one of a television, a monitor, or an outdoor billboard; and
a medium- or small-sized display device, the medium- or small-sized display device including at least one of a computer, a laptop computer, a personal digital assistant, a vehicular display device, a game console, a portable electronic device, or a camera.

16. A fused polycyclic compound represented by Formula 1: 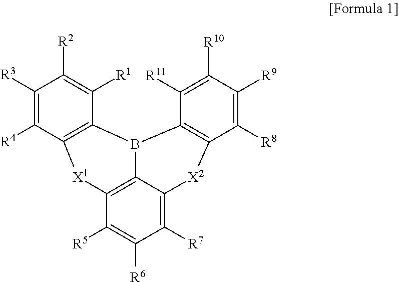
wherein, in Formula 1,
R¹ to R¹¹ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to each other to form a ring,
a continuous two or three selected from each of R¹ to R⁴ and R⁸ to R¹¹ are each connected to a separate group represented by Formula 2, such that the fused polycyclic compound includes two separate groups that are each represented by Formula 2, one of the two separate groups is connected to a continuous two or three of R¹ to R⁴ of Formula 1, and another one of the two separate groups is connected to a continuous two or three of R¹ to R¹¹ of Formula 1, and
X¹ and X² are each independently O, S, or Se, or represented by any one among Formula 3 to Formula 5: 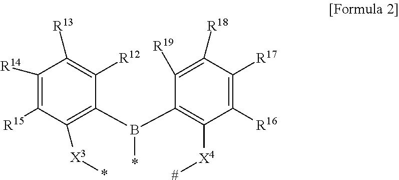
wherein, in Formula 2,
R¹² to R¹⁹ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to each other to form a ring,
X³ and X⁴ are each independently O, S, or Se, or represented by Formula 3 to Formula 5, [symbol]
is a position to which Formula 1 is connected, and [symbol]
is a position to which Formula 1 is connected or R¹² in Formula 2 is connected: 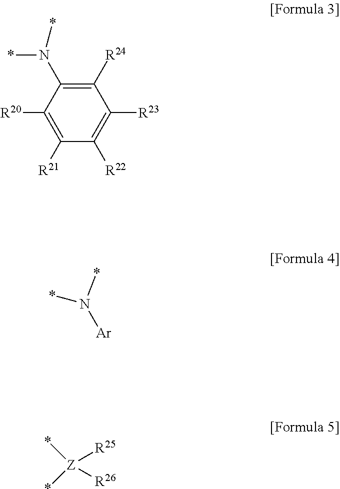
wherein, in Formula 3 to Formula 5, [symbol]
is a position to which Formula 2 or Formula 3 is connected,
R²⁰ to R²⁶ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
at least one among R²⁰ or R²⁴ is a substituted or unsubstituted aryl group having 6 to 30 ring-forming carbon atoms,
Ar is a substituted or unsubstituted aryl group having 10 to 30 ring-forming carbon atoms,
Z is a carbon atom or a silicon atom, wherein when Z is a silicon atom, R²⁵ and R²⁶ are not hydrogen atoms, and
at least one among X¹ to X⁴ is represented by Formula 3,
wherein, when X¹ and X² in Formula 1 are represented by Formula 4, Ar in Formula 4 is not a fluorenyl group or a heteroaryl group, and
wherein, when at least one of X¹ or X² in Formula 1 is represented by Formula 3, at least one of R²⁰ or R²⁴ in Formula 3 is a substituted or unsubstituted aryl group having 6 to 30 ring-forming carbon atoms.

17. The fused polycyclic compound of claim 16, wherein the fused polycyclic compound represented by Formula 1 is represented by Formula 1-1-1 or Formula 1-1-2: 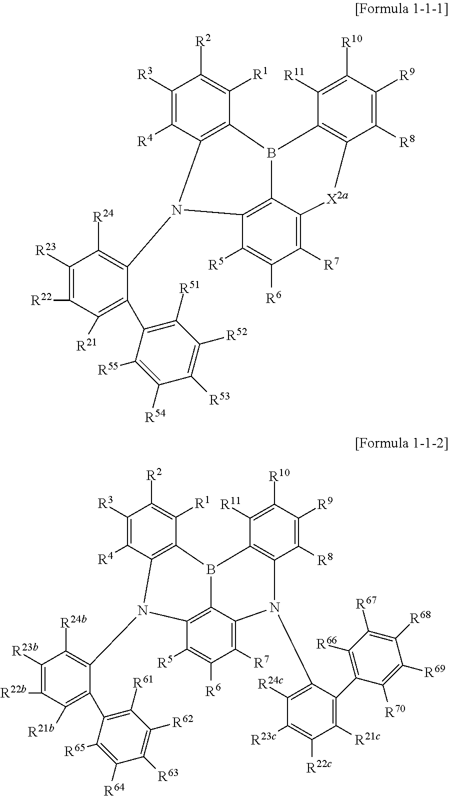
wherein, in Formula 1-1-1 and Formula 1-1-2,
X^{2a} is O, S, or Se, or represented by Formula 4 or Formula 5,
R^{24a} is a substituted or unsubstituted aryl group having 6 to 30 ring-forming carbon atoms,
R⁵¹ to R⁵⁵, R⁶¹ to R⁷⁰, R^{21b} to R^{24b}, and R^{21c} to R^{24c} are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
R¹ to R¹¹ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to each other to form a ring.

18. The fused polycyclic compound of claim 16, wherein the fused polycyclic compound represented by Formula 1 above is represented by Formula 1-2: 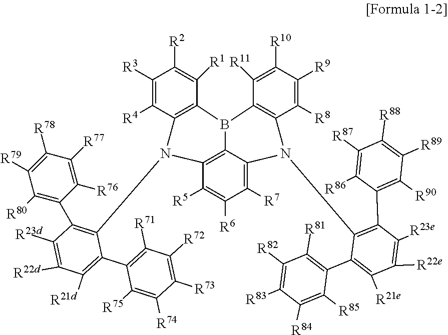
where in Formula 1-2,
R⁷¹ to R⁹⁰, R^{21d} to R^{23d}, and R^{21e} to R^{23e} are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
R¹ to R¹¹ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to each other to form a ring.

19. The fused polycyclic compound of claim 16, wherein the fused polycyclic compound represented by Formula 1 above is represented by any one among Formula 1-4-1 to Formula 1-4-3 below: 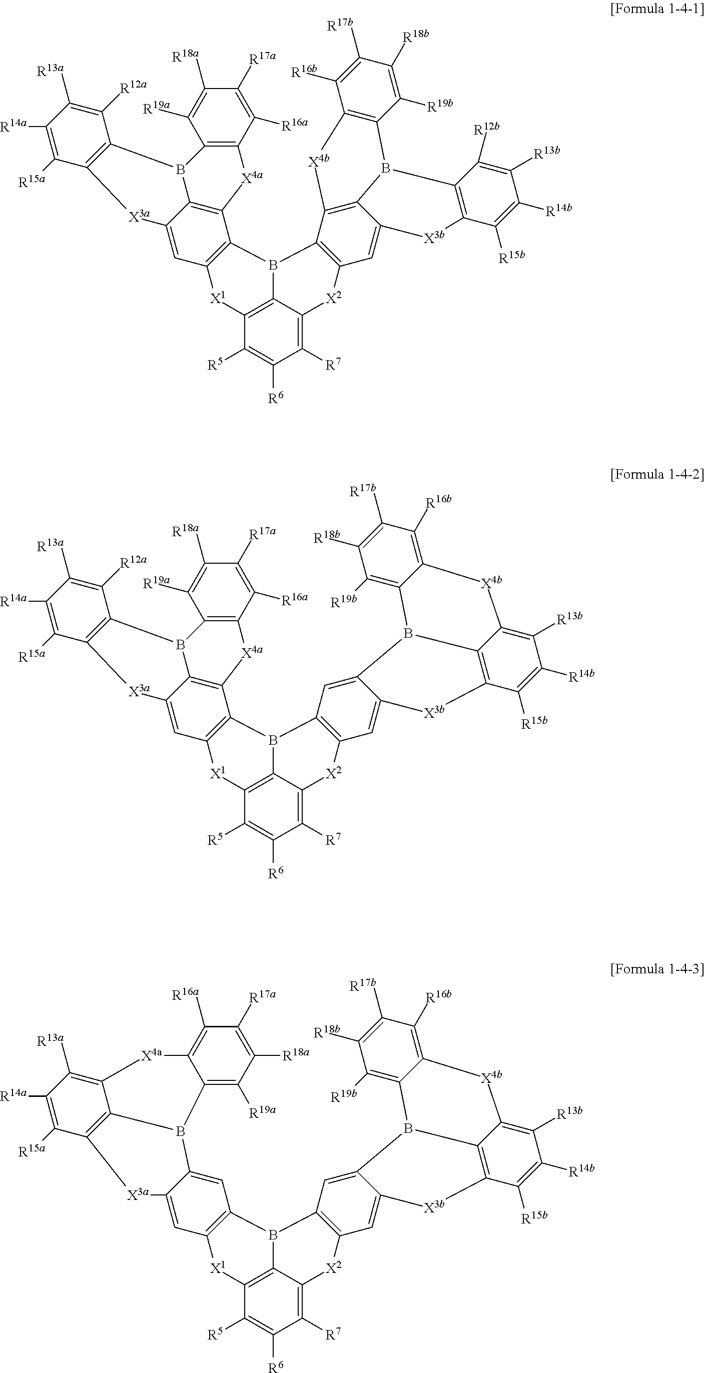
wherein, in Formula 1-4-1 to Formula 1-4-3,
X^{3a}, X^{3b}, X^{4a}, and X^{4b} are each independently O, S, or Se, or represented by any one among Formula 3 to Formula 5 above,
R^{12a} to R^{19a}, and R^{12b} to R^{19b} are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
X¹ and X² are each independently O, S, or Se, or represented by any one among Formula 3 to Formula 5, and
R⁵ to R⁷ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to each other to form a ring.

20. The fused polycyclic compound of claim 16, wherein the fused polycyclic compound represented by Formula 1 includes at least one among Compounds 1 to 51 in Compound Group 1: 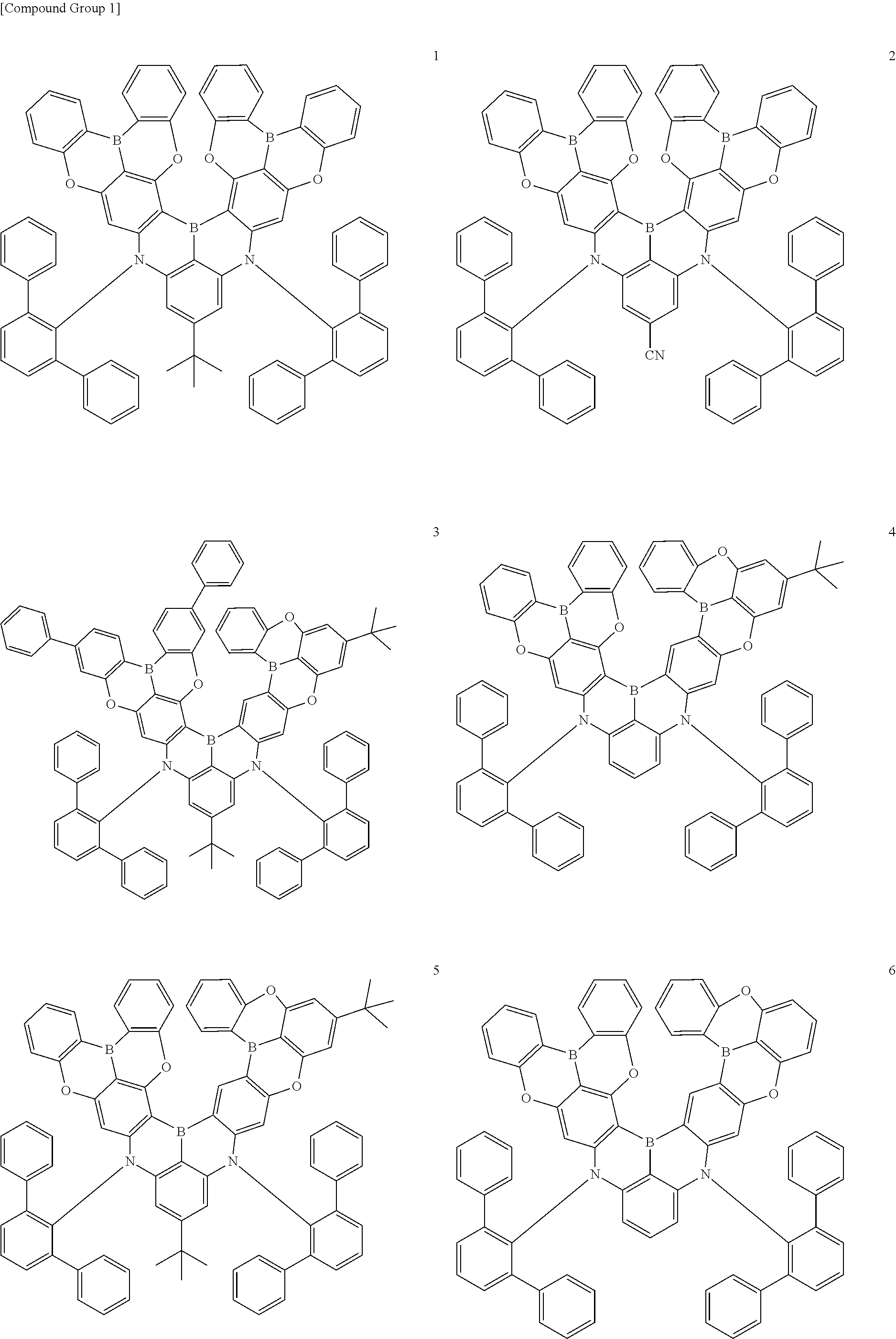 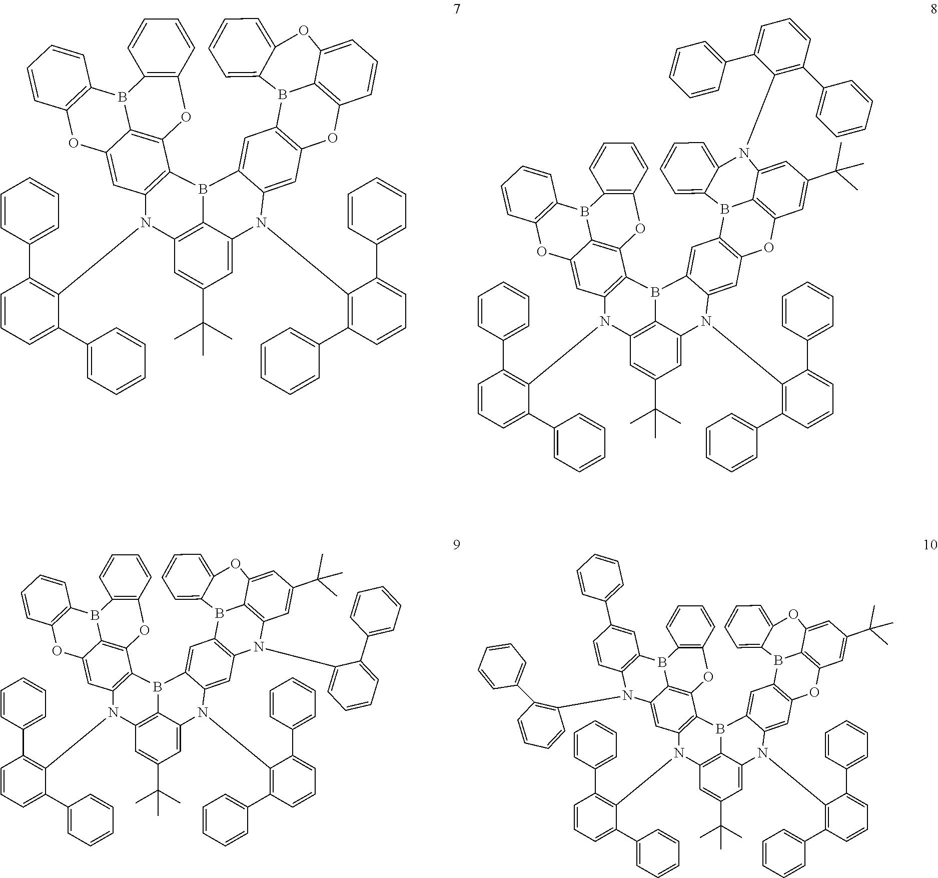 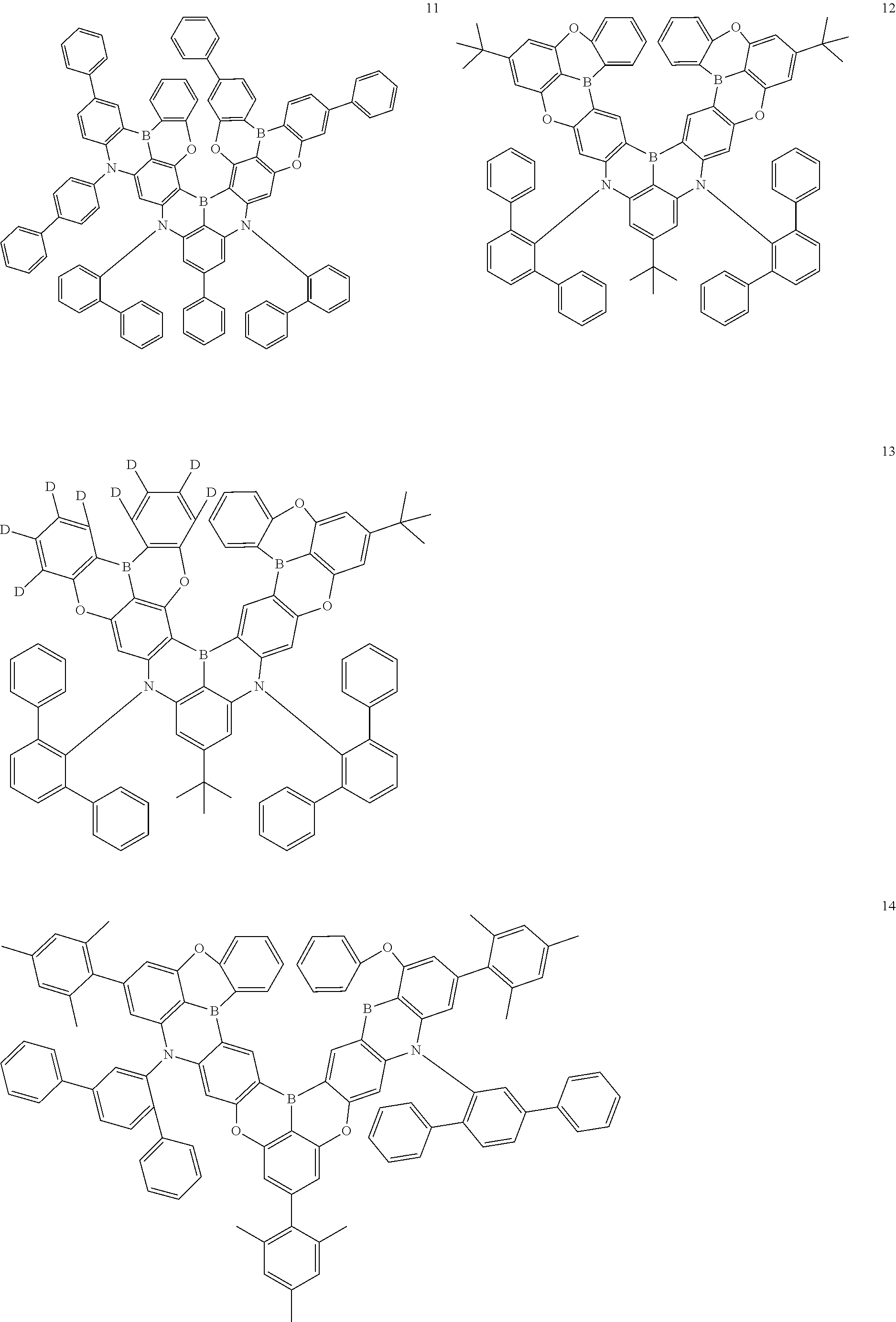 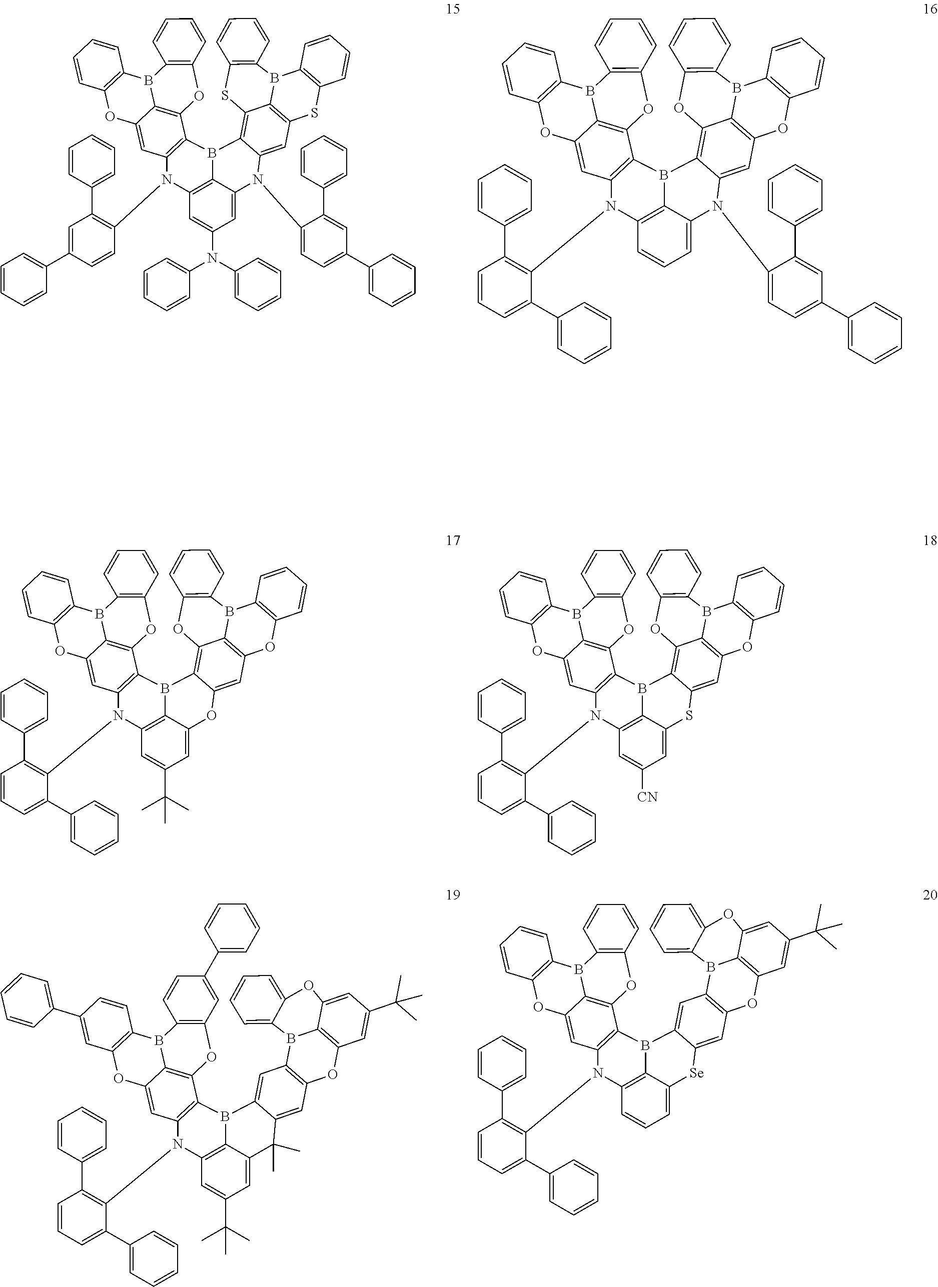 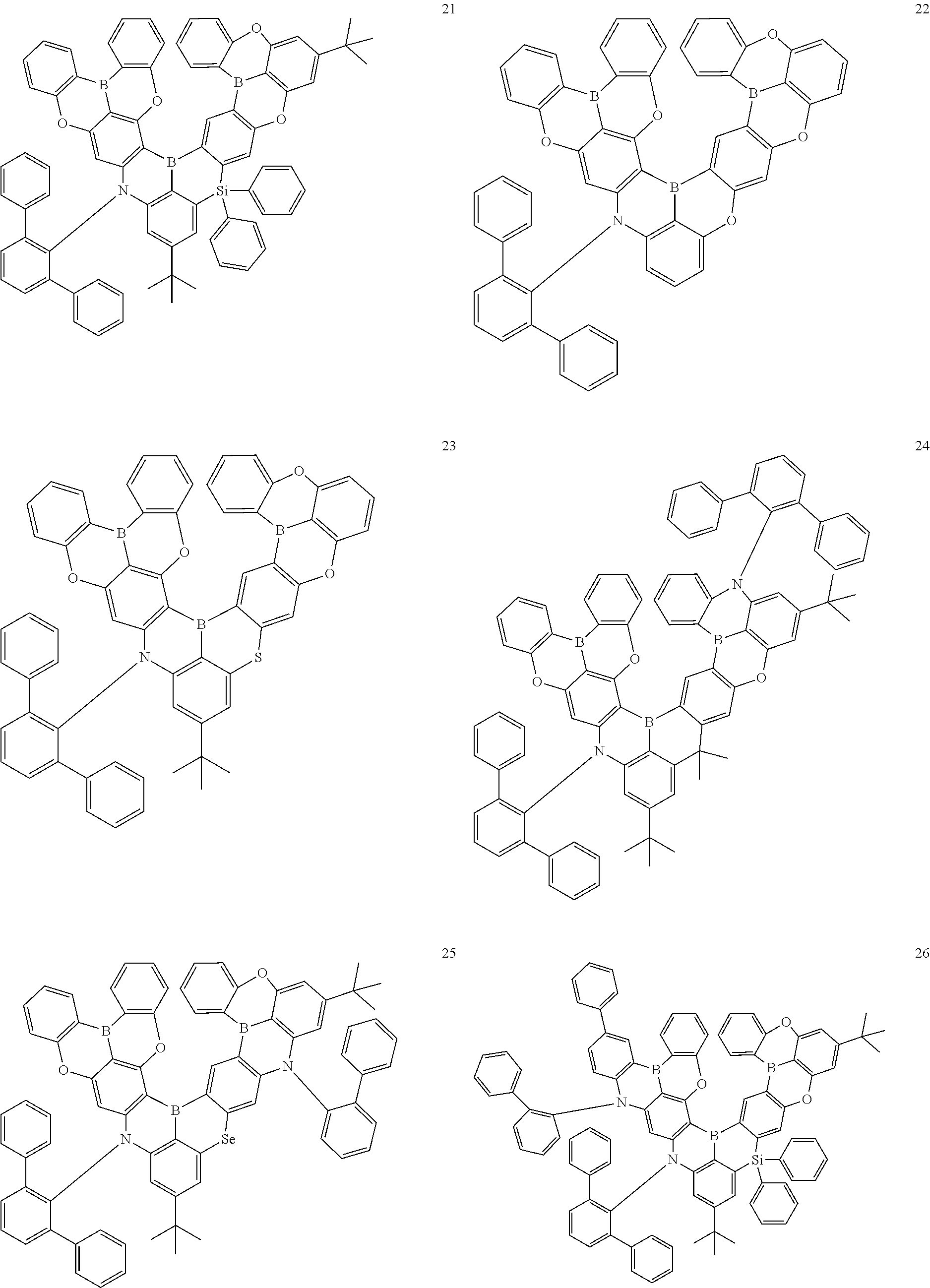 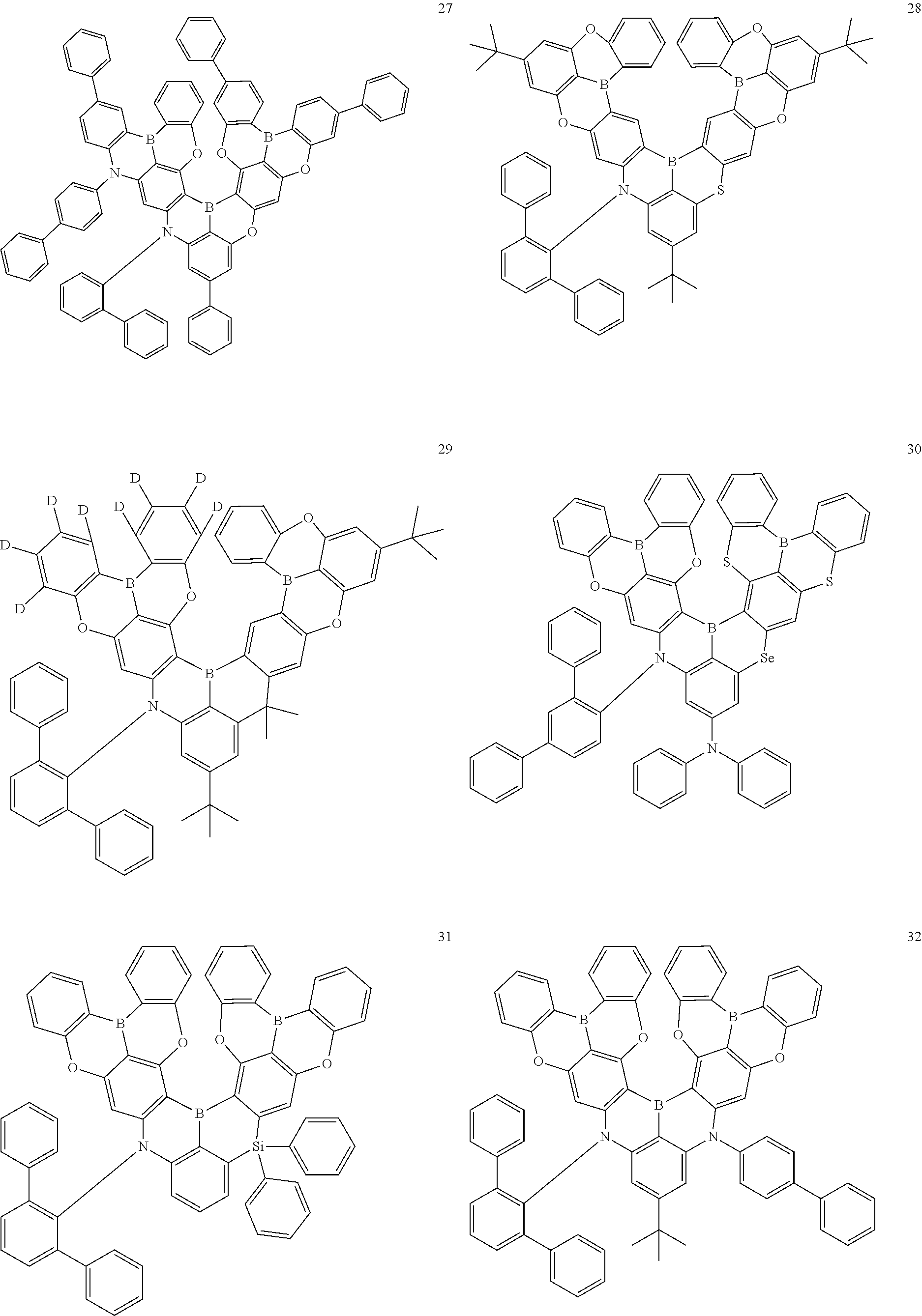 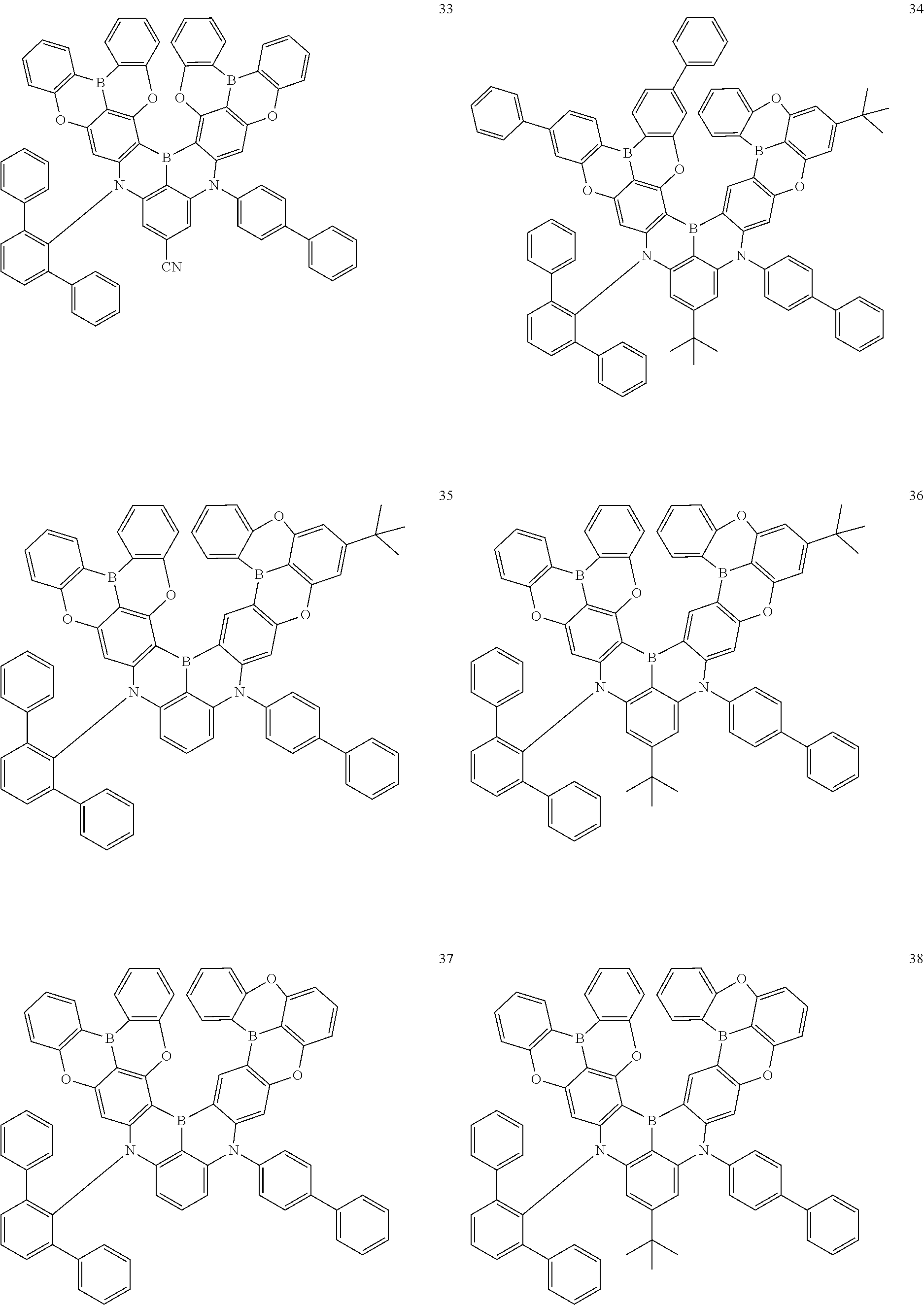 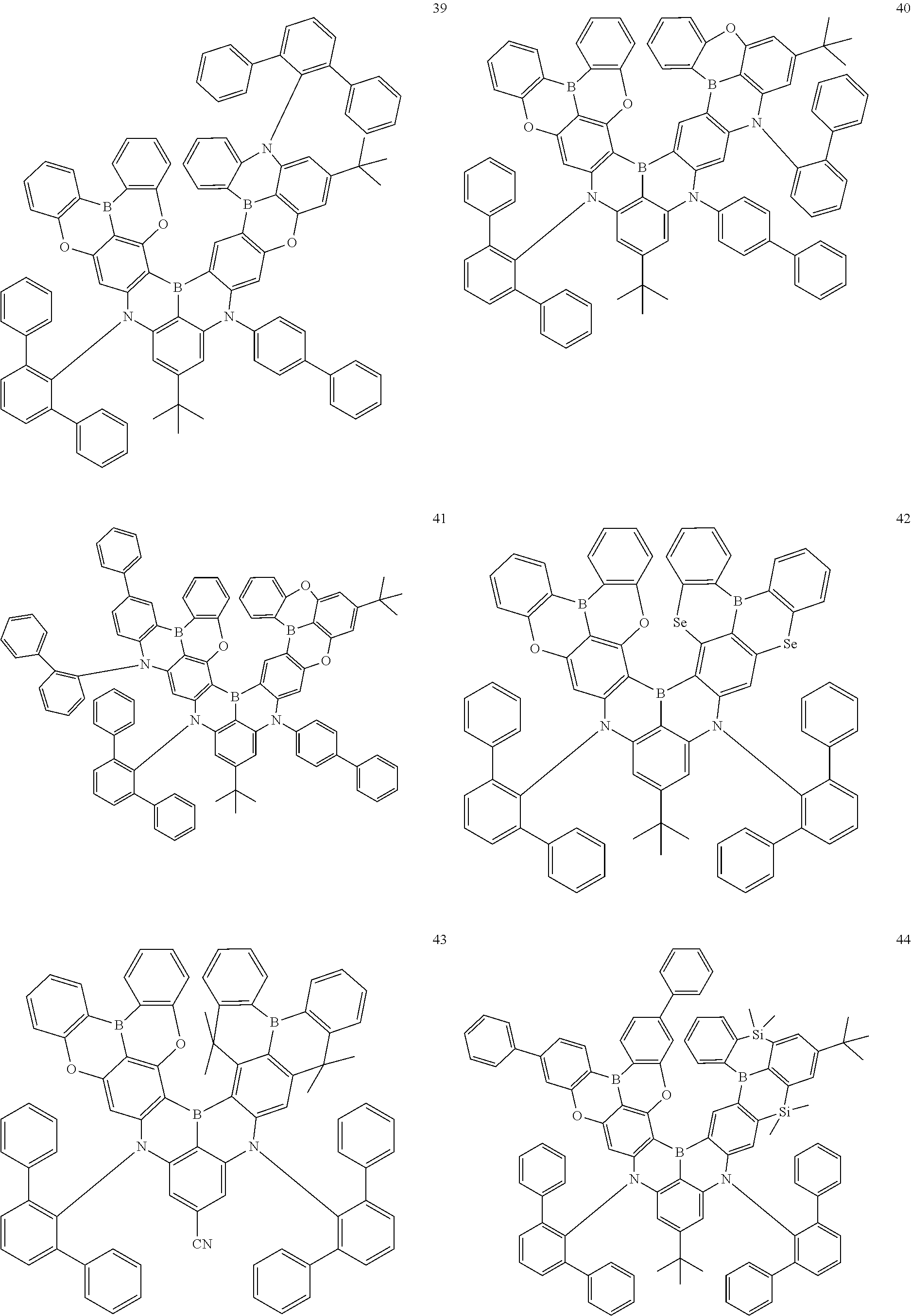 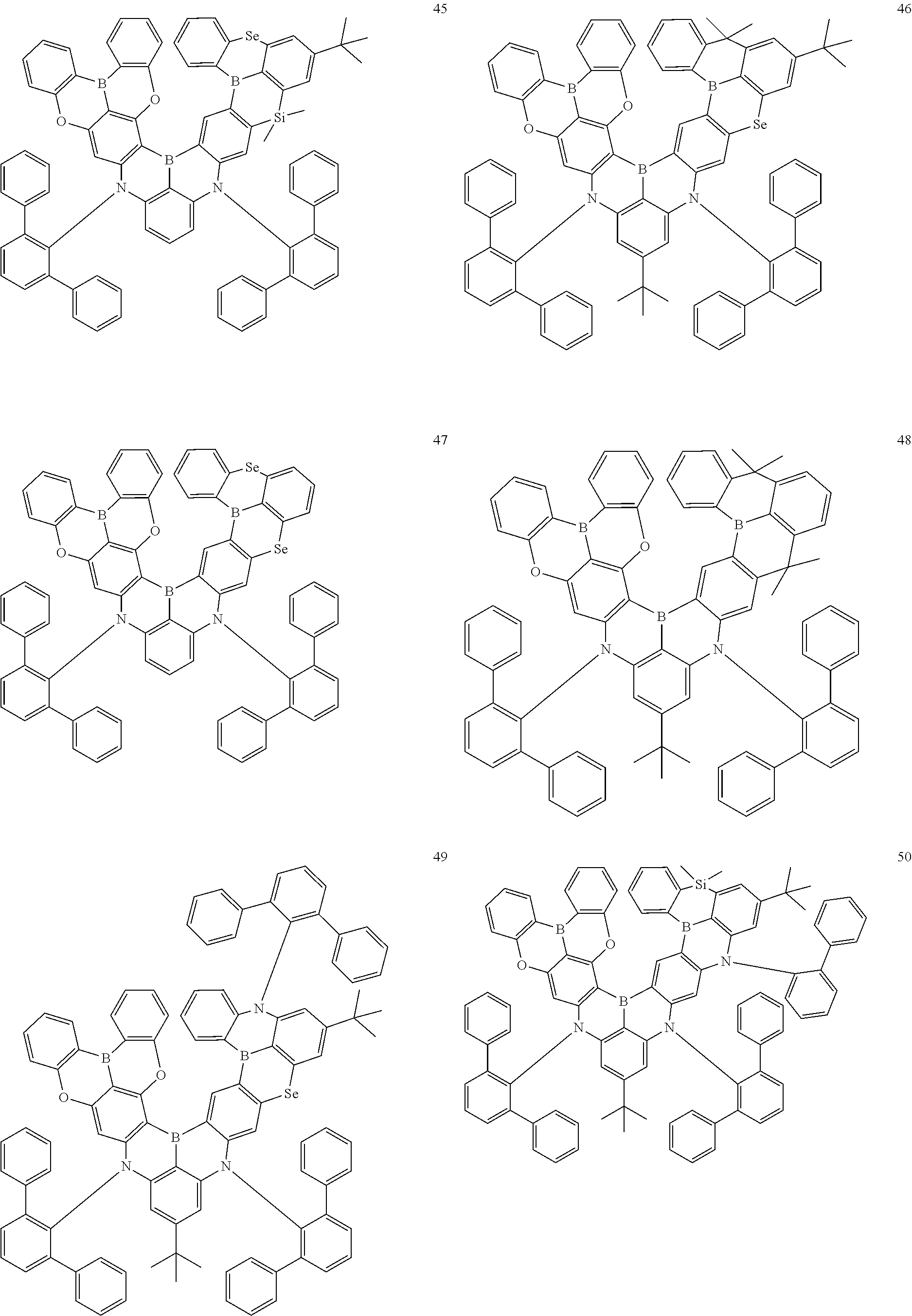 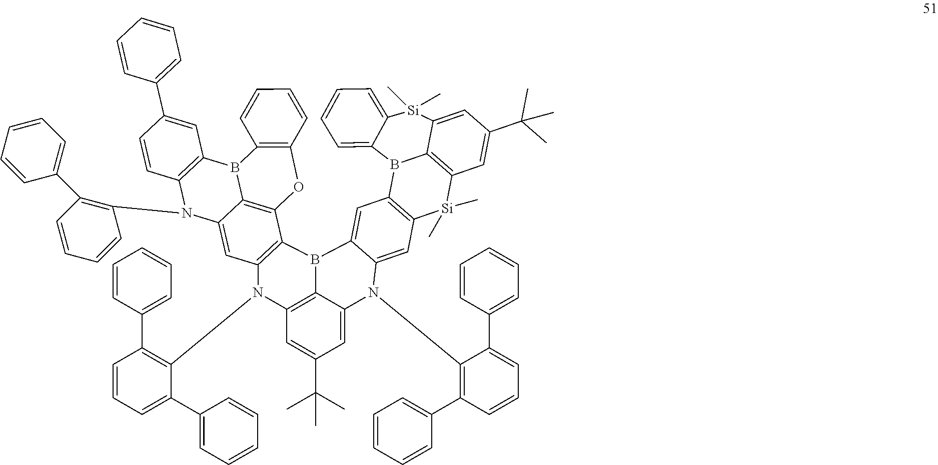 [SMILES: CC(C)(C)c1cc2c3c(c1)N(c1c(-c4ccccc4)cccc1-c1ccccc1)c1cc4c5c(c1B3c1cc3c(cc1N2c1c(-c2ccccc2)cccc1-c1ccccc1)[Si](C)(C)c1cc(C(C)(C)C)cc2c1B3c1ccccc1[Si]2(C)C)Oc1ccccc1B5c1cc(-c2ccccc2)ccc1N4c1ccccc1-c1ccccc1]
